(19) United States
(12) Patent Application Publication
(10) Pub. No.: US 2026/0003275 A1
(43) Pub. Date: Jan. 1, 2026

(54) RESIST COMPOSITION AND PATTERN FORMING PROCESS

(71) Applicant: Shin-Etsu Chemical Co., Ltd., Tokyo (JP)

(72) Inventors: Yutaro Otomo, Joetsu-shi (JP); Takahiro Suzuki, Joetsu-shi (JP); Kazuhiro Katayama, Joetsu-shi (JP); Takeshi Sasami, Joetsu-shi (JP); Tatsuya Suzuki, Joetsu-shi (JP); Yoshihiro Tsuji, Joetsu-shi (JP)

(73) Assignee: Shin-Etsu Chemical Co., Ltd., Tokyo (JP)

(21) Appl. No.: 19/242,079

(22) Filed: Jun. 18, 2025

(30) Foreign Application Priority Data
Jun. 26, 2024 (JP) 2024-103110

(51) Int. Cl. G03F 7/038; G03F 7/20

(52) U.S. Cl. CPC G03F 7/038; G03F 7/2053

(57) ABSTRACT

A resist composition comprising a base polymer comprising repeat units consisting of an iodized carboxylic acid anion bonded to the backbone and an organic cation and repeat units consisting of an iodized sulfonic acid anion bonded to the backbone and a sulfonium cation has a high sensitivity and resolution. A pattern of satisfactory profile with reduced LWR and improved CDU is formed therefrom.

### CROSS-REFERENCE TO RELATED APPLICATION

This non-provisional application claims priority under 35 U.S.C. § 119 (a) on Patent Application No. 2024-103110 filed in Japan on Jun. 26, 2024, the entire contents of which are hereby incorporated by reference.

### TECHNICAL FIELD

This invention relates to a resist composition and a pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-but-one generation.

As the feature size reduces, image blurs due to acid diffusion become a problem. To insure resolution for fine patterns with a size of 45 nm et seq., not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

A triangular tradeoff relationship among sensitivity, resolution, and line width roughness (LWR) of line patterns has been pointed out. Specifically, a resolution improvement requires to suppress acid diffusion whereas a short acid diffusion distance leads to a decline of sensitivity.

The addition of an acid generator capable of generating a bulky acid is an effective means for suppressing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond, capable of generating a specific sulfonic acid. Patent Document 2 discloses a sulfonium salt having a sulfonic acid directly attached to the backbone.

To restrain acid diffusion, Patent Documents 3 to 5 disclose resist compositions comprising a base polymer comprising repeat units derived from a polymerizable group-containing sulfonium salt of a weak acid having a pKa of −0.8 or larger wherein the base polymer functions as a polymer-bound quencher. In Patent Document 3, carboxylic acid, sulfonamide, phenol, and hexafluoroalcohol compounds are exemplified as the weak acid.

### CITATION LIST

Patent Document 1: JP-A 2006-045311 (U.S. Pat. No. 7,482,108)
Patent Document 2: JP-A 2006-178317
Patent Document 3: WO 2019/167737
Patent Document 4: WO 2022/264845
Patent Document 5: JP-A 2022-115072
Non-Patent Document 1: SPIE Vol. 6520 65203L-1 (2007)

### DISCLOSURE OF INVENTION

An object of the invention is to provide a resist composition which exhibits a high sensitivity and resolution surpassing prior art resist compositions, and forms patterns of satisfactory profile after exposure with reduced LWR and improved CDU, and a pattern forming process using the same.

For meeting the current demand for a resist material exhibiting a high resolution, reduced LWR and improved CDU, it is necessary to minimize the distance of acid diffusion and to uniform the acid concentration in a resist film of the exposed region. The inventor has found that the object is attained by a base polymer comprising repeat units consisting of an iodized carboxylic acid anion bonded to the backbone and an organic cation and repeat units consisting of an iodized sulfonic acid anion bonded to the backbone and a sulfonium cation.

When repeat units having a carboxy group or phenolic hydroxy group whose hydrogen is substituted by an acid labile group are further incorporated in the polymer, the polymer is improved in dissolution contrast. There is obtained a resist composition which exhibits a high sensitivity, a considerably high contrast of alkali dissolution rate before and after exposure, a significant acid diffusion suppressing effect, a high resolution, and forms a pattern of satisfactory profile after exposure, with reduced LWR and improved CDU. The resist composition is suitable as a small-size pattern forming material for the preparation of VLSIs and photomasks.

In one aspect, the invention provides a resist composition comprising a base polymer comprising repeat units having the formula (a) and repeat units having the formula (b) and an organic solvent.

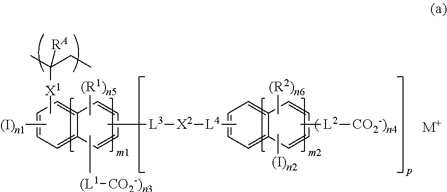

Herein p is 0 or 1, m1 and m2 are each independently 0 or 1,
n1 is 1, 2, 3 or 4 when p=0, n1 and n2 are each independently 0, 1, 2, 3 or 4 and n1+n2≥1 when p=1,
n3 is 1 when p=0, n3 and n4 are each independently 0 or 1 and n3+n4=1 when p=1,
n5 and n6 are each independently 0, 1, 2, 3 or 4,
R^{A} is hydrogen or methyl,
X¹ is a single bond or —C(═O)—O—X¹¹—, X¹¹ is a C₁-C₆ alkanediyl group,
X² is a single bond or C₁-C₆ alkanediyl group,
L¹ is a single bond or a C₁-C₁₂ linking group which contains at least one of ester bond and ether bond and may contain a heteroatom-containing group other than ester bond and ether bond,
L² and L³ are each independently a single bond, ether bond or ester bond,
R¹ and R² are each independently halogen, hydroxy, amino, nitro, a C₁-C₁₂ saturated hydrocarbyloxy group, or an optionally-substituted C₁-C₁₂ organic group which may contain at least one of ester bond and ether bond, a plurality of R¹ may be identical or different when n5 is 2 or more, a plurality of R² may be identical or different when n6 is 2 or more,
M⁺ is a monovalent organic cation.

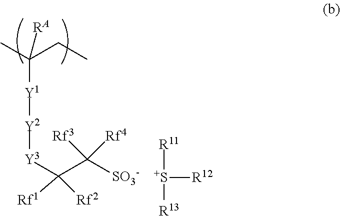

Herein R^{A} is each independently hydrogen or methyl,
Y¹ is a single bond or ester bond,
Y² is —Y²¹_C(═O)—O— or —Y²¹—O—, Y²¹ is a C₁-C₁₂ hydrocarbylene group, phenylene, naphthylene or a C₇-C₁₈ group obtained by combining the foregoing, which contains at least one iodine atom and may contain a carbonyl moiety, ester bond, ether bond, lactone ring, fluorine or bromine,
Y³ is a single bond, methylene group or ethylene group,
Rf¹ to Rf⁴ are each independently hydrogen, fluorine, or trifluoromethyl, at least one of Rf¹ to Rf⁴ being fluorine,
R¹¹, R¹² and R¹³ are each independently halogen or a C₁-C₂₀ hydrocarbyl group which may contain a heteroatom, R¹¹ and R¹² may bond together to form a ring with the sulfur atom to which they are attached.

Preferably, L¹ is a single bond, and X¹ is a single bond.

In a preferred embodiment, M⁺ is a cation having the formula (M-1), (M-2) or (M-3):

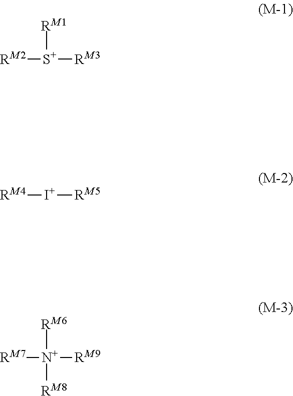

wherein R^{M1} to R^{M9} are each independently halogen or a C₁-C₂₀ hydrocarbyl group which may contain a heteroatom, R^{M1} and R^{M2} may bond together to form a ring with the sulfur atom to which they are attached, any two of R^{M6} to R^{M9} may bond together to form a ring with the nitrogen atom to which they are attached.

Also preferably, R¹ is hydroxy or a C₁-C₁₂ saturated hydrocarbyloxy group.

In a preferred embodiment, the base polymer further comprises repeat units of at least one type selected from repeat units having the formula (c1) and repeat units having the formula (c2).

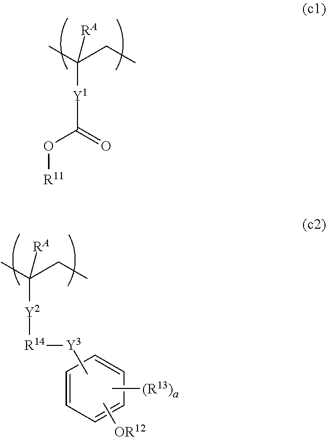

Herein R^{A} is each independently hydrogen or methyl,
Z¹ is a single bond, phenylene group, naphthylene group or a C₁-C₁₂ linking group which contains at least one of ester bond, ether bond and lactone ring,
Z² is a single bond, ester bond or amide bond,
Z³ is a single bond, ether bond or ester bond,
R²¹ and R²² are each independently an acid labile group,
R²³ is fluorine, trifluoromethyl, cyano or a C₁-C₆ saturated hydrocarbyl group,
R²⁴ is a single bond or a C₁-C₆ alkanediyl group in which some —CH₂— may be replaced by an ether bond or ester bond,
a is 1 or 2, and b is 0, 1, 2, 3 or 4.

In a preferred embodiment, the base polymer further comprises repeat units (d) containing an adhesive group selected from hydroxy, carboxy, lactone ring, carbonate bond, thiocarbonate bond, carbonyl group, cyclic acetal group, ether bond, ester bond, sulfonate ester bond, cyano, amide bond, —O—C(═O)—S—, and —O—C(═O)—NH—.

The resist composition may further comprise at least one additive selected from an acid generator, quencher, and surfactant.

Preferably the resist composition comprises a quencher. Typically the quencher has the formula (1):

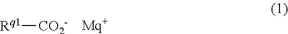

wherein R^{q1} is a C₁-C₃₀ hydrocarbyl group which may contain a heteroatom, and Mq⁺ is a monovalent organic cation.

In another aspect, the invention provides a pattern forming process comprising the steps of applying the resist composition defined above onto a substrate to form a resist film thereon, exposing the resist film to high-energy radiation, and developing the exposed resist film in a developer.

Typically, the high-energy radiation is i-line, KrF excimer laser, ArF excimer laser, EB or EUV of wavelength 3 to 15 nm.

### Advantageous Effects of Invention

According to the invention, there is constructed a resist composition which exhibits a high sensitivity and resolution surpassing prior art resist compositions, and forms patterns of satisfactory profile after exposure with reduced LWR and improved CDU.

### DESCRIPTION OF EMBODIMENTS

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In chemical formulae, Me stands for methyl, Et for ethyl, Ac for acetyl, and the broken line ( - - - ) designates a point of attachment or valence bond. As used herein, the term “iodized” refers to a iodine-substituted or iodine-containing compound or group. The terms “group” and “moiety” are interchangeable.

The abbreviations and acronyms have the following meaning.
EB: electron beam
EUV: extreme ultraviolet
Mw: weight average molecular weight
Mn: number average molecular weight
Mw/Mn: molecular weight distribution or dispersity
GPC: gel permeation chromatography
PEB: post-exposure bake
PAG: photoacid generator
LWR: line width roughness
CDU: critical dimension uniformity

### Resist Composition

One embodiment of the invention is a resist composition comprising a base polymer comprising repeat units (a) consisting of an iodized carboxylic acid anion bonded to the backbone and an organic cation and repeat units (b) consisting of an iodized sulfonic acid anion bonded to the backbone and a sulfonium cation.

### Base Polymer

The repeat unit (a) has the formula (a).

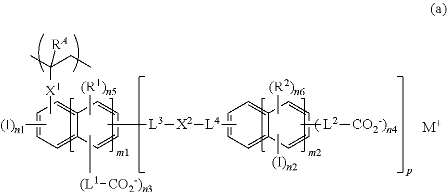

In formula (a), p is 0 or 1, m1 and m2 are each independently 0 or 1. When p=0, n1 is 1, 2, 3 or 4, preferably 1 or 2. When p=1, n1 and n2 are each independently 0, 1, 2, 3 or 4 and n1+n2≥1, preferably n1+n2 is 1 or 2. When p=0, n3 is 1. When p=1, n3 and n4 are each independently 0 or 1, and n3+n4=1. The subscripts n5 and n6 are each independently 0, 1, 2, 3 or 4, preferably 0 or 1.

In formula (a), R^{A} is hydrogen or methyl, with hydrogen being preferred.

In formula (a), X¹ is a single bond or —C(═O)—O—X¹¹—. X¹¹ is a C₁-C₆ alkanediyl group. Examples of the alkanediyl group include methanediyl, ethane-1,1-diyl, ethane-1,2-diyl, propane-1,3-diyl, butane-1,4-diyl, pentane-1,5-diyl, and hexane-1,6-diyl. X¹ is preferably a single bond. When X¹ is a single bond, a resist film having superior etching resistance can be formed.

In formula (a), X² is a single bond or C₁-C₆ alkanediyl group. Examples of the alkanediyl group are as exemplified above for the alkanediyl group X¹¹.

In formula (a), L¹ is a single bond or a C₁-C₁₂ linking group containing at least one of ester bond and ether bond. The linking group may contain a heteroatom-containing group other than ester bond and ether bond. L¹ is preferably a single bond. When L¹ is a single bond, a resist film having superior heat resistance and etching resistance can be formed.

When both X¹ and L¹ are a single bond, a polymer having repeat units (a) incorporated therein is effective for suppressing the mobility of side chains. It is then expected that the image blur by material diffusion is reduced.

In formula (a), L² and L³ are each independently a single bond, ether bond or ester bond.

In formula (a), R¹ and R² are each independently halogen, hydroxy, amino, nitro, a C₁-C₁₂ saturated hydrocarbyloxy group, or an optionally-substituted C₁-C₁₂ organic group which may contain at least one of ester bond and ether bond. Exemplary of the saturated hydrocarbyloxy group are methoxy, ethoxy, propoxy, butoxy, hexyloxy, octyloxy, and dodecyloxy. Examples of the optionally-substituted C₁-C₁₂ organic group include —O—C(═O)—RX, —O—CH₂—CH₂—O—R^{x}, and —C(═O)—O—R^{x} wherein R^{x} is phenyl, iodophenyl, diiodophenyl, hydroxyphenyl, or methoxyphenyl. R¹ and R² each are preferably hydroxy or a C₁-C₁₂ saturated hydrocarbyloxy group. When R¹ and R² each are hydroxy or a C₁-C₁₂ saturated hydrocarbyloxy group, the acid diffusion controlling effect is enhanced so that reduced LWR and improved CDU may be achieved. When n5 is 2 or more, a plurality of R¹ may be identical or different. When n6 is 2 or more, a plurality of R² may be identical or different.

Examples of the anion in the monomer from which repeat units (a) are derived are shown below, but not limited thereto. Herein R^{A} is as defined above.

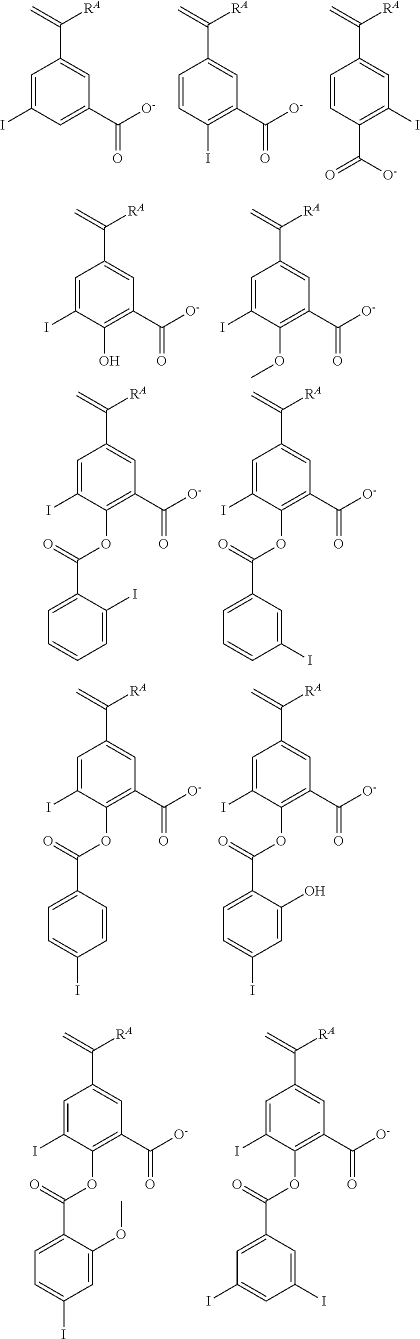

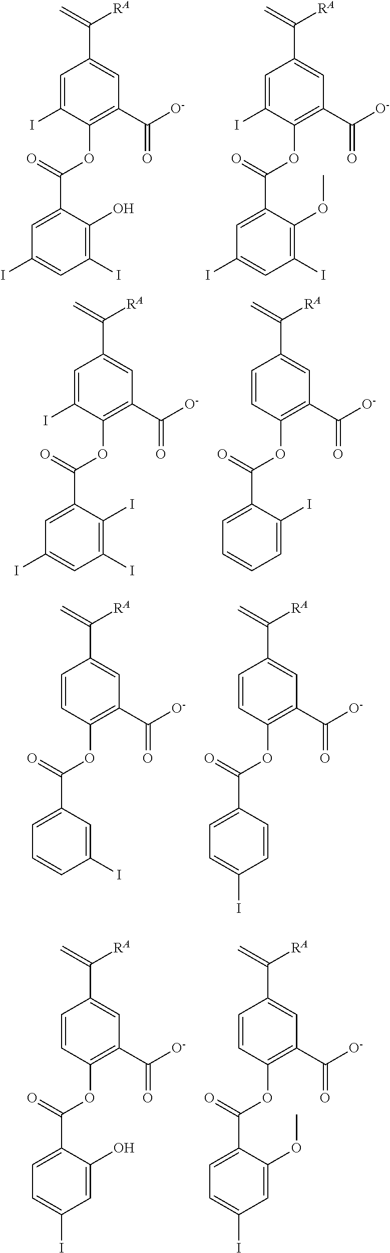

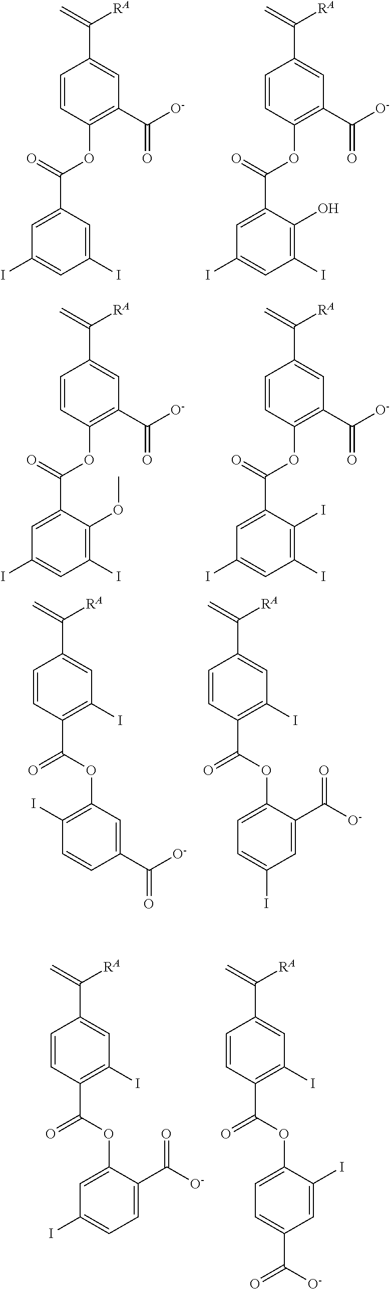

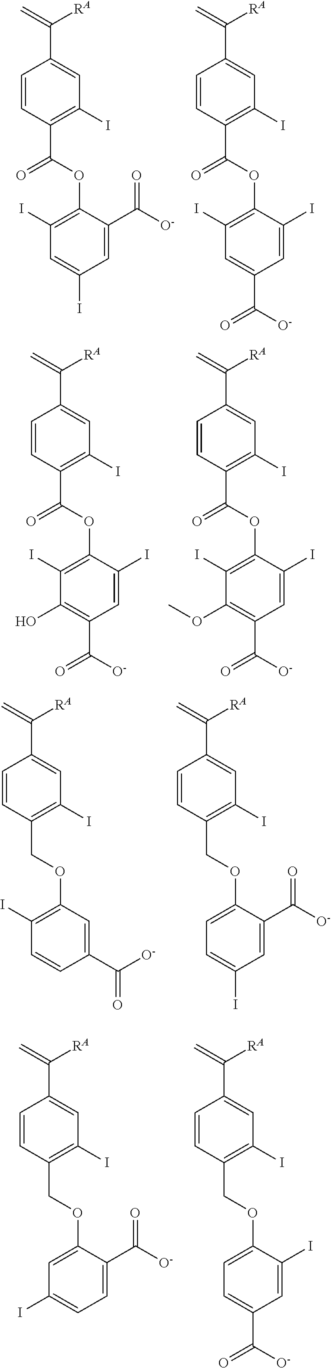

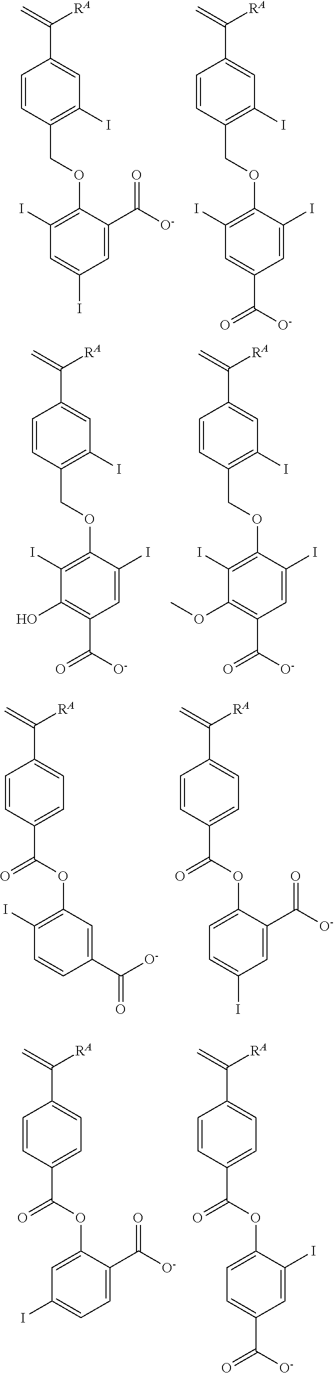

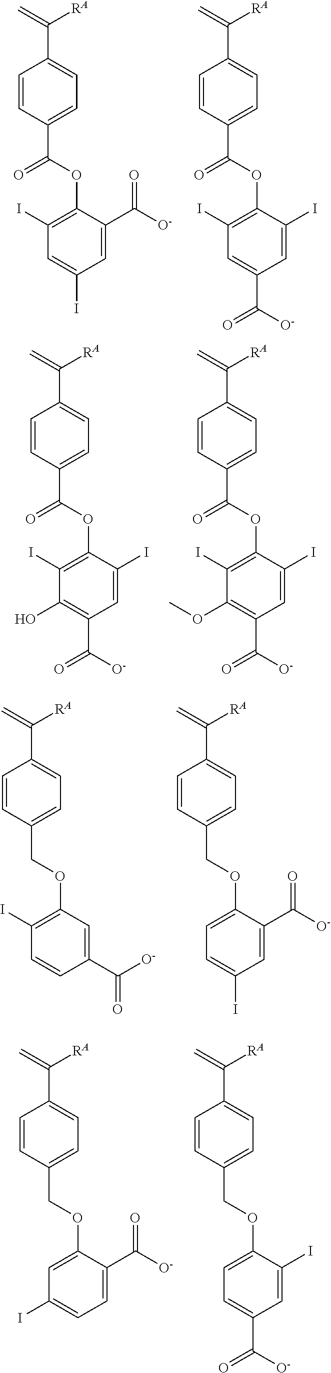

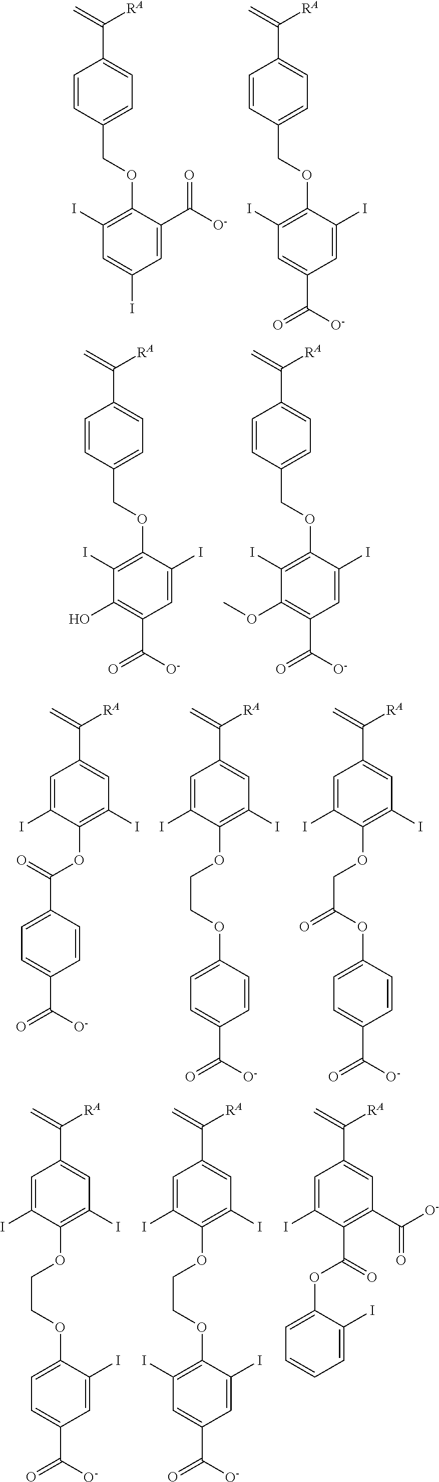

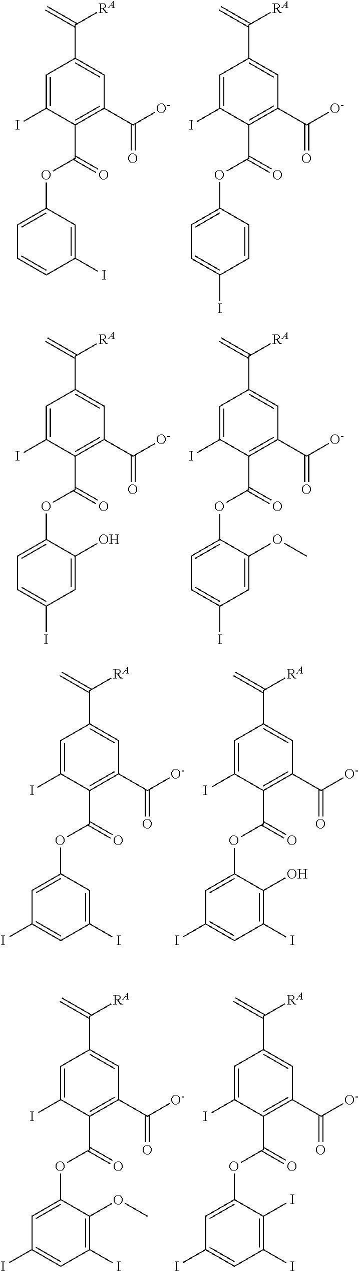

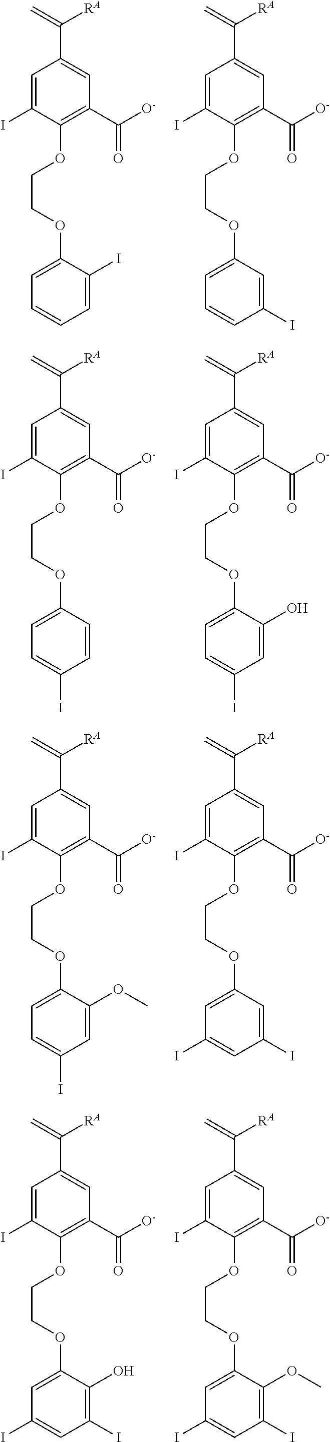

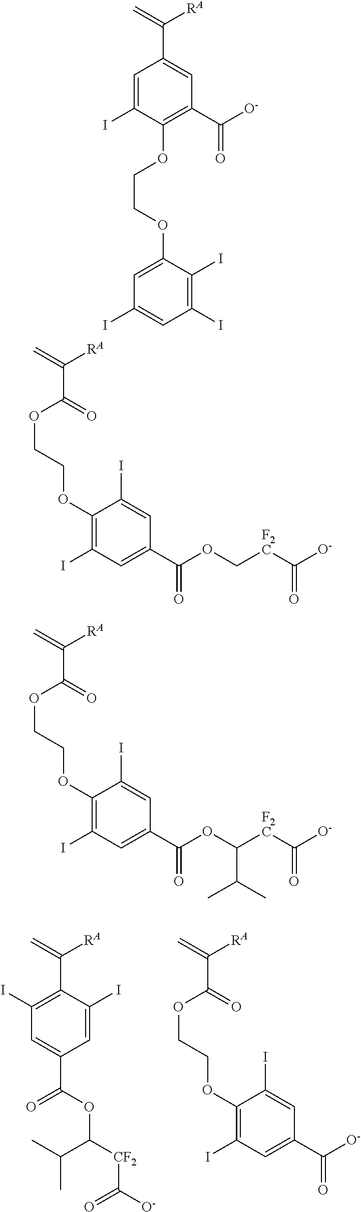

In formula (a), M⁺ is a monovalent organic cation. The organic cation is preferably selected from sulfonium cations having the formula (M-1), iodonium cations having the formula (M-2), and ammonium cations having the formula (M-3).

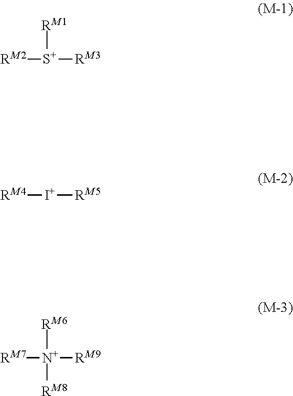

In formulae (M-1) to (M-3), R^{M1} to R^{M9} are each independently halogen or a C₁-C₂₀ hydrocarbyl group which may contain a heteroatom.

Suitable halogen atoms include fluorine, chlorine, bromine, and iodine.

The C₁-C₂₀ hydrocarbyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl and icosyl; C₃-C₂₀ cyclic saturated hydrocarbyl groups such as cyclopropyl, cyclopentyl, cyclohexyl, cylopropylmethyl, 4-methylcyclohexyl, cyclohexylmethyl, norbornyl, and adamantyl; C₂-C₂₀ alkenyl groups such as vinyl, allyl, propenyl, butenyl, and hexenyl; C₂-C₂₀ alkynyl groups such as ethynyl, propynyl and butynyl; C₃-C₂₀ cyclic unsaturated aliphatic hydrocarbyl groups such as cyclohexenyl and norbornenyl; C₆-C₂₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, and tert-butylnaphthyl; C₇-C₂₀ aralkyl groups such as benzyl and phenethyl, and combinations thereof.

In the foregoing hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, mercapto moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

Also, R^{M1} and R^{M2} may bond together to form a ring with the sulfur atom to which they are attached. Exemplary structures of the ring are shown below.

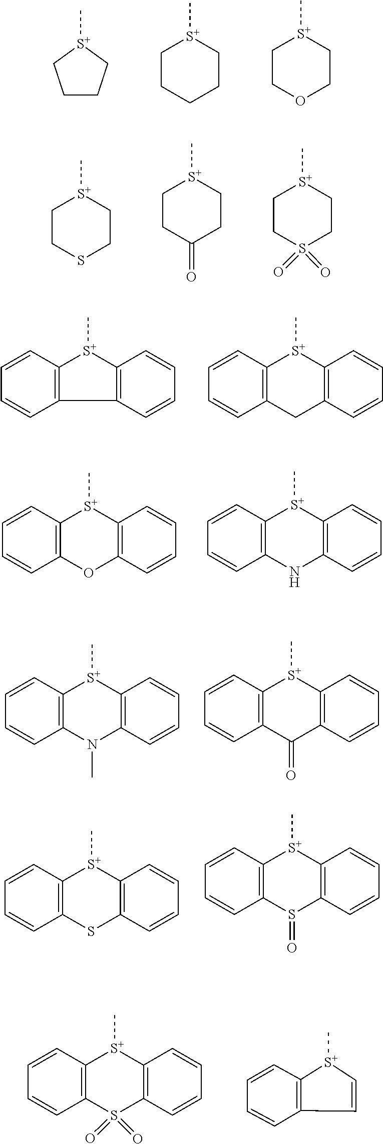

Any two of R^{M6} to R^{M9} may bond together to form a ring with the nitrogen atom to which they are attached.

Of the cations in repeat units (a), sulfonium cations having formula (M-1) are preferred.

Examples of the cation in repeat unit (a) are shown below, but not limited thereto.

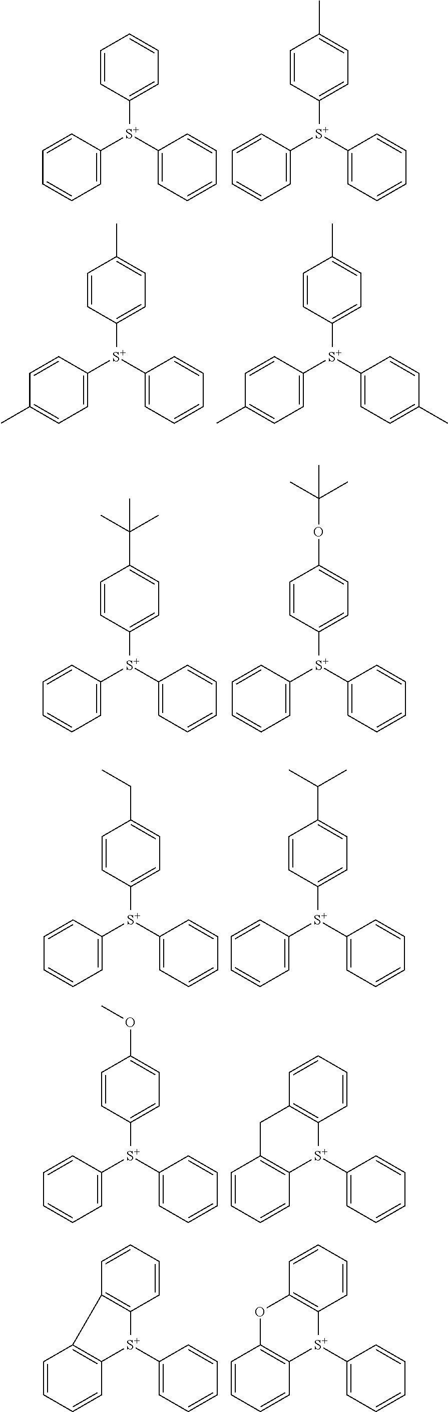

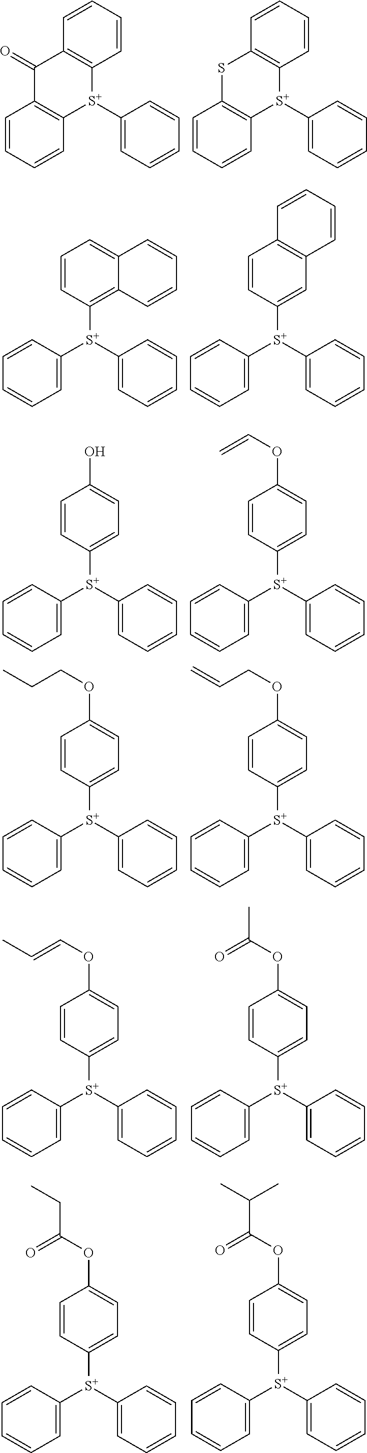

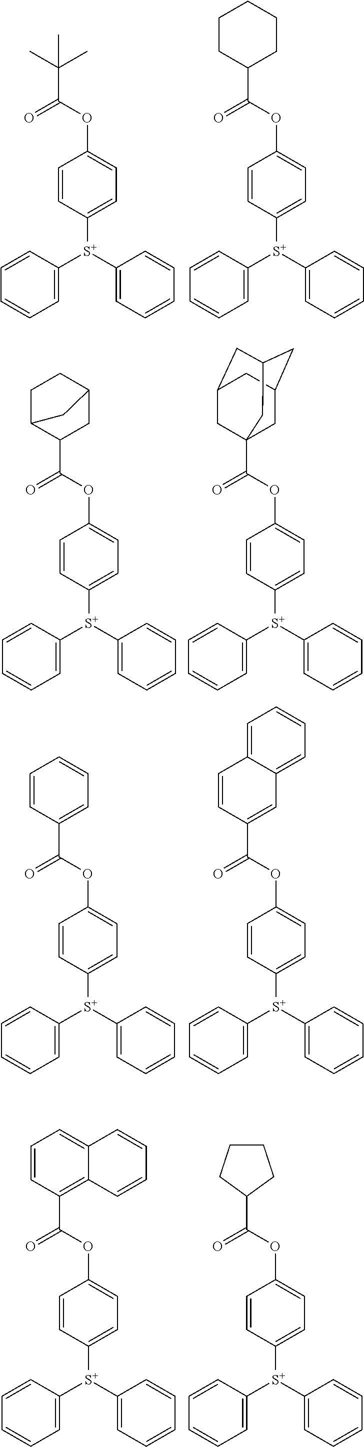

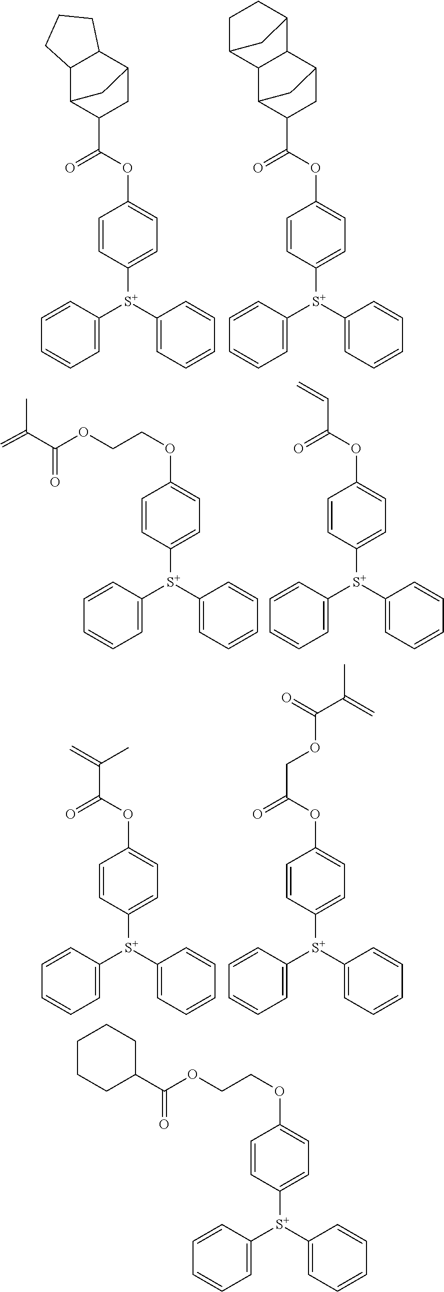

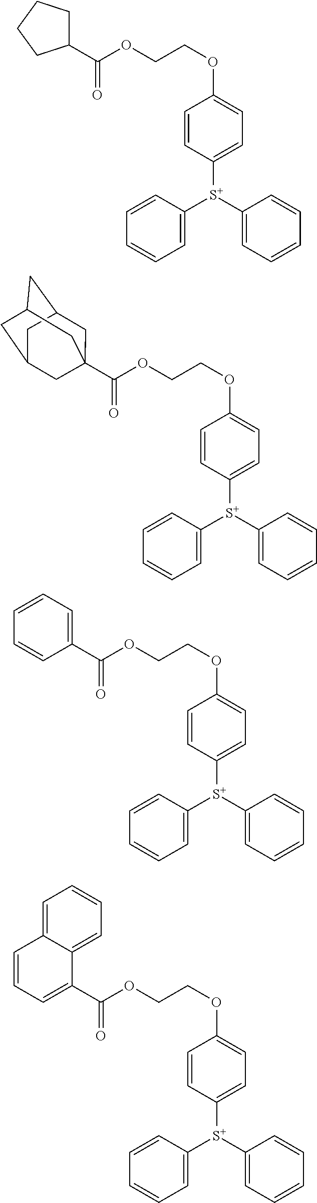

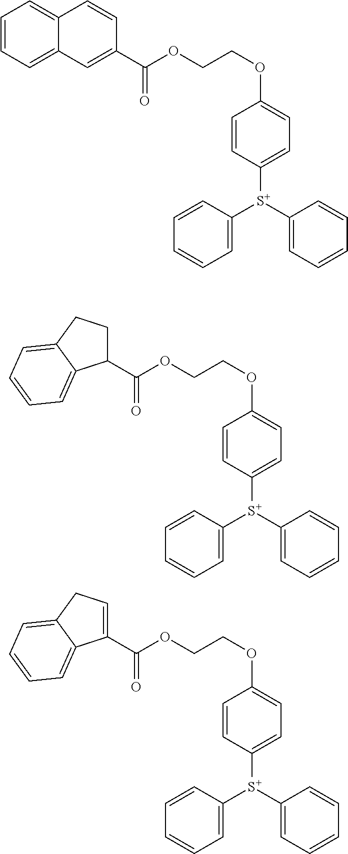

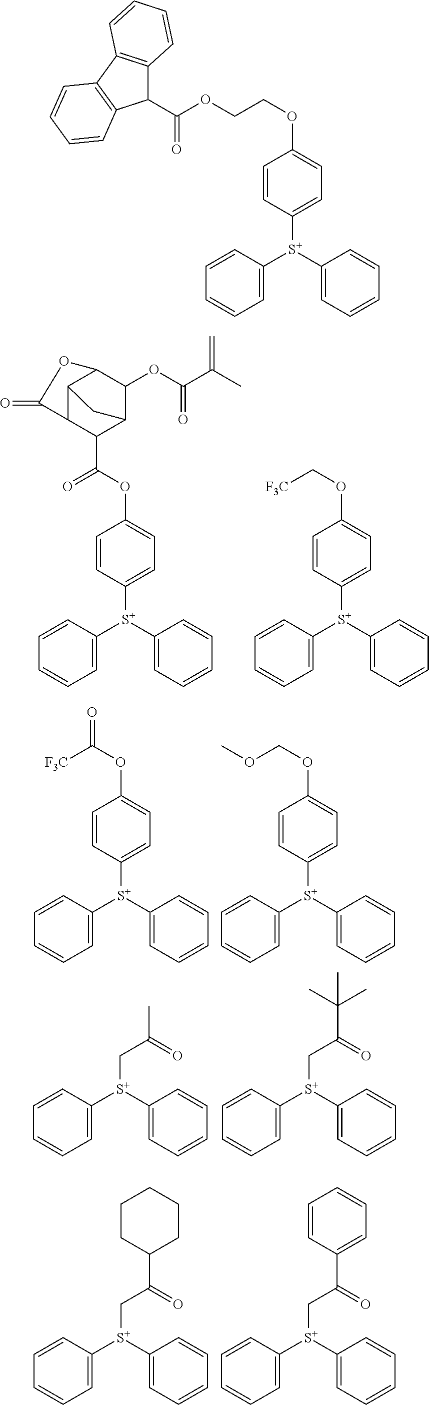

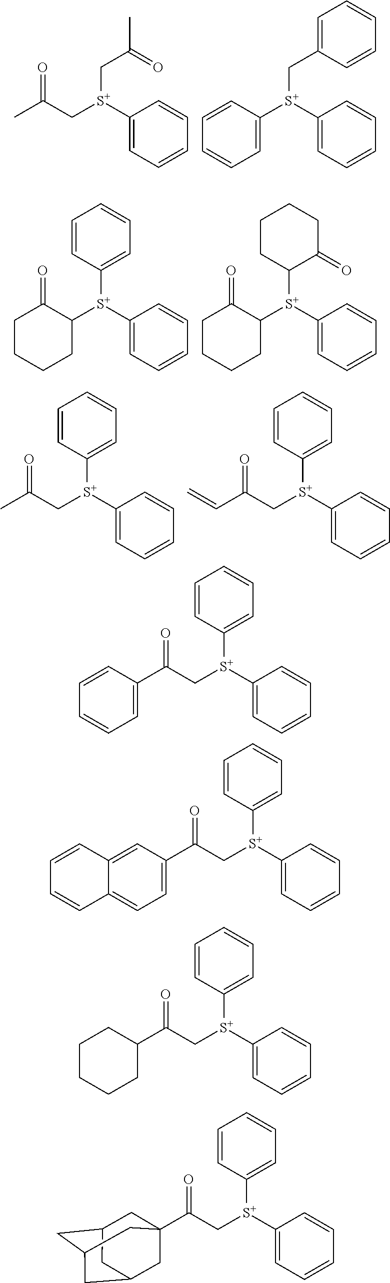

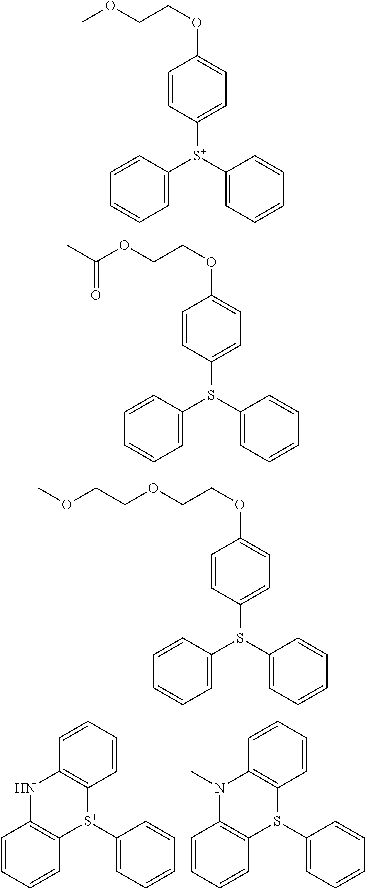

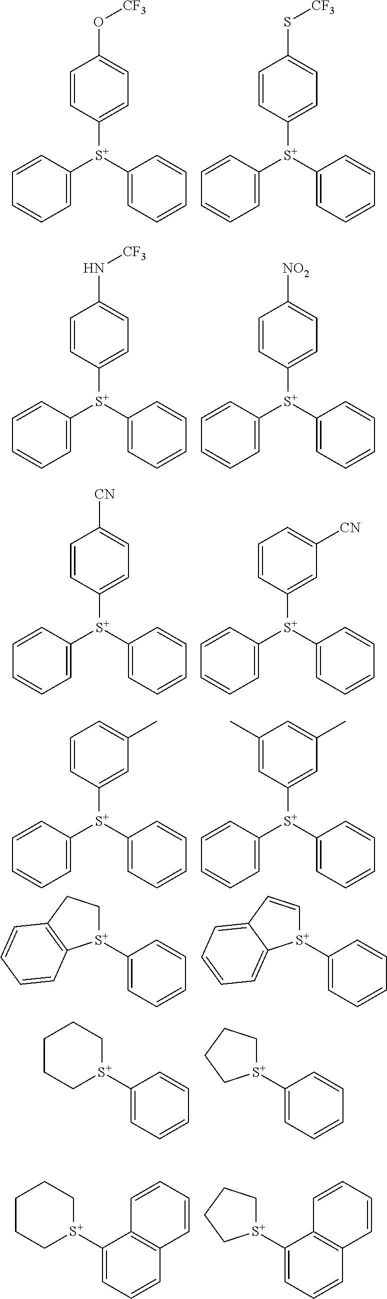

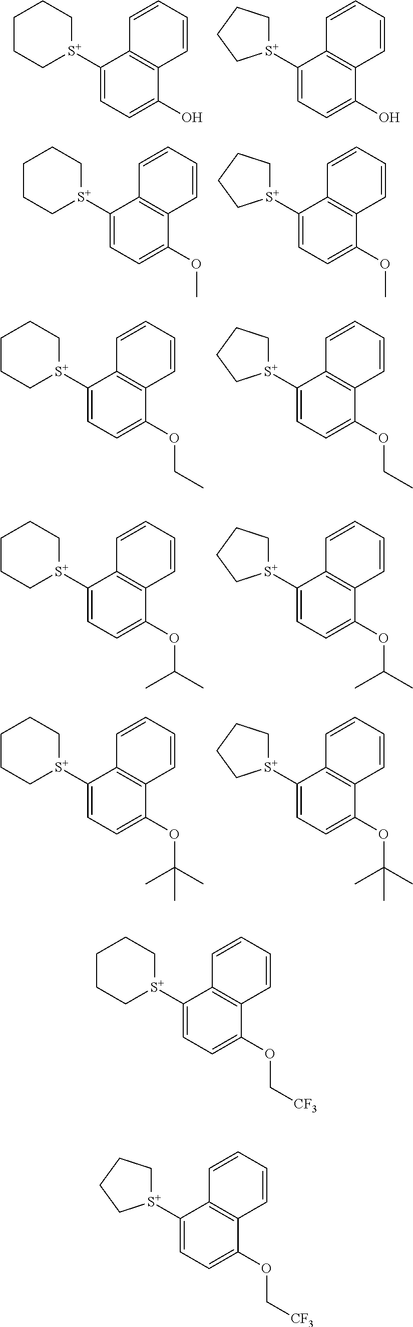

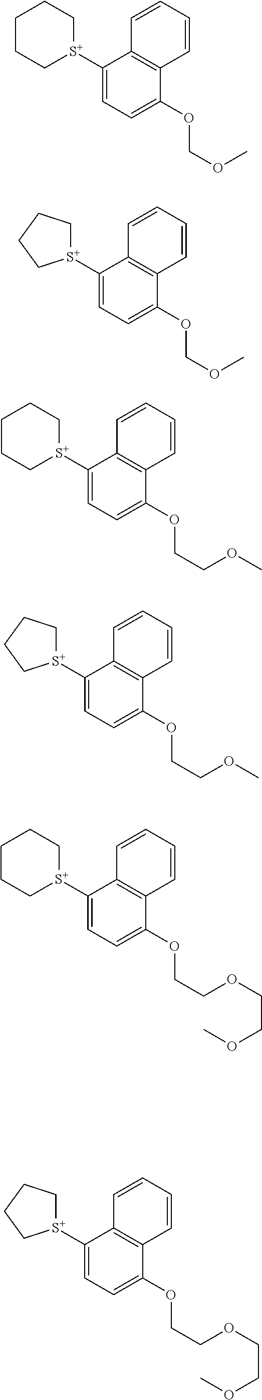

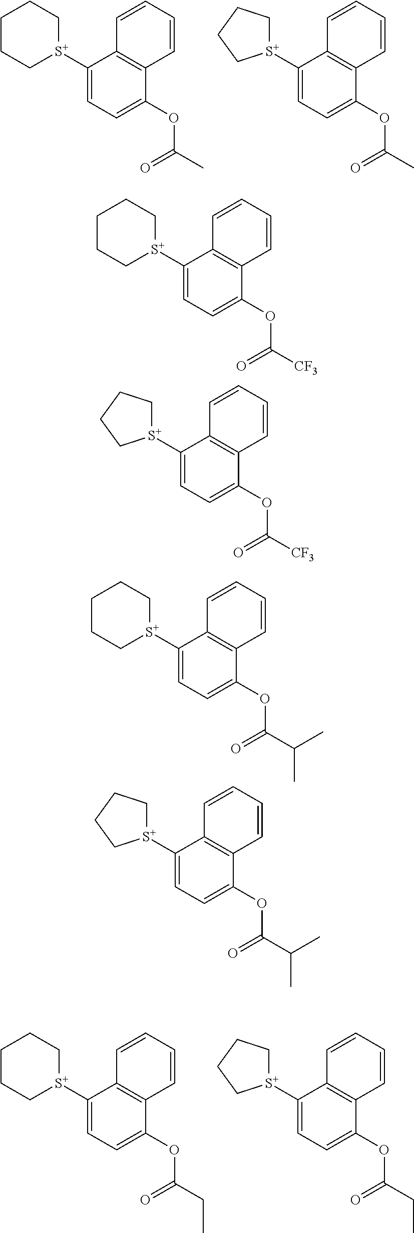

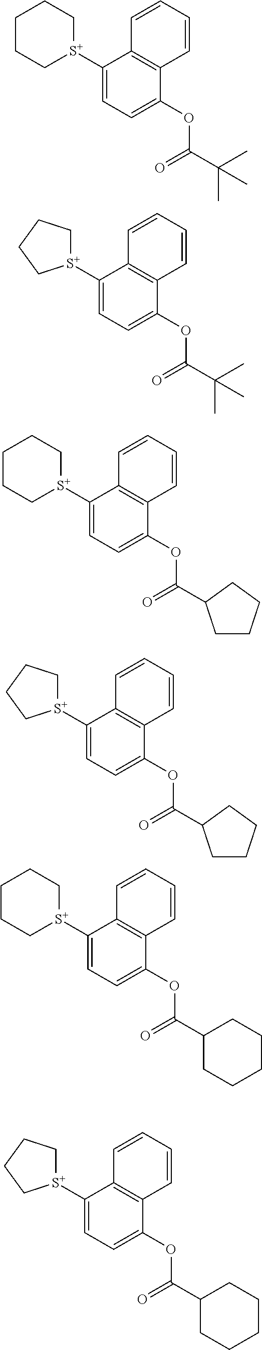

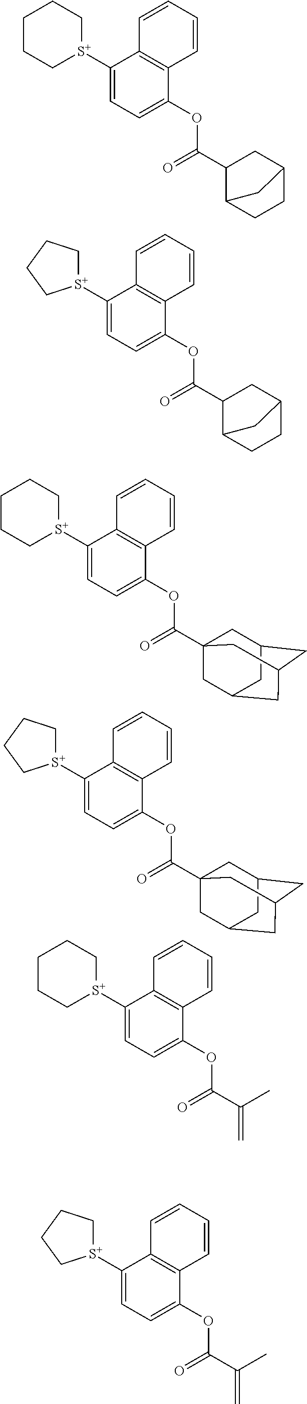

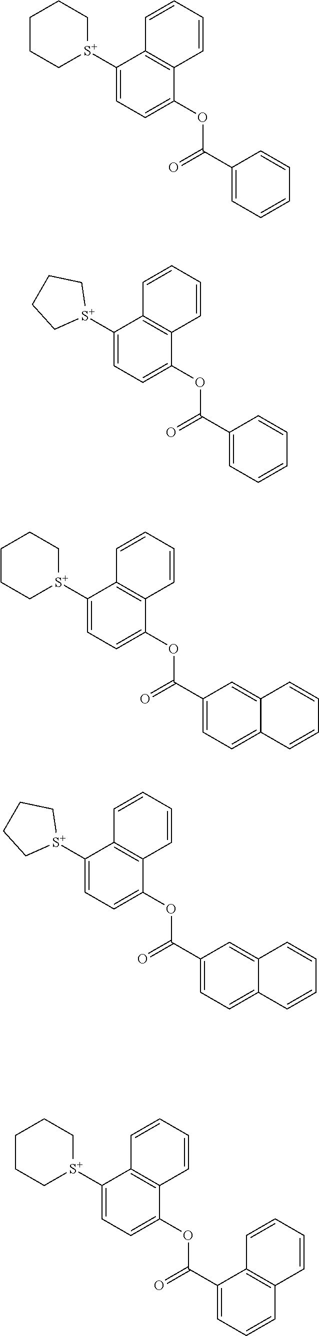

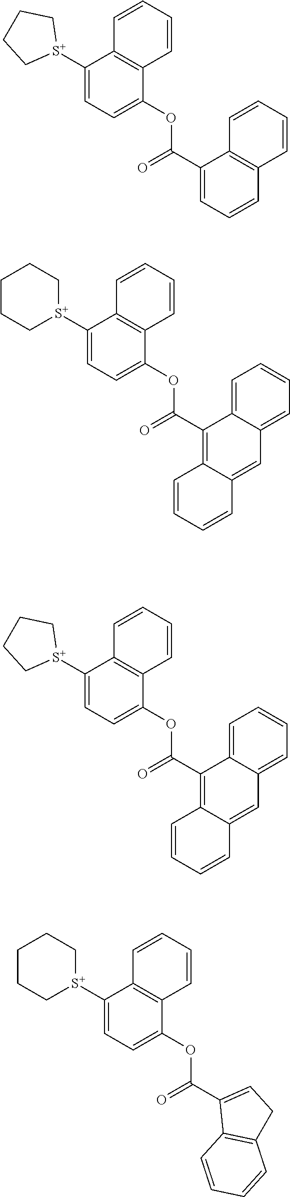

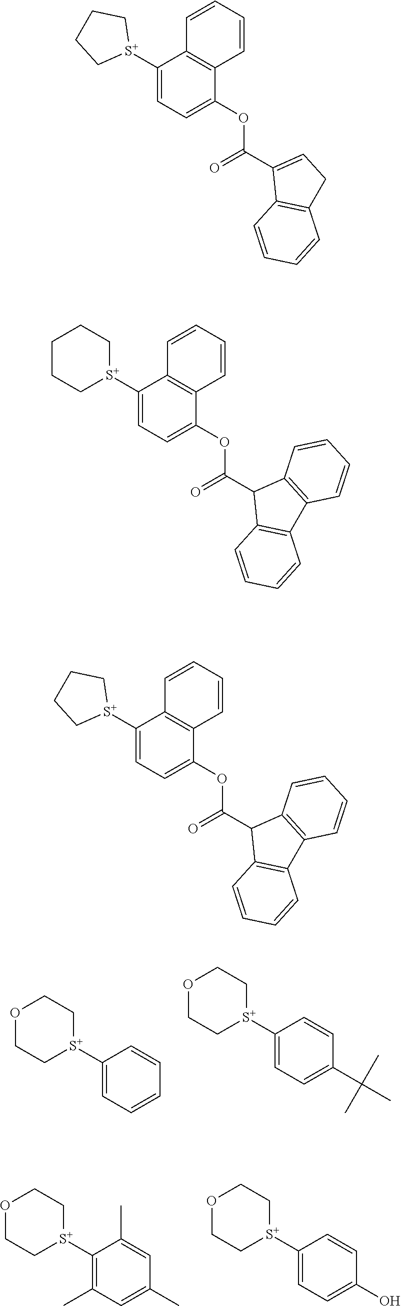

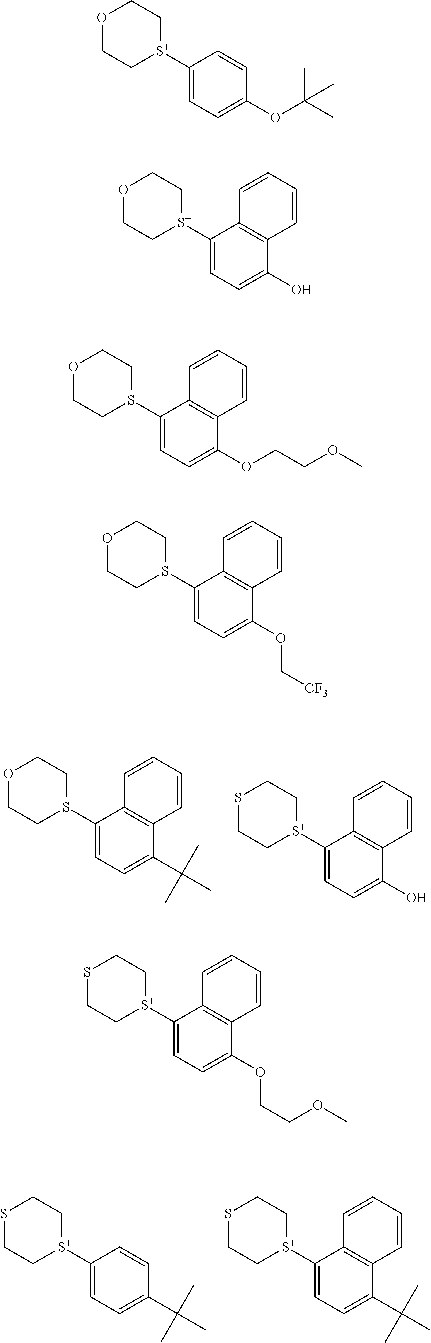

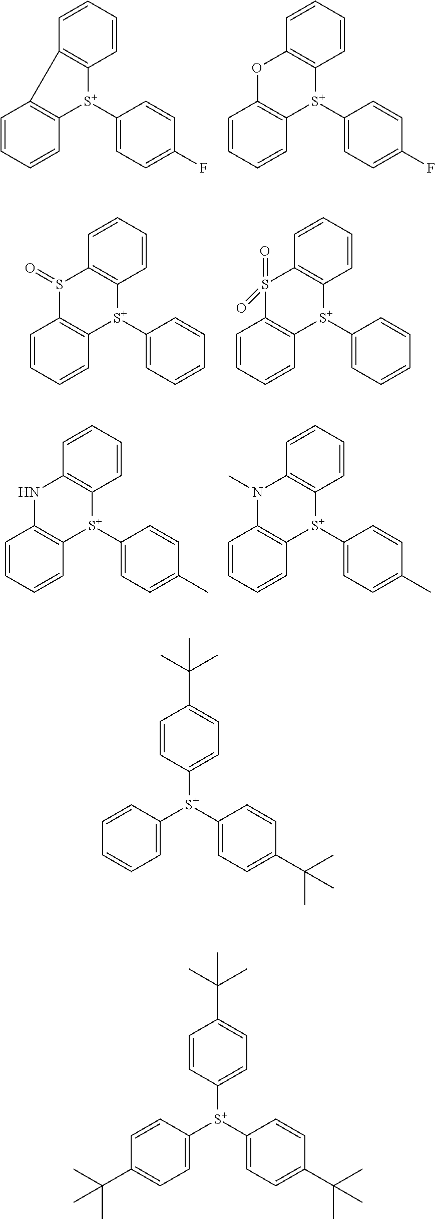

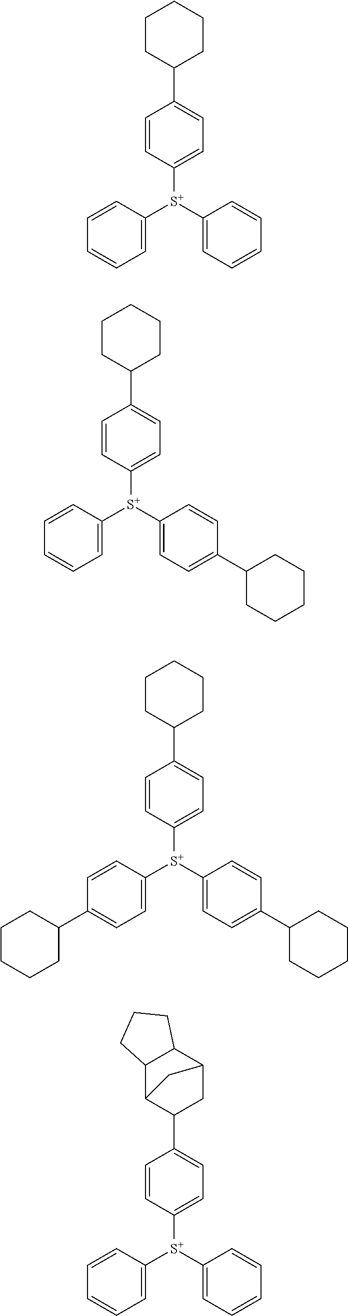

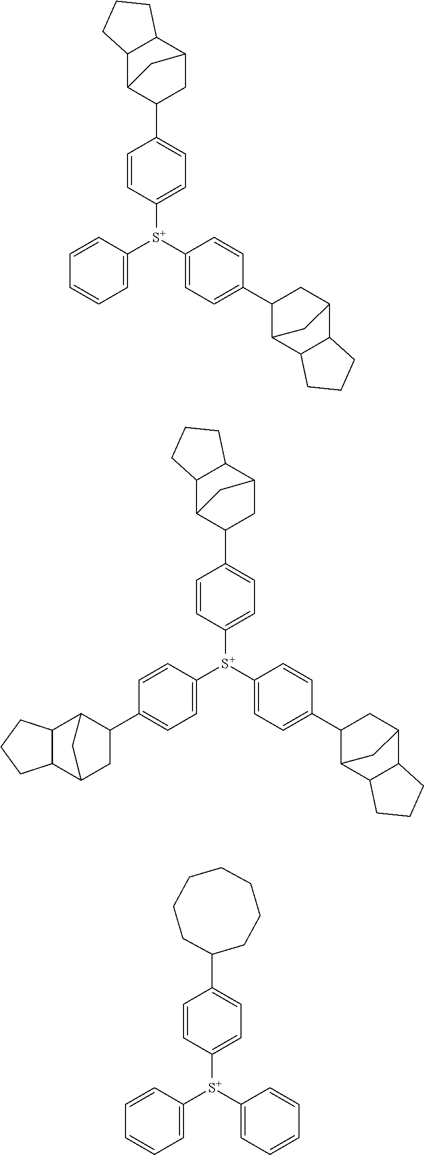

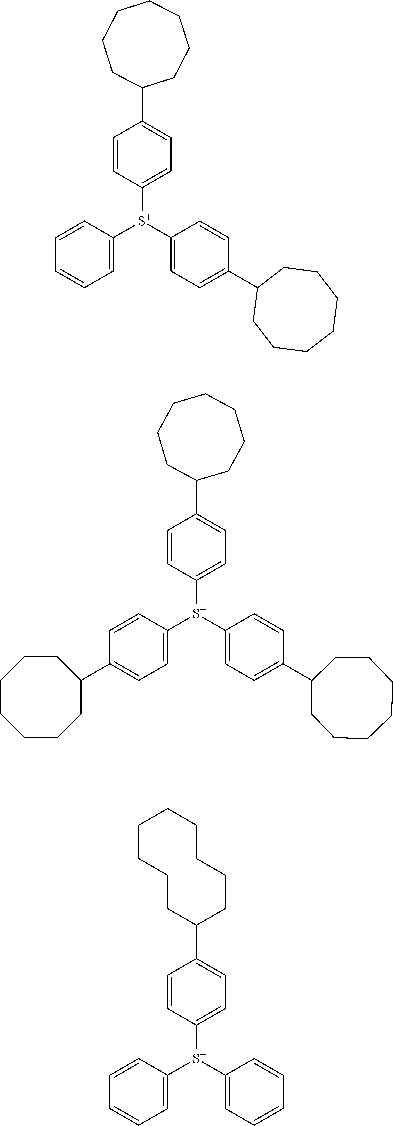

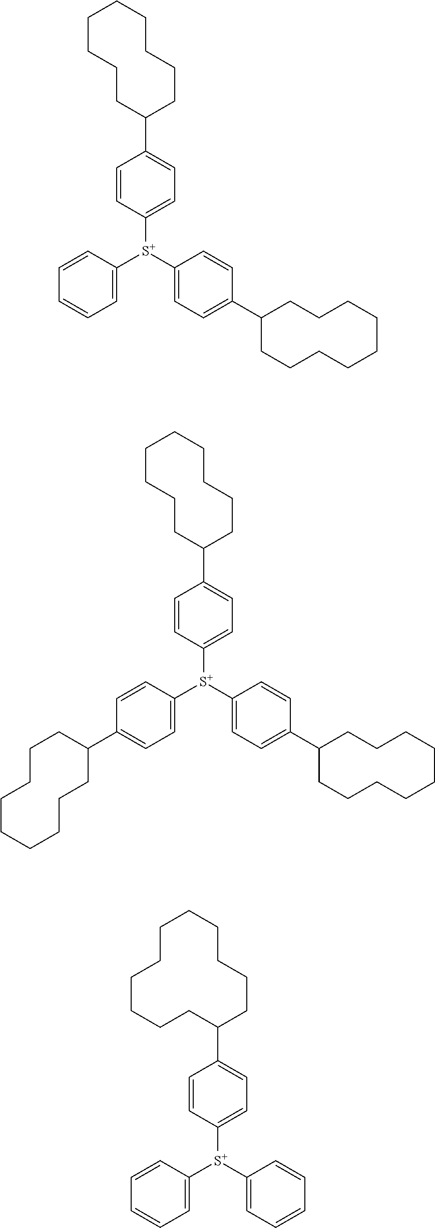

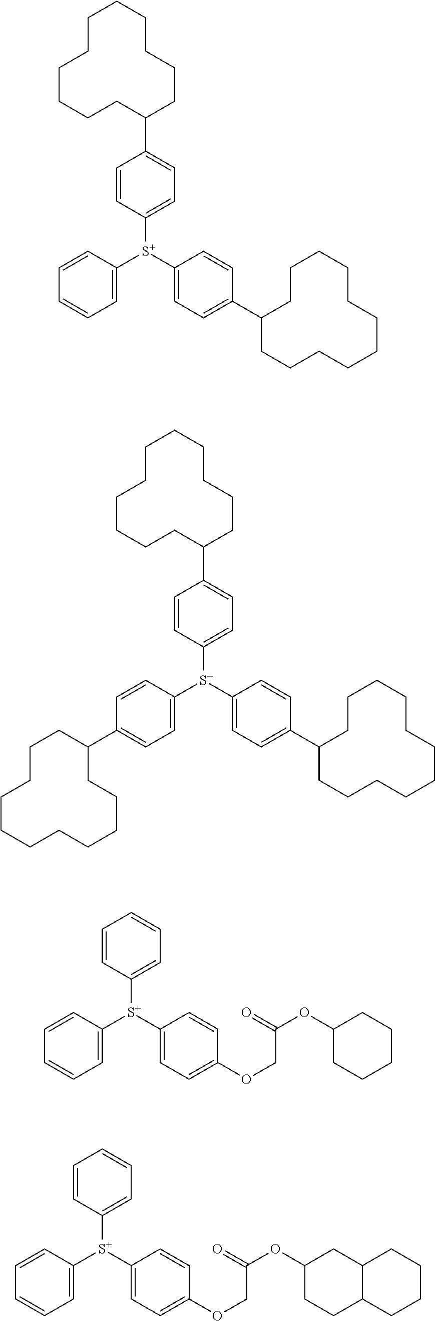

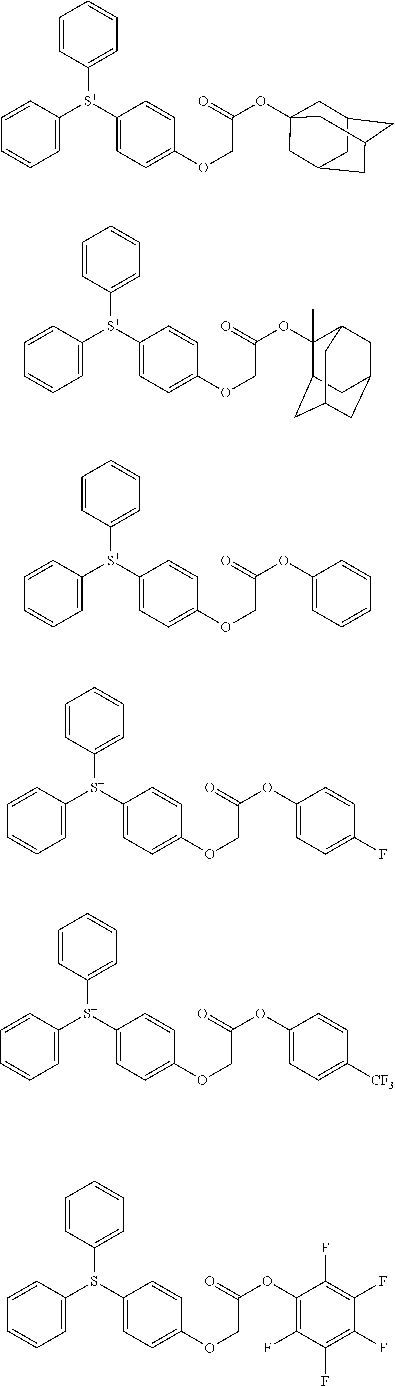

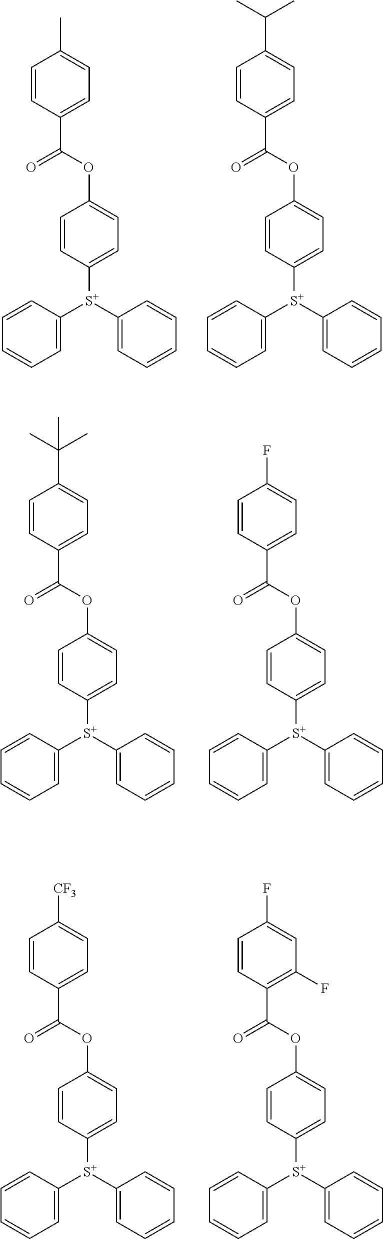

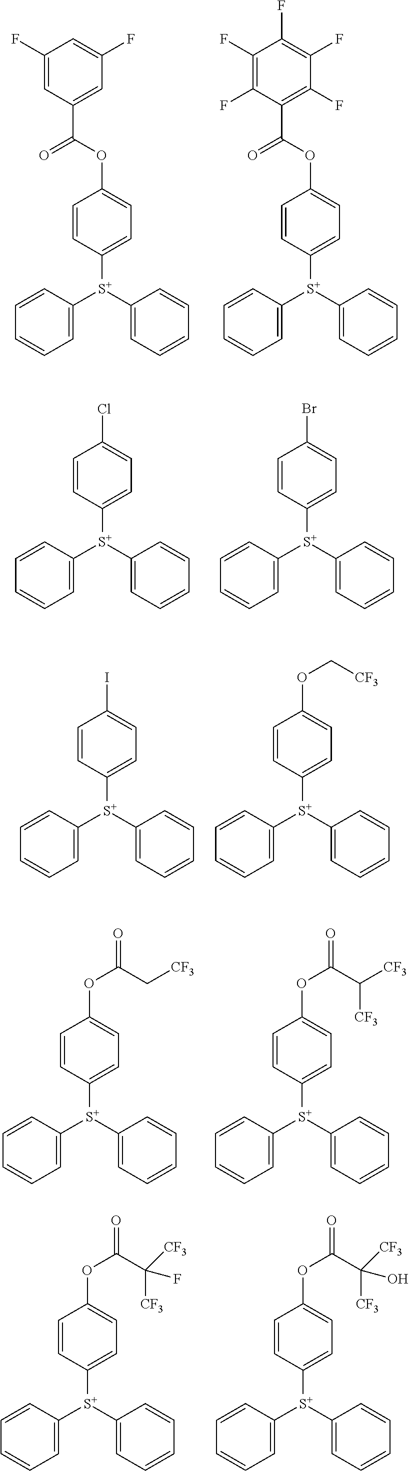

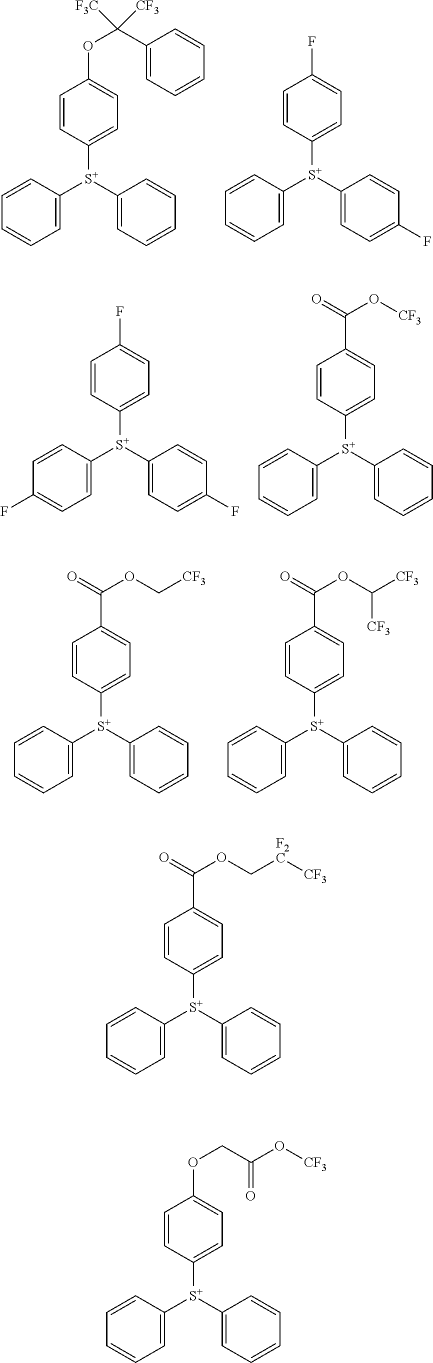

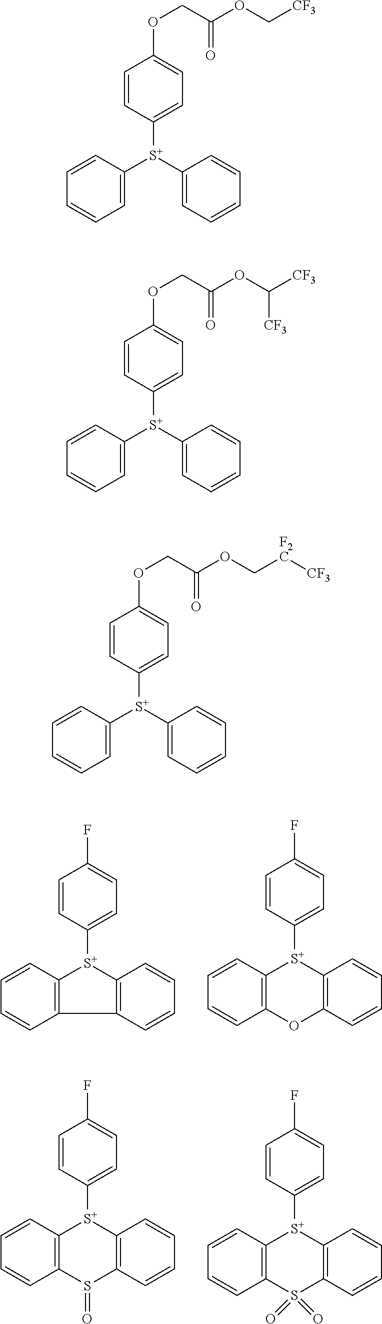

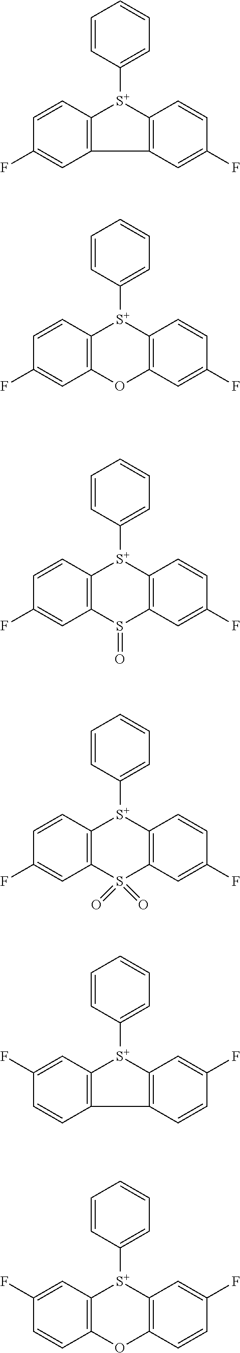

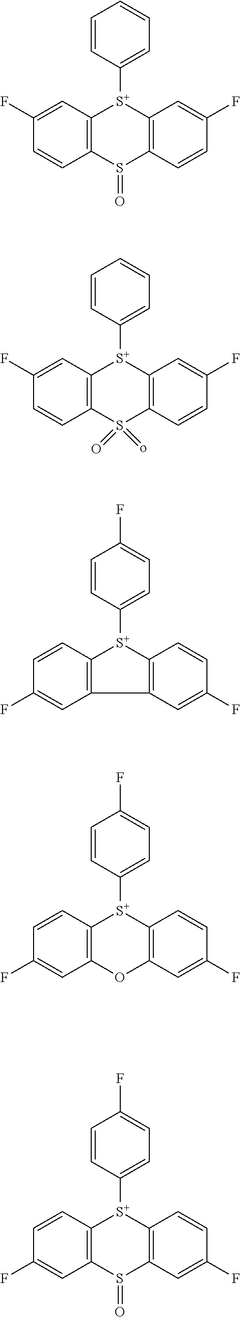

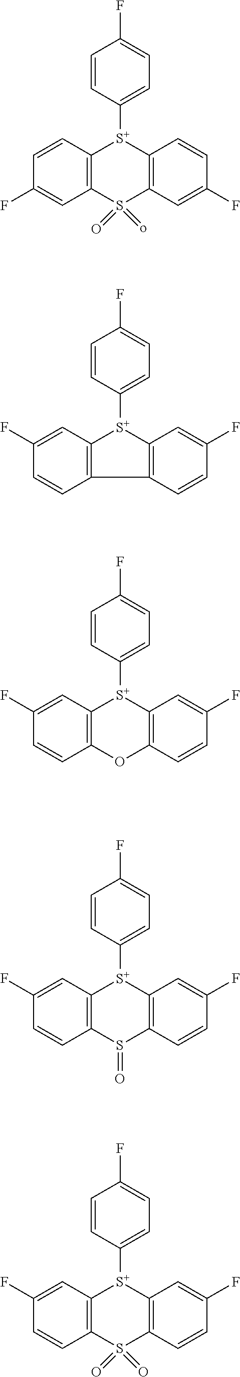

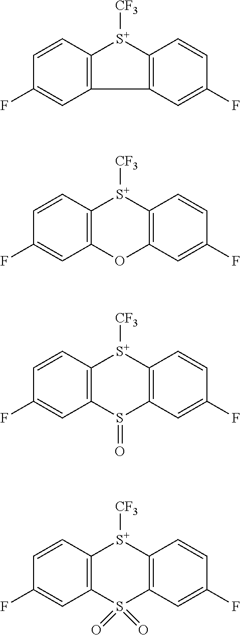

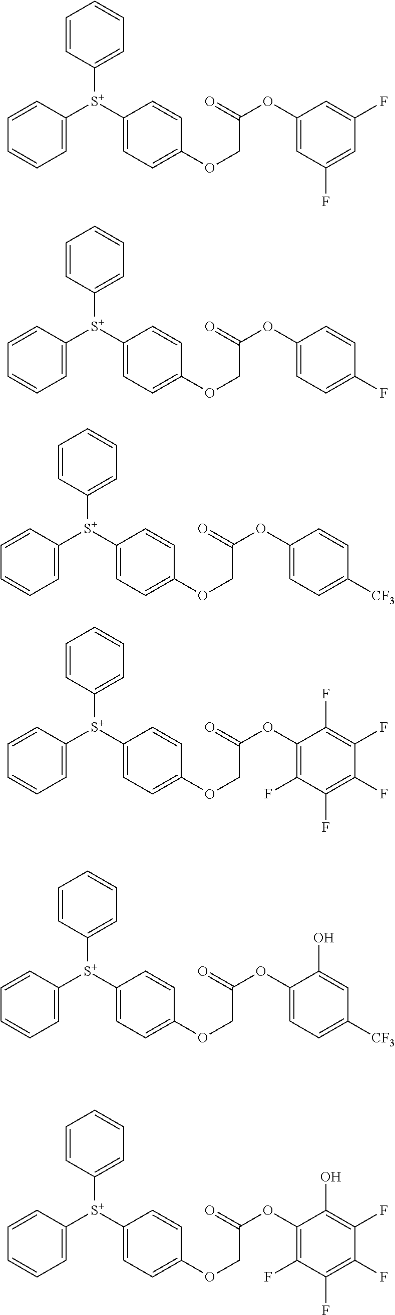

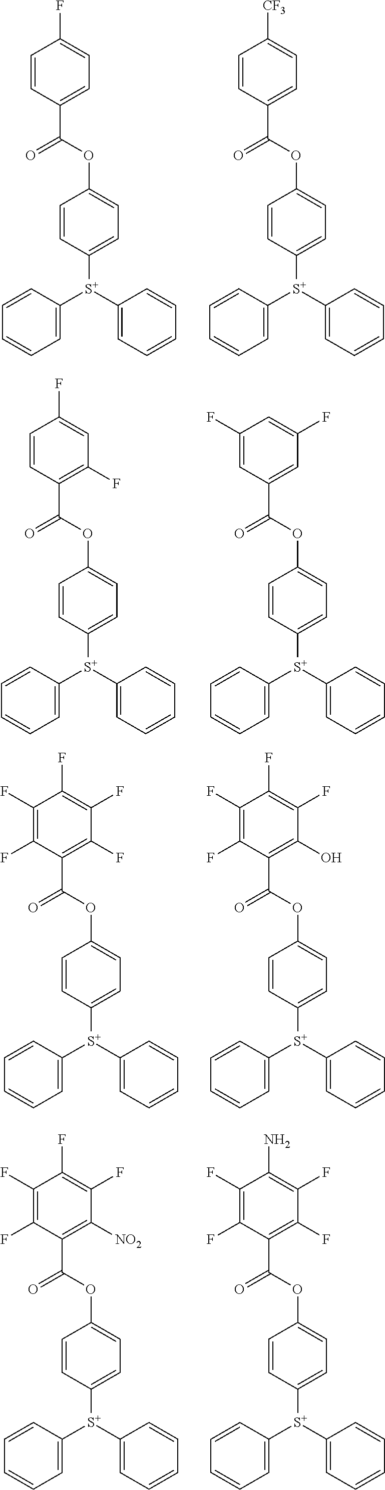

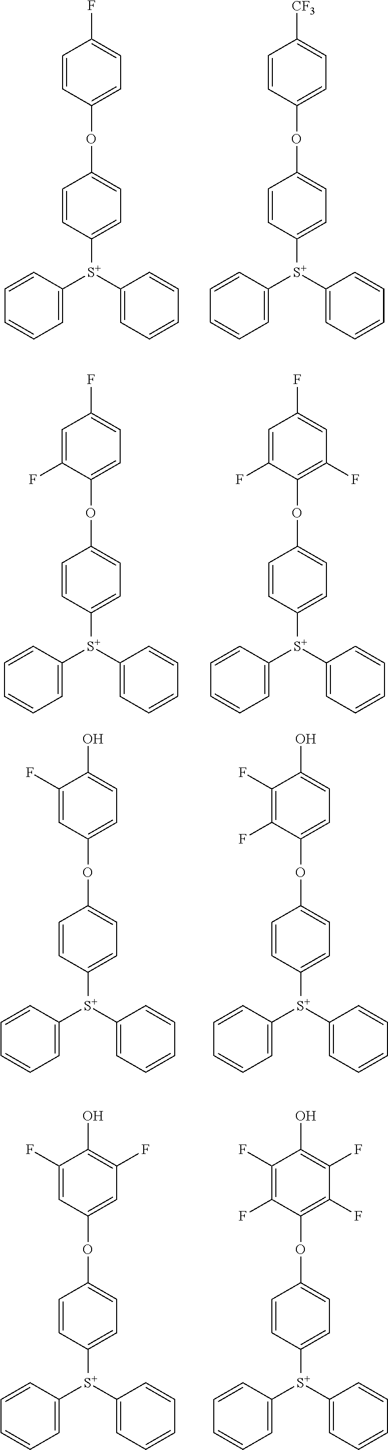

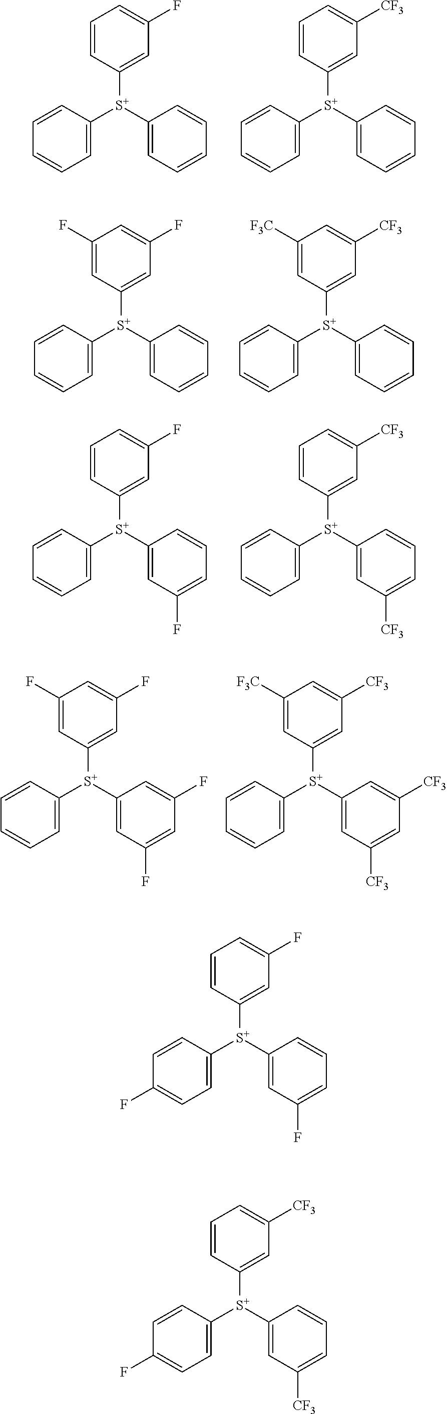

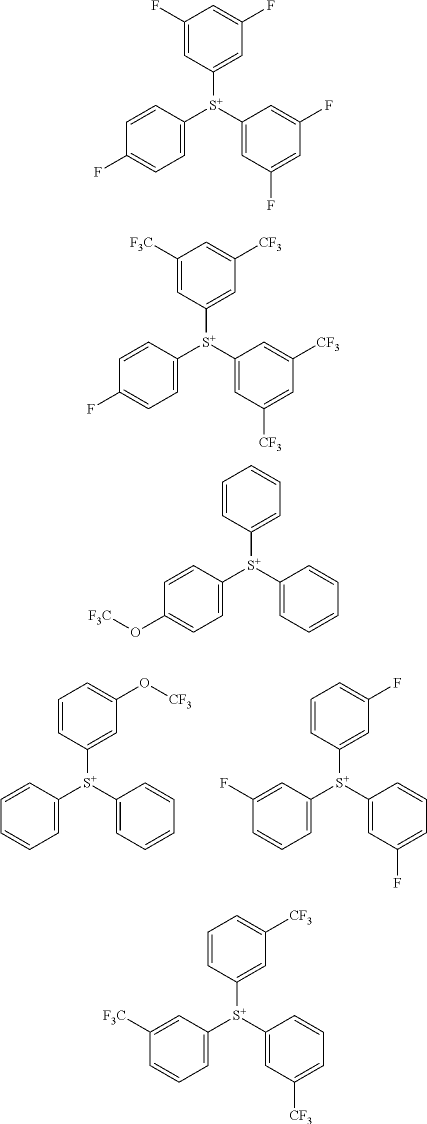

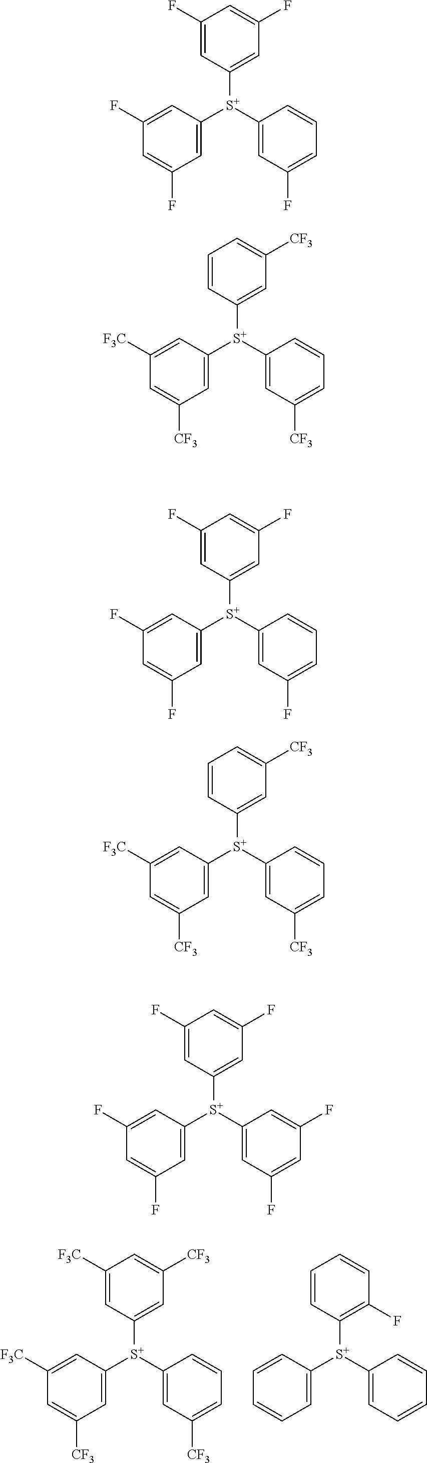

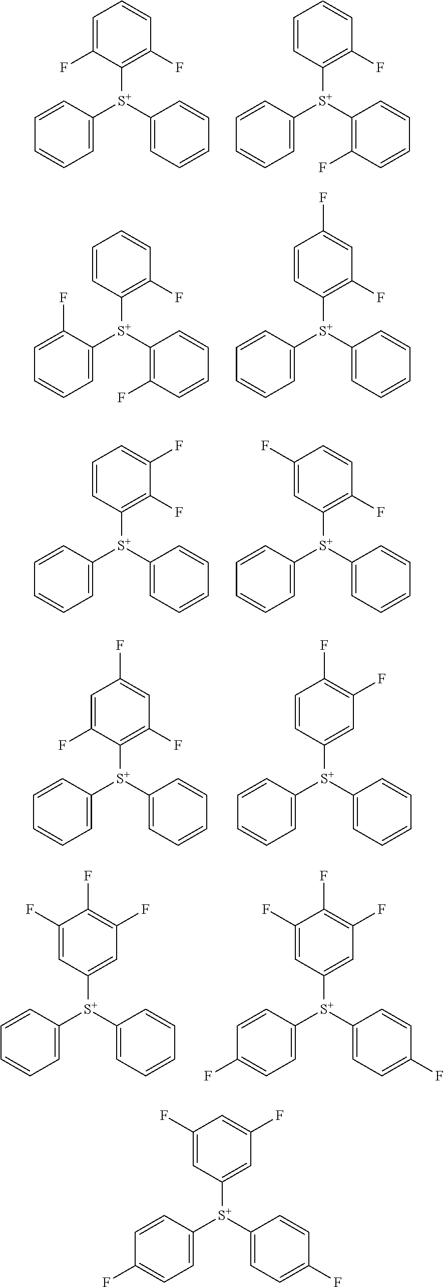

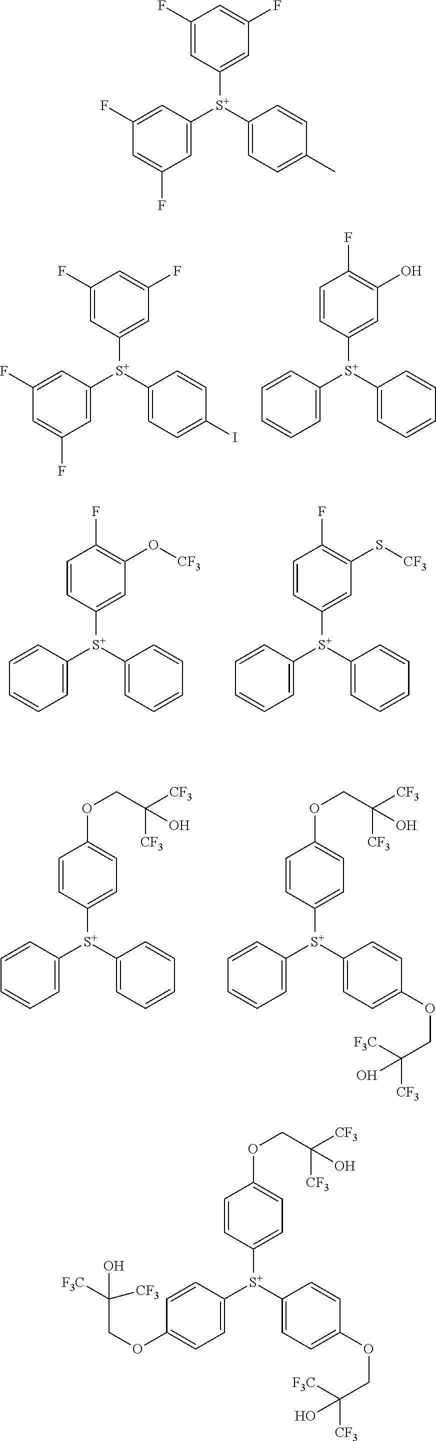

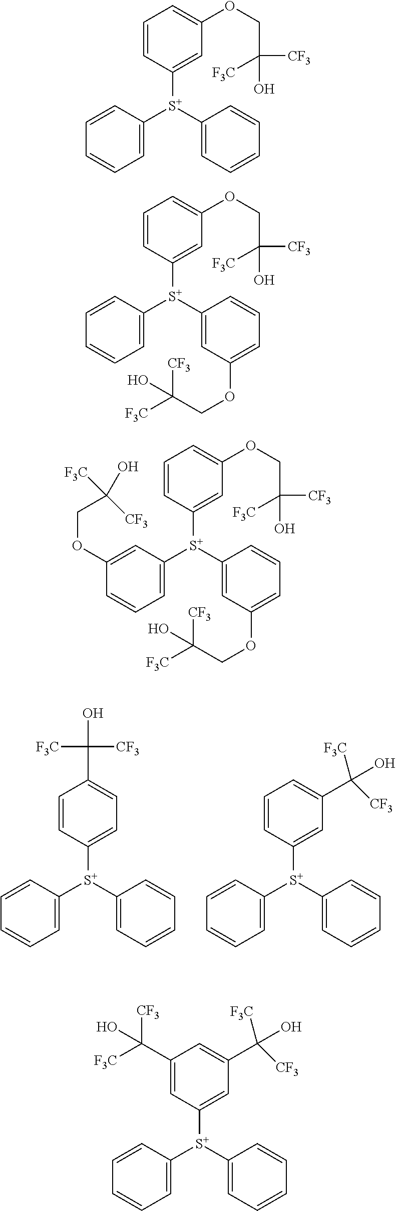

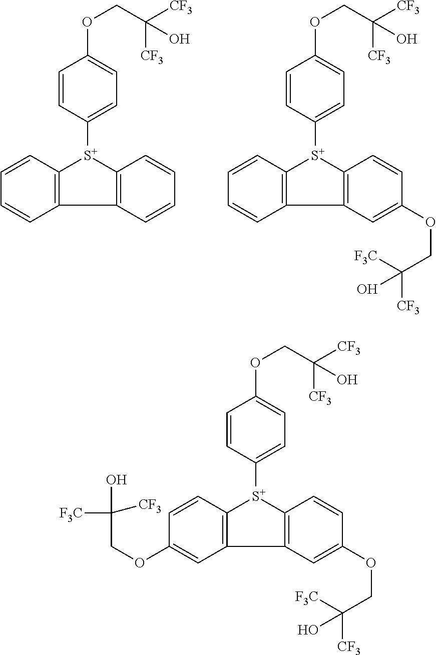

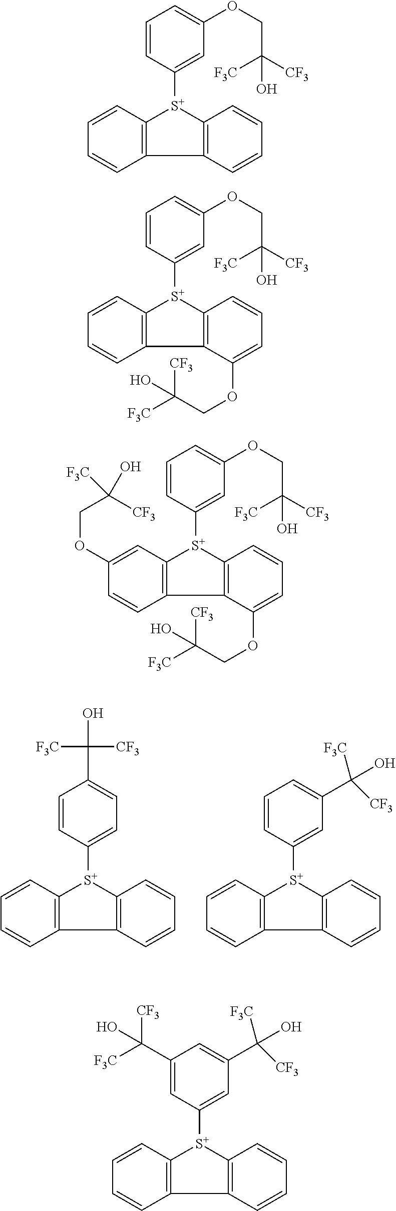

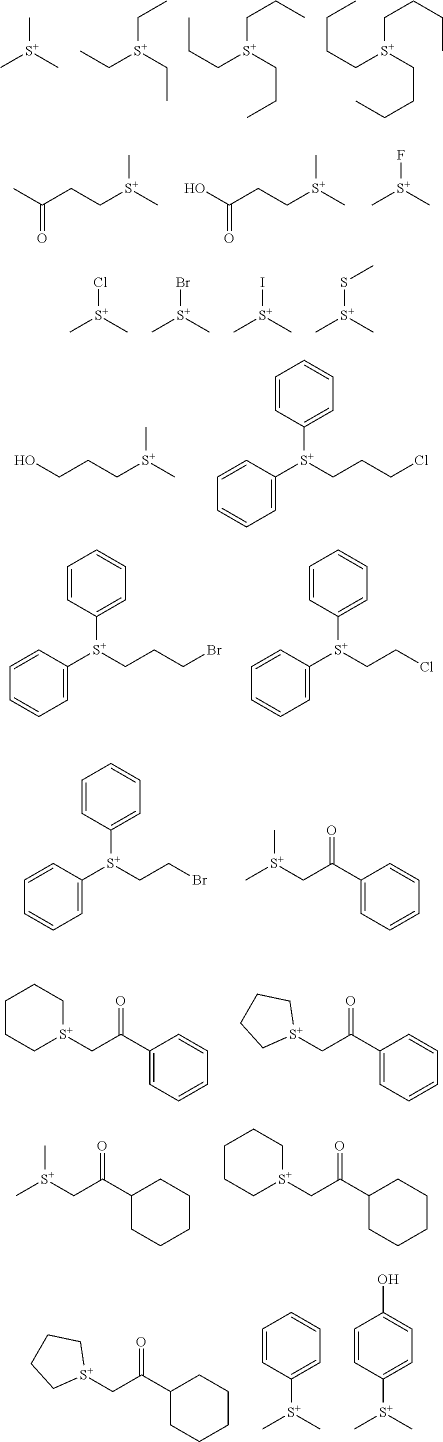

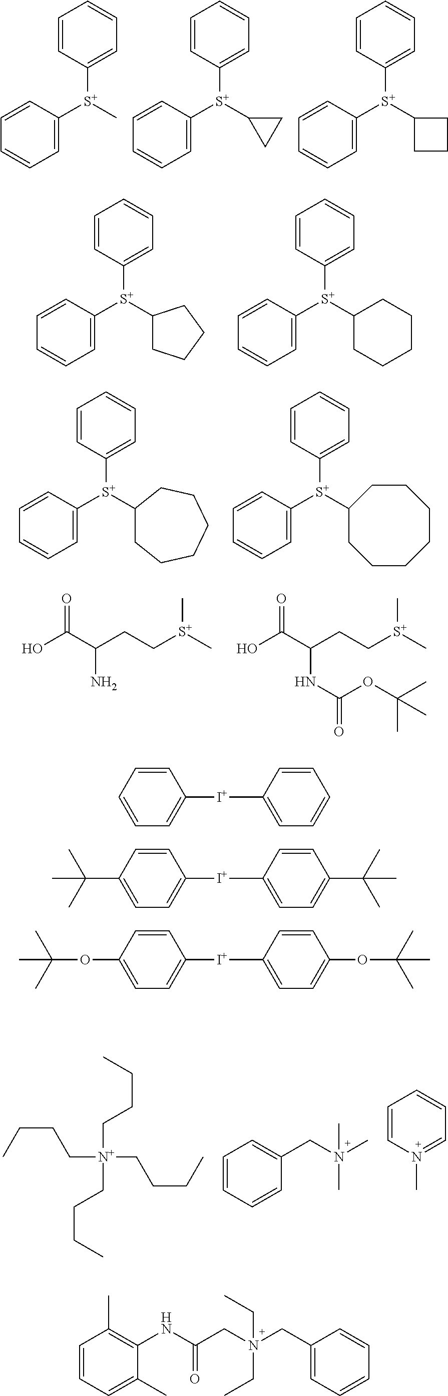

The repeat unit (b) has the formula (b).

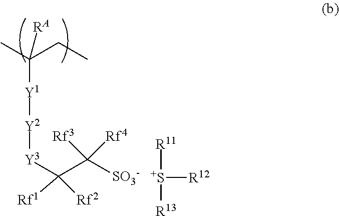

In formula (b), R^{A} is each independently hydrogen or methyl.

In formula (b), Y¹ is a single bond or ester bond.

In formula (b), Y² is —Y²¹—C(═O)—O— or —Y²¹—O—. Y²¹ is a C₁-C₁₂ hydrocarbylene group, phenylene, naphthylene or a C₇-C₁₈ group obtained by combining the foregoing, which contains at least one iodine atom and may contain a carbonyl moiety, ester bond, ether bond, lactone ring, fluorine or bromine.

In formula (b), Y³ is a single bond, methylene group or ethylene group.

In formula (b), Rf¹ to Rf⁴ are each independently hydrogen, fluorine, or trifluoromethyl, at least one of Rf¹ to Rf⁴ being fluorine.

In formula (b), R¹¹, R¹² and R¹³ are each independently halogen or a C₁-C₂₀ hydrocarbyl group which may contain a heteroatom. The hydrocarbyl group may be saturated or unsaturated and straight, branched or cyclic. Examples of the halogen and hydrocarbyl group are as exemplified above for the halogen and hydrocarbyl group represented by R^{M1} to R^{M9} in formulae (M-1) to (M-3). Also, R¹¹ and R¹² may bond together to form a ring with the sulfur atom to which they are attached. Examples of the ring are as exemplified above for the ring that R^{M1} and R^{M2} in formulae (M-1) to (M-3), taken together, form with the sulfur atom to which they are attached.

Examples of the anion in the monomer from which repeat units (b) are derived are shown below, but not limited thereto. R^{A} is as defined above.

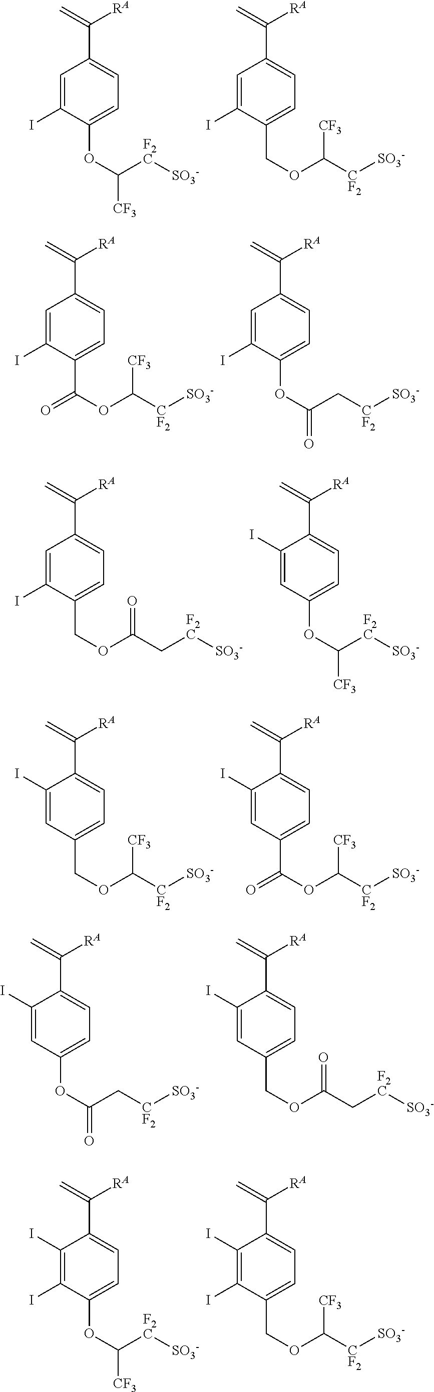

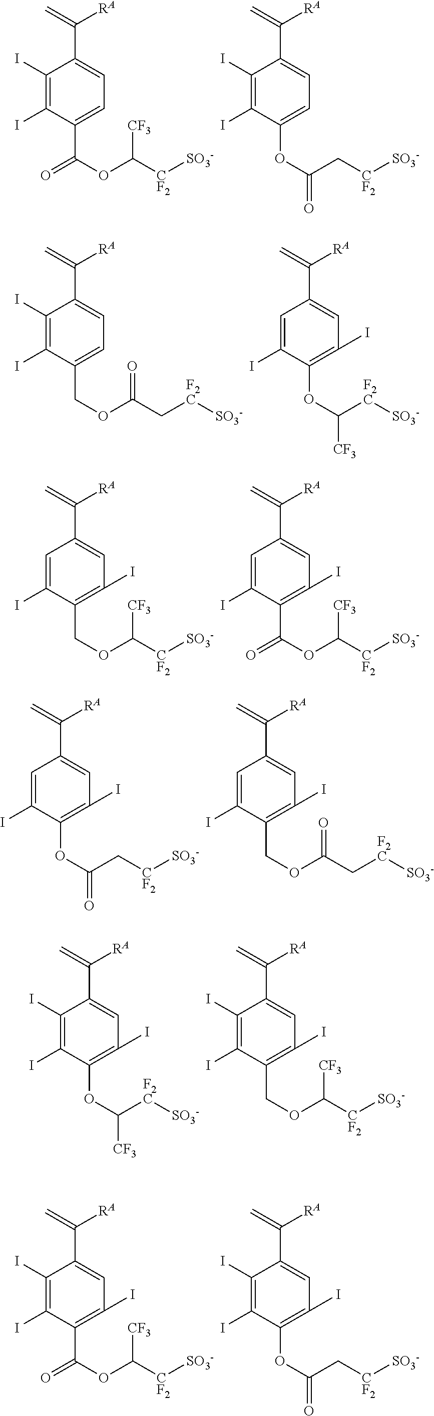

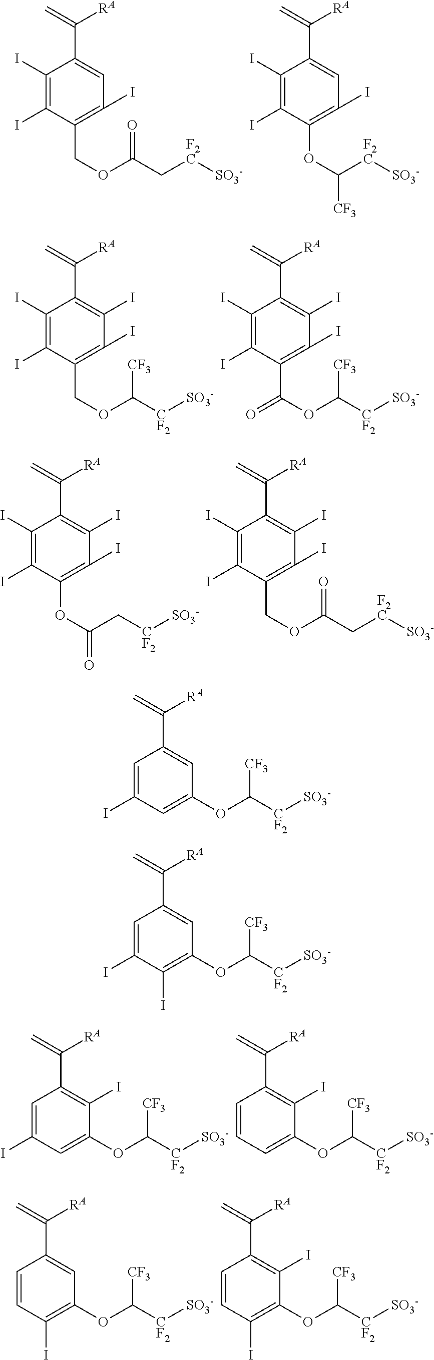

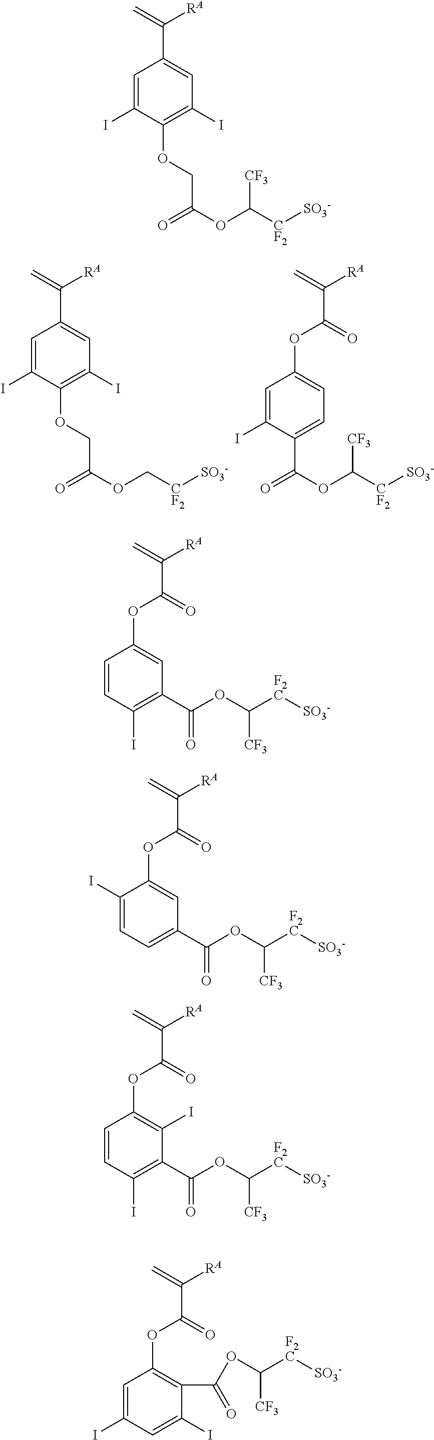

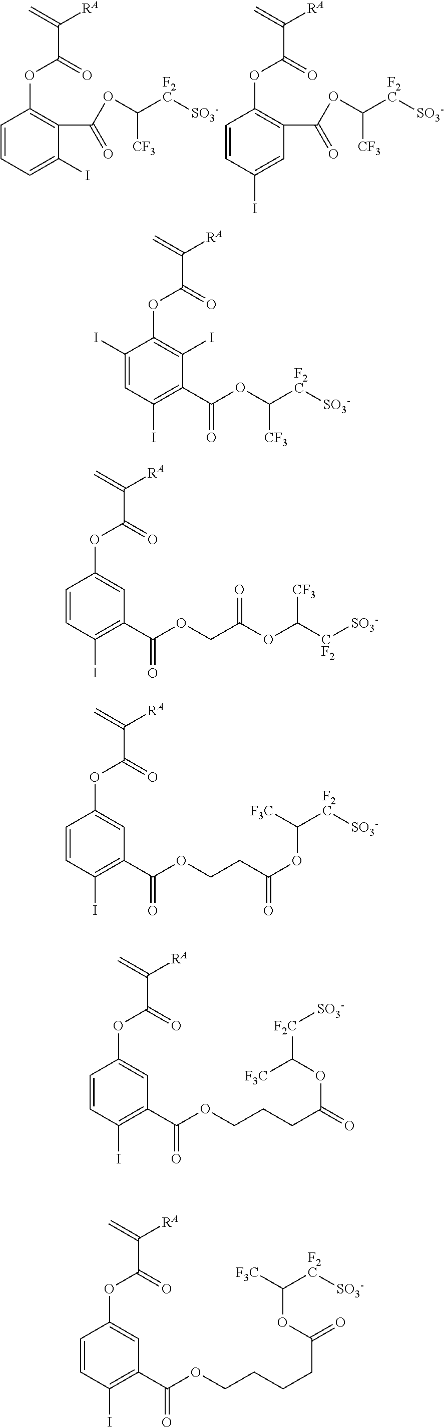

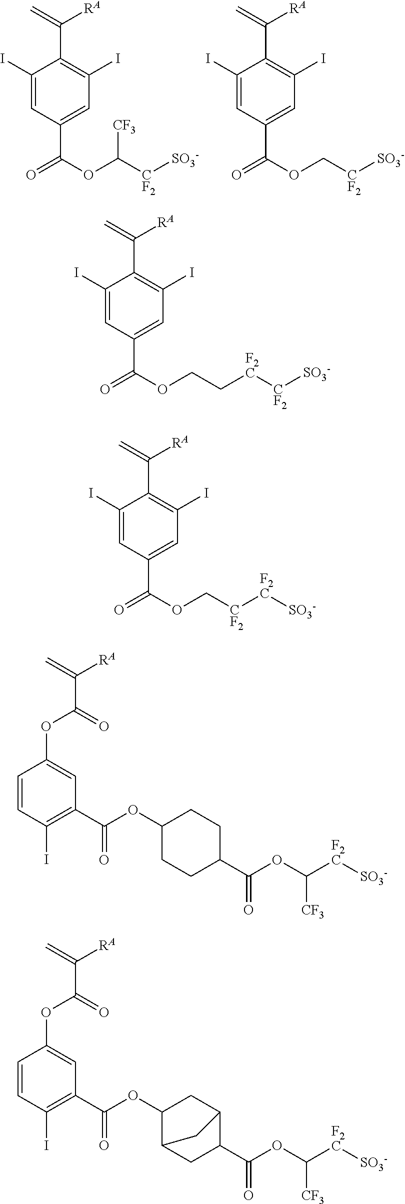

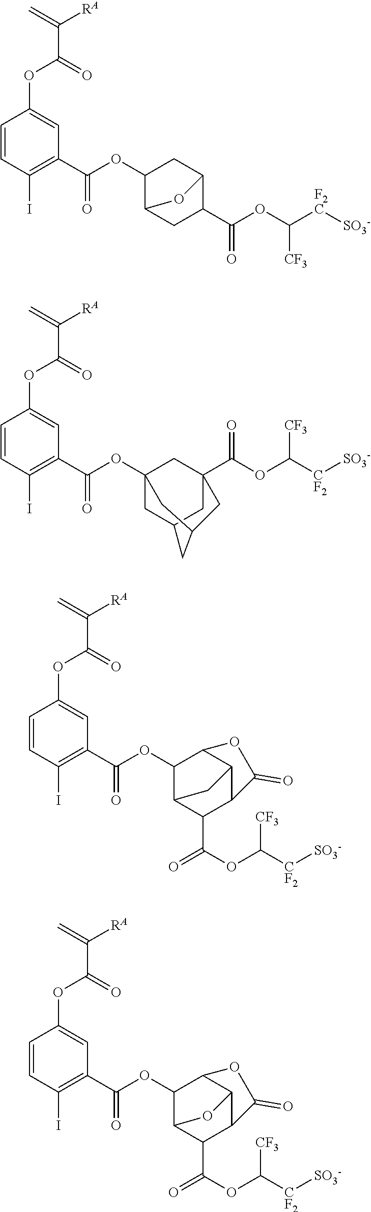

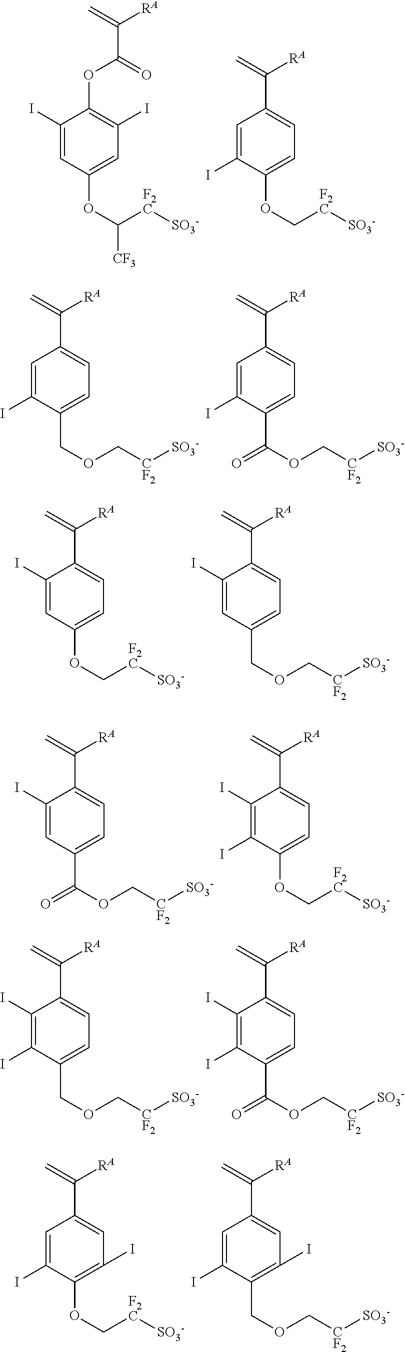

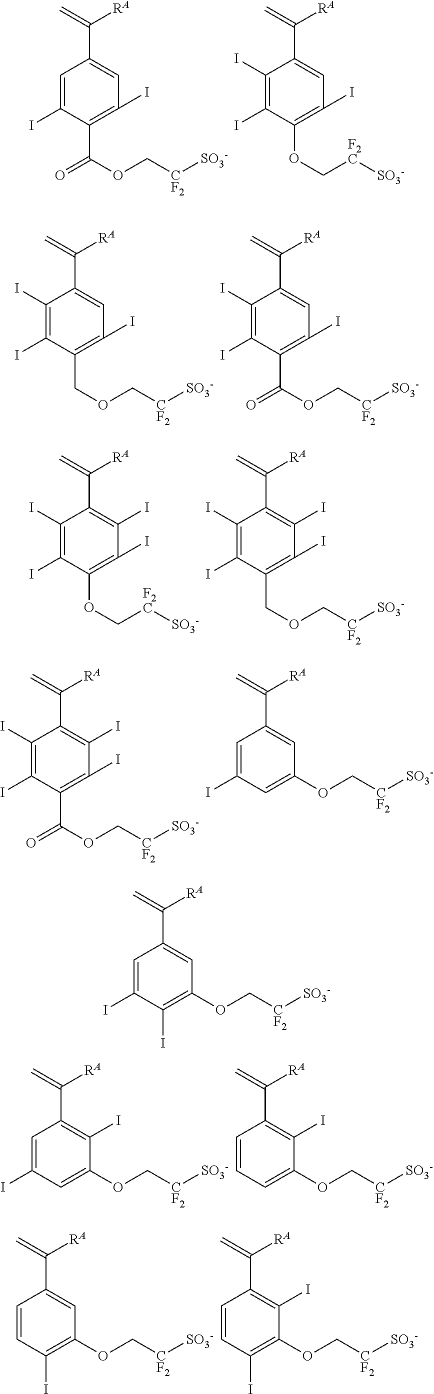

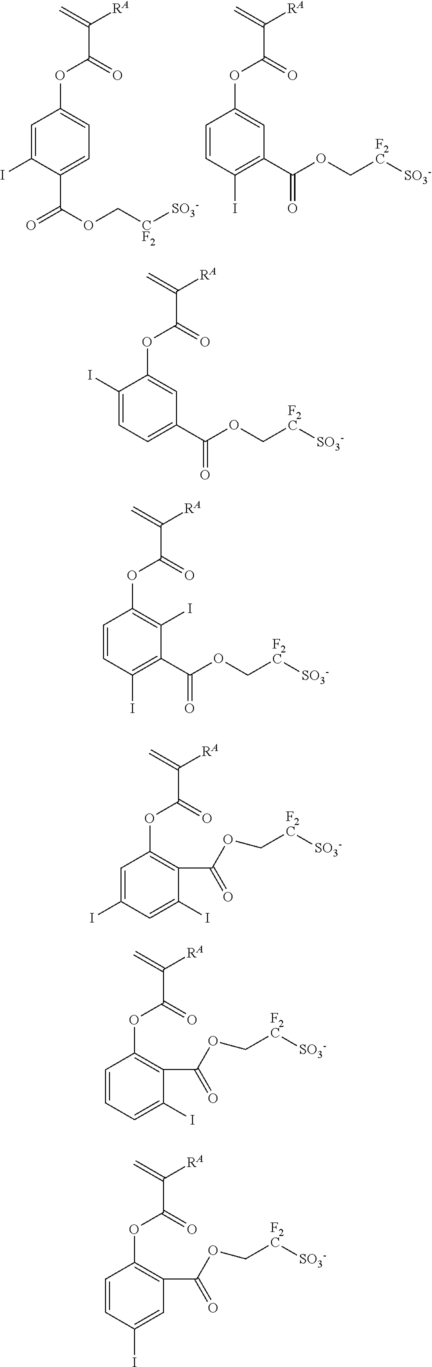

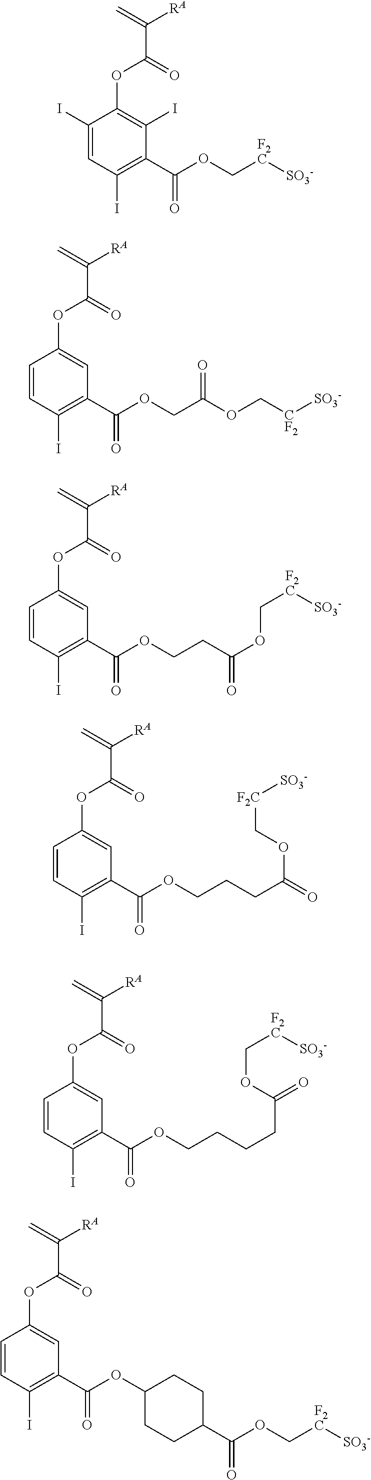

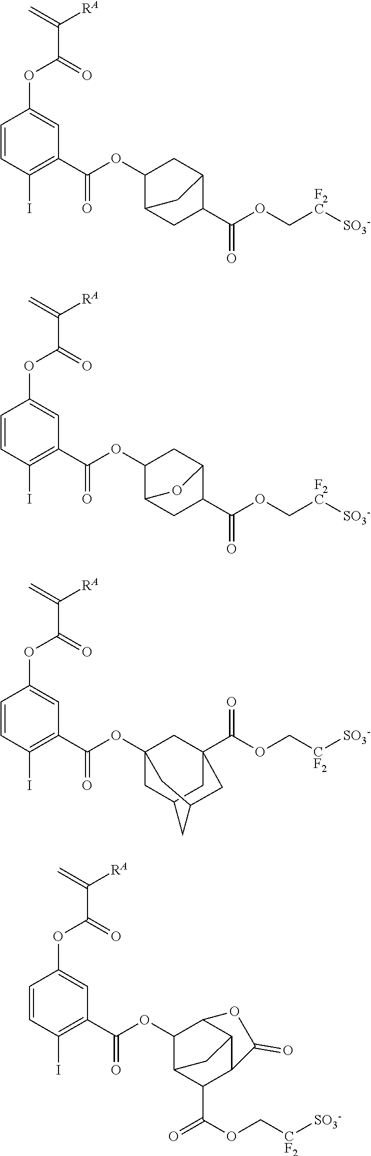

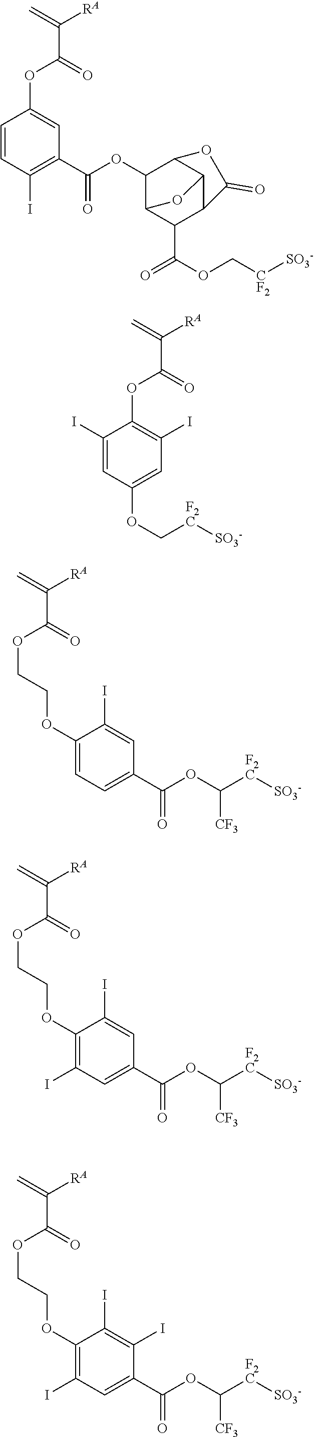

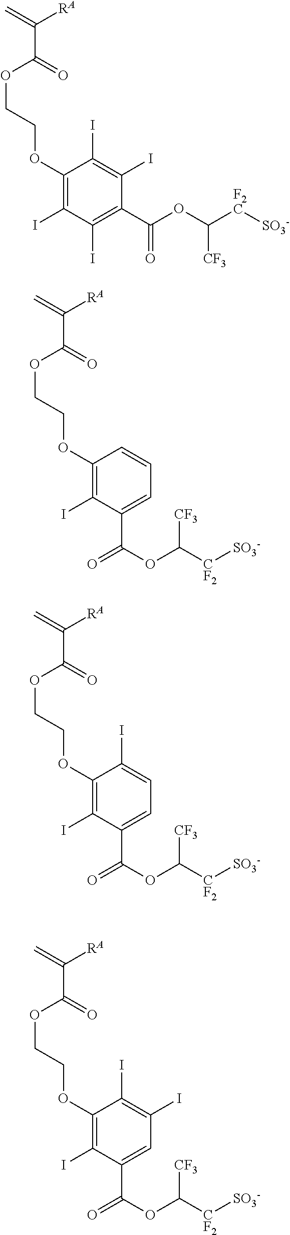

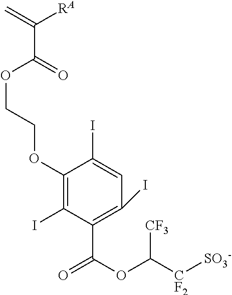

Examples of the cation in repeat unit (b) are as exemplified above for the sulfonium cation in repeat unit (a).

The repeat unit (b) has a function of acid generator. The binding of an acid generator to the polymer backbone is effective in restraining acid diffusion, thereby preventing a reduction of resolution due to blur by acid diffusion. Also, the acid generator is uniformly distributed, leading to an improvement in LWR.

Since the polymerization rate of the monomer from which repeat unit (a) functioning as a quencher is derived is approximately equal to the polymerization rate of the monomer from which repeat unit (b) functioning as an acid generator having a double bond, represented by formula (b), is derived, repeat units (a) and repeat units (b) are uniformly distributed in the polymer. This leads to an improvement in LWR after development. Since both the anions in the repeat units (a) and (b) contain iodine, the number of photons absorbed is increased and the film is improved in homogeneity, leading to improvements in contrast and LWR.

For the purpose of increasing the dissolution contrast, the base polymer may further comprise repeat units of at least one type selected from repeat units having a carboxy group whose hydrogen is substituted by an acid labile group, represented by the formula (c1), and repeat units having a phenolic hydroxy group whose hydrogen is substituted by an acid labile group, represented by the formula (c2). These units are also referred to as repeat units (c1) and (c2), respectively.

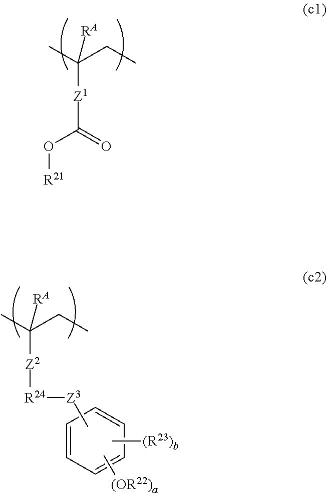

In formulae (c1) and (c2), R^{A} is each independently hydrogen or methyl. Z¹ is a single bond, phenylene group, naphthylene group or a C₁-C₁₂ linking group which contains at least one of ester bond, ether bond and lactone ring. Z² is a single bond, ester bond or amide bond. Z³ is a single bond, ether bond or ester bond. R²¹ and R²² are each independently an acid labile group. R²³ is fluorine, trifluoromethyl, cyano or a C₁-C₆ saturated hydrocarbyl group. R²⁴ is a single bond or a C₁-C₆ alkanediyl group in which some —CH₂— may be replaced by an ether bond or ester bond. The subscript “a” is 1 or 2, and b is 0, 1, 2, 3 or 4.

Examples of the monomer from which repeat units (c1) are derived are shown below, but not limited thereto. R^{A} and R¹¹ are as defined above.

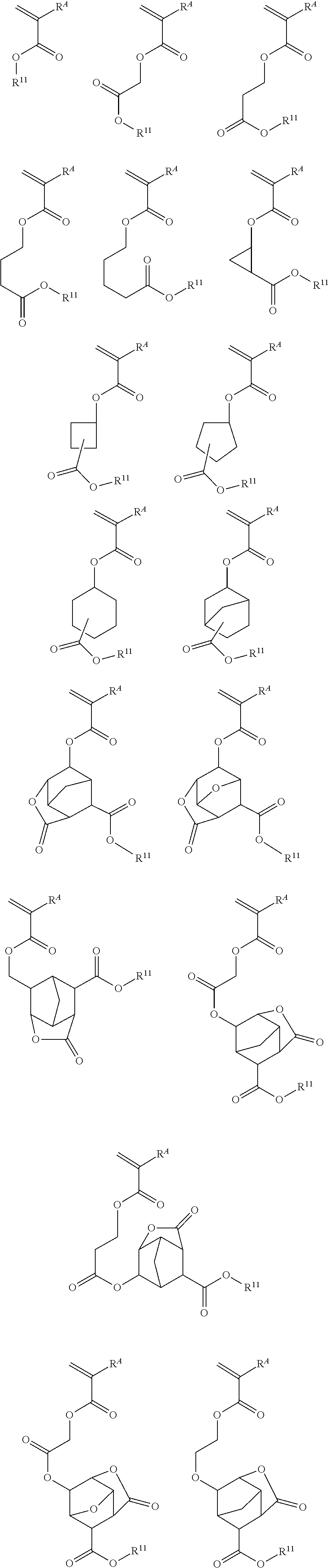

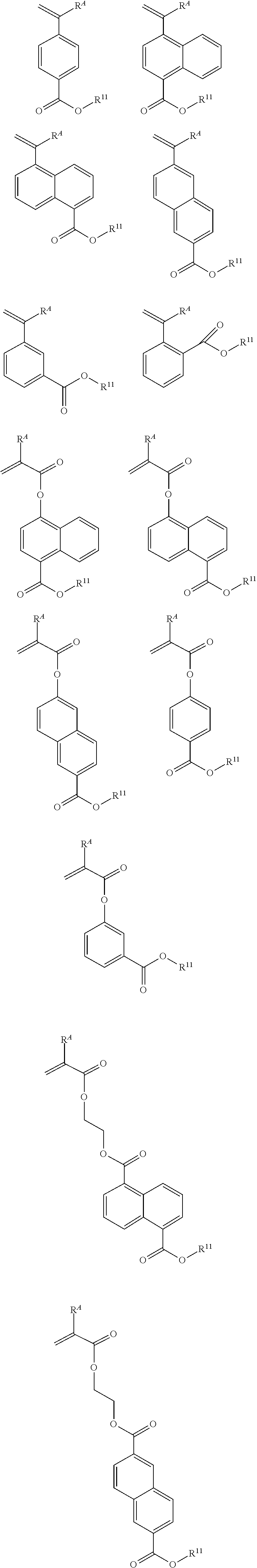

Examples of the monomer from which repeat units (c2) are derived are shown below, but not limited thereto. R^{A} and R¹² are as defined above.

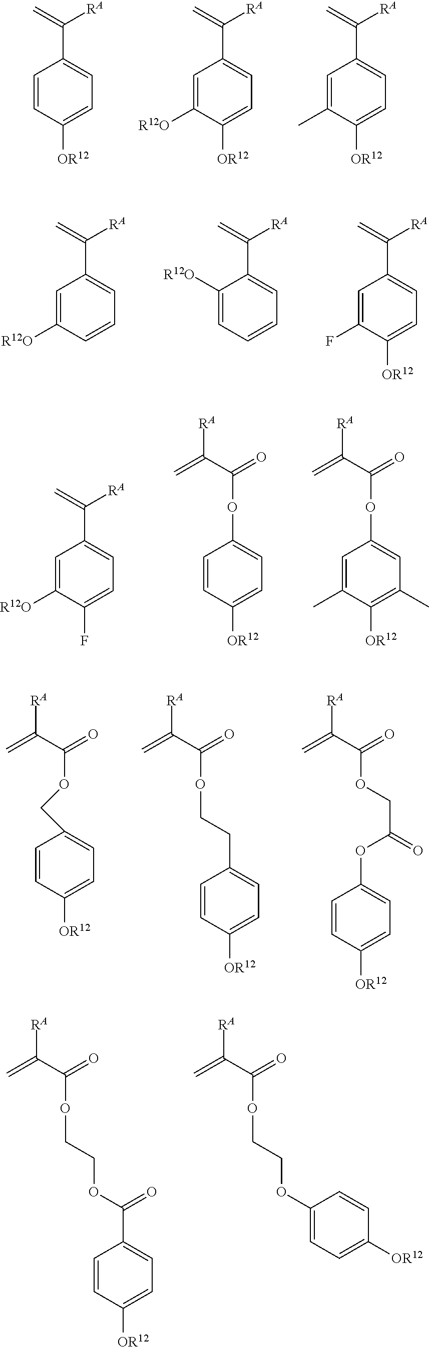

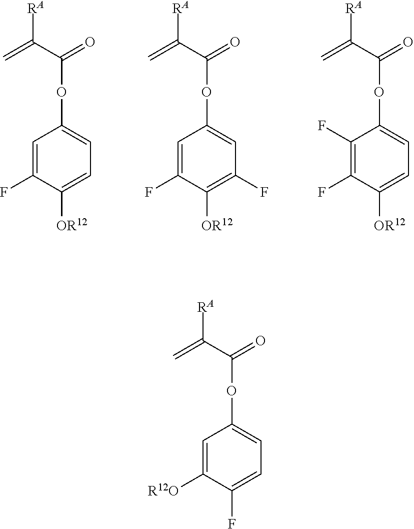

The acid labile groups represented by R¹¹ and R¹² may be selected from a variety of such groups, for example, groups having the following formulae (AL-1) to (AL-3).

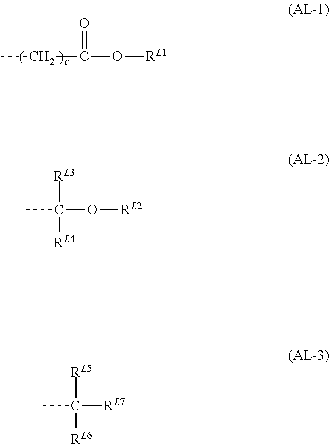

In formula (AL-1), c is an integer of 0 to 6. R^{L1} is a C₄-C₂₀, preferably C₄-C₁₅ tertiary hydrocarbyl group, a trihydrocarbylsilyl group in which each hydrocarbyl moiety is a C₁-C₆ saturated one, a C₄-C₂₀ saturated hydrocarbyl group containing a carbonyl moiety, ether bond or ester bond, or a group of formula (AL-3). Notably, the tertiary hydrocarbyl group is a group obtained from a tertiary hydrocarbon by eliminating hydrogen on the tertiary carbon.

The tertiary hydrocarbyl group R^{L1} may be saturated or unsaturated and branched or cyclic. Examples thereof include tert-butyl, tert-pentyl, 1,1-diethylpropyl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, and 2-methyl-2-adamantyl. Examples of the trihydrocarbylsilyl group include trialkylsilyl groups such as trimethylsilyl, triethylsilyl, and dimethyl-tert-butylsilyl. The saturated hydrocarbyl group containing a carbonyl moiety, ether bond or ester bond may be straight, branched or cyclic, preferably cyclic and examples thereof include 3-oxocyclohexyl, 4-methyl-2-oxooxan-4-yl, 5-methyl-2-oxooxolan-5-yl, 2-tetrahydropyranyl, and 2-tetrahydrofuranyl.

Examples of the acid labile group having formula (AL-1) include tert-butoxycarbonyl, tert-butoxycarbonylmethyl, tert-pentyloxycarbonyl, tert-pentyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl.

Other examples of the acid labile group having formula (AL-1) include groups having the formulae (AL-1)-1 to (AL-1)-10.

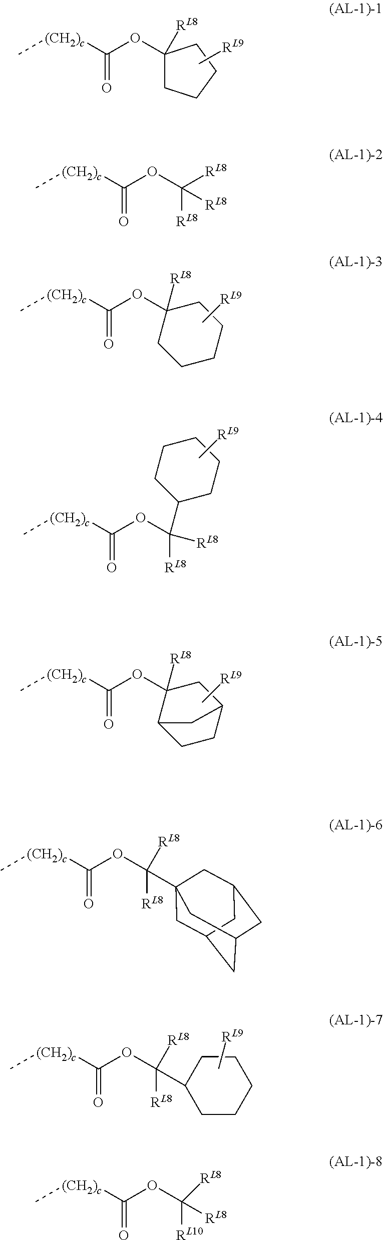

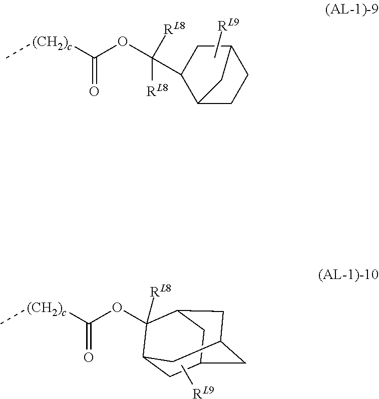

In formulae (AL-1)-1 to (AL-1)-10, c is as defined above. R^{L8} is each independently a C₁-C₁₀ saturated hydrocarbyl group or C₆-C₂₀ aryl group. R^{L9} is hydrogen or a C₁-C₁₀ saturated hydrocarbyl group. R^{L10} is a C₂-C₁₀ saturated hydrocarbyl group or C₆-C₂₀ aryl group. The saturated hydrocarbyl group may be straight, branched or cyclic.

In formula (AL-2), R^{L2} and R^{L3} are each independently hydrogen or a C₁-C₁₈, preferably C₁-C₁₀ saturated hydrocarbyl group. The saturated hydrocarbyl group may be straight, branched or cyclic and examples thereof include methyl, ethyl, n-propyl, isopropyl, n-butyl, isobutyl, sec-butyl, tert-butyl, cyclopentyl, cyclohexyl, 2-ethylhexyl and n-octyl.

R^{L4} is a C₁-C₁₈, preferably C₁-C₁₀ hydrocarbyl group which may contain a heteroatom. The hydrocarbyl group may be saturated or unsaturated and straight, branched or cyclic. Typical are C₁-C₁₈ saturated hydrocarbyl groups, in which some hydrogen may be substituted by hydroxy, alkoxy, oxo, amino or alkylamino. Examples of the substituted saturated hydrocarbyl group are shown below.

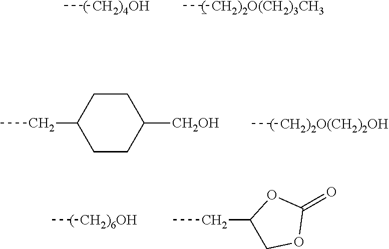

A pair of R^{L2} and R^{L3}, R^{L2} and R^{L4}, or R^{L3} and R^{L4} may bond together to form a ring with the carbon atom or carbon and oxygen atoms to which they are attached. R^{L2} and R^{L3}, R^{L2} and R^{L4}, or R^{L3} and R^{L4} that form a ring are each independently a C₁-C₁₈, preferably C₁-C₁₀ alkanediyl group. The ring thus formed is preferably of 3 to 10, more preferably 4 to 10 carbon atoms.

Of the acid labile groups having formula (AL-2), suitable straight or branched groups include those having formulae (AL-2)-1 to (AL-2)-69, but are not limited thereto.

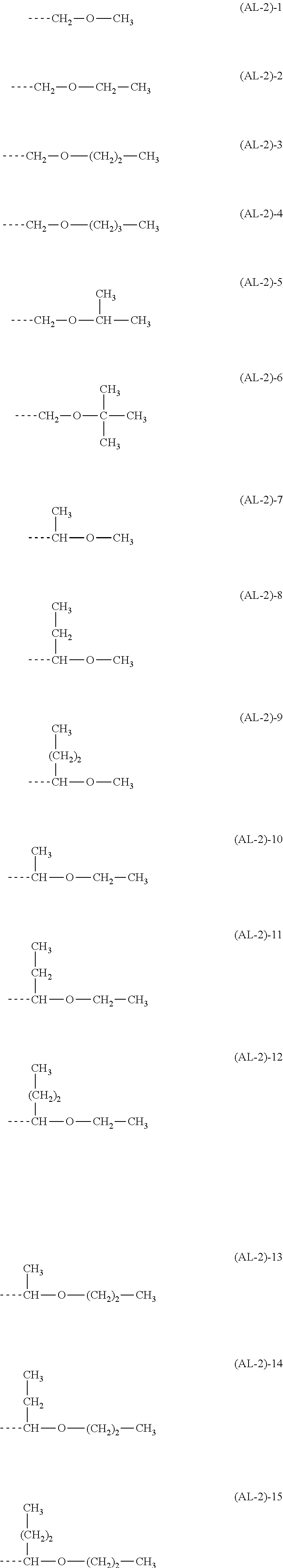

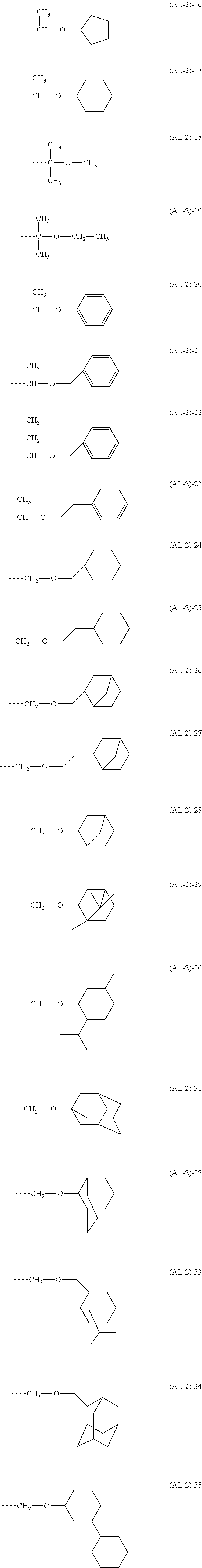

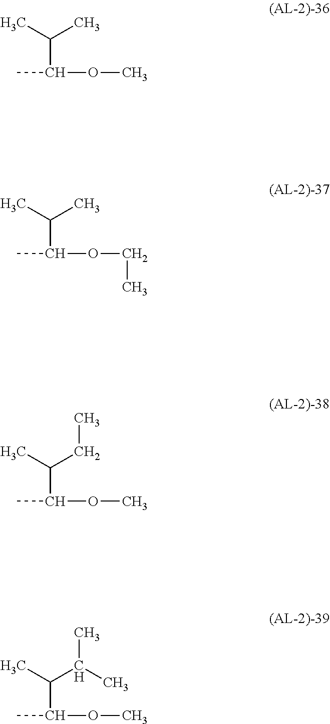

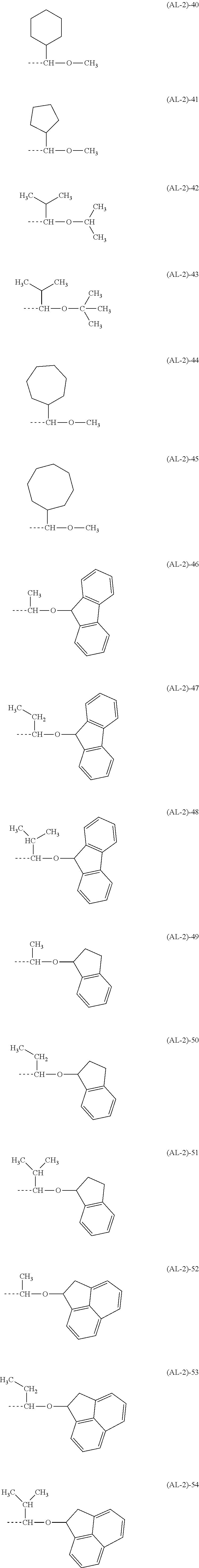

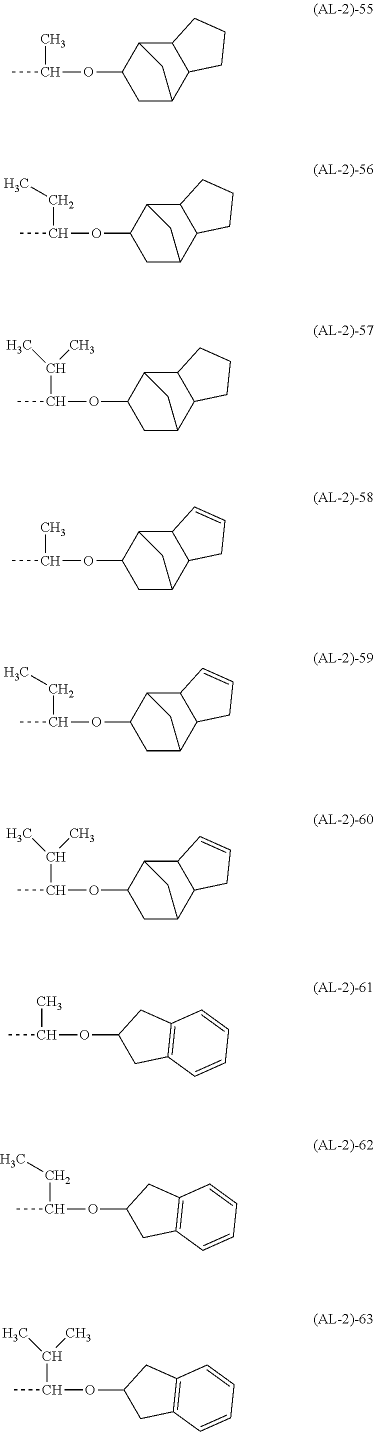

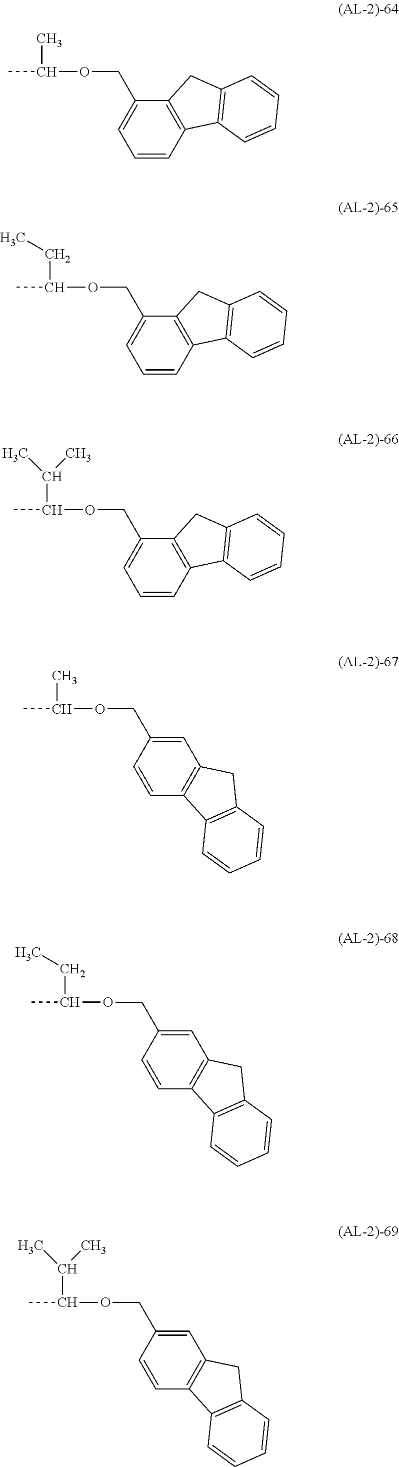

Of the acid labile groups having formula (AL-2), suitable cyclic groups include tetrahydrofuran-2-yl, 2-methyltetrahydrofuran-2-yl, tetrahydropyran-2-yl, and 2-methyltetrahydropyran-2-yl.

Also included are acid labile groups having the following formulae (AL-2a) and (AL-2b). The base polymer may be crosslinked within the molecule or between molecules with these acid labile groups.

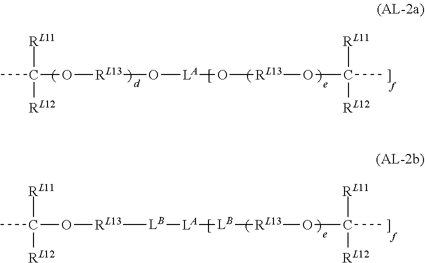

In formulae (AL-2a) and (AL-2b), R^{L11} and R^{L12} are each independently hydrogen or a C₁-C₈ saturated hydrocarbyl group which may be straight, branched or cyclic. Also, R^{L11} and R^{L12} may bond together to form a ring with the carbon atom to which they are attached, and in this case, R^{L11} and R^{L12} are each independently a C₁-C₈ alkanediyl group. R^{L13} is each independently a C₁-C₁₀ saturated hydrocarbylene group which may be straight, branched or cyclic. The subscripts d and e are each independently an integer of 0 to 10, preferably 0 to 5, and f is an integer of 1 to 7, preferably 1 to 3.

In formulae (AL-2a) and (AL-2b), L^{A} is a (f+1)-valent C₁-C₅₀ aliphatic saturated hydrocarbon group, (f+1)-valent C₃-C₅₀ alicyclic saturated hydrocarbon group, (f+1)-valent C₆-C₅₀ aromatic hydrocarbon group or (f+1)-valent C₃-C₅₀ heterocyclic group. In these groups, some constituent —CH₂— may be replaced by a heteroatom-containing moiety, or some hydrogen may be substituted by a hydroxy, carboxy, acyl moiety or fluorine. L^{A} is preferably a C₁-C₂₀ saturated hydrocarbylene, saturated hydrocarbon group (e.g., tri- or tetravalent saturated hydrocarbon group), or C₆-C₃₀ arylene group. The saturated hydrocarbon group may be straight, branched or cyclic. L^{B} is —C(═O)—O—, —NH—C(═O)—O— or —NH—C(═O)—NH—.

Examples of the crosslinking acetal groups having formulae (AL-2a) and (AL-2b) include groups having the formulae (AL-2)-70 to (AL-2)-77.

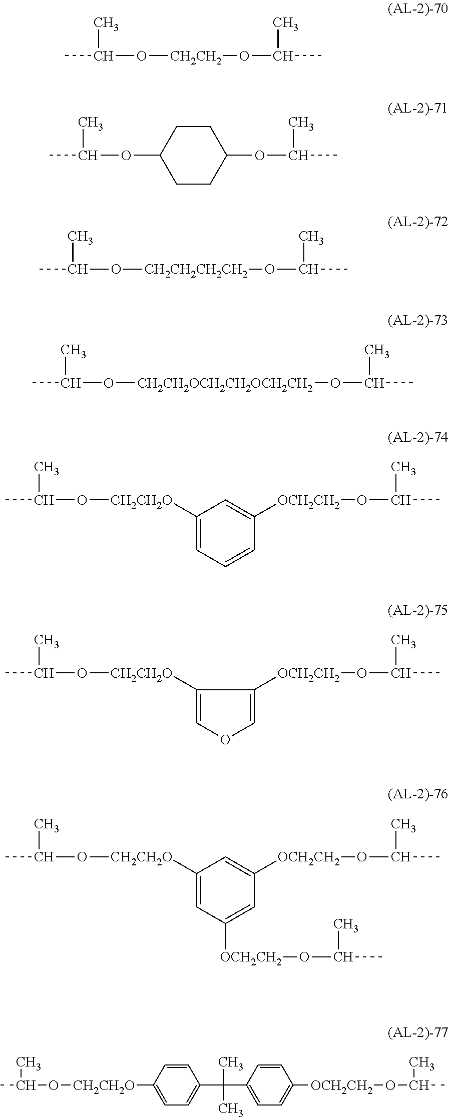

In formula (AL-3), R^{L5}, R^{L6} and R^{L7} are each independently a C₁-C₂₀ hydrocarbyl group which may contain a heteroatom such as oxygen, sulfur, nitrogen or fluorine. The hydrocarbyl group may be saturated or unsaturated and straight, branched or cyclic. Examples thereof include C₁-C₂₀ alkyl groups, C₃-C₂₀ cyclic saturated hydrocarbyl groups, C₂-C₂₀ alkenyl groups, C₃-C₂₀ cyclic unsaturated hydrocarbyl groups, and C₆-C₁₀ aryl groups. A pair of R^{L5} and R^{L6}, R^{L5} and R^{L7}, or R^{L6} and R^{L7} may bond together to form a C₃-C₂₀ aliphatic ring with the carbon atom to which they are attached.

Examples of the group having formula (AL-3) include tert-butyl, 1,1-diethylpropyl, 1-ethylnorbornyl, 1-methylcyclopentyl, 1-ethylcyclopentyl, 1-isopropylcyclopentyl, 1-methylcyclohexyl, 2-(2-methyl) adamantyl, 2-(2-ethyl) adamantyl, and tert-pentyl.

Examples of the group having formula (AL-3) also include groups having the formulae (AL-3)-1 to (AL-3)-19.

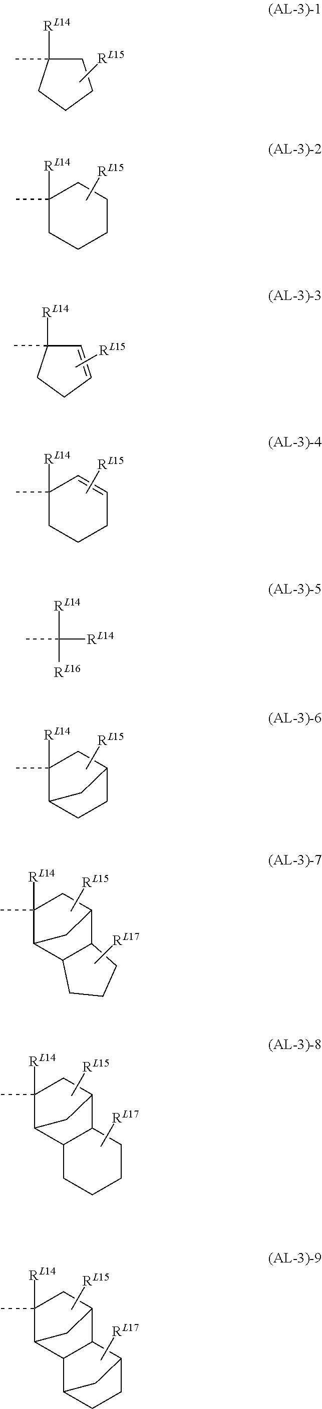

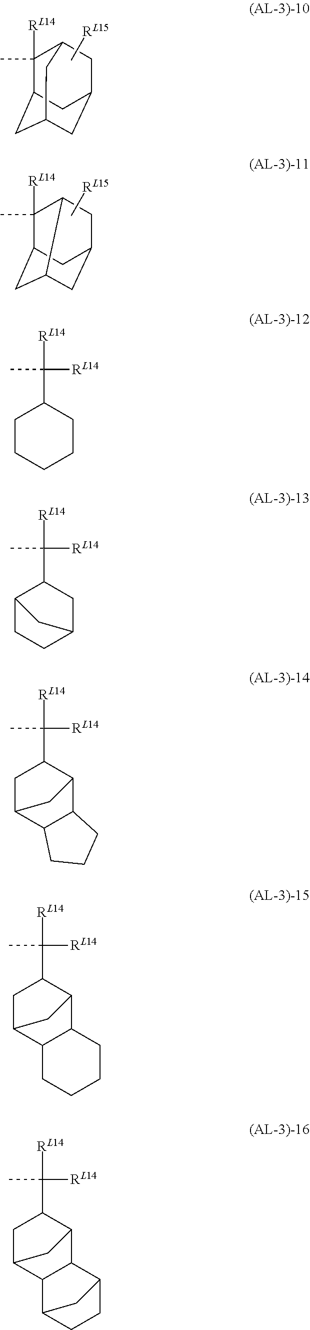

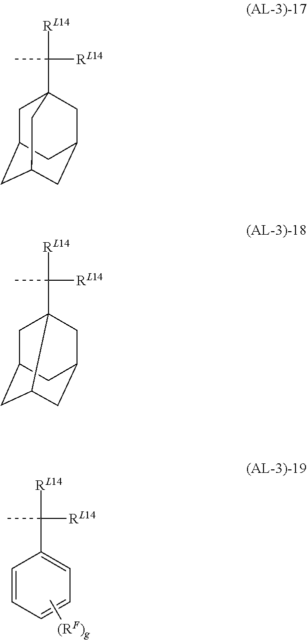

In formulae (AL-3)-1 to (AL-3)-19, R^{L14} is each independently hydrogen, a C₁-C₈ saturated hydrocarbyl group or C₆-C₂₀ aryl group. R^{L15} and R^{L17} are each independently hydrogen or a C₁-C₂₀ saturated hydrocarbyl group. R^{L16} is a C₆-C₂₀ aryl group. The saturated hydrocarbyl group may be straight, branched or cyclic. Typical of the aryl group is phenyl. R^{F} is fluorine or trifluoromethyl, and g is an integer of 1 to 5.

Other examples of the acid labile group having formula (AL-3) include groups having the formulae (AL-3)-20 and (AL-3)-21. The base polymer may be crosslinked within the molecule or between molecules with these acid labile groups.

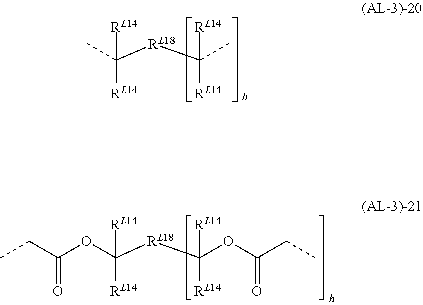

In formulae (AL-3)-20 and (AL-3)-21, R^{L14} is as defined above. R^{L18} is a (h+1)-valent C₁-C₂₀ saturated hydrocarbylene group or (h+1)-valent C₆-C₂₀ arylene group, which may contain a heteroatom such as oxygen, sulfur or nitrogen. The saturated hydrocarbylene group may be straight, branched or cyclic. The subscript h is an integer of 1 to 3.

Examples of the monomer from which repeat units containing an acid labile group of formula (AL-3) are derived include (meth)acrylates (inclusive of exo-form structure) having the formula (AL-3)-22.

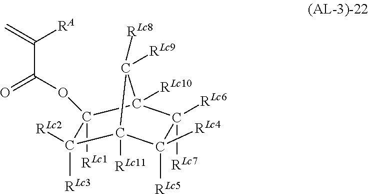

In formula (AL-3)-22, R^{A} is as defined above. R^{Le1} is a C₁-C₈ saturated hydrocarbyl group or an optionally substituted C₆-C₂₀ aryl group; the saturated hydrocarbyl group may be straight, branched or cyclic. R^{Lc2} to R^{Lc11} are each independently hydrogen or a C₁-C₁₅ hydrocarbyl group which may contain a heteroatom; oxygen is a typical heteroatom. Suitable hydrocarbyl groups include C₁-C₁₅ alkyl groups and C₆-C₁₅ aryl groups. Alternatively, a pair of R^{Lc2} and R^{Lc3}, R^{Lc4} and R^{Lc6}, R^{Lc4} and R^{Lc7}, R^{Lc5} and R^{Lc7}, R^{Lc5} and R^{Lc11}, R^{Lc6} and R^{Lc10}, R^{Lc8} and R^{Lc9}, or R^{Lc9} and R^{Lc10}, taken together, may form a ring with the carbon atom to which they are attached, and in this event, the ring-forming group is a C₁-C₁₅ hydrocarbylene group which may contain a heteroatom. Also, a pair of R^{Lc2} and R^{Lc11}, R^{Lc8} and R^{Lc11}, or R^{Lc4} and R^{Lc6} which are attached to vicinal carbon atoms may bond together directly to form a double bond. The formula also represents an enantiomer.

Examples of the monomer having formula (AL-3)-22 are described in U.S. Pat. No. 6,448,420 (JP-A 2000-327633). Illustrative non-limiting examples of suitable monomers are given below. R^{A} is as defined above.

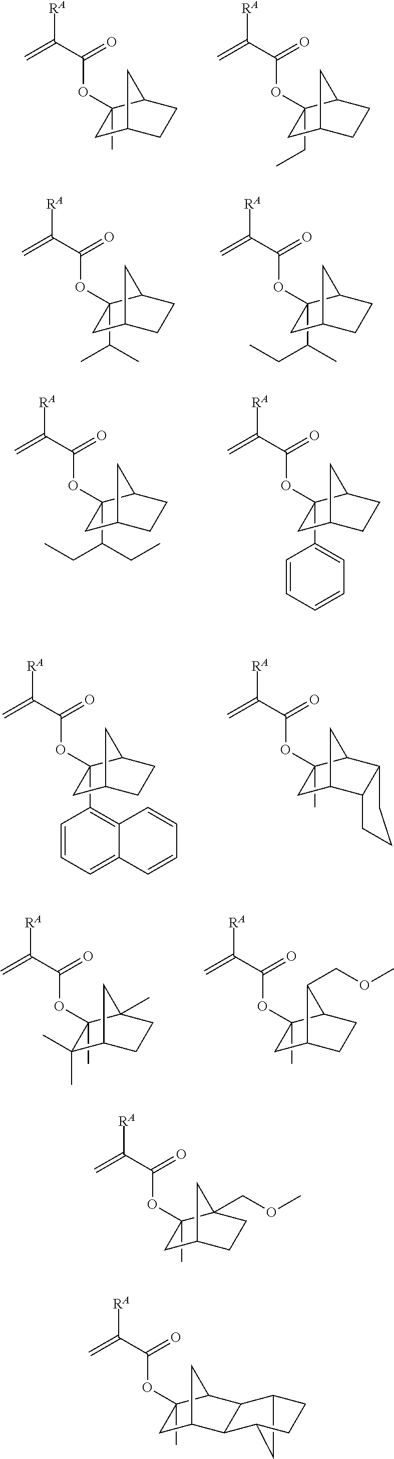

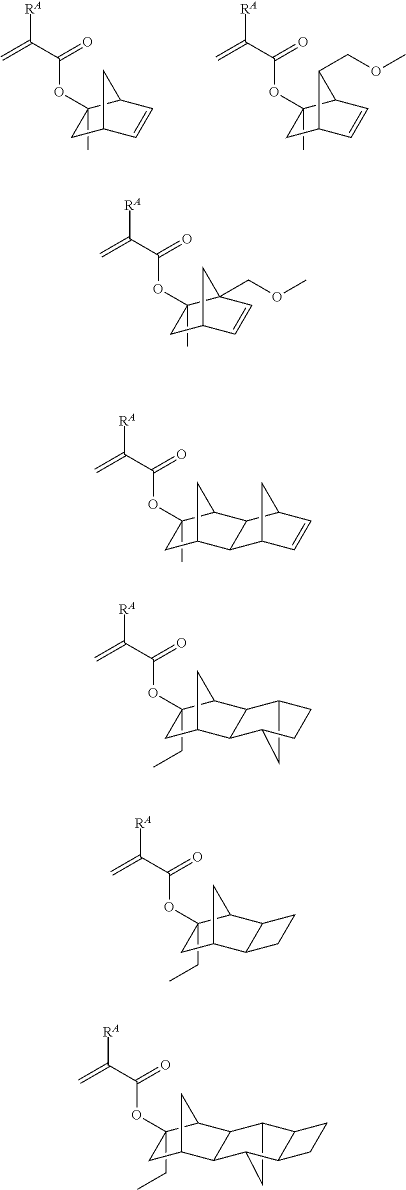

Examples of the monomer from which the repeat units having an acid labile group of formula (AL-3) are derived also include (meth)acrylate monomers having a furandiyl, tetrahydrofurandiyl or oxanorbornanediyl group as represented by the following formula (AL-3)-23.

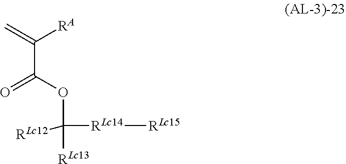

In formula (AL-3)-23, R^{A} is as defined above. R^{Lc12} and R^{Lc13} are each independently a C₁-C₁₀ hydrocarbyl group, or R^{Lc12} and R^{Lc13}, taken together, may form an aliphatic ring with the carbon atom to which they are attached. R^{Lc14} is furandiyl, tetrahydrofurandiyl or oxanorbornanediyl. R^{Lc15} is hydrogen or a C₁-C₁₀ hydrocarbyl group which may contain a heteroatom. The hydrocarbyl group may be straight, branched or 10 cyclic, and examples thereof include C₁-C₁₀ saturated hydrocarbyl groups.

Examples of the monomer having formula (AL-3)-23 are shown below, but not limited thereto. Herein R^{A} is as defined above.

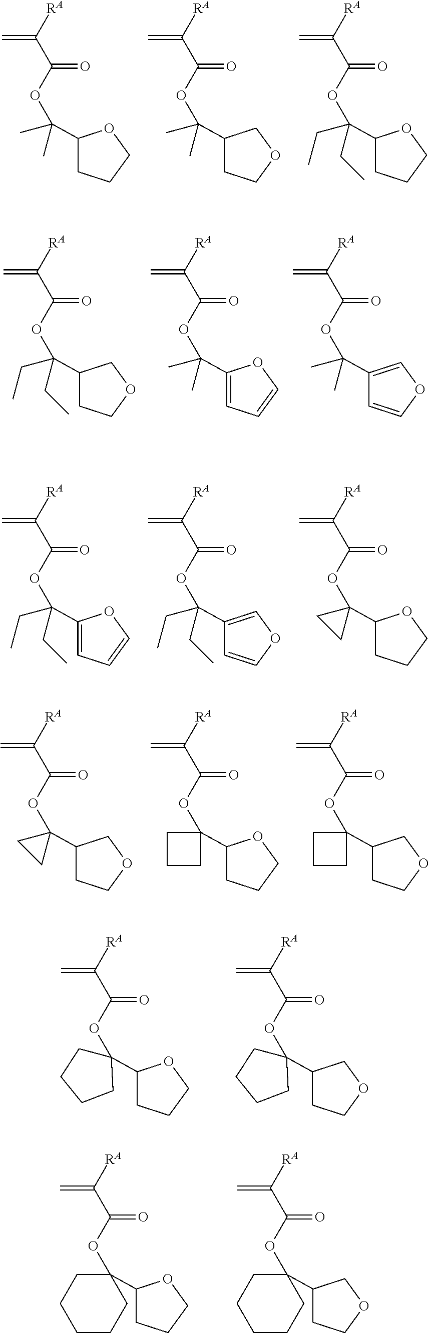

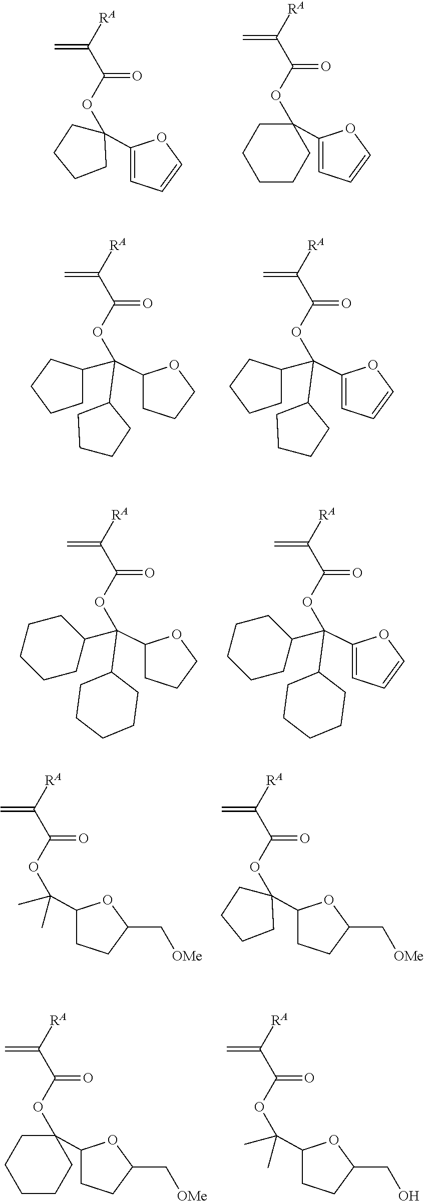

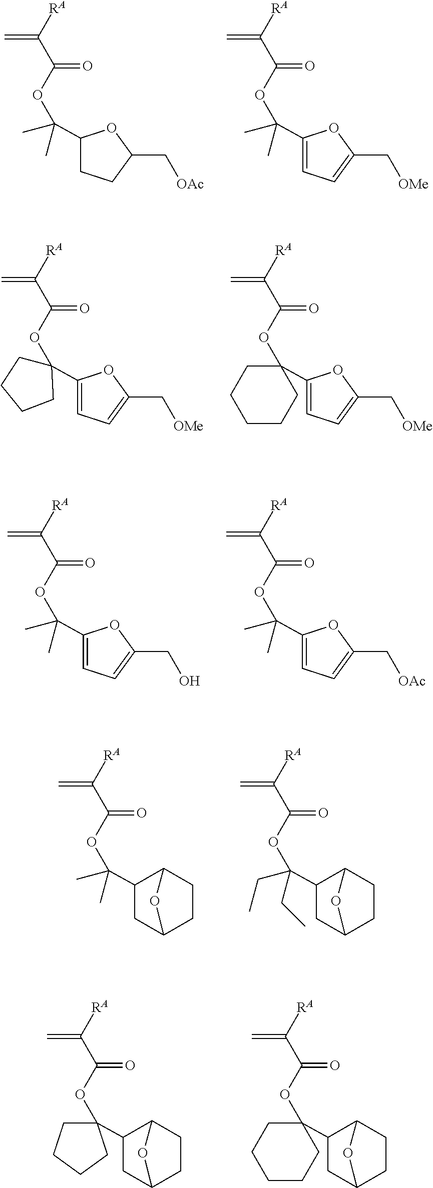

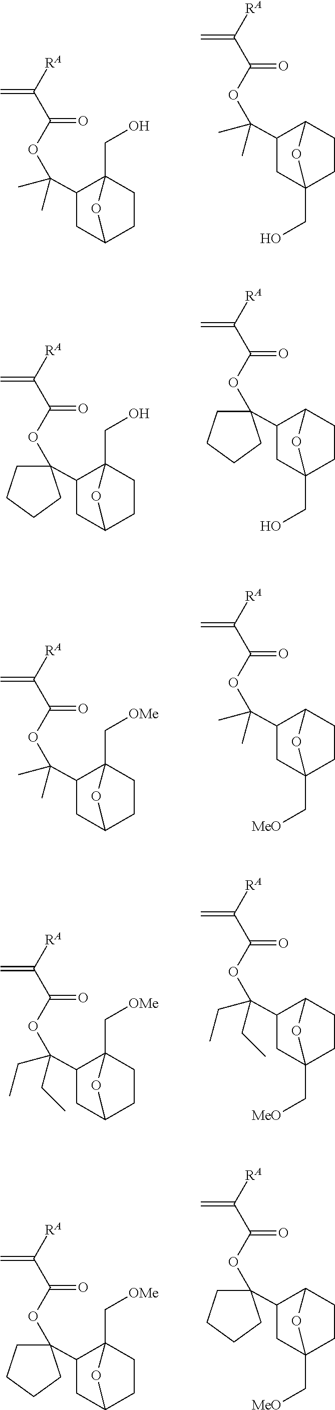

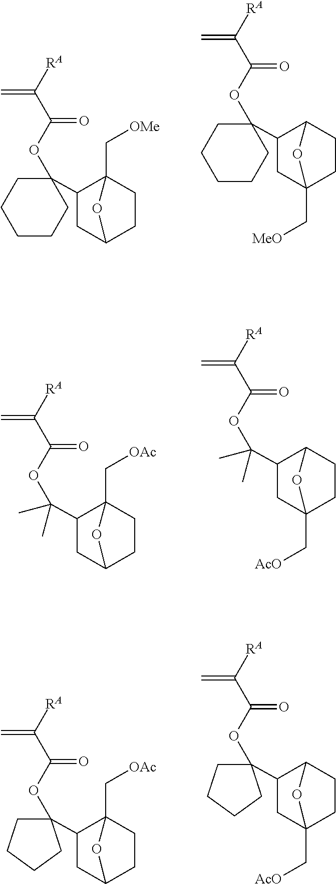

The base polymer may further comprise a repeat unit (d) having an adhesive group. The adhesive group is selected from hydroxy, carboxy, lactone ring, carbonate bond, thiocarbonate bond, carbonyl, cyclic acetal, ether bond, ester bond, sulfonate ester bond, cyano, amide bond, —O—C(═O)—S— and —O—C(═O)—NH—.

Examples of the monomer from which repeat unit (d) is derived are given below, but not limited thereto. Herein R^{A} is as defined above.

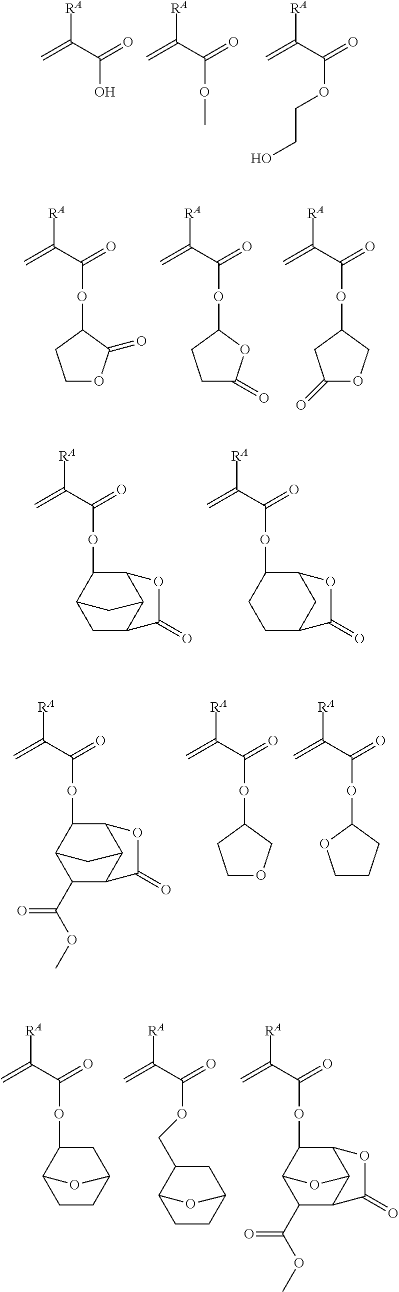

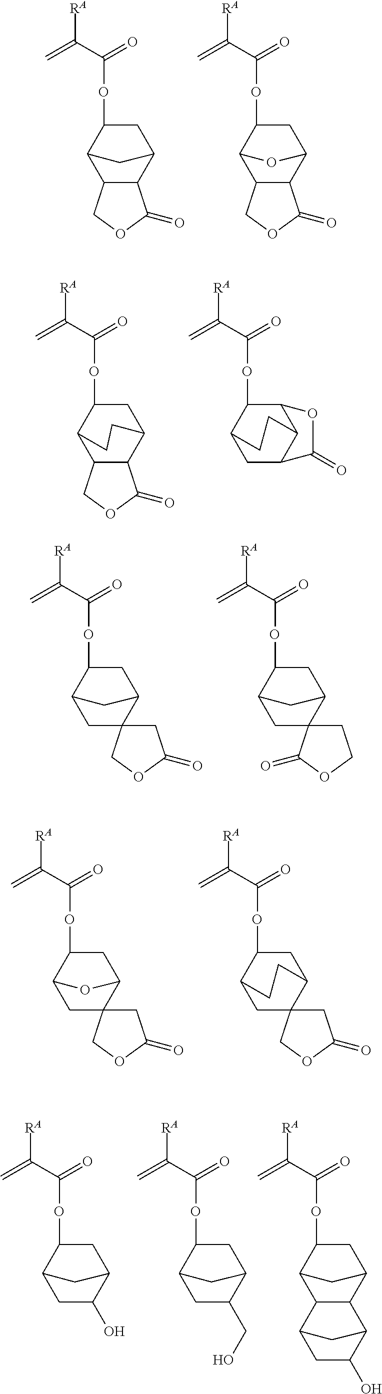

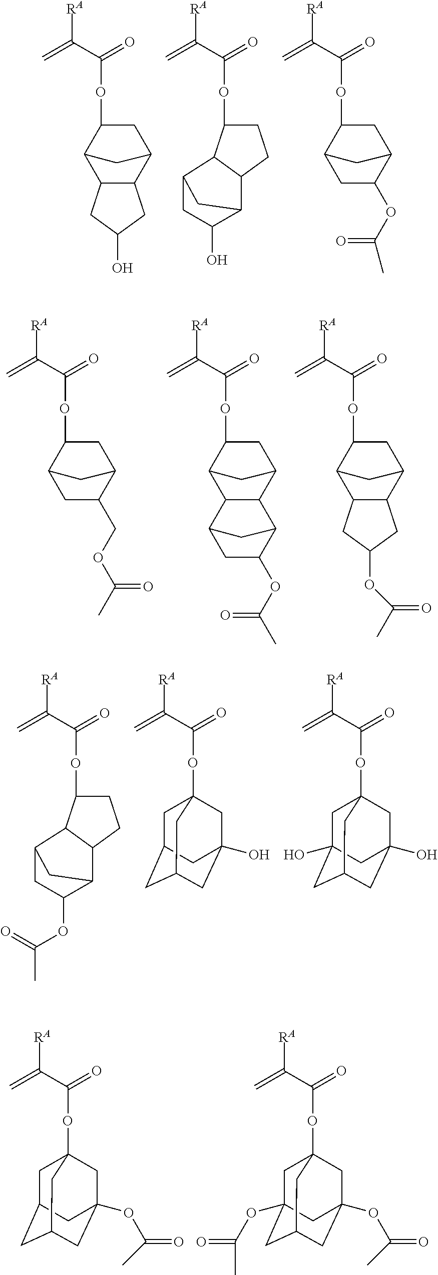

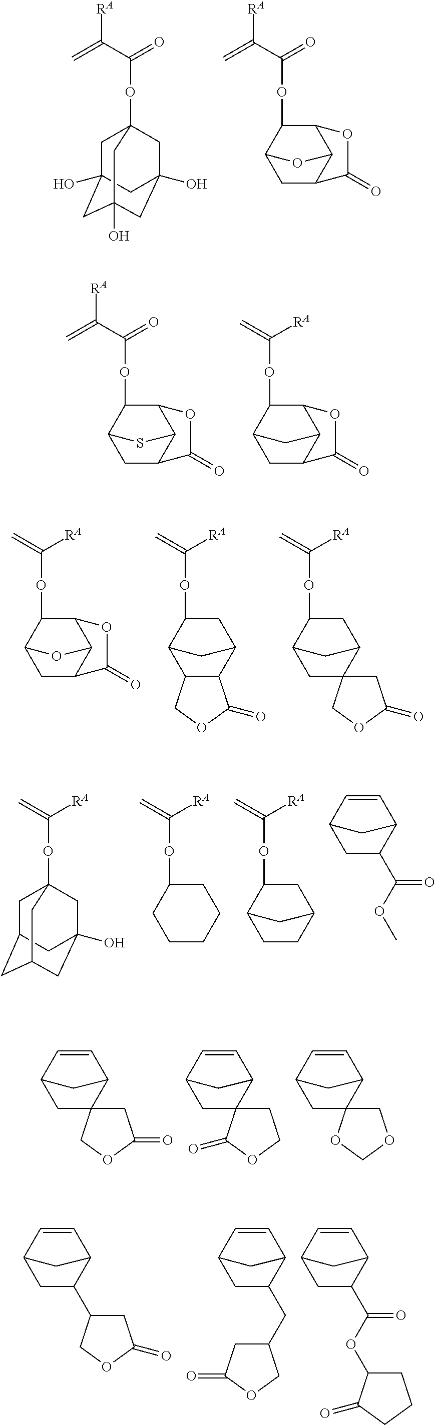

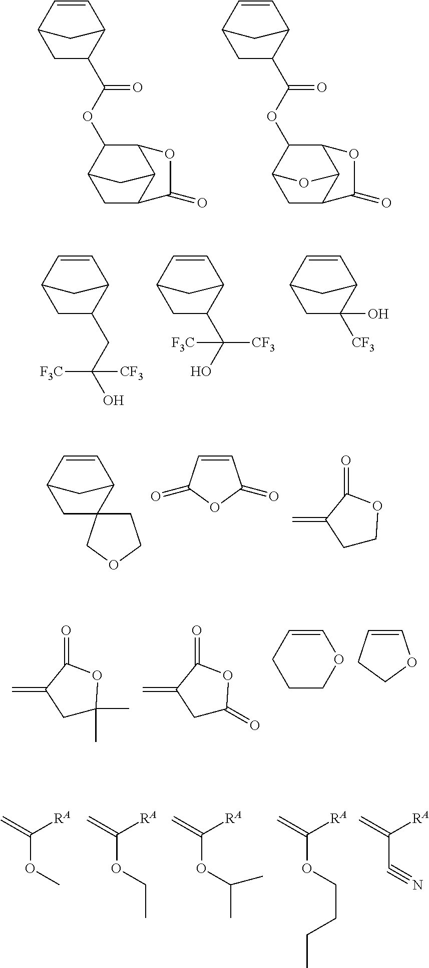

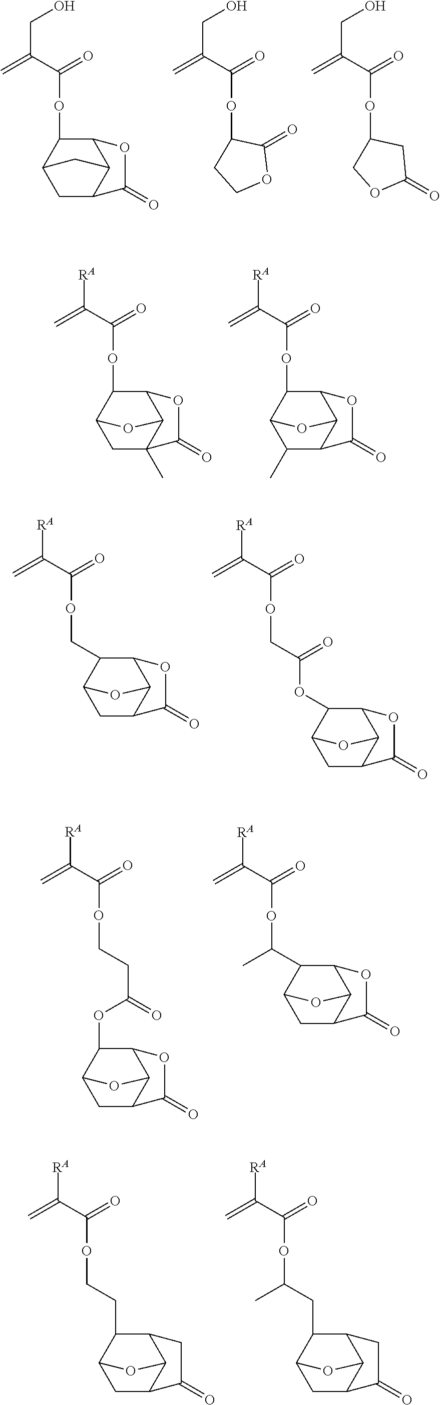

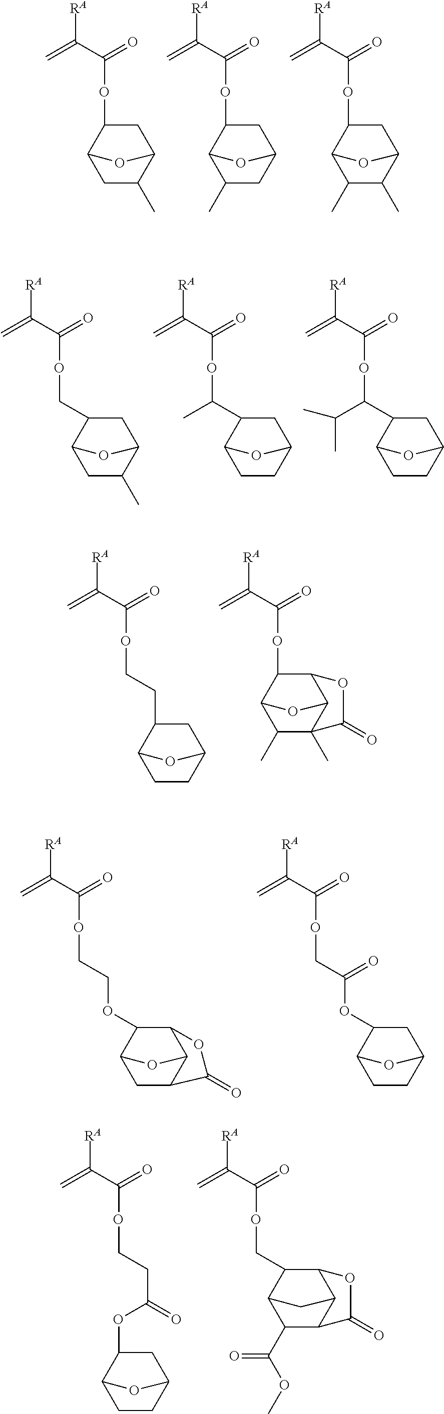

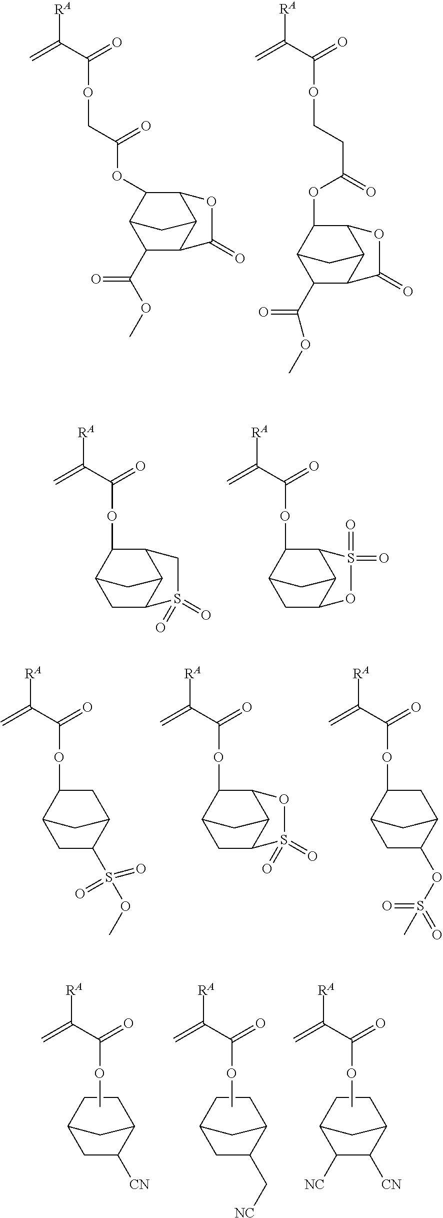

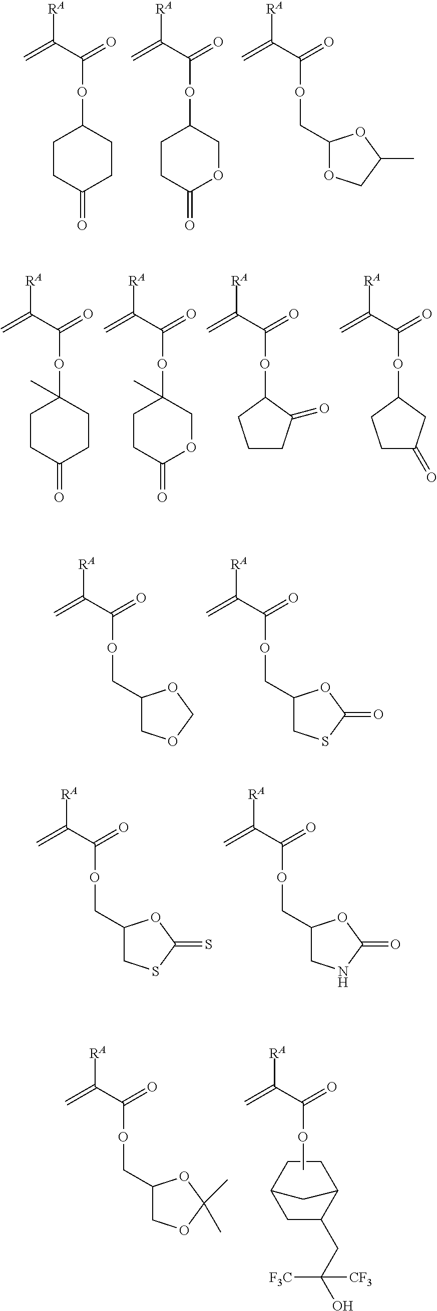

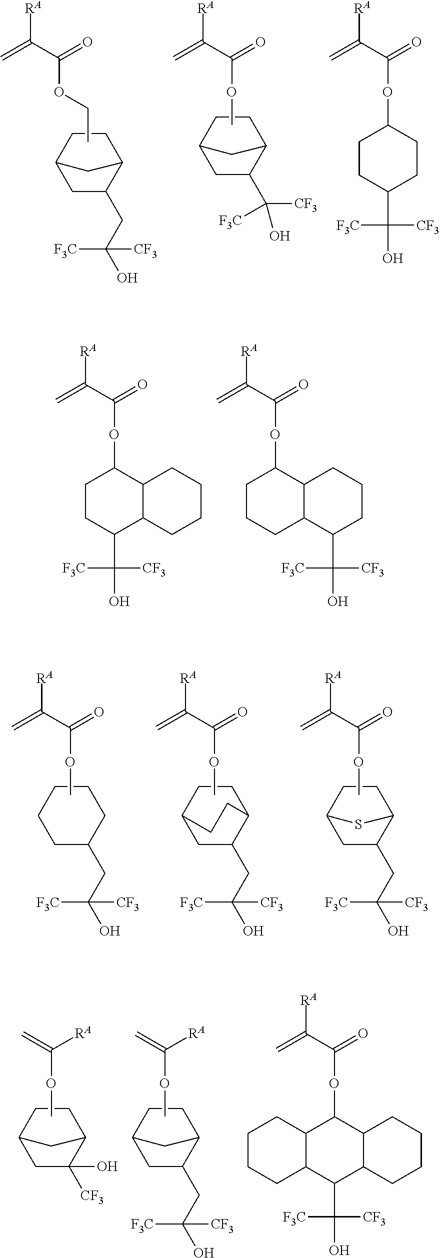

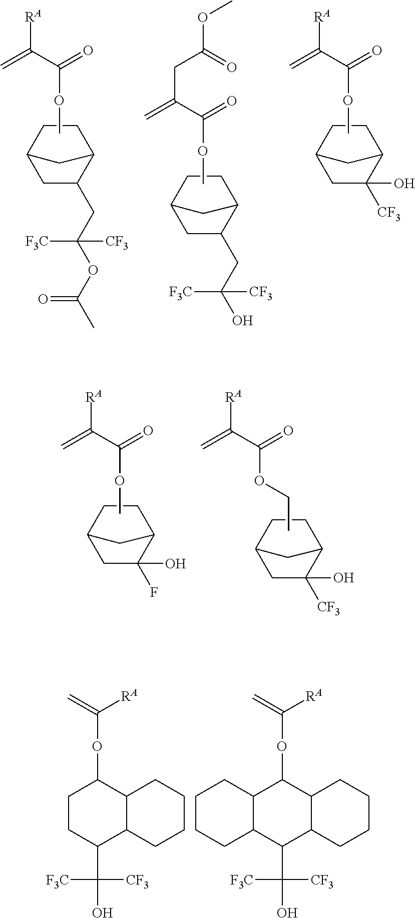

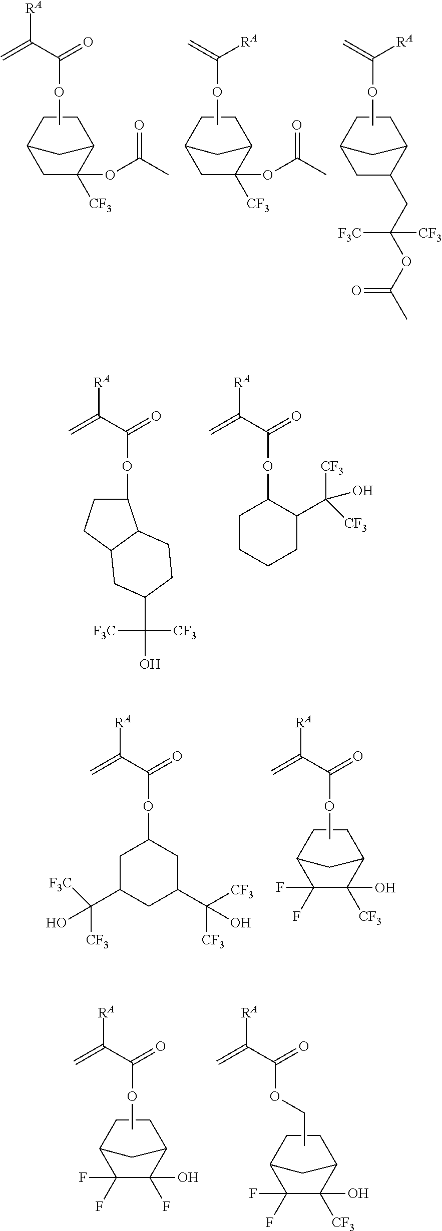

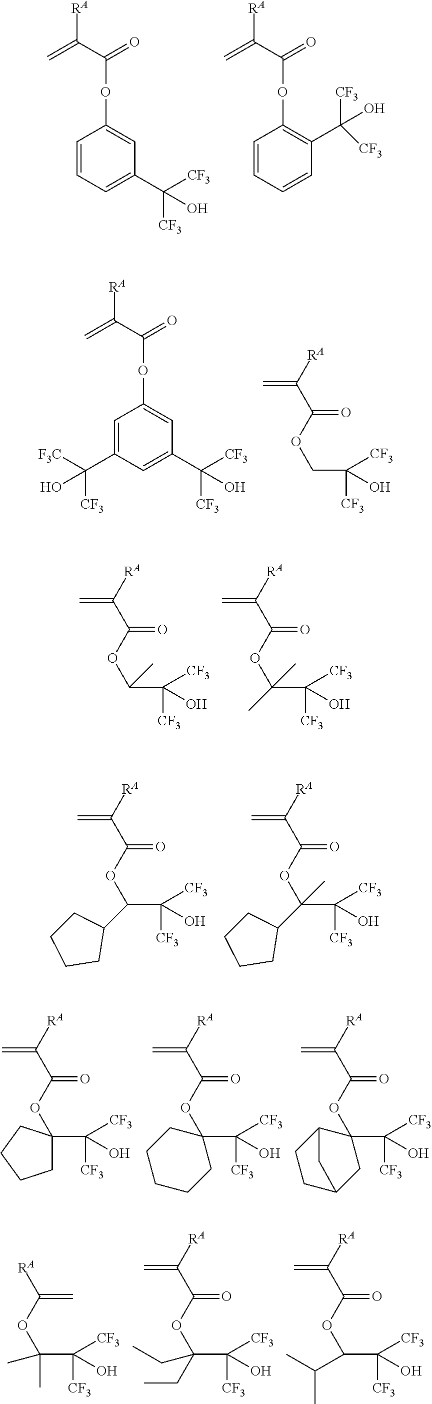

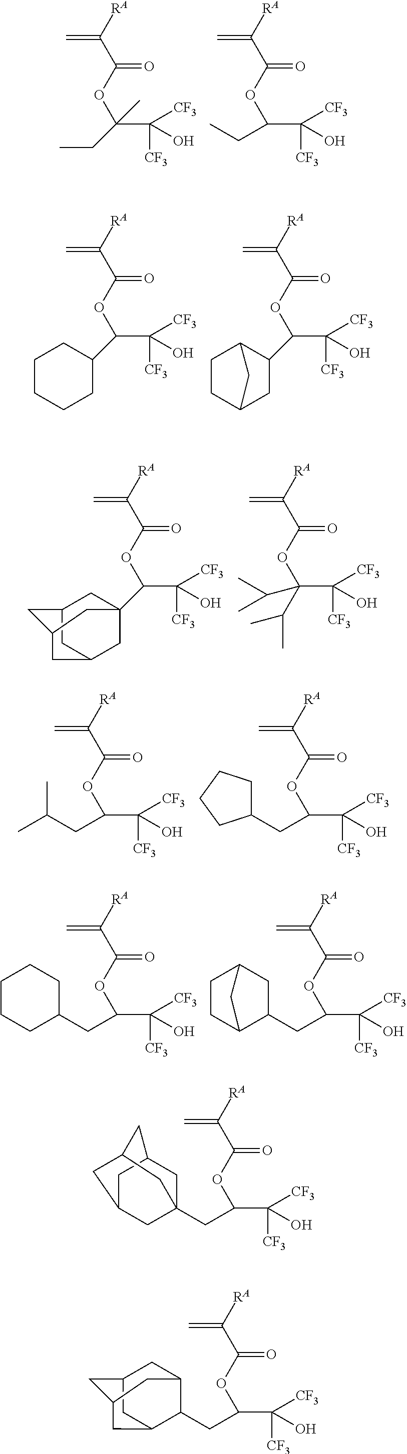

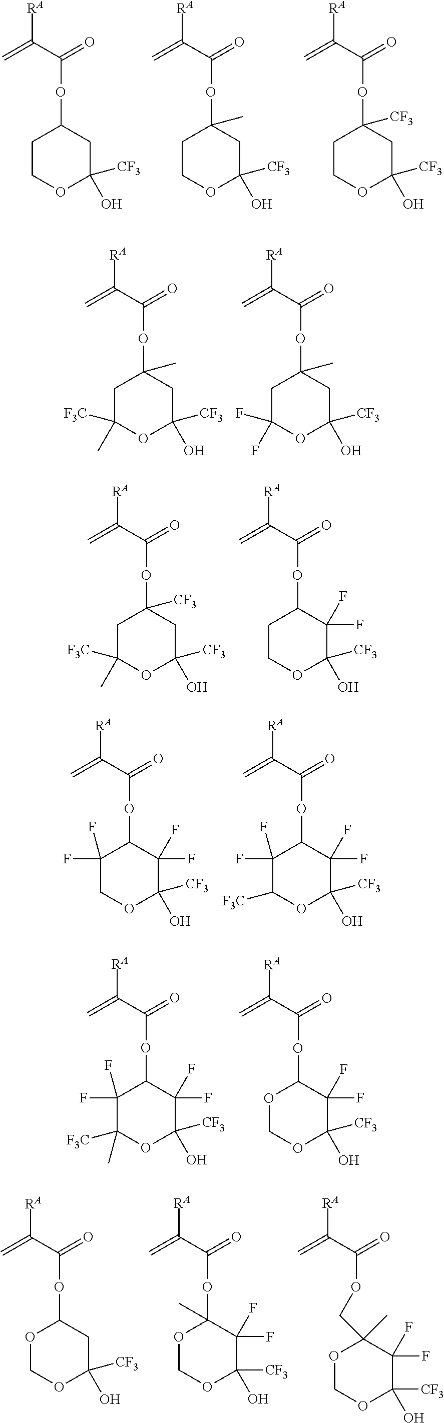

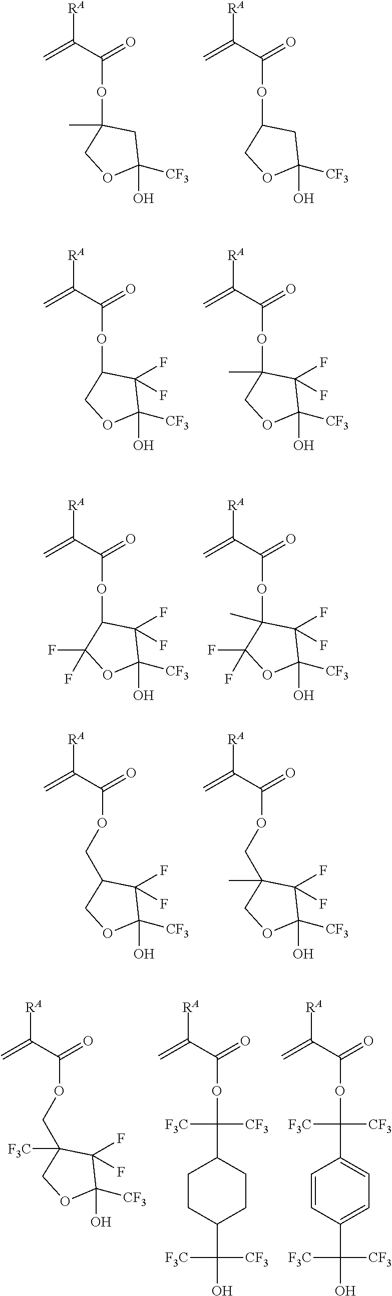

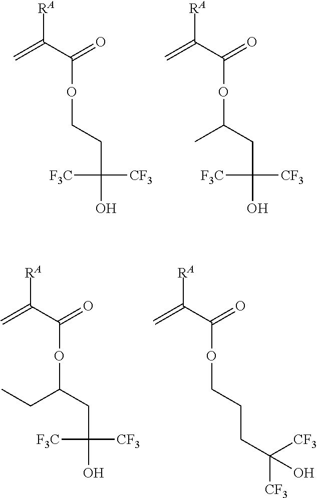

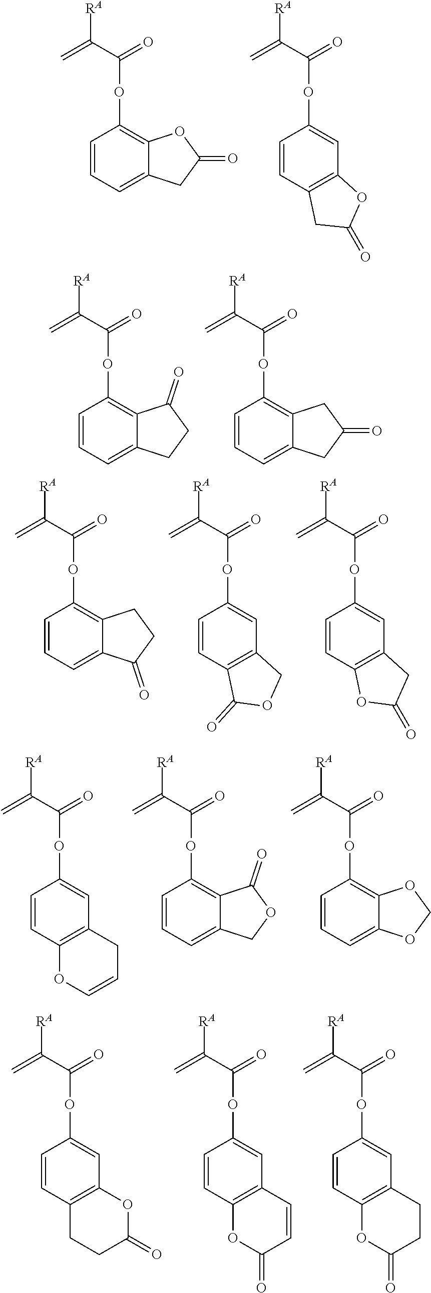

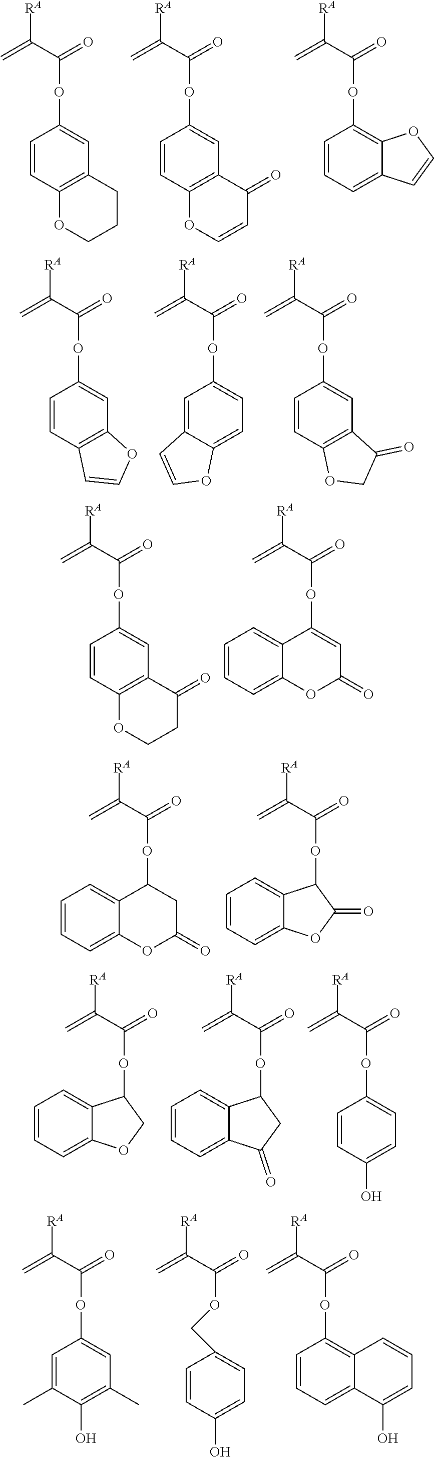

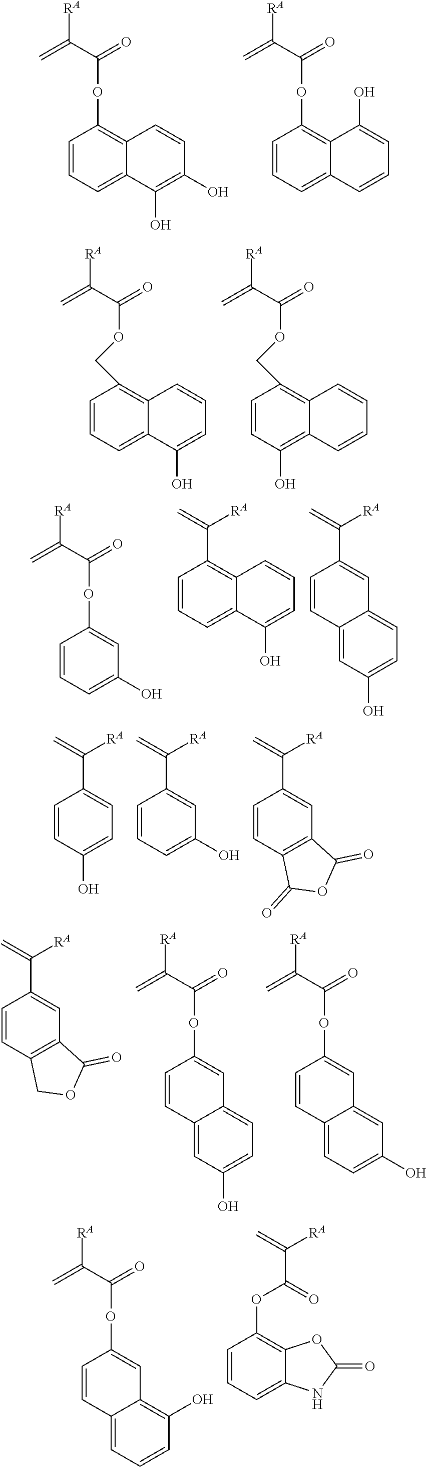

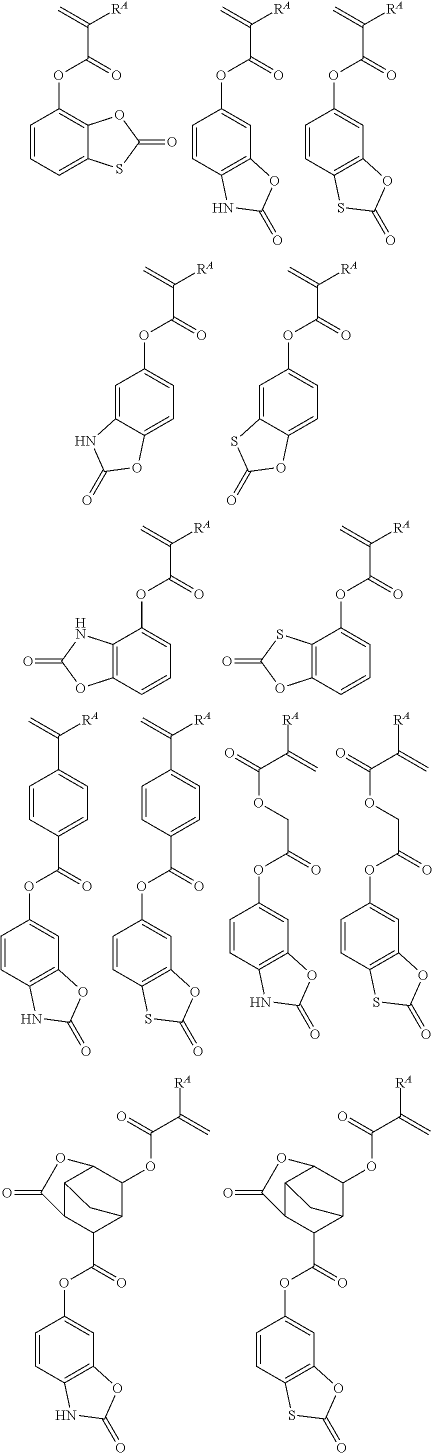

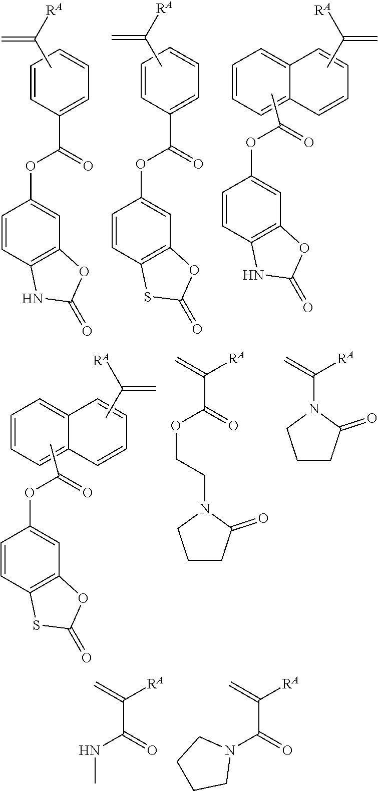

The base polymer may further comprise a repeat unit (e) containing iodine, but not amino group. Examples of the monomer from which repeat unit (e) is derived are given below, but not limited thereto. Herein R^{A} is as defined above.

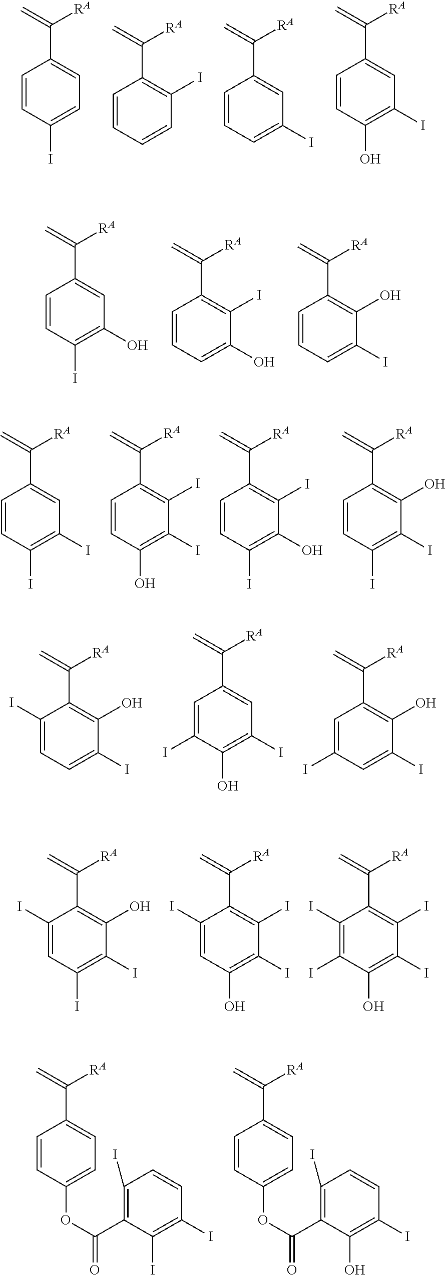

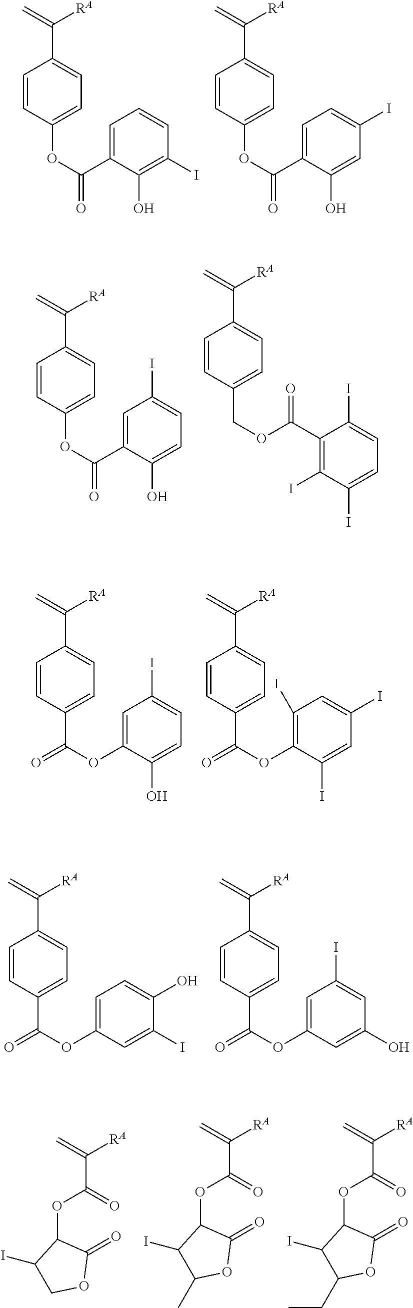

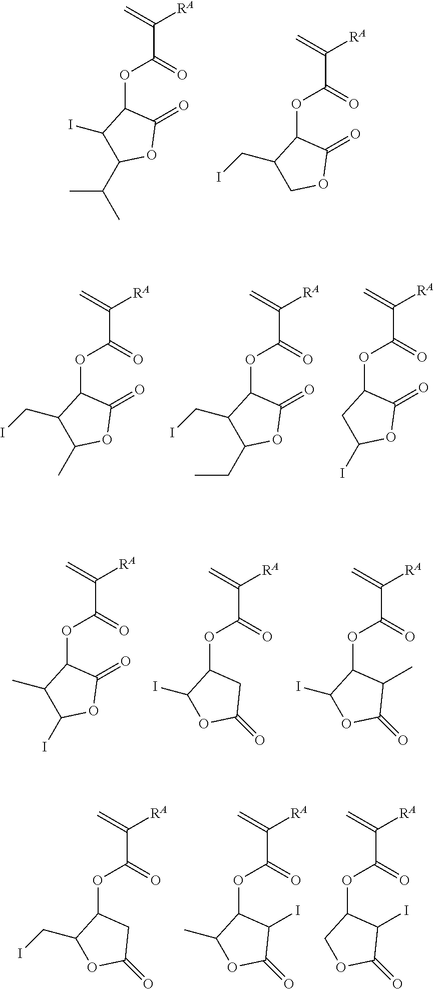

Besides the above-mentioned repeat units, the base polymer may further comprise a repeat unit (f) which is derived from styrene, vinylnaphthalene, indene, acenaphthylene, coumarin, and coumarone compounds.

In the base polymer comprising repeat units (a1), (a2), (b1), (b2), (c), (d1), (d2), (d3), (e) and (f), a fraction of these units is:
preferably 0≤a1<1.0, 0≤a2<1.0, 0<a1+a2<1.0, 0≤b1≤0.9, 0≤b2≤0.9, 0<b1+b2≤0.9, 0≤c≤0.9, 0≤d1≤0.5, 0≤d2≤0.5, 0≤d3≤0.5, 0≤d1+d2+d3≤0.5, 0≤e≤0.5, and 0≤f≤0.5;
more preferably 0.001≤a1≤0.8, 0.001≤a2≤0.8, 0.001≤a1+a2≤0.8, 0≤b1≤0.8, 0≤b2≤0.8, 0.1≤b1+b2≤0.8, 0≤c≤0.8, 0≤d1≤0.4, 0≤d2≤0.4, 0≤d3≤0.4, 0≤d1+d2+d3≤0.4, 0≤e≤0.4, and 0≤f≤0.4; and
even more preferably 0.005≤a1≤0.7, 0.005≤a2≤0.7, 0.005≤a1+a2≤0.7, 0≤b1≤0.7, 0≤b2≤0.7, 0≤b1+b2≤0.7, 0≤c≤0.7, 0≤d1≤0.3, 0≤d2≤0.3, 0≤d3≤0.3, 0≤d1+d2+d3≤0.3, 0≤e≤0.3, and 0≤f≤0.3. Notably, a1+a2+b1+b2+c+d1+d2+d3+e+f=1.0.

The base polymer may be synthesized by any desired methods, for example, by dissolving monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, propylene glycol monomethyl ether, γ-butyrolactone, and mixtures thereof. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably the reaction temperature is 50 to 80° C., and the reaction time is 2 to 100 hours, more preferably 5 to 20 hours.

In the case of a monomer having a hydroxy group, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaphthalene. For alkaline hydrolysis, a base such as aqueous ammonia or triethylamine may be used. Preferably the reaction temperature is −20° C. to 100° C., more preferably 0° C. to 60° C., and the reaction time is 0.2 to 100 hours, more preferably 0.5 to 20 hours.

The base polymer should preferably have a weight average molecular weight (Mw) in the range of 1,000 to 500,000, and more preferably 2,000 to 30,000, as measured by GPC versus polystyrene standards using tetrahydrofuran (THF) solvent. A Mw in the range ensures that a resist film has heat resistance and a high solubility in alkaline developer. If a base polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the base polymer should preferably have a narrow dispersity (Mw/Mn) of 1.0 to 2.0, especially 1.0 to 1.7, in order to provide a resist composition suitable for micropatterning to a small feature size.

The base polymer may be a blend of two or more polymers which differ in compositional ratio, Mw or Mw/Mn. It may also be a blend of a polymer comprising repeat units (a) and (b) and a polymer comprising repeat units (b), but not repeat units (a).

### Quencher

The resist composition may contain a quencher which is referred to as quencher of addition type, hereinafter. The quencher of addition type is typically selected from conventional basic compounds. Conventional basic compounds include primary, secondary, and tertiary aliphatic amines, mixed amines, aromatic amines, heterocyclic amines, nitrogen-containing compounds with carboxy group, nitrogen-containing compounds with sulfonyl group, nitrogen-containing compounds with hydroxy group, nitrogen-containing compounds with hydroxyphenyl group, alcoholic nitrogen-containing compounds, amide derivatives, imide derivatives, and carbamate derivatives. Also included are primary, secondary, and tertiary amine compounds, specifically amine compounds having a hydroxy group, ether bond, ester bond, lactone ring, cyano group, or sulfonate ester bond as described in JP-A 2008-111103, paragraphs [0146]-[0164], and compounds having a carbamate group as described in JP 3790649. Addition of a basic compound may be effective for further suppressing the diffusion rate of acid in the resist film or correcting the pattern profile.

Onium salts such as sulfonium, iodonium and ammonium salts of sulfonic acids which are not fluorinated at α-position as described in U.S. Pat. No. 8,795,942 (JP-A 2008-158339) and similar onium salts of carboxylic acid may also be used as the quencher of addition type. While an α-fluorinated sulfonic acid, imide acid, and methide acid are necessary to deprotect the acid labile group of carboxylic acid ester, an α-non-fluorinated sulfonic acid and a carboxylic acid are released by salt exchange with an α-non-fluorinated onium salt. An α-non-fluorinated sulfonic acid and a carboxylic acid function as a quencher because they do not induce deprotection reaction.

Other examples of the quencher of addition type include onium salts of α-fluorinated carboxylic acids described in JP 5904180. Since the α-fluorocarboxylic acids have a lower acidity than sulfonic acids and hence, a higher quenching function, a pattern with better roughness and resolution can be formed.

Also useful are quenchers of polymer type as described in U.S. Pat. No. 7,598,016 (JP-A 2008-239918). The polymeric quencher segregates at the resist surface and thus enhances the rectangularity of resist pattern. When a protective film is applied as is often the case in the immersion lithography, the polymeric quencher is also effective for preventing a film thickness loss of resist pattern or rounding of pattern top.

Preferred examples of the quencher include onium salts having the formula (1).

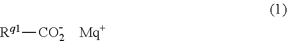

In formula (1), R^{q1} is a C₁-C₄₀ hydrocarbyl group which may contain a heteroatom.

Examples of the C₁-C₄₀ hydrocarbyl group Ral include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl, and adamantylmethyl; C₂-C₄₀ alkenyl groups such as vinyl, allyl, propenyl, butenyl and hexenyl; C₃-C₄₀ cyclic unsaturated aliphatic hydrocarbyl groups such as cyclohexenyl; C₆-C₄₀ aryl groups such as phenyl, naphthyl, alkylphenyl groups (e.g., 2-methylphenyl, 3-methylphenyl, 4-methylphenyl, 4-ethylphenyl, 4-tert-butylphenyl, 4-n-butylphenyl), di- and trialkylphenyl groups (e.g., 2,4-dimethylphenyl and 2,4,6-triisopropylphenyl), alkylnaphthyl groups (e.g., methylnaphthyl and ethylnaphthyl), dialkylnaphthyl groups (e.g., dimethylnaphthyl and diethylnaphthyl); and C₇-C₄₀ aralkyl groups such as benzyl, 1-phenylethyl and 2-phenylethyl.

In the hydrocarbyl group, some or all hydrogen may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, carbonyl moiety, ether bond, ester bond, sulfonic ester bond, carbonate bond, lactone ring, sultone ring, carboxylic anhydride (—C(═O)—O—C(═O)—), or haloalkyl moiety. Suitable heteroatom-containing hydrocarbyl groups include fluorinated alkyl groups such as trifluoromethyl, trifluoroethyl, 2,2,2-trifluoro-1-methyl-1-hydroxyethyl, 2,2,2-trifluoro-1-(trifluoromethyl)-1-hydroxyethyl; fluorinated aryl groups such as pentafluorophenyl and 4-trifluoromethylphenyl; heteroaryl groups such as thienyl; 4-hydroxyphenyl, alkoxyphenyl groups such as 4-methoxyphenyl, 3-methoxyphenyl, 2-methoxyphenyl, 4-ethoxyphenyl, 4-tert-butoxyphenyl, 3-tert-butoxyphenyl; alkoxynaphthyl groups such as methoxynaphthyl, ethoxynaphthyl, n-propoxynaphthyl and n-butoxynaphthyl; dialkoxynaphthyl groups such as dimethoxynaphthyl and diethoxynaphthyl; and aryloxoalkyl groups, typically 2-aryl-2-oxoethyl groups such as 2-phenyl-2-oxoethyl, 2-(1-naphthyl)-2-oxoethyl and 2-(2-naphthyl)-2-oxoethyl.

R^{q1} is preferably a C₆-C₁₂ hydrocarbyl group, more preferably halogen-substituted hydrocarbyl group, most preferably iodine-substituted hydrocarbyl group.

Examples of the anion in the quencher having formula (1) are shown below, but not limited thereto.

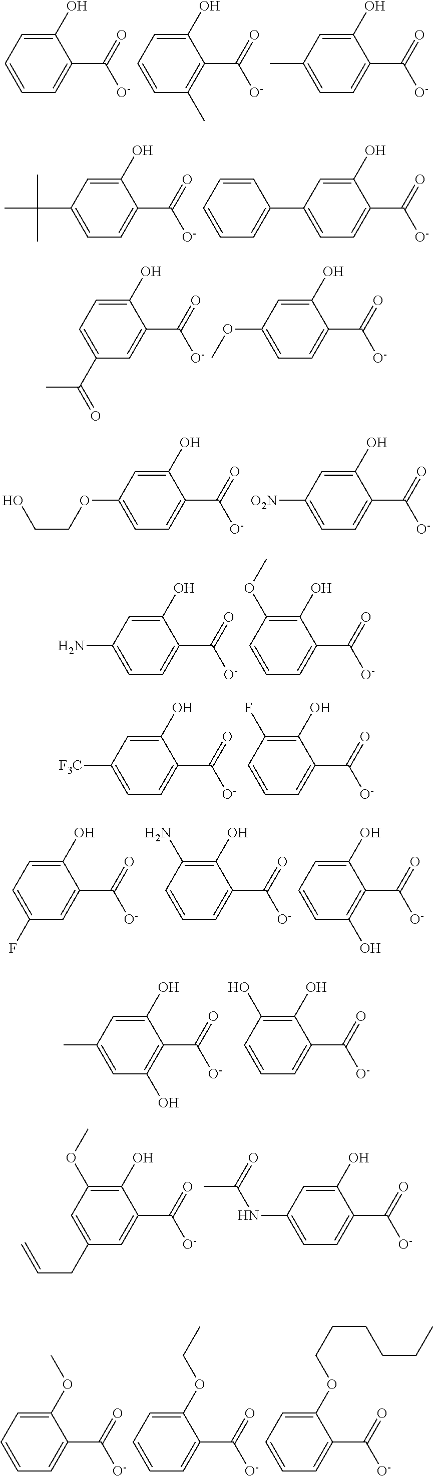

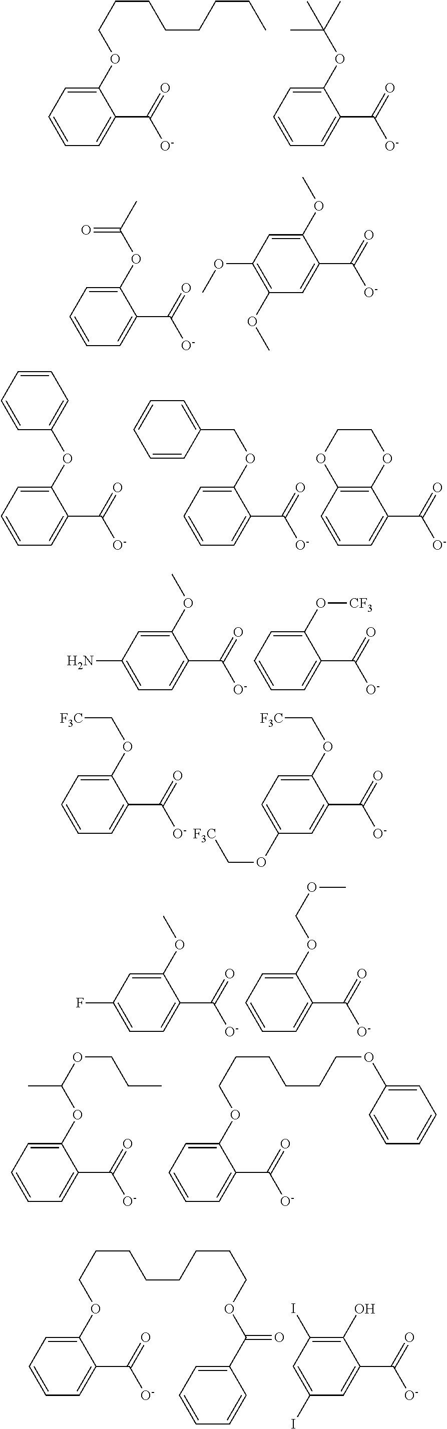

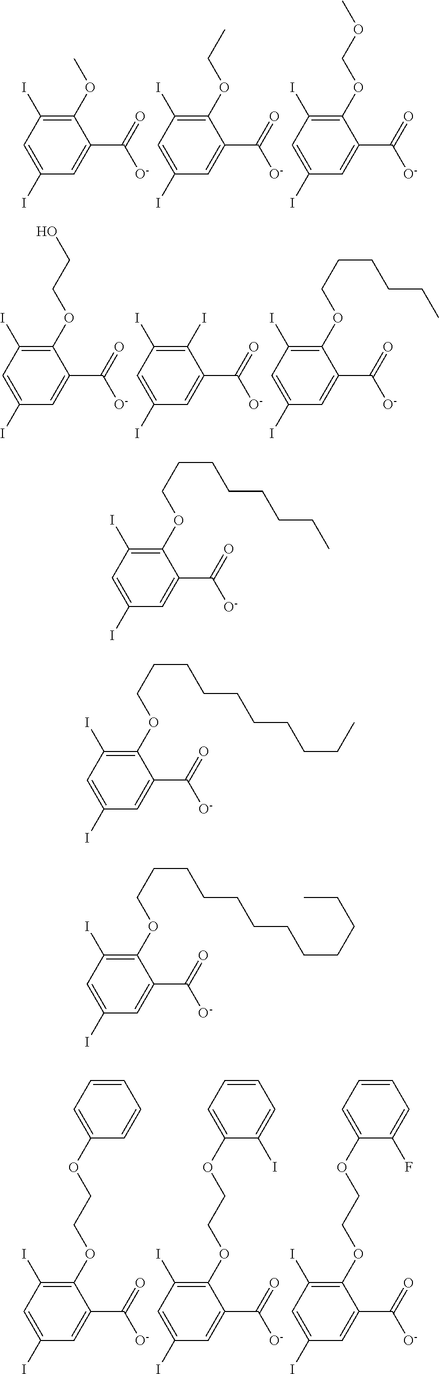

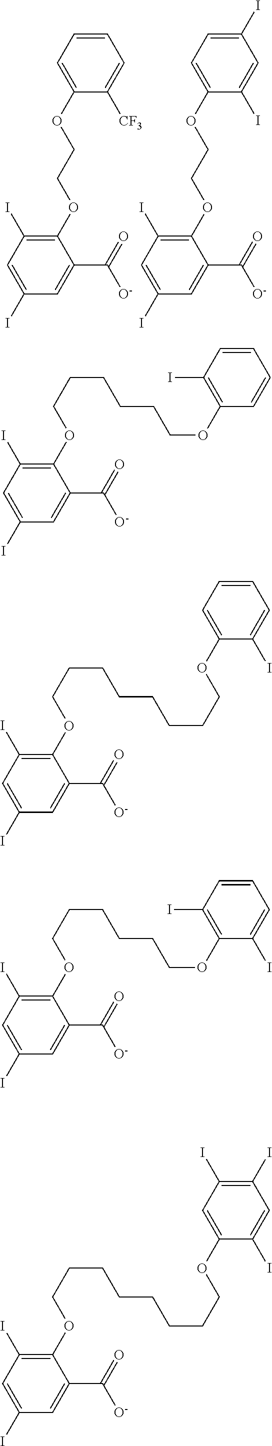

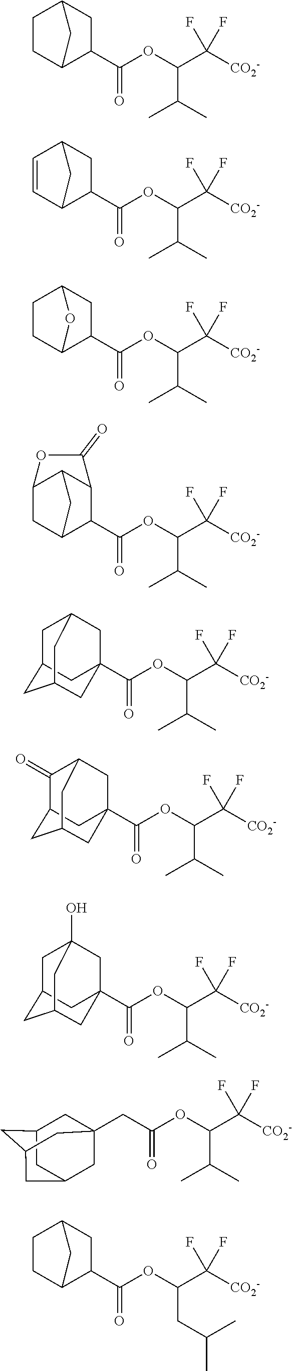

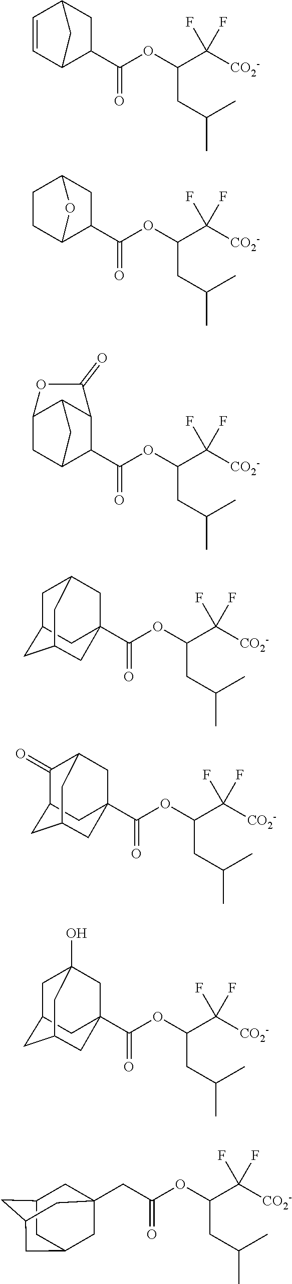

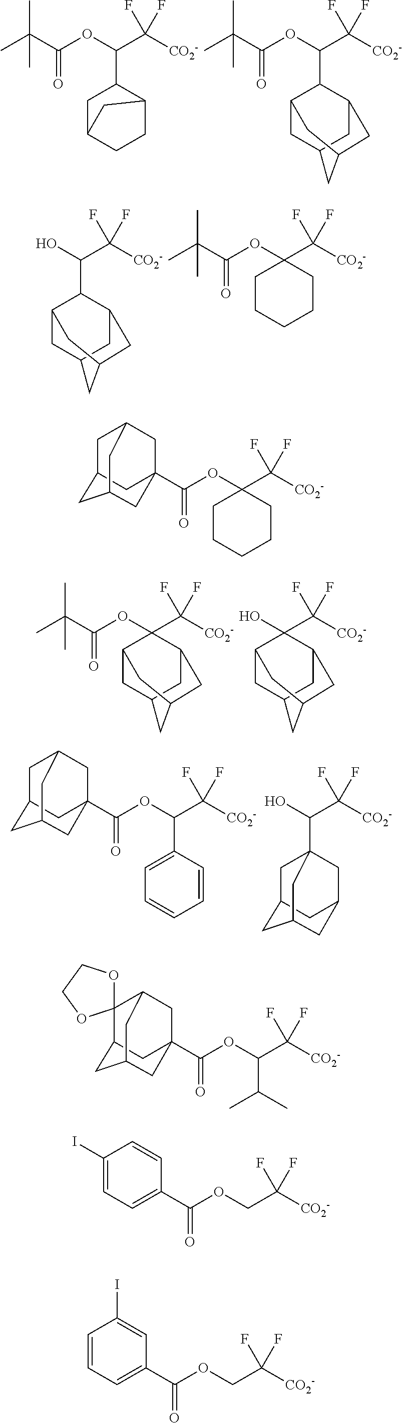

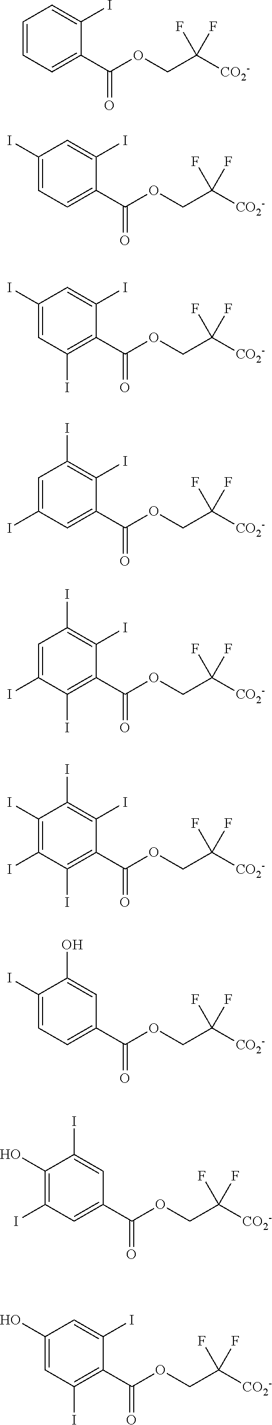

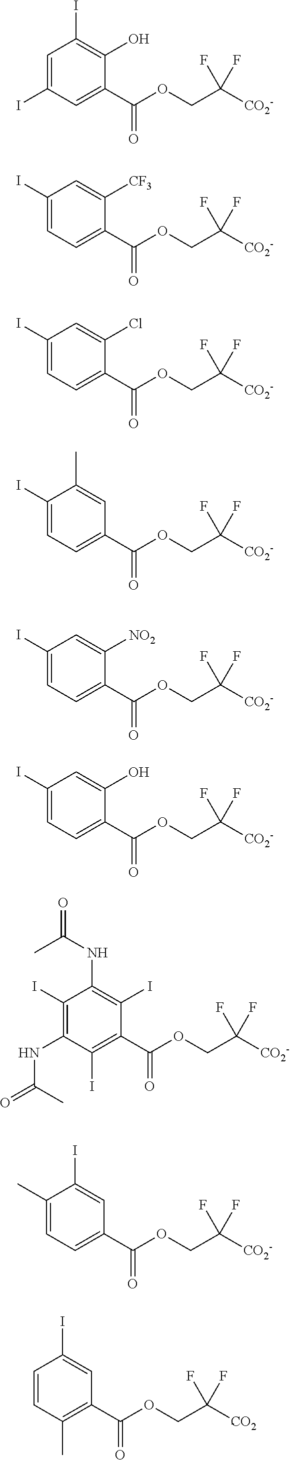

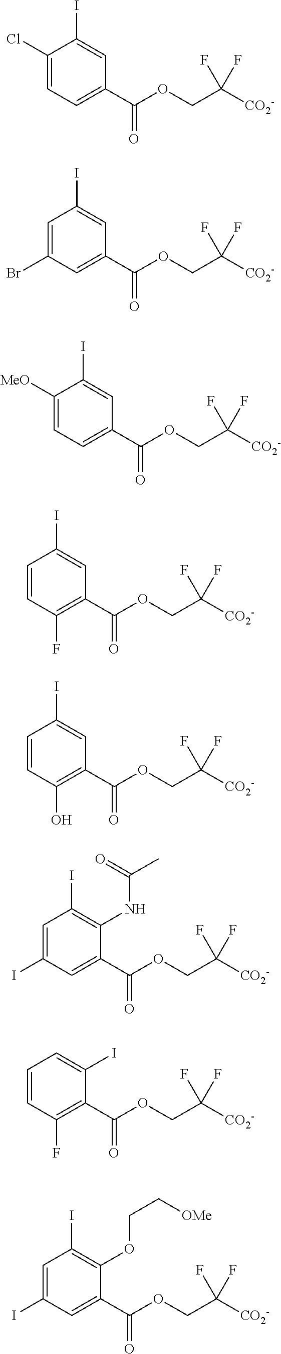

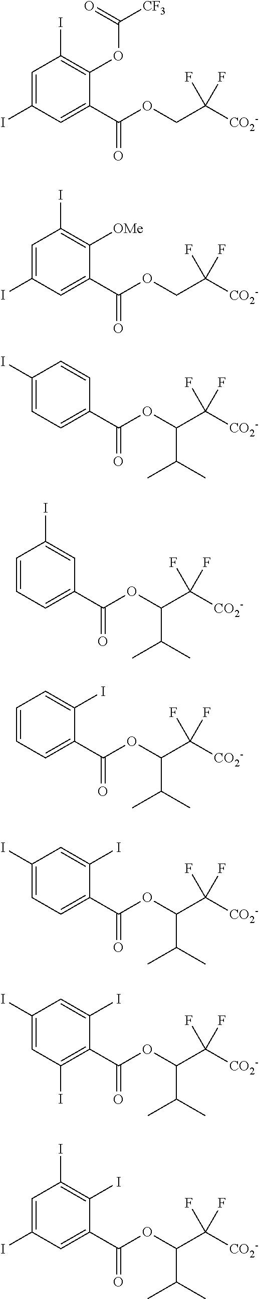

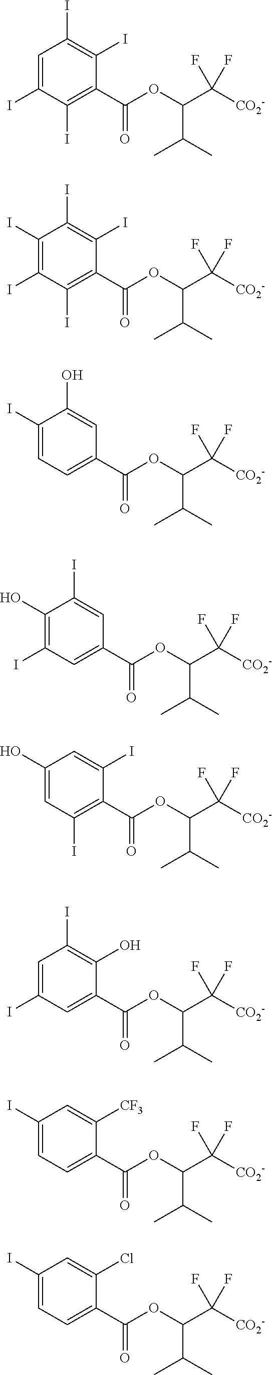

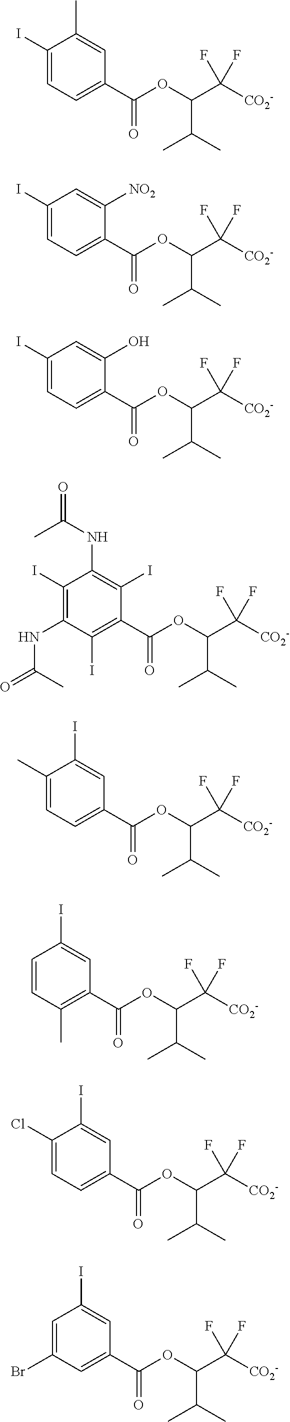

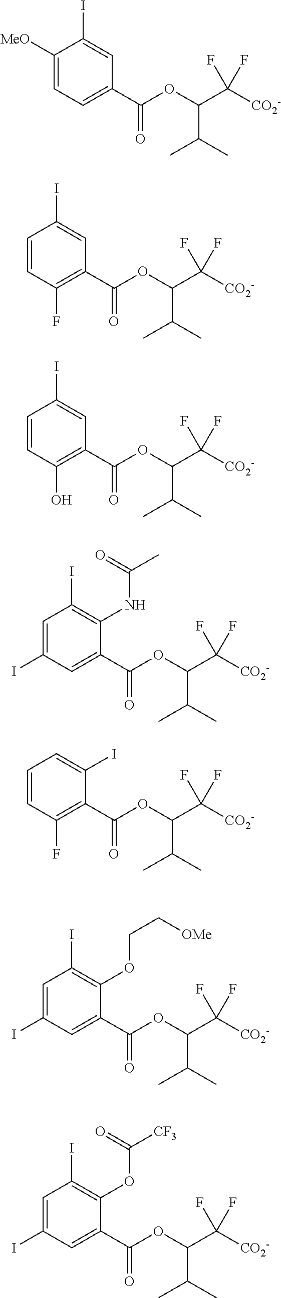

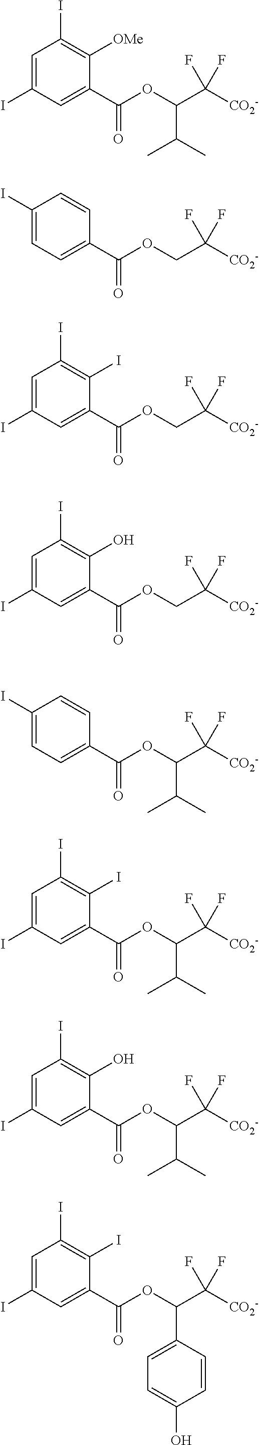

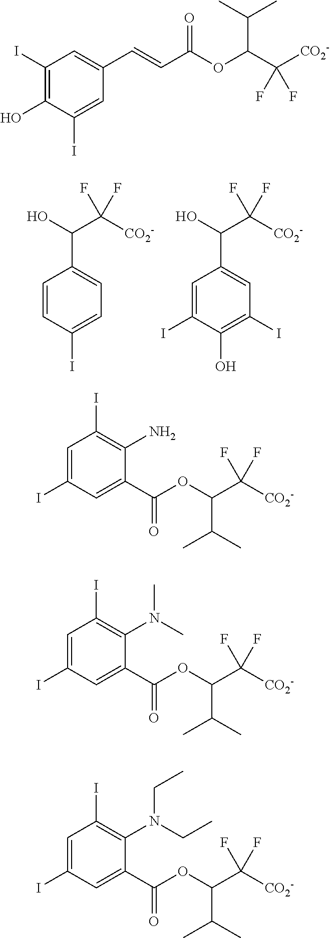

In formula (1), Mq⁺ is a monovalent organic cation. The organic cation is preferably selected from sulfonium cations having formula (M-1), iodonium cations having formula (M-2), and ammonium cations having formula (M-3). Examples thereof are as exemplified above for the cation in repeat unit (a).

In the resist composition, the quencher of addition type is preferably added in an amount of 0 to 10 parts by weight, more preferably 0 to 7 parts by weight per 100 parts by weight of the base polymer. The quencher may be used alone or in admixture.

### Acid Generator

The resist composition may contain an acid generator capable of generating a strong acid, also referred to as acid generator of addition type. As used herein, the “strong acid” is a compound having a sufficient acidity to induce deprotection reaction of acid labile groups on the base polymer.

The acid generator is typically a compound (PAG) capable of generating an acid upon exposure to actinic ray or radiation. Although the PAG used herein may be any compound capable of generating an acid upon exposure to high-energy radiation, those compounds capable of generating sulfonic acid, imidic acid (imide acid) or methide acid are preferred. Suitable PAGs include sulfonium salts, iodonium salts, sulfonyldiazomethane, N-sulfonyloxyimide, and oxime-O-sulfonate acid generators. Suitable PAGs are as exemplified in U.S. Pat. No. 7,537,880 (JP-A 2008-111103, paragraphs [0122]-[0142]).

As the PAG used herein, sulfonium salts having the formula (2-1) and iodonium salts having the formula (2-2) are also preferred.

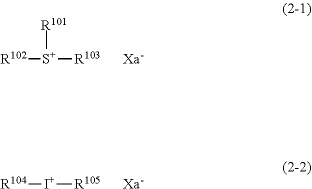

In formulae (2-1) and (2-2), R¹⁰¹ to R¹⁰⁵ are each independently halogen or a C₁-C₂₀ hydrocarbyl group which may contain a heteroatom. The hydrocarbyl group may be saturated or unsaturated and straight, branched or cyclic. Examples of the halogen and hydrocarbyl group are as exemplified above for the halogen and hydrocarbyl groups R^{M1} to R^{M9} in formulae (M-1) to (M-3). Any two of R¹⁰¹, R¹⁰² and R¹⁰³ may bond together to form a ring with the sulfur atom to which they are attached. Examples of the ring are as exemplified above for the ring that R^{M1} and R^{M2} in formulae (M-1) to (M-3), taken together, form with the sulfur atom to which they are attached.

Examples of the cation in the sulfonium salt having formula (2-1) are as exemplified above for the sulfonium cation in repeat units (a). Examples of the cation in the iodonium salt having formula (2-2) are as exemplified above for the iodonium cation in repeat units (a).

In formulae (2-1) and (2-2), Xa⁻ is an anion selected from the following formulae (2A) to (2D).

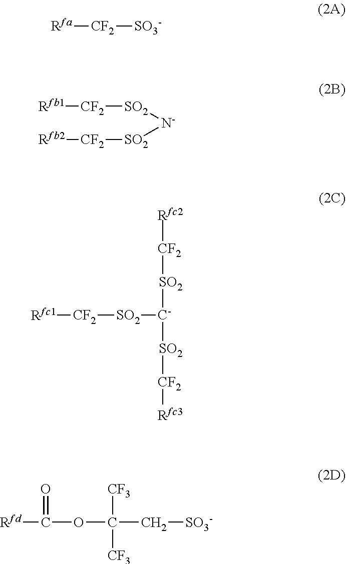

In formula (2A), R^{fa} is fluorine or a C₁-C₄₀ hydrocarbyl group which may contain a heteroatom. The hydrocarbyl group may be saturated or unsaturated and straight, branched or cyclic. Examples thereof are as will be exemplified later for the hydrocarbyl group R^{fa1} in formula (2A′).

Of the anions having formula (2A), an anion having the formula (2A′) is preferred.

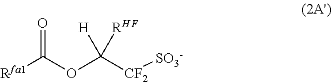

In formula (2A′), R^{HF} is hydrogen or trifluoromethyl, preferably trifluoromethyl.

R^{fa1} is a C₁-C₃₈ hydrocarbyl group which may contain a heteroatom. As the heteroatom, oxygen, nitrogen, sulfur and halogen atoms are preferred, with oxygen being most preferred. Of the hydrocarbyl groups represented by R^{fa1}, those groups of 6 to 30 carbon atoms are preferred from the aspect of achieving a high resolution in forming patterns of fine feature size. The hydrocarbyl group may be saturated or unsaturated and straight, branched or cyclic. Examples thereof include C₁-C₃₈ alkyl groups such as methyl, ethyl, n-propyl, isopropyl, n-butyl, isobutyl, sec-butyl, tert-butyl, pentyl, neopentyl, hexyl, heptyl, 2-ethylhexyl, nonyl, undecyl, tridecyl, pentadecyl, heptadecyl, and icosyl; C₃-C₃₈ cyclic saturated hydrocarbyl groups such as cyclopentyl, cyclohexyl, 1-adamantyl, 2-adamantyl, 1-adamantylmethyl, norbornyl, norbornylmethyl, tricyclodecanyl, tetracyclododecanyl, tetracyclododecanylmethyl, and dicyclohexylmethyl; C₂-C₃₈ unsaturated aliphatic hydrocarbyl groups such as allyl and 3-cyclohexenyl; C₆-C₃₈ aryl groups such as phenyl, 1-naphthyl and 2-naphthyl; C₇-C₃₈ aralkyl groups such as benzyl and diphenylmethyl; and combinations thereof.

In the foregoing hydrocarbyl groups, some or all hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—), or haloalkyl moiety. Examples of the heteroatom-containing hydrocarbyl group include tetrahydrofuryl, methoxymethyl, ethoxymethyl, methylthiomethyl, acetamidemethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl.

With respect to the synthesis of the sulfonium salt having an anion of formula (2A′), reference may be made to JP-A 2007-145797, JP-A 2008-106045, JP-A 2009-007327, and JP-A 2009-258695. Also useful are the sulfonium salts described in JP-A 2010-215608, JP-A 2012-041320, JP-A 2012-106986, and JP-A 2012-153644.

Examples of the anion having formula (2A) include those exemplified as the anion having formula (1A) in JP-A 2018-197853.

In formula (2B), R^{fb1} and R^{fb2} are each independently fluorine or a C₁-C₄₀ hydrocarbyl group which may contain a heteroatom. The hydrocarbyl group may be saturated or unsaturated and straight, branched or cyclic, and examples thereof are as exemplified above for R^{fa1} in formula (2A′). Preferably R^{fb1} and R^{fb2} are fluorine or C₁-C₄ straight fluorinated alkyl groups. Also, R^{fb1} and R^{fb2} may bond together to form a ring with the linkage: —CF₂—SO₂—N⁻—SO₂—CF₂— to which they are attached. It is preferred that a combination of R^{fb1} and R^{fb2} be a fluorinated ethylene or fluorinated propylene group.

In formula (2C), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic, and examples thereof are as exemplified above for R^{fa1} in formula (2A′). Preferably R^{fc1}, R^{fc2} and R^{fc3} are fluorine or C₁-C₄ straight fluorinated alkyl groups. Also, R^{fc1} and R^{fc2} may bond together to form a ring with the linkage: —CF₂—SO₂—C⁻—SO₂—CF₂— to which they are attached. It is preferred that a combination of R^{fc1} and R^{fc2} be a fluorinated ethylene or fluorinated propylene group.

In formula (2D), R^{fd} is a C₁-C₄₀ hydrocarbyl group which may contain a heteroatom. The hydrocarbyl group may be saturated or unsaturated and straight, branched or cyclic, and examples thereof are as exemplified above for R^{fa1} in formula (2A′).

With respect to the synthesis of the sulfonium salt having an anion of formula (2D), reference may be made to JP-A 2010-215608 and JP-A 2014-133723.

Examples of the anion having formula (2D) include those exemplified as the anion having formula (1D) in U.S. Pat. No. 11,022,883 (JP-A 2018-197853).

Notably, the compound having the anion of formula (2D) does not have fluorine at the α-position relative to the sulfo group, but two trifluoromethyl groups at the β-position. For this reason, it has a sufficient acidity to sever the acid labile groups in the base polymer. Thus the compound is an effective PAG.

Another preferred PAG is a compound having the formula (3).

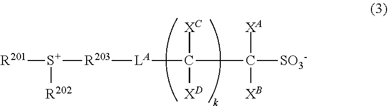

In formula (3), R²⁰¹ and R²⁰² are each independently halogen or a C₁-C₃₀ hydrocarbyl group which may contain a heteroatom. R²⁰³ is a C₁-C₃₀ hydrocarbylene group which may contain a heteroatom. Any two of R²⁰¹, R²⁰² and R²⁰³ may bond together to form a ring with the sulfur atom to which they are attached. Examples of the ring are as exemplified above for the ring that R^{M1} and R^{M2} in formulae (M-1) to (M-3), taken together, form with the sulfur atom to which they are attached.

The hydrocarbyl groups R²⁰¹ and R²⁰² may be saturated or unsaturated and straight, branched or cyclic. Examples thereof include C₁-C₃₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₃₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, oxanorbornyl, tricyclo[5.2.1.0^{2,6}]decyl, and adamantyl; C₆-C₃₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, tert-butylnaphthyl, and anthracenyl; and combinations thereof. In the foregoing hydrocarbyl groups, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety.

The hydrocarbylene group R²⁰³ may be saturated or unsaturated and straight, branched or cyclic. Examples thereof include C₁-C₃₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₃₀ cyclic saturated hydrocarbylene groups such as cyclopentanediyl, cyclohexanediyl, norbornanediyl and adamantanediyl; C₆-C₃₀ arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene; and combinations thereof. In these groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety. Of the heteroatoms, oxygen is preferred.

In formula (3), L^{A} is a single bond, ether bond or a C₁-C₂₀ hydrocarbylene group which may contain a heteroatom. The hydrocarbylene group may be saturated or unsaturated and straight, branched or cyclic. Examples thereof are as exemplified above for R²⁰³.

In formula (3), X^{A}, X^{B}, X^{C} and X^{D} are each independently hydrogen, fluorine or trifluoromethyl. At least one of X^{A}, X^{B}, X^{C} and X^{D} is fluorine or trifluoromethyl.

In formula (3), k is 0, 1, 2 or 3.

Of the PAGs having formula (3), those having formula (3′) are preferred.

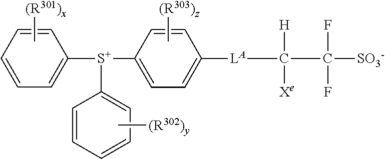

In formula (3′), L^{A} is as defined above. X^{E} is hydrogen or trifluoromethyl, preferably trifluoromethyl. R³⁰¹, R³⁰² and R³⁰³ are each independently hydrogen or a C₁-C₂₀ hydrocarbyl group which may contain a heteroatom. The hydrocarbyl group may be saturated or unsaturated and straight, branched or cyclic. Examples thereof are as exemplified above for R^{fa1} in formula (2A′). The subscripts x and y are each independently an integer of 0 to 5, and z is an integer of 0 to 4.

Examples of the PAG having formula (3) are as exemplified as the PAG having formula (2) in U.S. Pat. No. 9,720,324 (JP-A 2017-026980).

Of the foregoing PAGs, those having an anion of formula (2A′) or (2D) are especially preferred because of reduced acid diffusion and high solubility in the solvent. Also those having formula (3′) are especially preferred because of extremely reduced acid diffusion.

A sulfonium or iodonium salt having an iodized or brominated aromatic ring-containing anion may also be used as the PAG. Suitable are sulfonium and iodonium salts having the formulae (4-1) and (4-2).

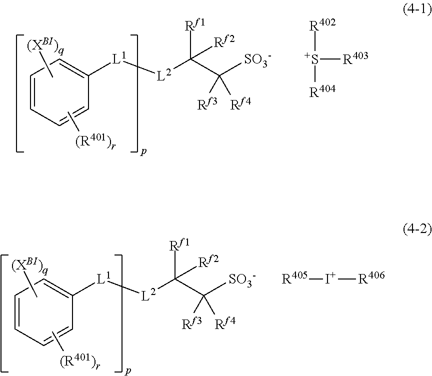

In formulae (4-1) and (4-2), p is 1, 2 or 3, q is 1, 2, 3, 4 or 5, r is 0, 1, 2 or 3, and 1≤q+r≤5. Preferably, q is 1, 2 or 3, more preferably 2 or 3, and r is 0, 1 or 2.

X^{BI} is iodine or bromine, and may be the same or different when p and/or q is 2 or more.

L¹ is a single bond, ether bond, ester bond, or a C₁-C₆ saturated hydrocarbylene group which may contain an ether bond or ester bond. The saturated hydrocarbylene group may be straight, branched or cyclic.

L² is a single bond or a C₁-C₂₀ divalent linking group when p=1, or a C₁-C₂₀ (p+1)-valent linking group when p=2 or 3. The linking group may contain an oxygen, sulfur or nitrogen atom.

R⁴⁰¹ is a hydroxy group, carboxy group, fluorine, chlorine, bromine, amino group, or a C₁-C₂₀ hydrocarbyl, C₁-C₂₀ hydrocarbyloxy, C₂-C₂₀ hydrocarbylcarbonyl, C₂-C₂₀ hydrocarbyloxycarbonyl, C₂-C₂₀ hydrocarbylcarbonyloxy or C₁-C₂₀ hydrocarbylsulfonyloxy group, which may contain fluorine, chlorine, bromine, hydroxy, amino or ether bond, or —N(R^{401A})(R^{401B}), —N(R^{401C})—C(═O)—R^{401D} or —N(R^{401C})—C(═O)—O—R^{401D}. R^{401A} and R^{401B} are each independently hydrogen or a C₁-C₆ saturated hydrocarbyl group. R^{401C} is hydrogen or a C₁-C₆ saturated hydrocarbyl group which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. R^{401D} is a C₁-C₁₆ aliphatic hydrocarbyl, C₆-C₁₄ aryl or C₇-C₁₅ aralkyl group, which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy, and hydrocarbylsulfonyloxy groups may be straight, branched or cyclic. A plurality of R⁴⁰¹ may be the same or different when p and/or r is 2 or more.

Of these, R⁴⁰¹ is preferably hydroxy, —N(R^{401C})—C(═O)—R^{401D}, —N(R^{401C})—C(═O)—O—R^{401D}, fluorine, chlorine, bromine, methyl or methoxy.

In formulae (4-1) and (4-2), Rf¹ to Rf⁴ are each independently hydrogen, fluorine or trifluoromethyl, at least one of Rf¹ to Rf⁴ is fluorine or trifluoromethyl. Rf¹ and Rf², taken together, may form a carbonyl group. Preferably, both Rf³ and Rf⁴ are fluorine.

R⁴⁰² to R⁴⁰⁶ are each independently halogen or a C₁-C₂₀ hydrocarbyl group which may contain a heteroatom. The hydrocarbyl group may be saturated or unsaturated and straight, branched or cyclic. Examples thereof are as exemplified above for the hydrocarbyl groups R^{M1} to R^{M9} in formulae (M-1) to (M-3). In these hydrocarbyl groups, some or all of the hydrogen atoms may be substituted by hydroxy, carboxy, halogen, cyano, nitro, mercapto, sultone, sulfone, or sulfonium salt-containing moieties, and some constituent —CH₂— may be replaced by an ether bond, ester bond, carbonyl moiety, amide bond, carbonate bond or sulfonate ester bond. R⁴⁰² and R⁴⁰³ may bond together to form a ring with the sulfur atom to which they are attached. Exemplary rings are the same as described above for the ring that R^{M1} and R^{M2} in formulae (M-1) to (M-3), taken together, form with the sulfur atom to which they are attached.

Examples of the cation in the sulfonium salt having formula (4-1) include those exemplified above as the sulfonium cation in repeat unit (a). Examples of the cation in the iodonium salt having formula (4-2) include those exemplified above as the iodonium cation in repeat unit (a).

Examples of the anion in the onium salts having formulae (4-1) and (4-2) are shown below, but not limited thereto. Herein X^{BI} is as defined above.

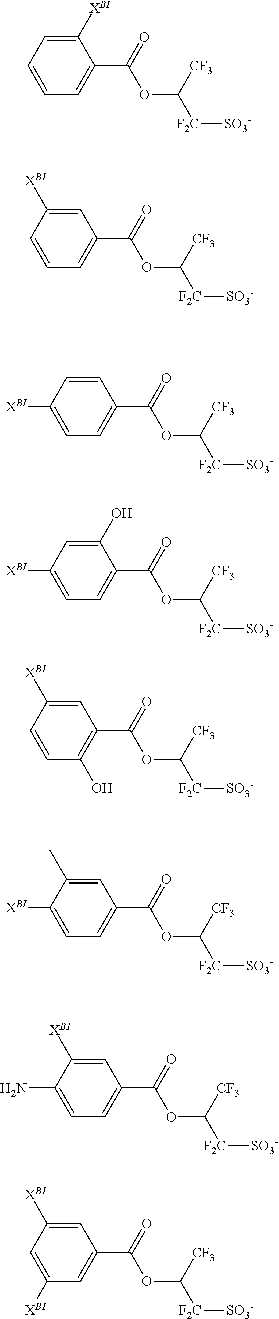

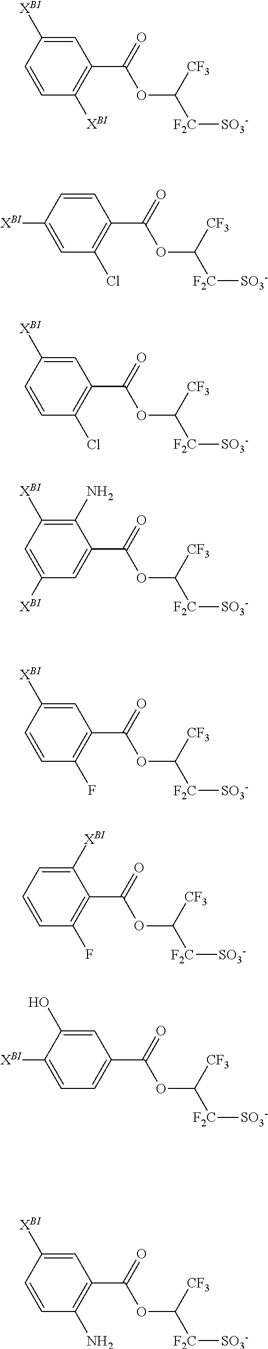

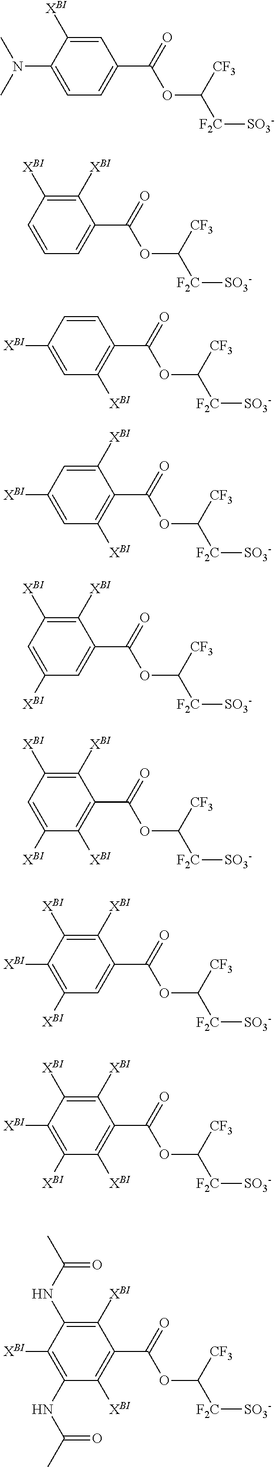

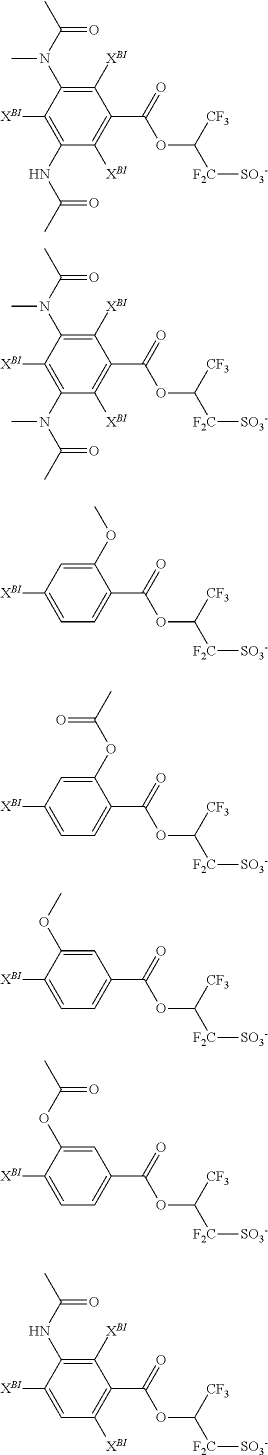

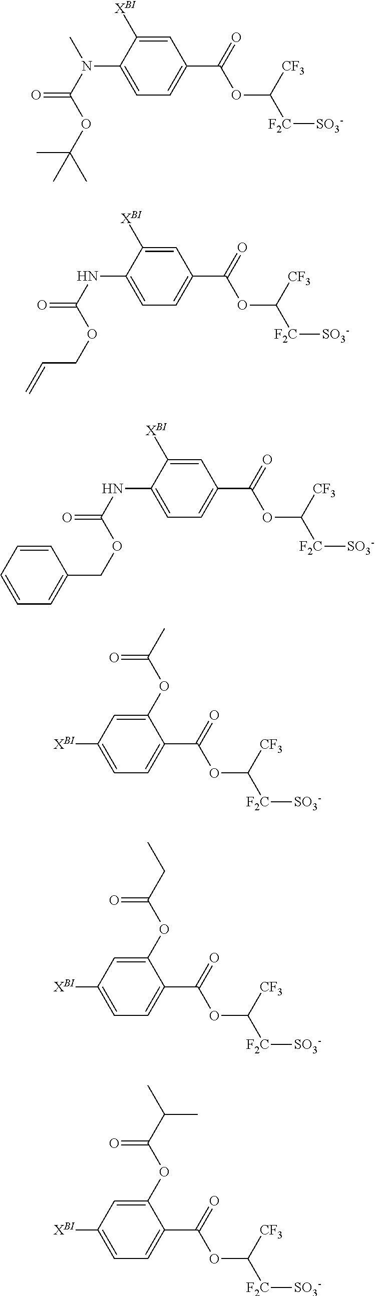

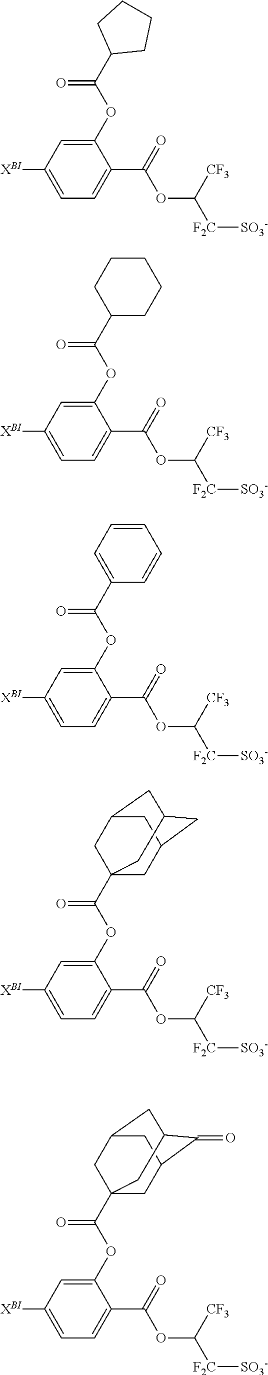

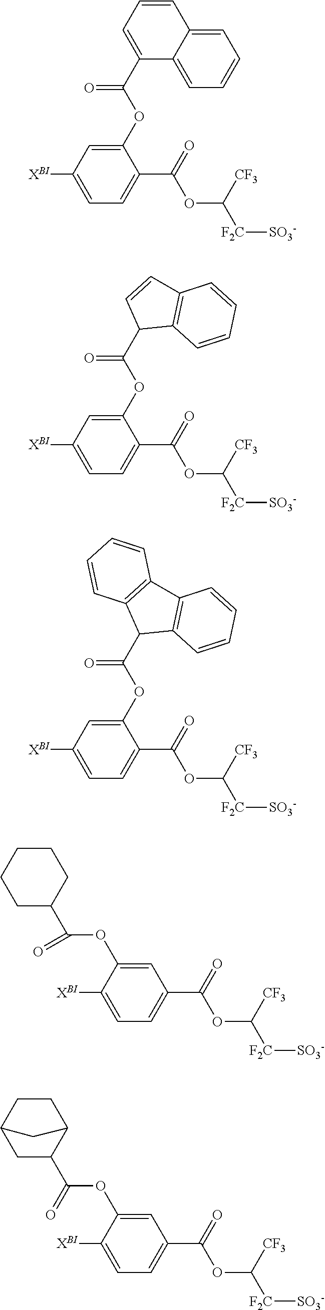

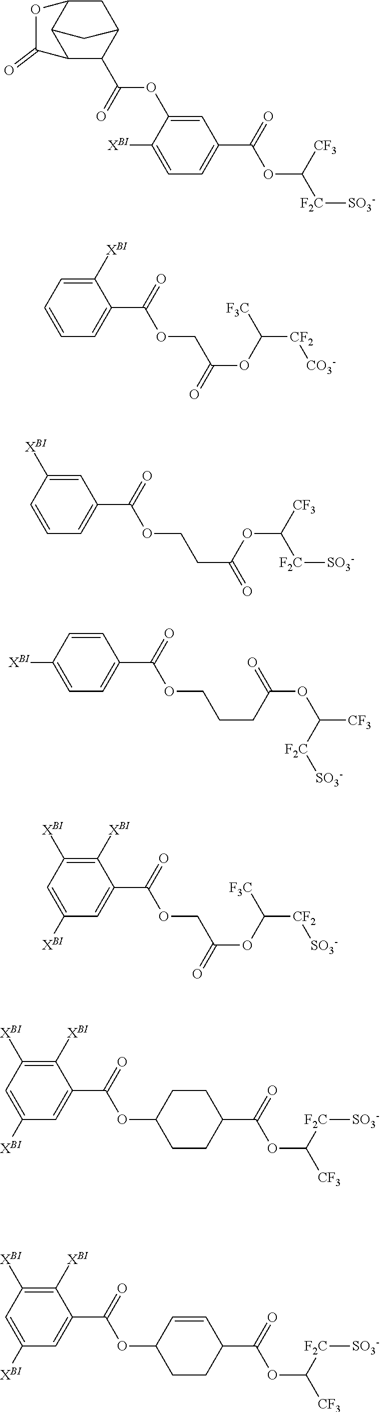

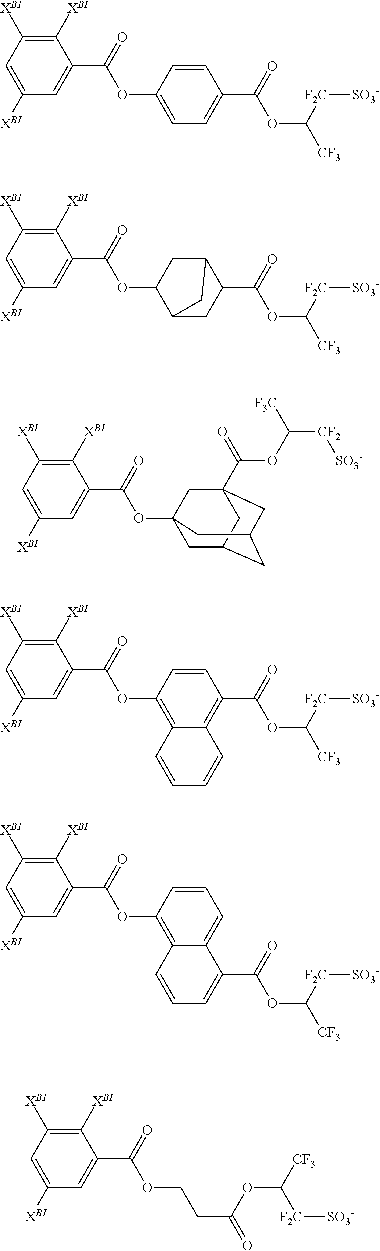

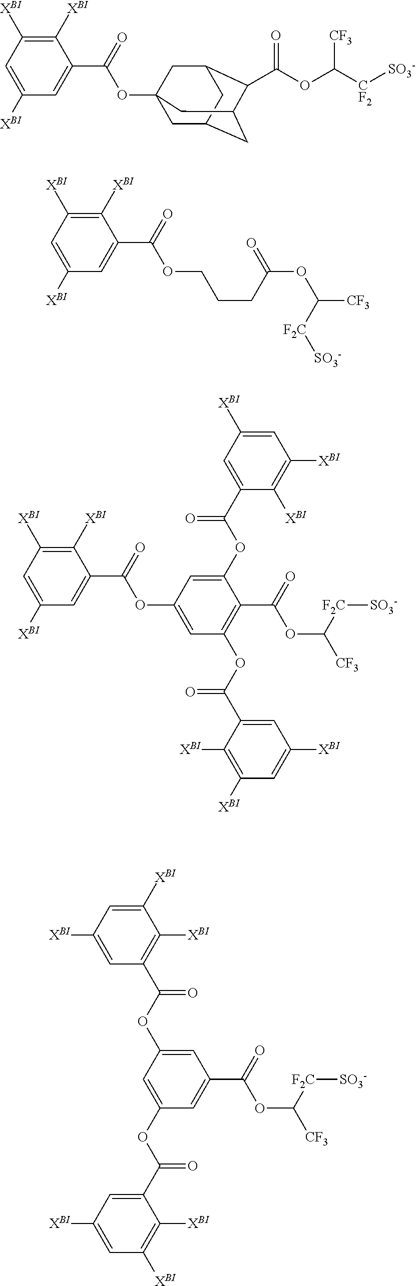

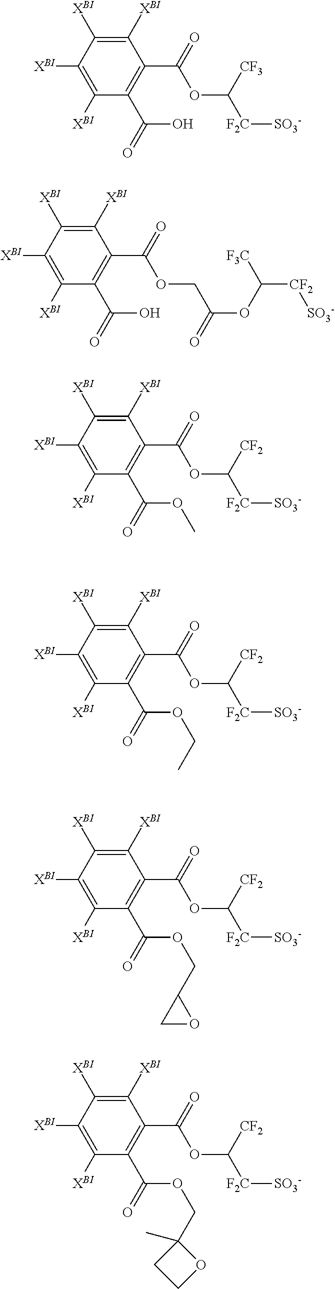

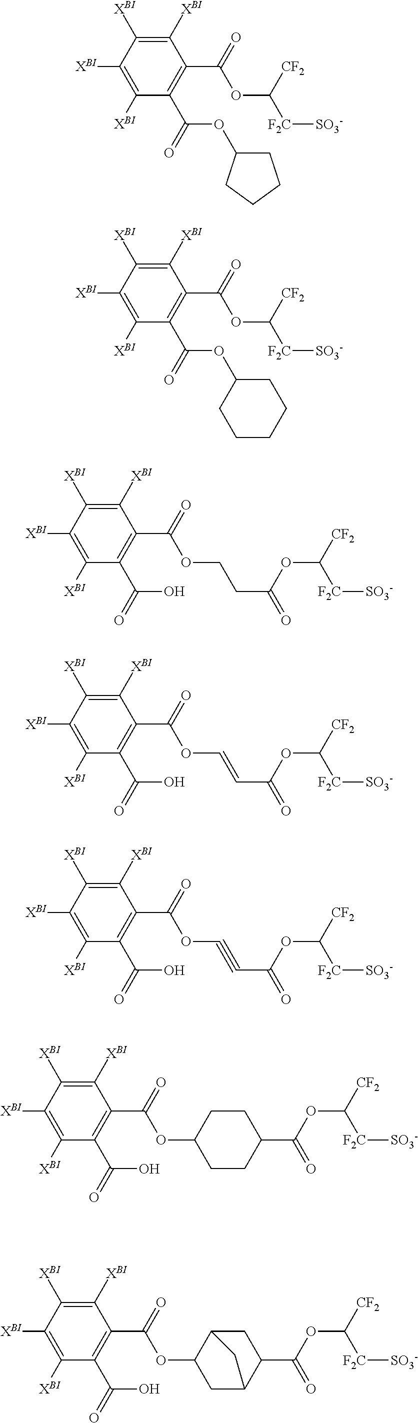

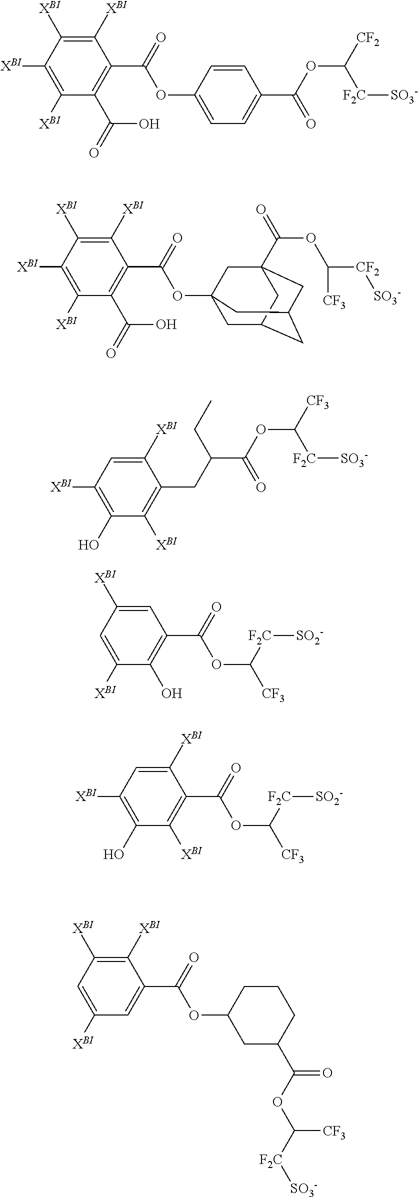

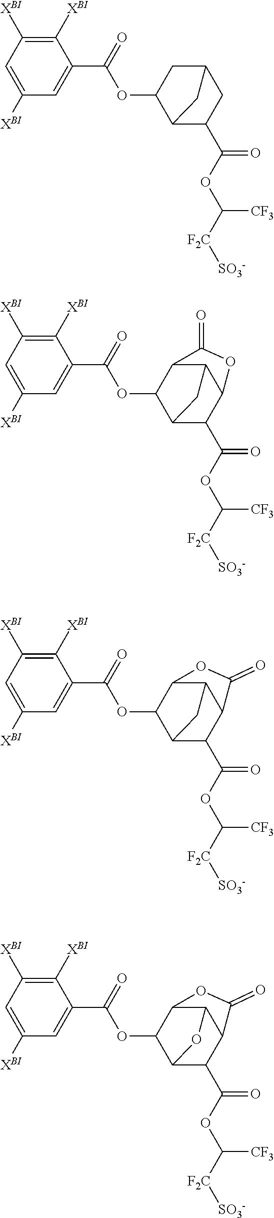

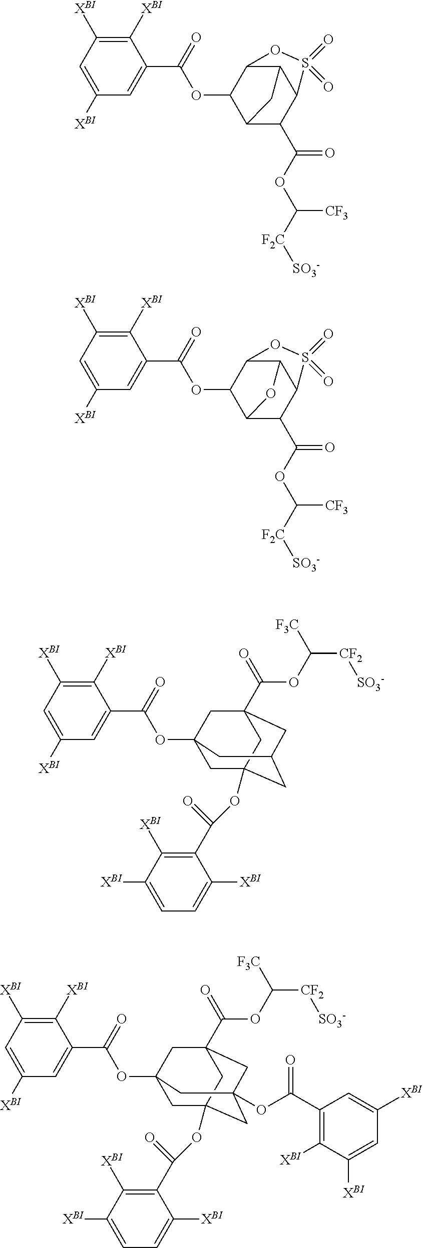

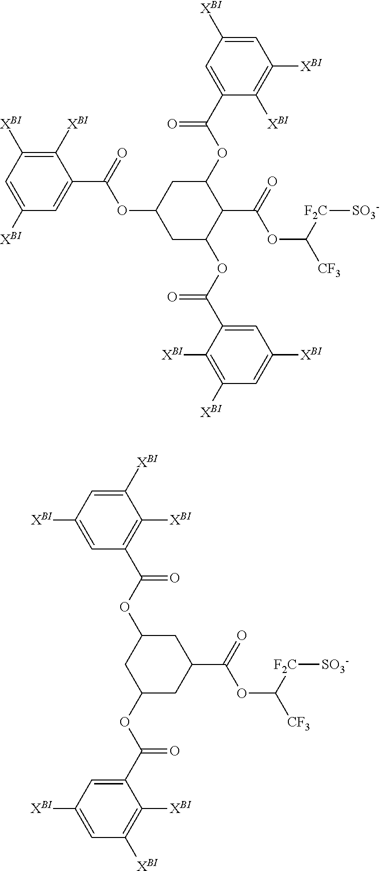

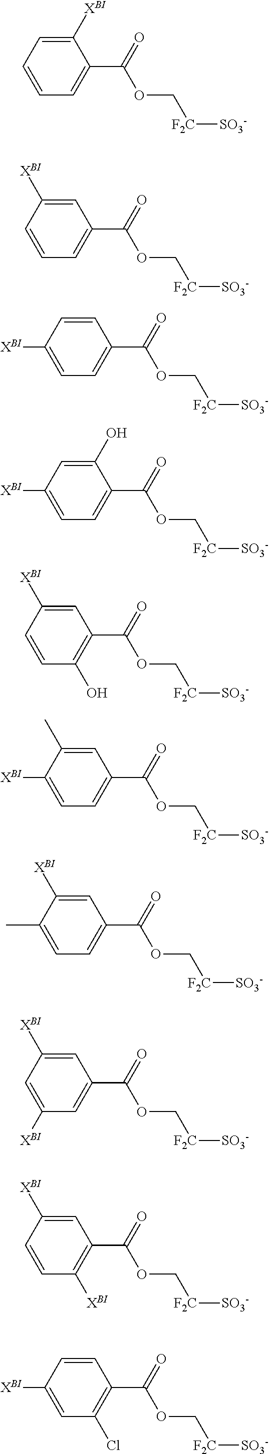

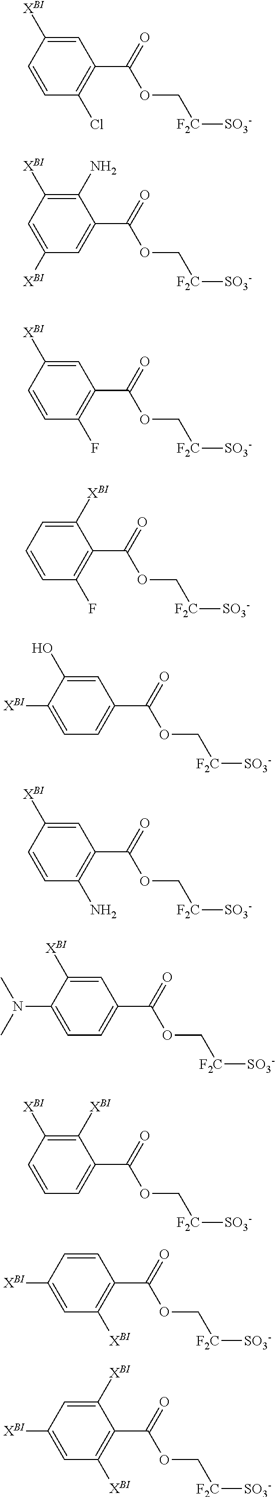

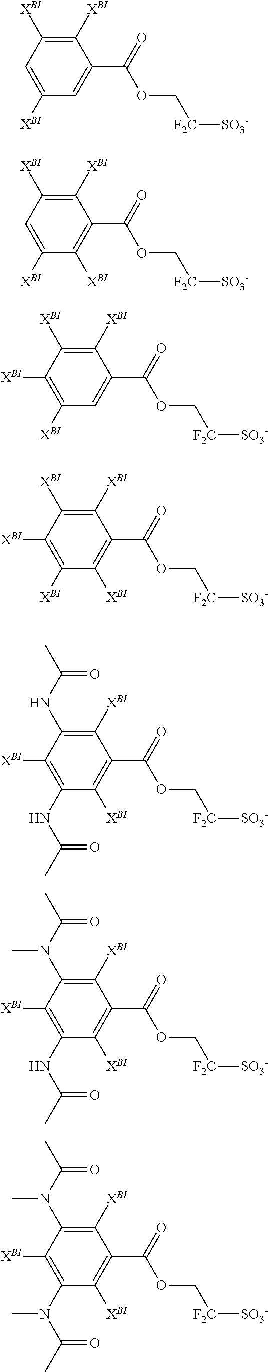

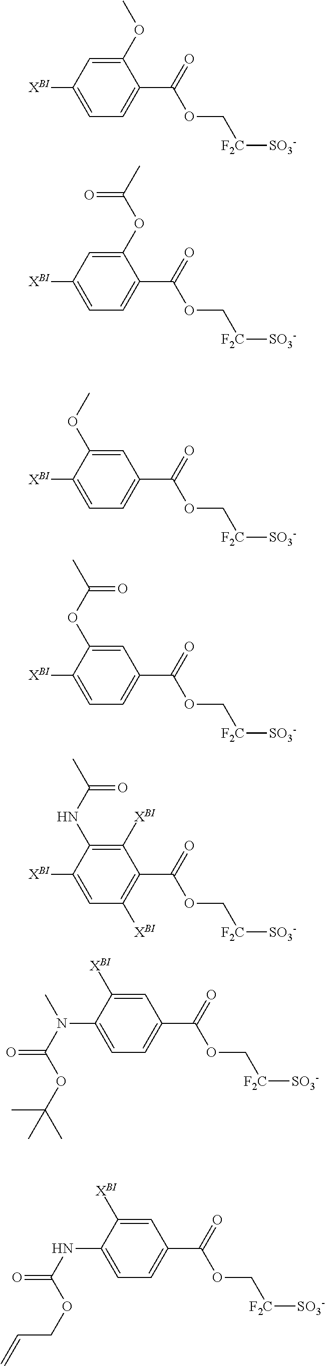

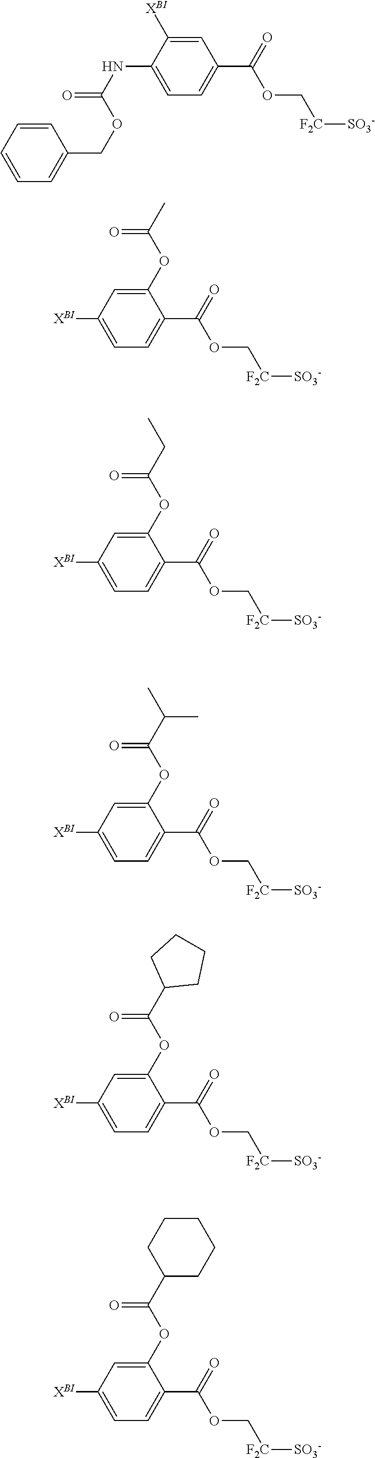

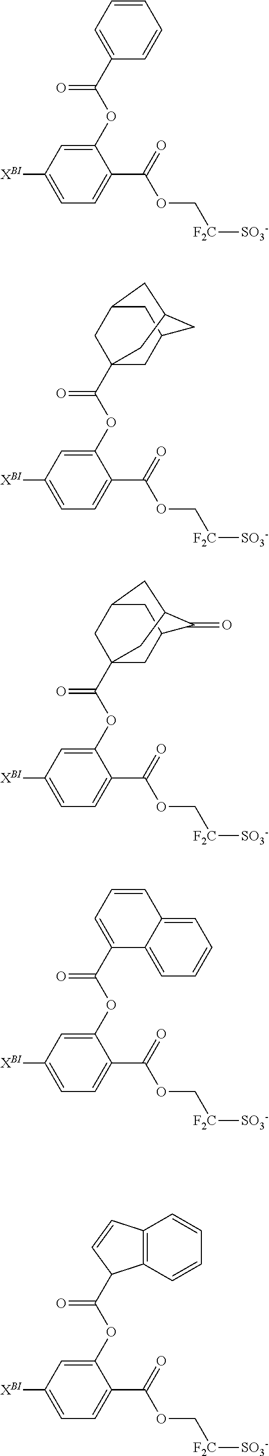

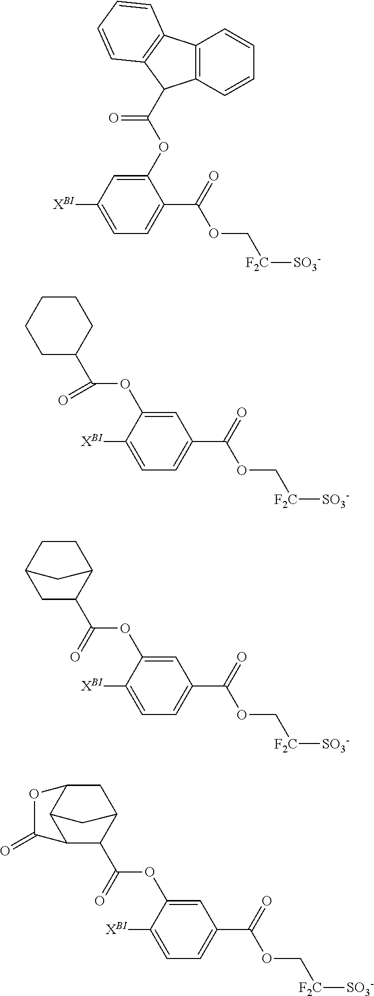

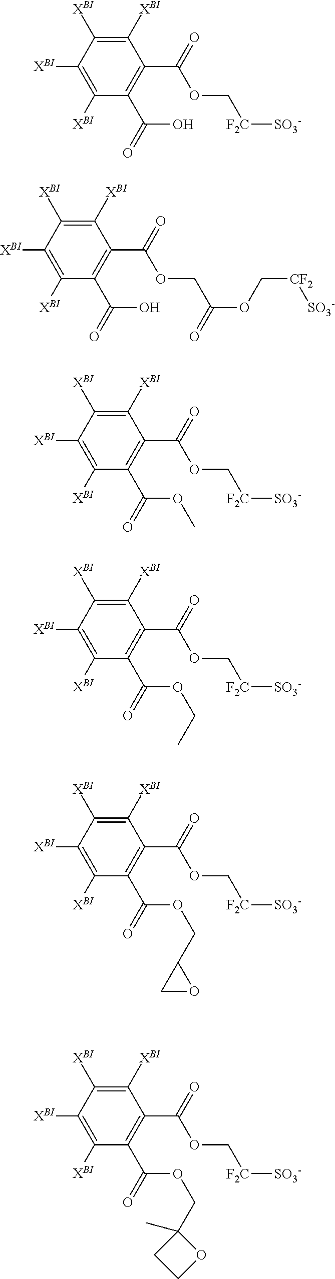

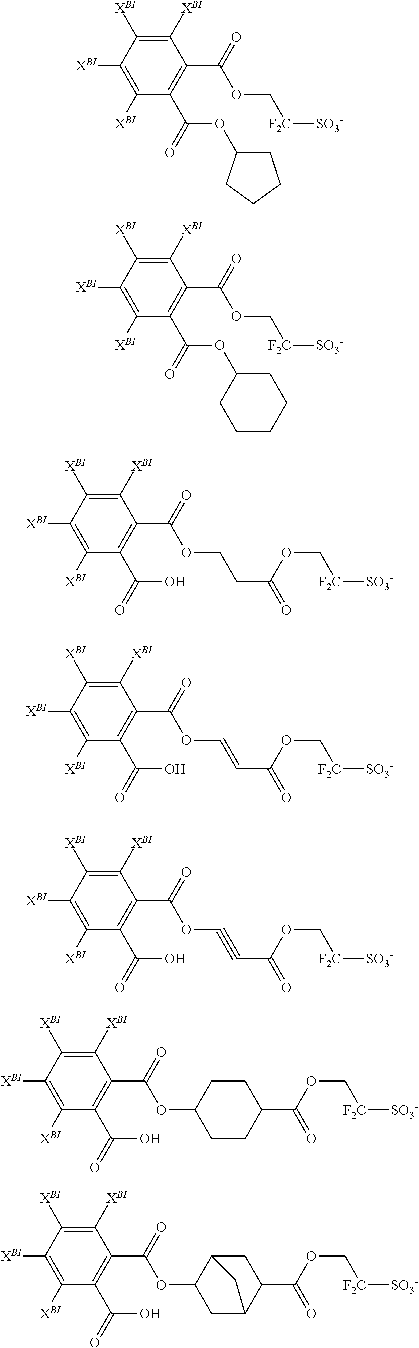

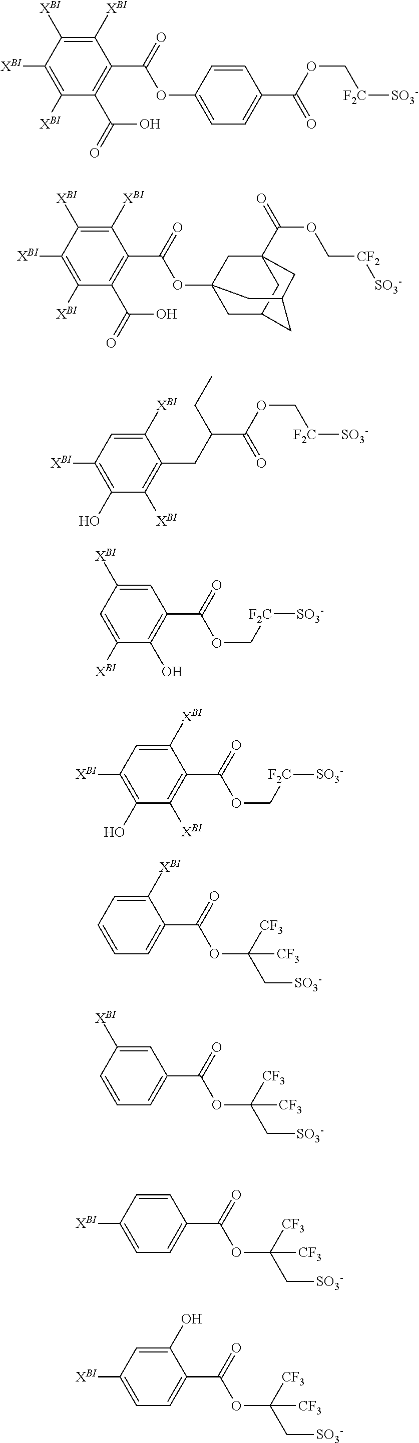

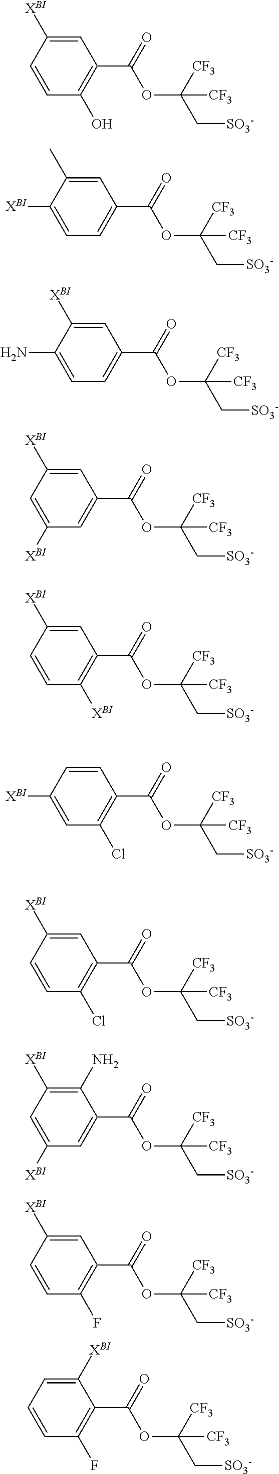

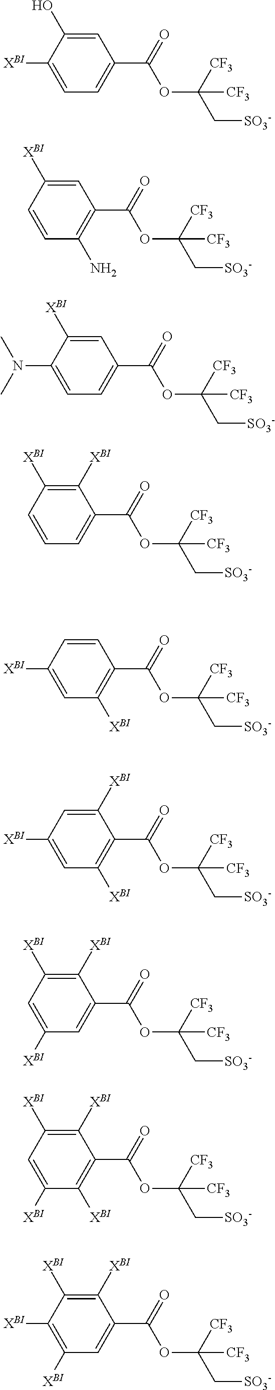

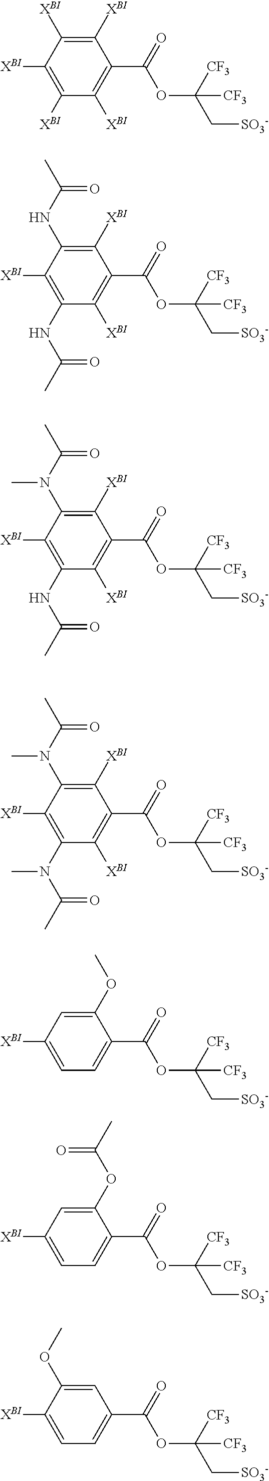

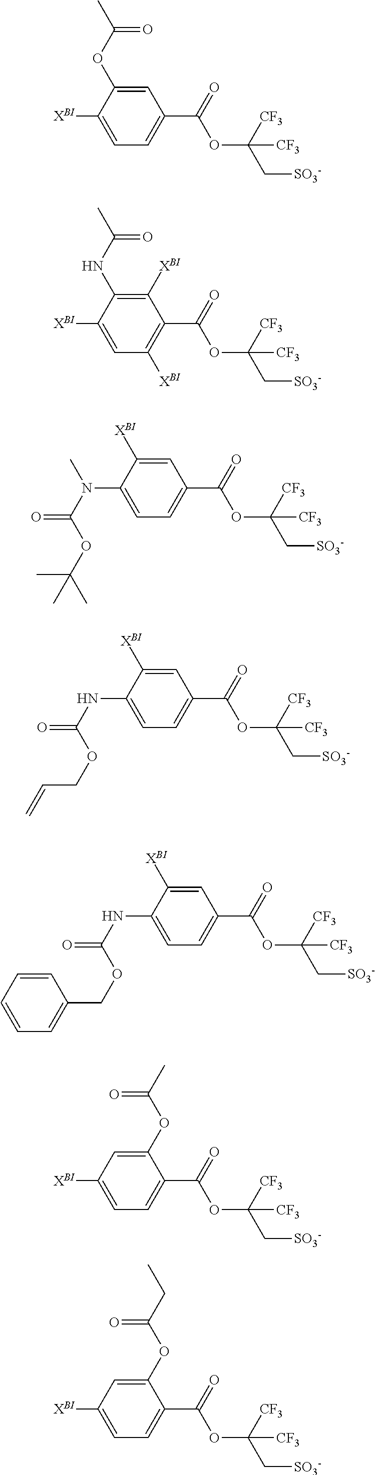

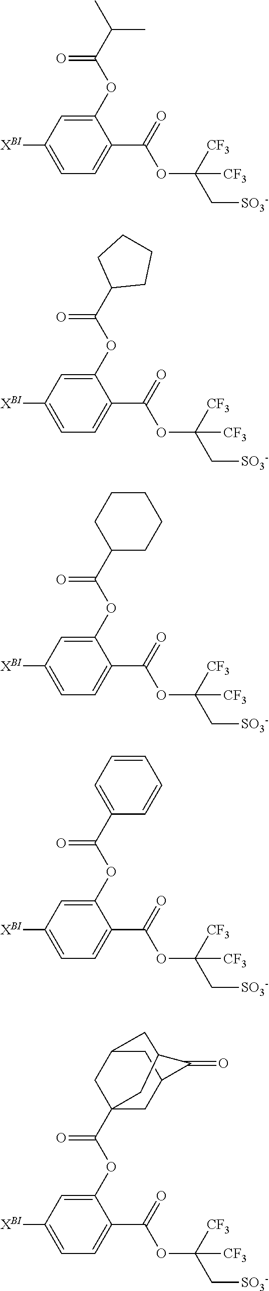

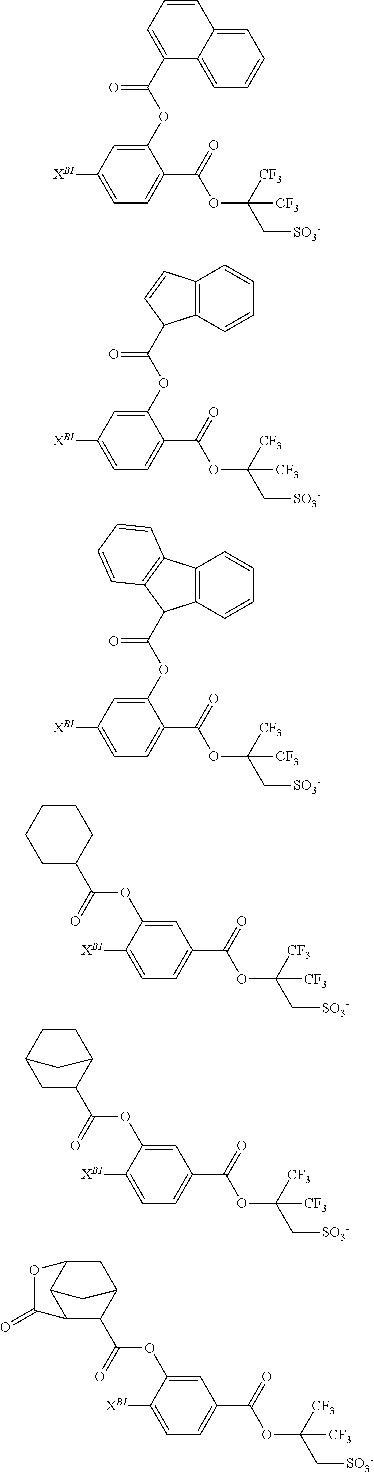

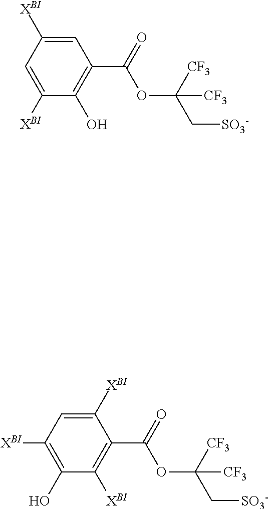

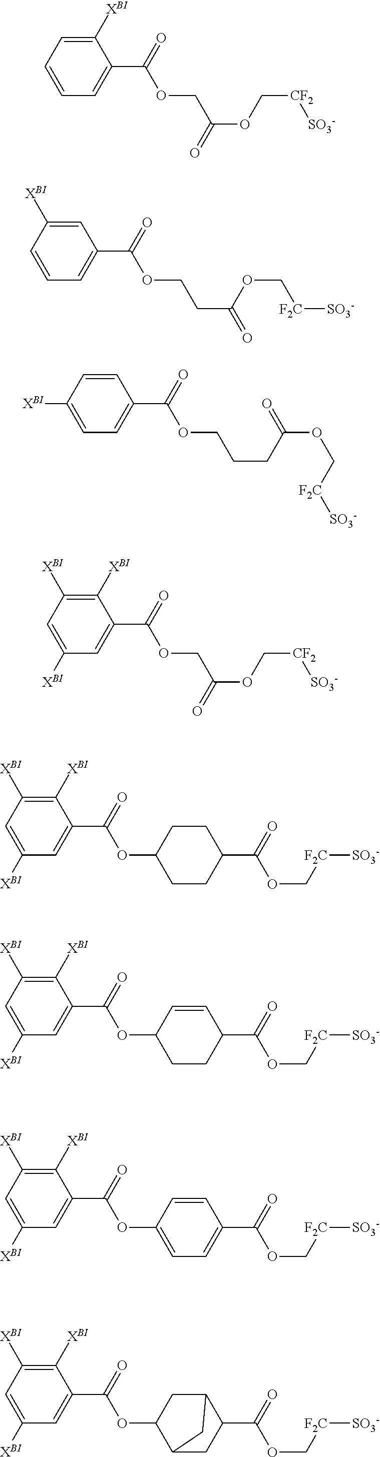

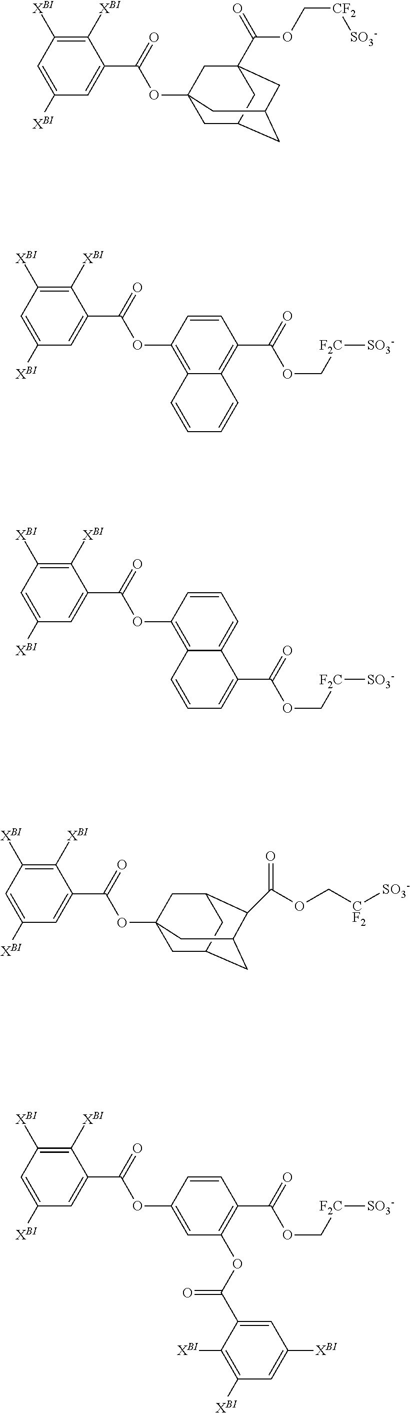

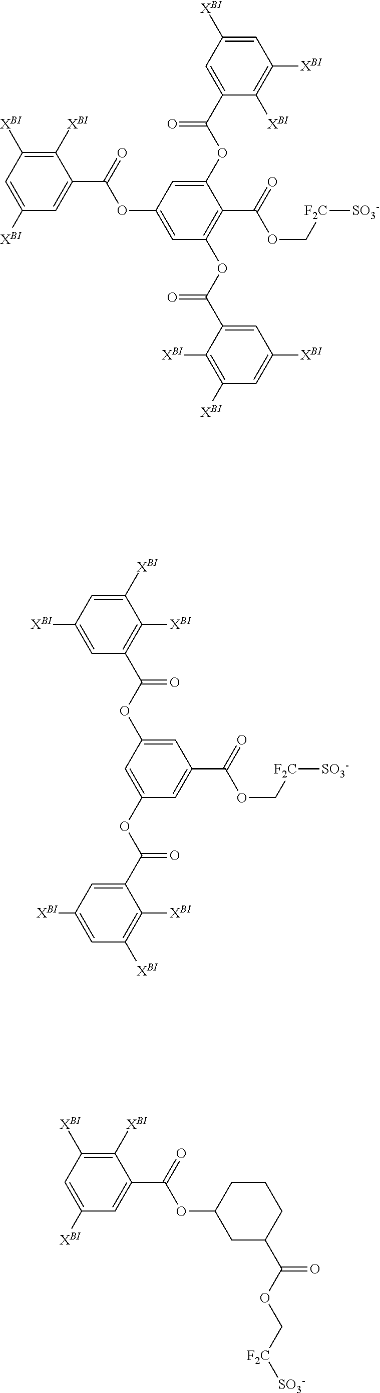

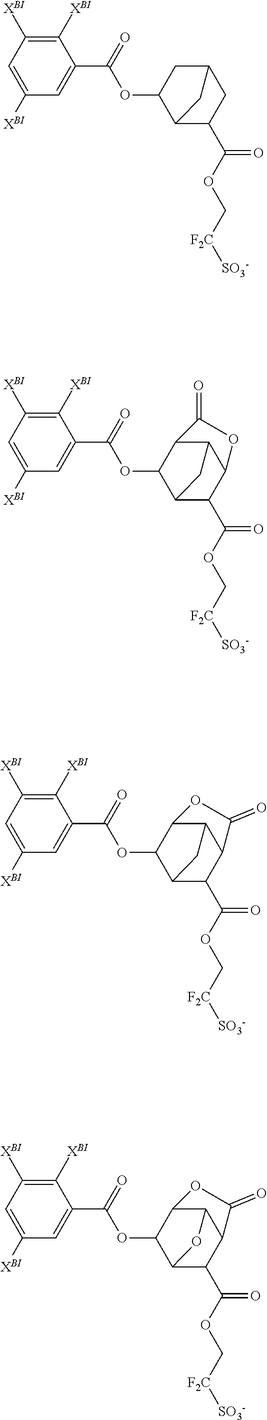

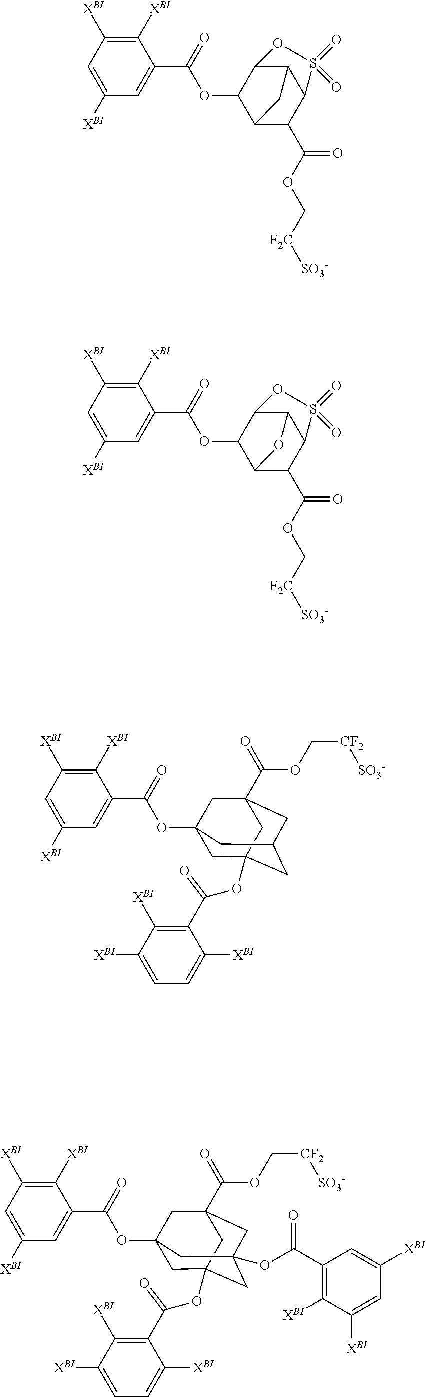

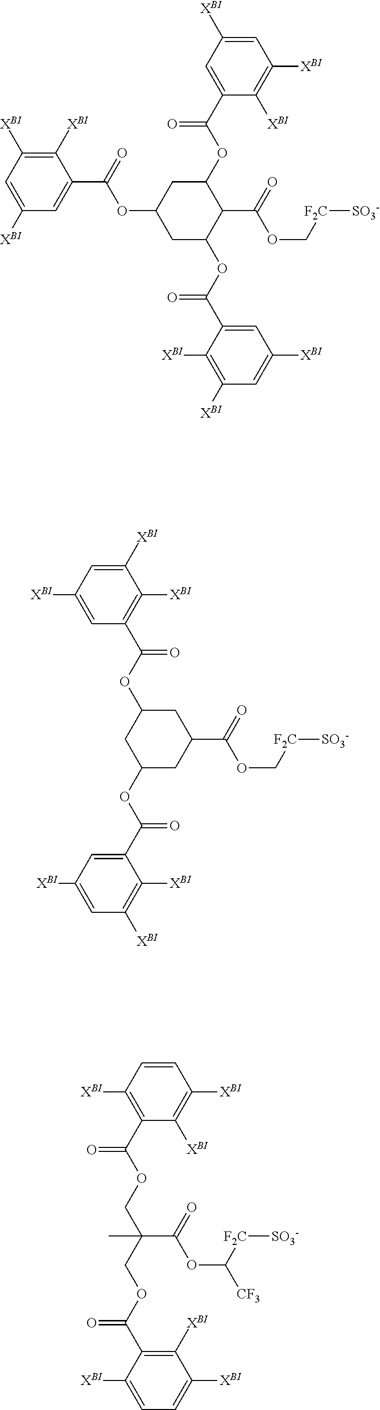

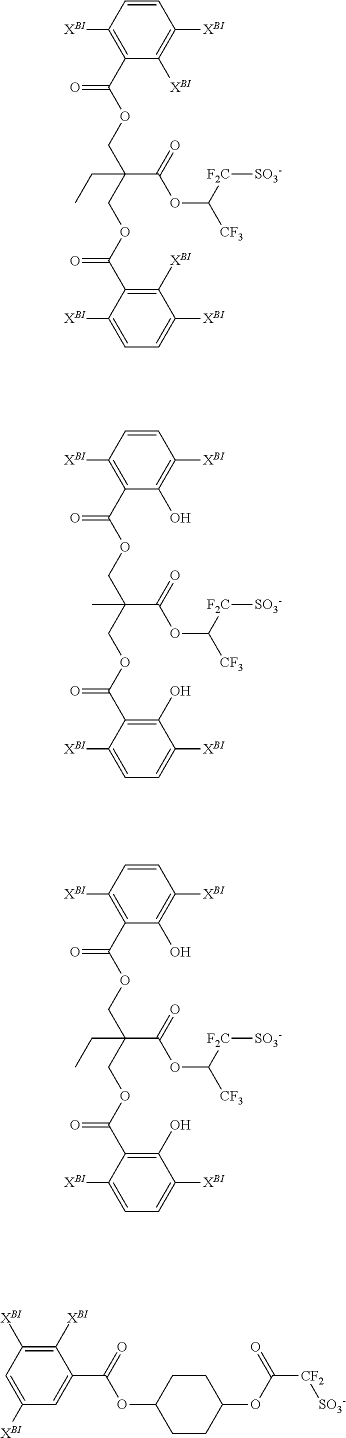

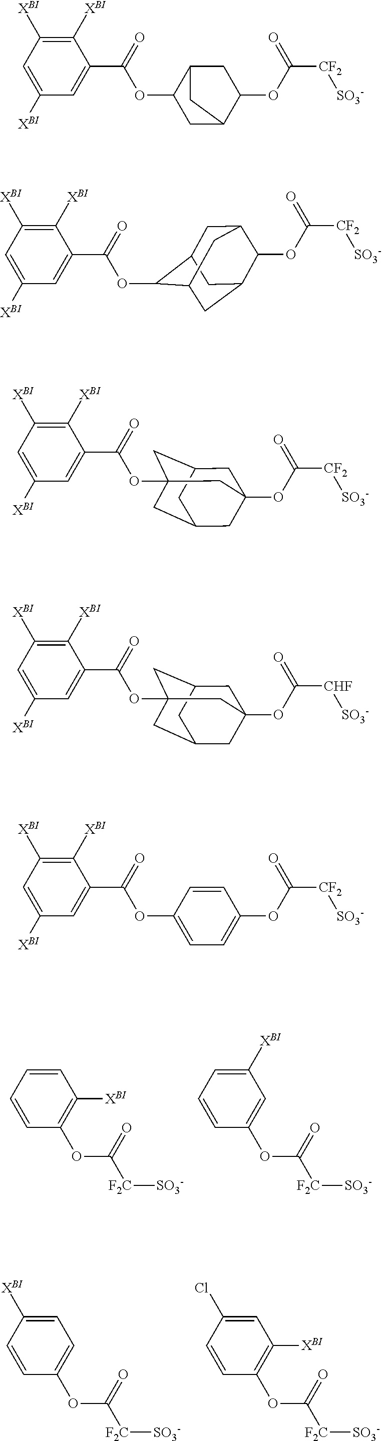

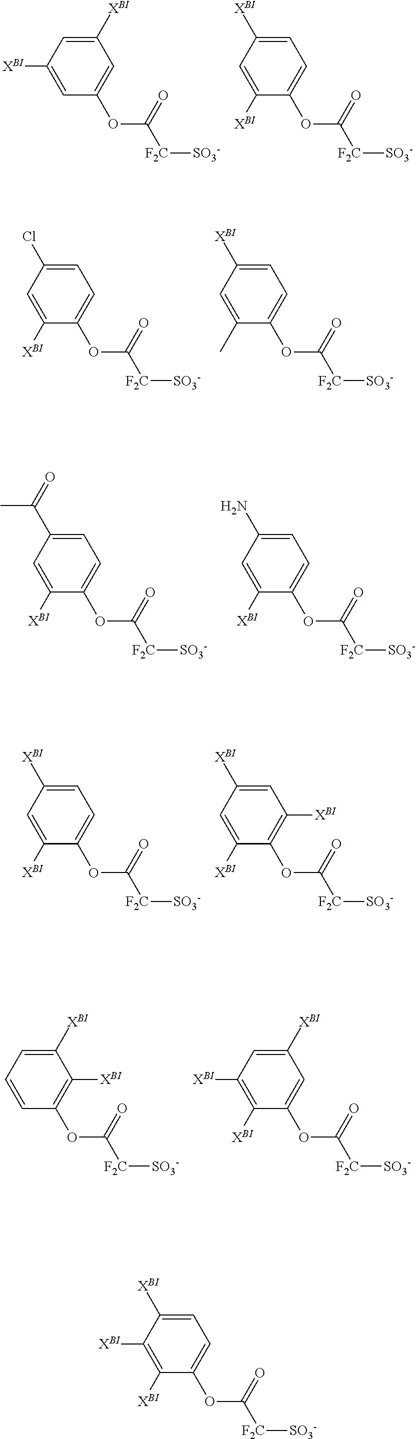

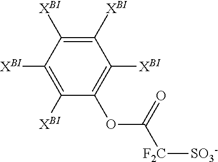

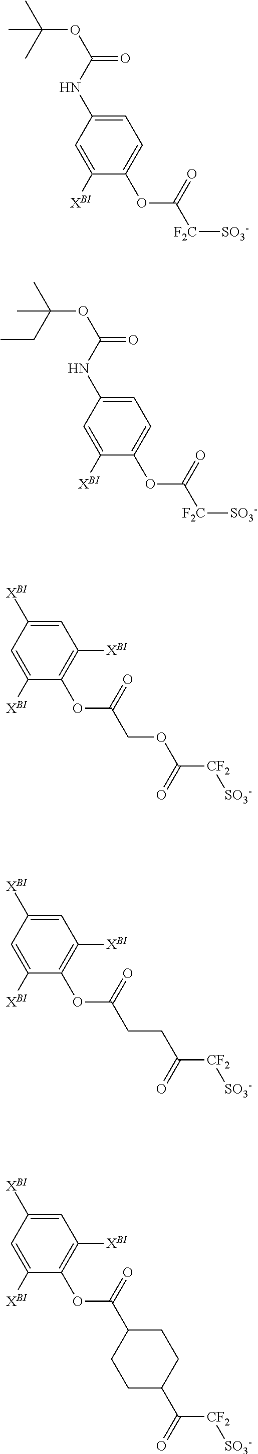

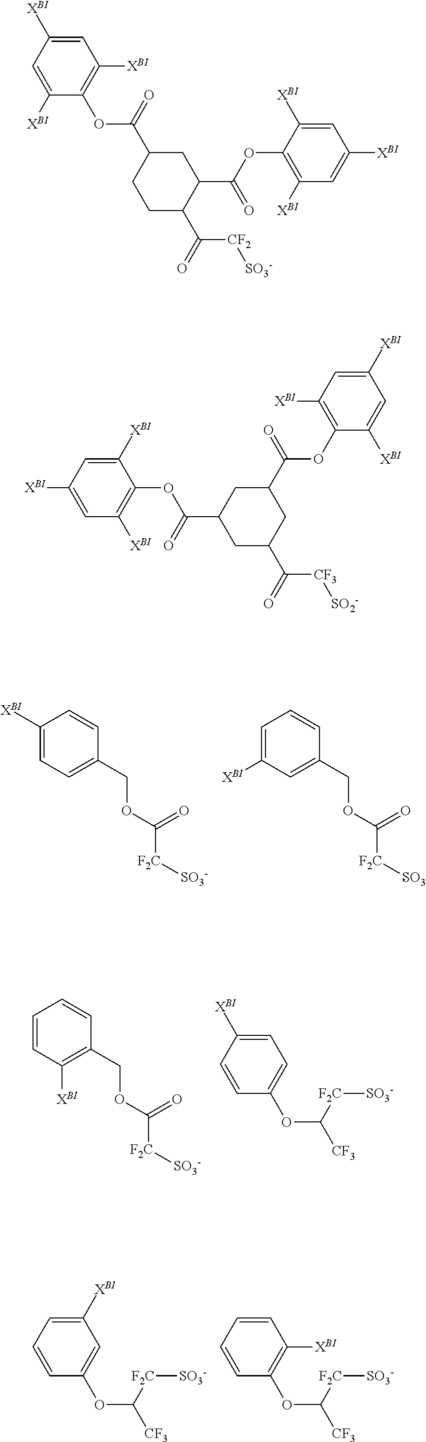

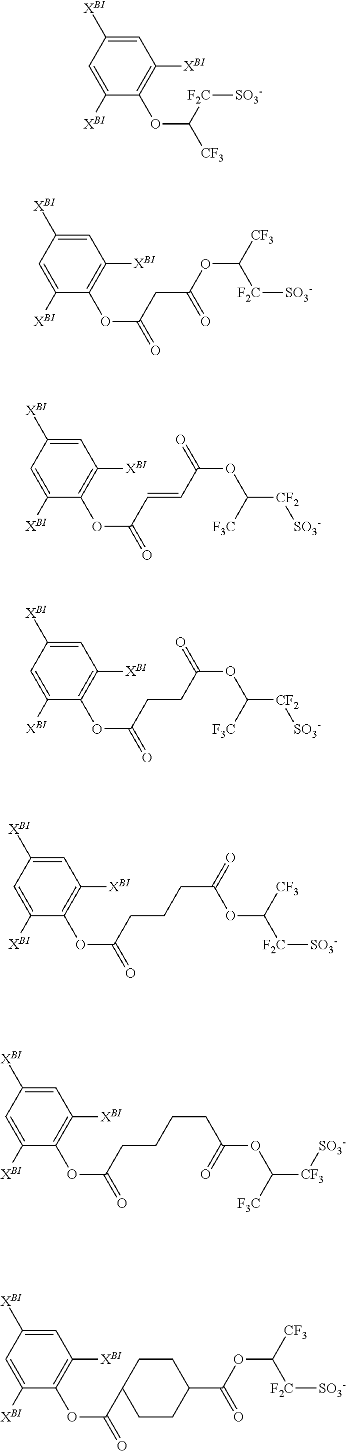

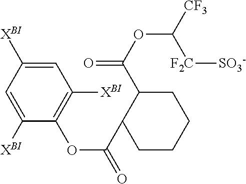

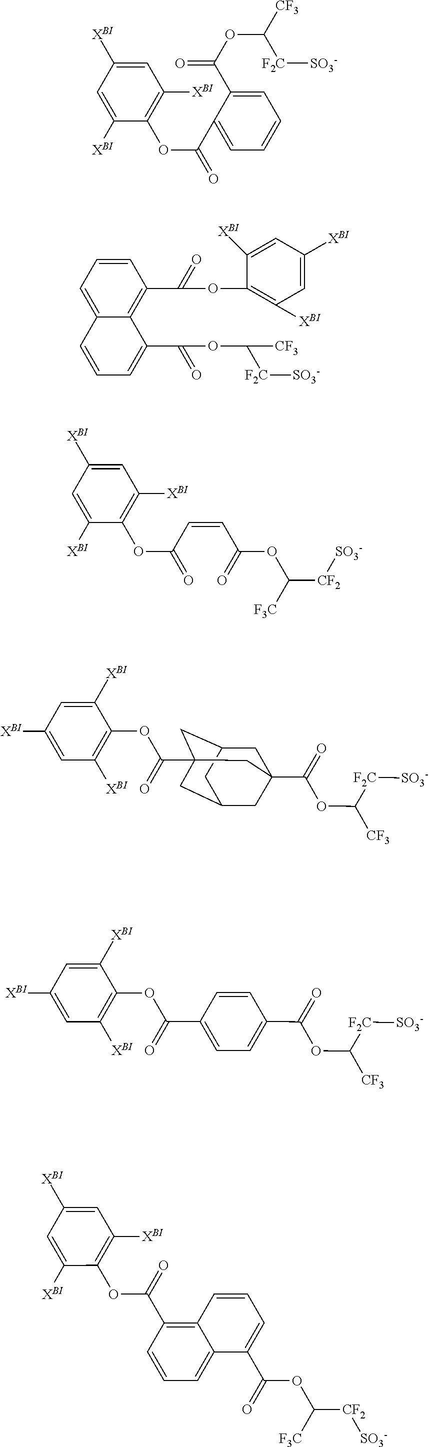

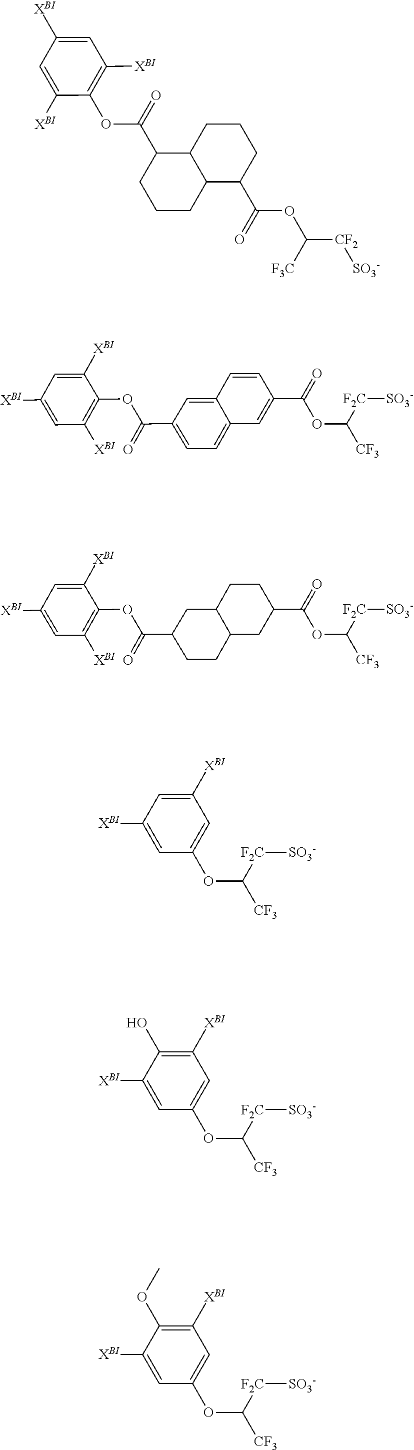

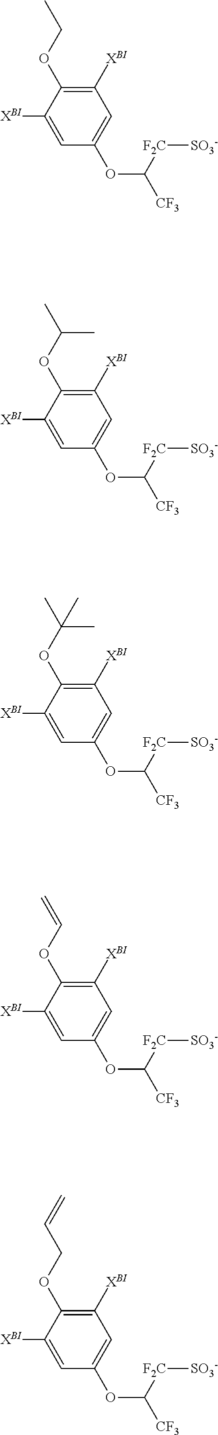

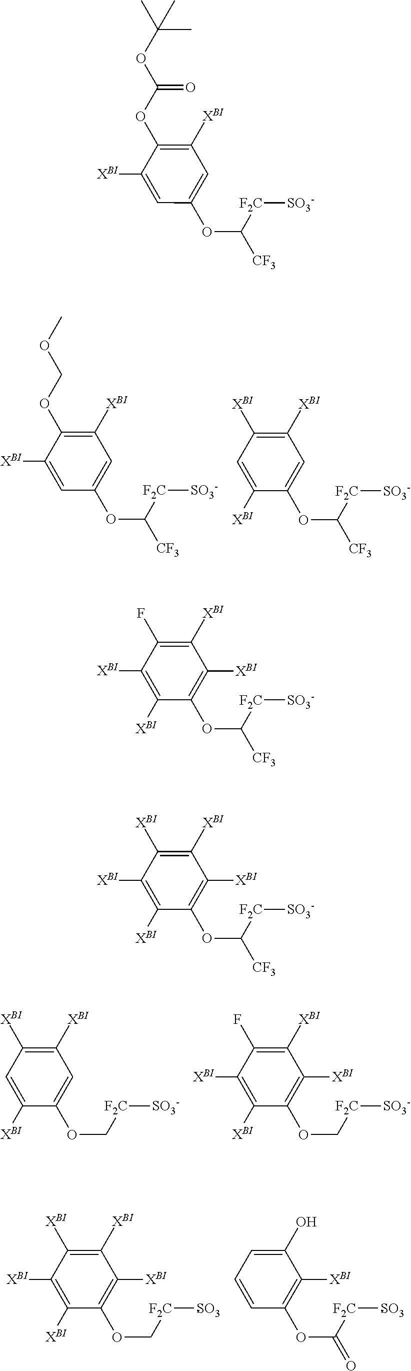

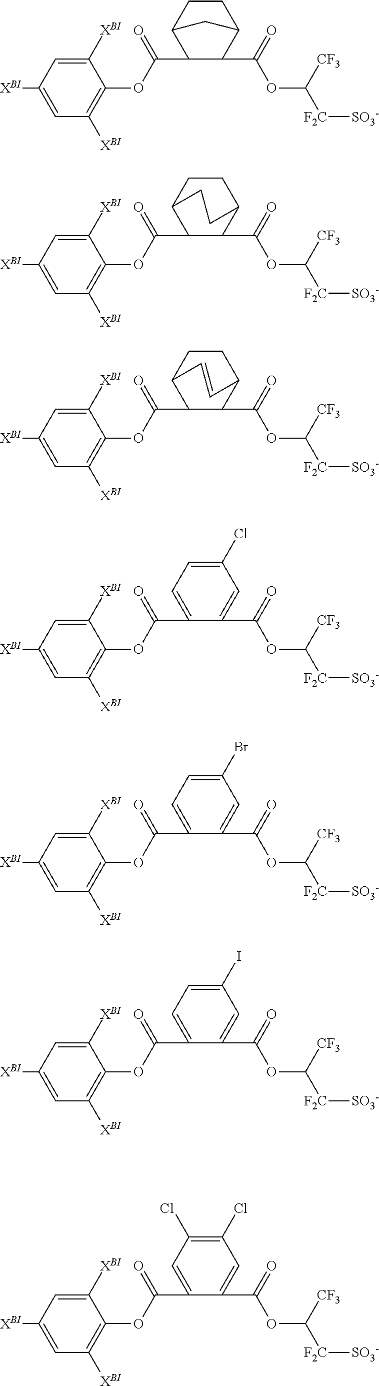

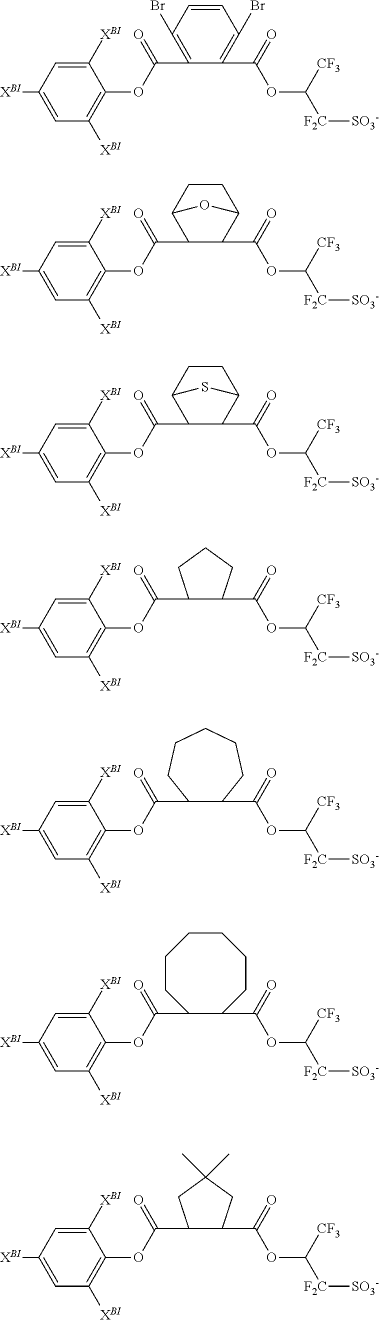

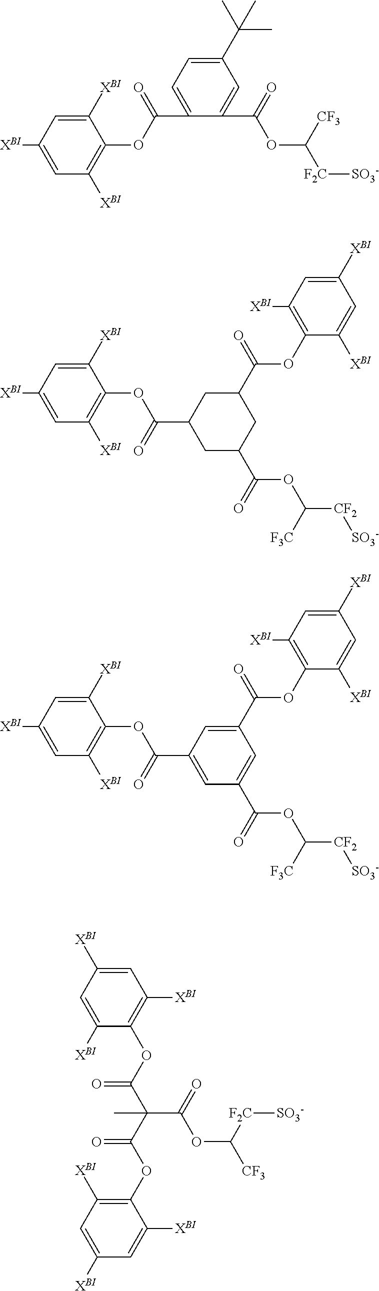

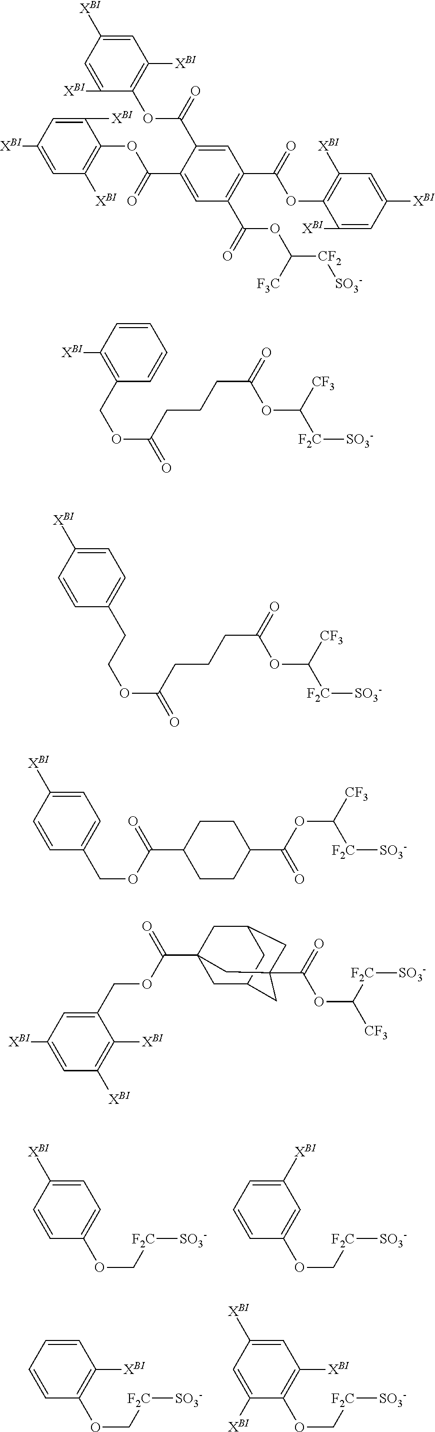

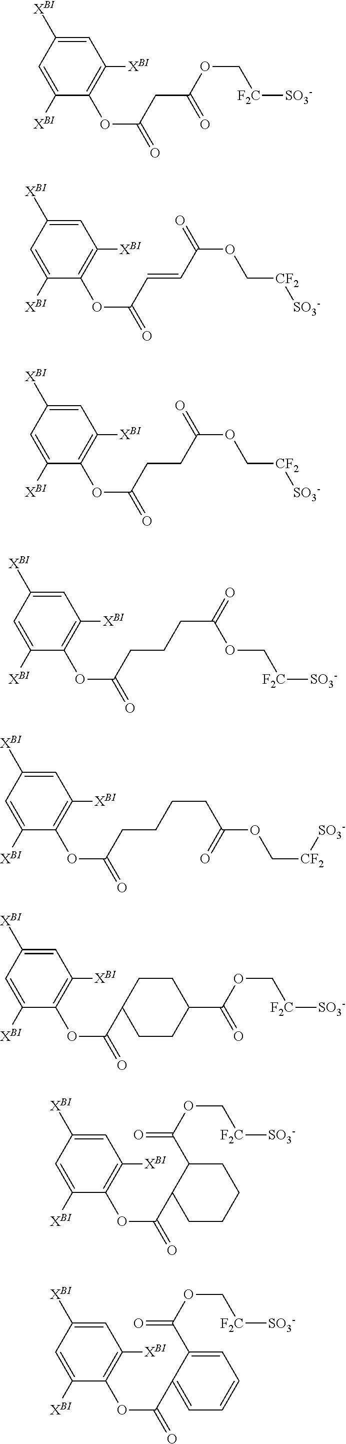

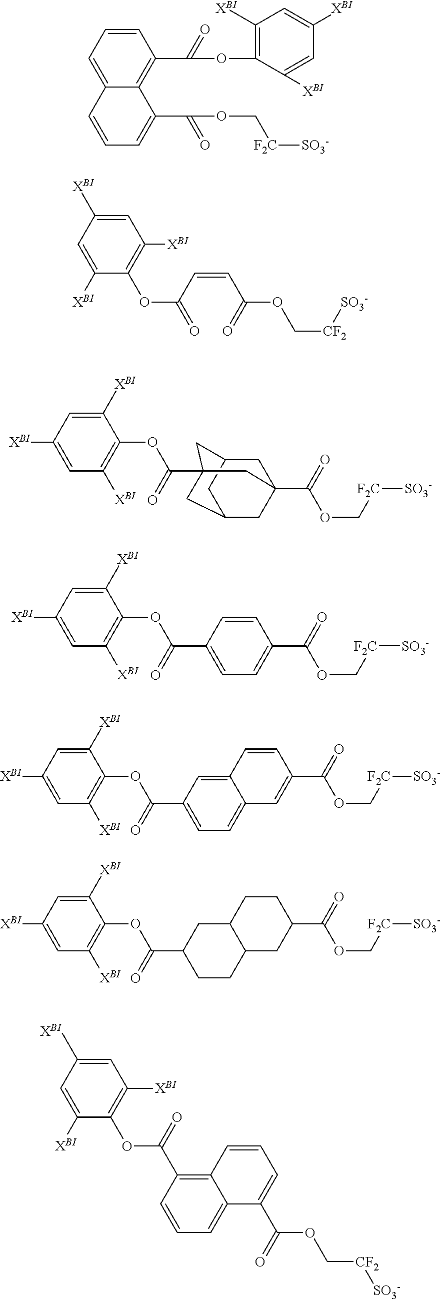

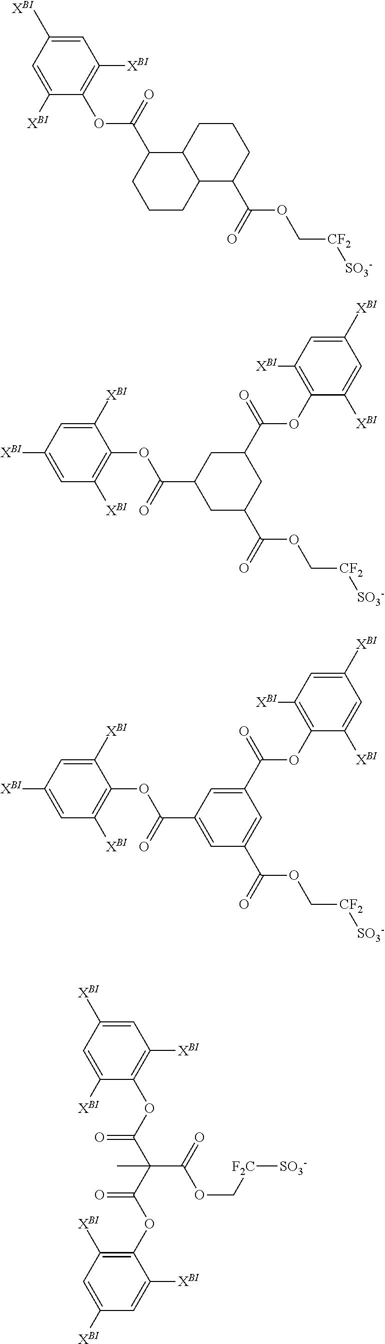

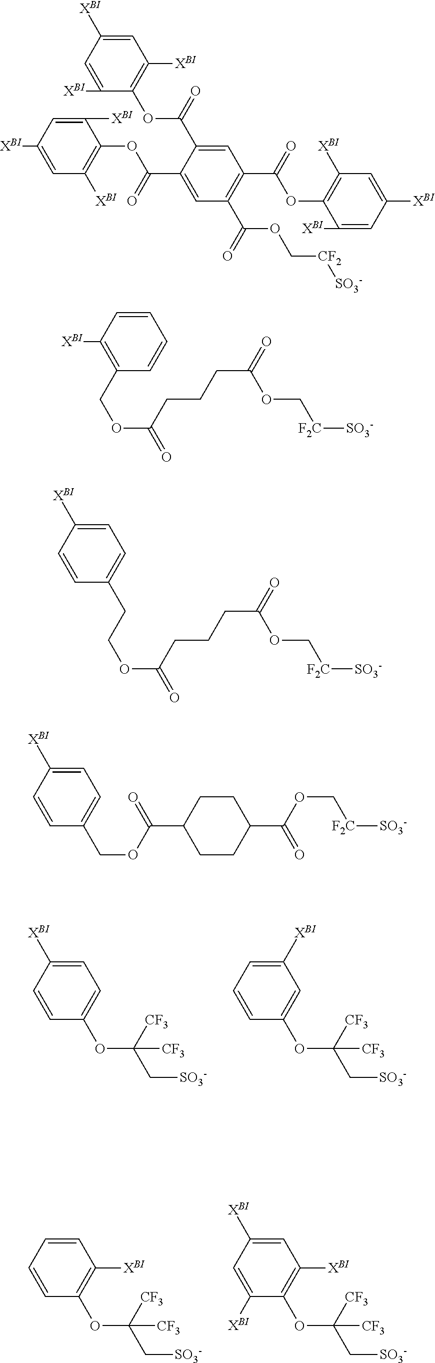

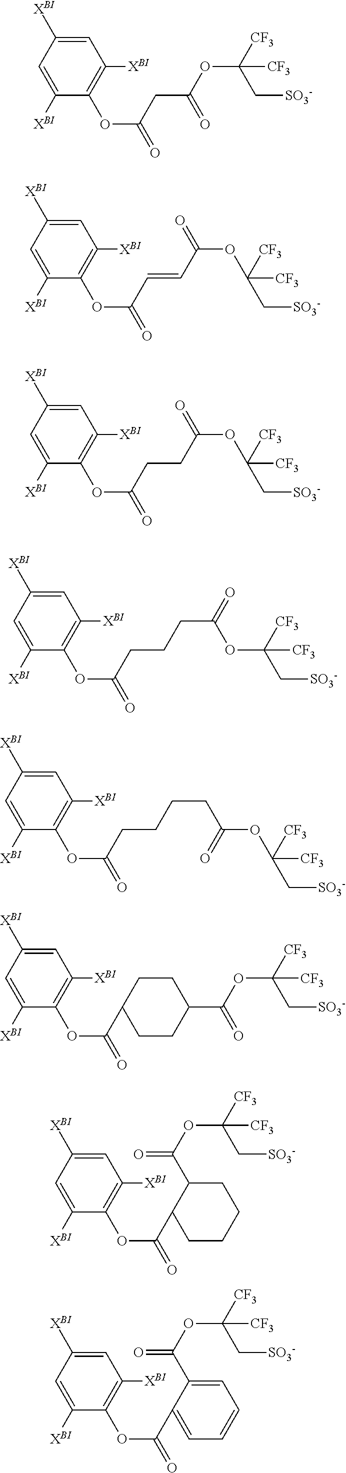

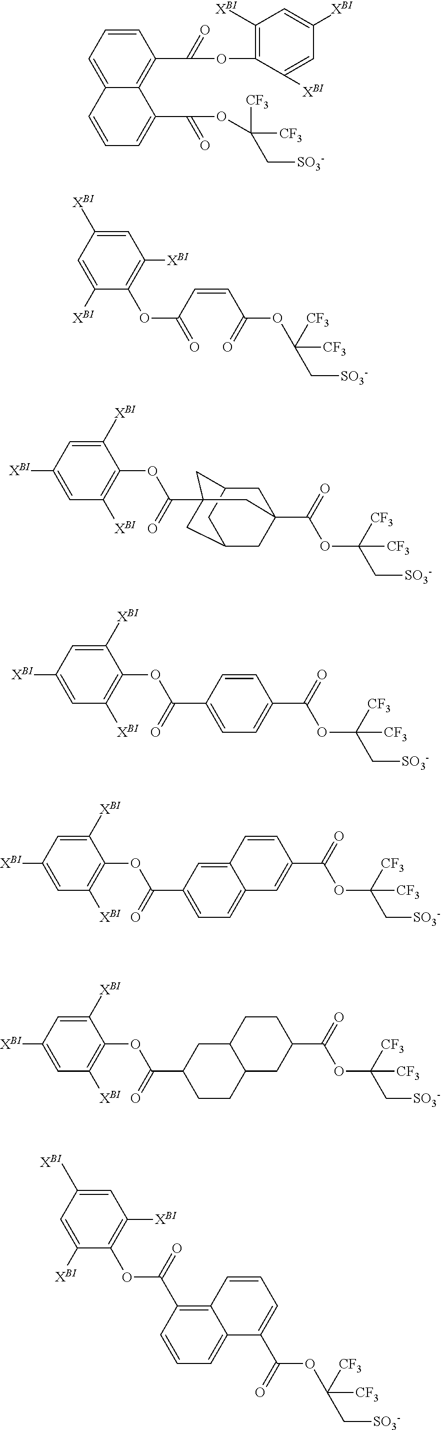

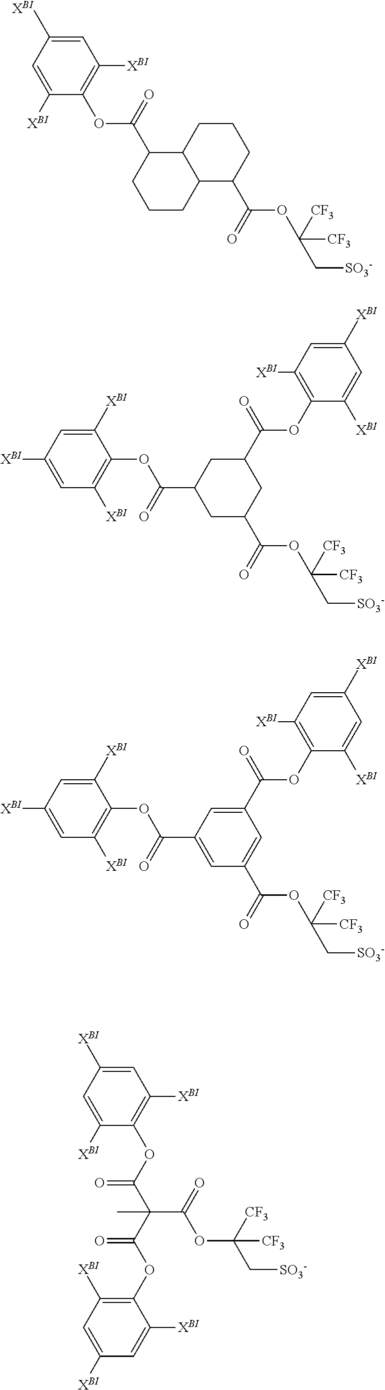

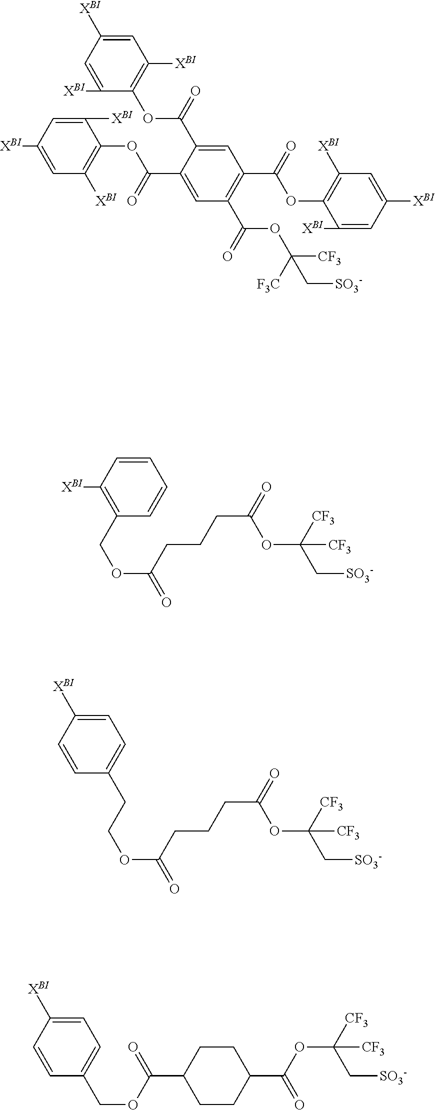

When used, the acid generator of addition type is preferably added in an amount of 0.1 to 50 parts, and more preferably 1 to 40 parts by weight per 100 parts by weight of the base polymer. The resist composition functions as a chemically amplified resist composition when the base polymer includes repeat units (b) and/or the resist composition contains the acid generator of addition type.

### Organic Solvent

An organic solvent may be added to the resist composition. The organic solvent used herein is not particularly limited as long as the foregoing and other components are soluble therein. Examples of the organic solvent are described in JP-A 2008-111103, paragraphs [0144]-[0145] (U.S. Pat. No. 7,537,880). Exemplary solvents include ketones such as cyclohexanone, cyclopentanone, methyl-2-n-pentyl ketone and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone, which may be used alone or in admixture.

The organic solvent is preferably added in an amount of 100 to 10,000 parts, and more preferably 200 to 8,000 parts by weight per 100 parts by weight of the base polymer.

### Other Components

In addition to the foregoing components, the resist composition may further comprise other components such as a surfactant, dissolution inhibitor, water repellency improver, and acetylene alcohol. Each of additional components may be used alone or in admixture of two or more.

Exemplary surfactants are described in JP-A 2008-111103, paragraphs [0165]-[0166]. Inclusion of a surfactant may improve or control the coating characteristics of the resist composition. When used, the surfactant is preferably added in an amount of 0.0001 to 10 parts by weight per 100 parts by weight of the base polymer.

The inclusion of a dissolution inhibitor in the resist composition leads to an increased difference in dissolution rate between exposed and unexposed areas and a further improvement in resolution. The dissolution inhibitor which can be used herein is a compound having at least two phenolic hydroxy groups on the molecule, in which an average of from 0 to 100 mol % of all the hydrogen atoms on the phenolic hydroxy groups are replaced by acid labile groups or a compound having at least one carboxy group on the molecule, in which an average of 50 to 100 mol % of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid, and cholic acid derivatives in which the hydrogen atom on the hydroxy or carboxy group is replaced by an acid labile group, as described in U.S. Pat. No. 7,771,914 (JP-A 2008-122932, paragraphs [0155]-[0178]).

When the resist composition contains a dissolution inhibitor, the dissolution inhibitor is preferably added in an amount of 0 to 50 parts, more preferably 5 to 40 parts by weight per 100 parts by weight of the base polymer.

To the resist composition, a water repellency improver may also be added for improving the water repellency on surface of a resist film. The water repellency improver may be used in the topcoatless immersion lithography. Suitable water repellency improvers include polymers having a fluoroalkyl group and polymers of specific structure having a 1,1,1,3,3,3-hexafluoro-2-propanol residue and are described in JP-A 2007-297590 and JP-A 2008-111103, for example. The water repellency improver should be soluble in the alkaline developer and organic solvent developer. The water repellency improver of specific structure having a 1,1,1,3,3,3-hexafluoro-2-propanol residue is well soluble in the developer. A polymer comprising repeat units having an amino group or amine salt may serve as the water repellent additive and is effective for preventing evaporation of acid during PEB, thus preventing any hole pattern opening failure after development. An appropriate amount of the water repellency improver is 0 to 20 parts, more preferably 0.5 to 10 parts by weight per 100 parts by weight of the base polymer.

Also, an acetylene alcohol may be blended in the resist composition. Suitable acetylene alcohols are described in JP-A 2008-122932, paragraphs [0179]-[0182]. An appropriate amount of the acetylene alcohol blended is 0 to 5 parts by weight per 100 parts by weight of the base polymer.

### Process

The resist composition is used in the fabrication of various integrated circuits. Pattern formation using the resist composition may be performed by well-known lithography processes. The process generally involves the steps of applying the resist composition onto a substrate to form a resist film thereon, exposing the resist film to high-energy radiation, and developing the exposed resist film in a developer. If necessary, any additional steps may be added.

Specifically, the resist composition is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying or doctor coating. The coating is prebaked on a hotplate preferably at a temperature of 60 to 150° C. for 10 seconds to 30 minutes, more preferably at 80 to 120° C. for 30 seconds to 20 minutes. The resulting resist film is generally 0.01 to 2 μm thick.

The resist film is then exposed to a desired pattern of high-energy radiation such as UV, deep-UV, EB, EUV of wavelength 3 to 15 nm, x-ray, soft x-ray, excimer laser light, γ-ray or synchrotron radiation. When UV, deep-UV, EUV, x-ray, soft x-ray, excimer laser light, γ-ray or synchrotron radiation is used as the high-energy radiation, the resist film is exposed thereto directly or through a mask having a desired pattern in a dose of preferably about 1 to 200 mJ/cm², more preferably about 10 to 100 mJ/cm². When EB is used as the high-energy radiation, the resist film is exposed thereto directly or through a mask having a desired pattern in a dose of preferably about 0.1 to 100 μC/cm², more preferably about 0.5 to 50 μC/cm². It is appreciated that the inventive resist composition is suited in micropatterning using i-line of wavelength 365 nm, KrF excimer laser, ArF excimer laser, EB, EUV, x-ray, soft x-ray, γ-ray or synchrotron radiation, especially in micropatterning using EB or EUV.

After the exposure, the resist film may be baked (PEB) on a hotplate or in an oven preferably at 50 to 150° C. for 10 seconds to 30 minutes, more preferably at 60 to 120° C. for 30 seconds to 20 minutes.

After the exposure or PEB, the resist film is developed in a developer in the form of an aqueous base solution for 3 seconds to 3 minutes, preferably 5 seconds to 2 minutes by conventional techniques such as dip, puddle and spray techniques. A typical developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). Typically, the resist film in the exposed area is dissolved in the developer whereas the resist film in the unexposed area is not dissolved. In this way, the desired positive pattern is formed on the substrate.

In an alternative embodiment, a negative pattern can be obtained from the resist composition comprising a base polymer containing acid labile groups by effecting organic solvent development. The developer used herein is preferably selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate, and mixtures thereof.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable aromatic solvents include toluene, xylene, ethylbenzene, isopropylbenzene, t-butylbenzene and mesitylene.

Rinsing is effective for minimizing the risks of resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by coating a shrink agent thereto, and baking such that the shrink agent may undergo crosslinking at the resist surface as a result of the acid catalyst diffusing from the resist layer during bake, and the shrink agent may attach to the sidewall of the hole pattern. The bake is preferably at a temperature of 70 to 180° C., more preferably 80 to 170° C., for a time of 10 to 300 seconds. The extra shrink agent is stripped and the hole pattern is shrunk.

### EXAMPLES

Examples of the invention are given below by way of illustration and not by way of limitation. All parts are by weight (pbw).

Polymers were synthesized using Monomers PM-1 to PM-5, QM-1 to QM-10, and ALG-1 to ALG-4 shown below. The polymers were analyzed for composition by ¹³C- and ¹H-NMR spectroscopy and for Mw and Mw/Mn by GPC versus polystyrene standards using THE solvent.

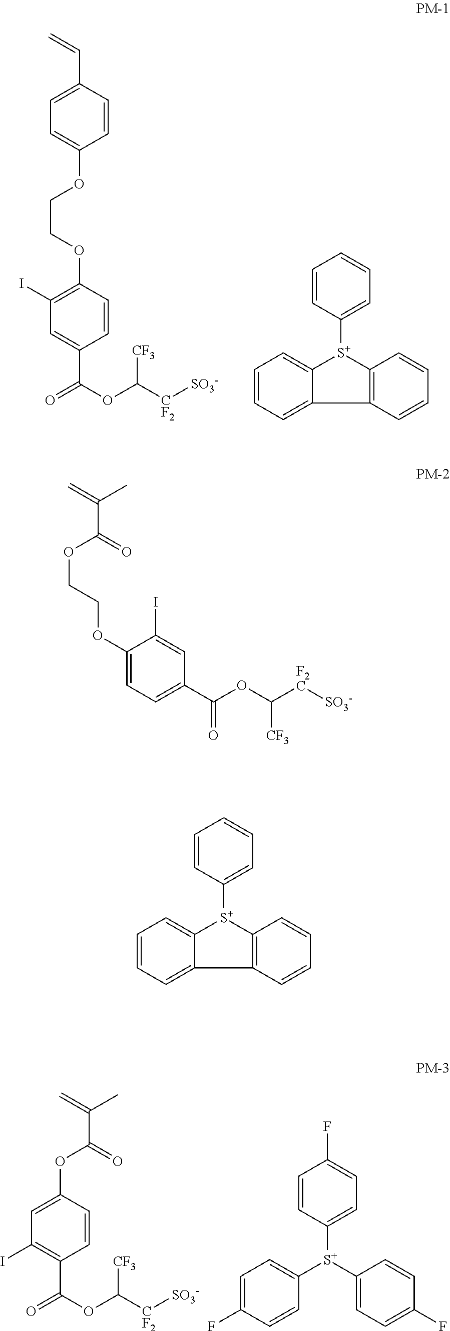

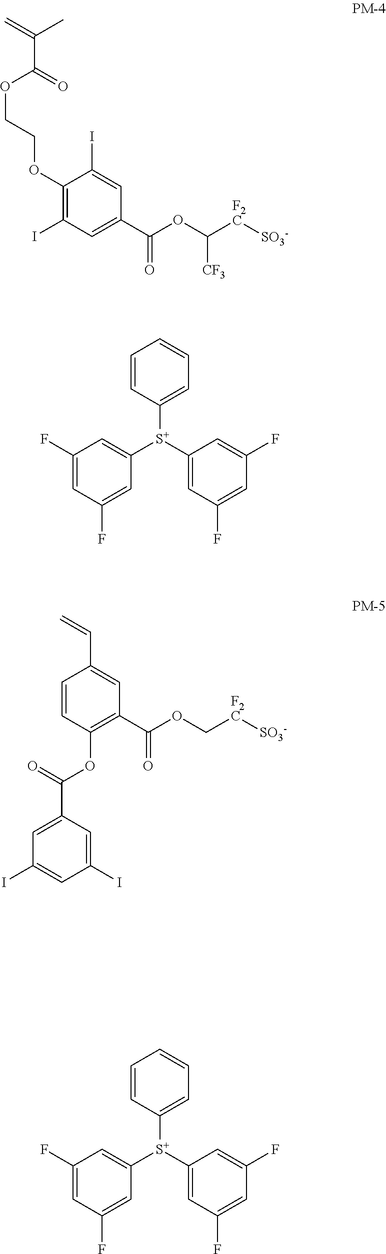

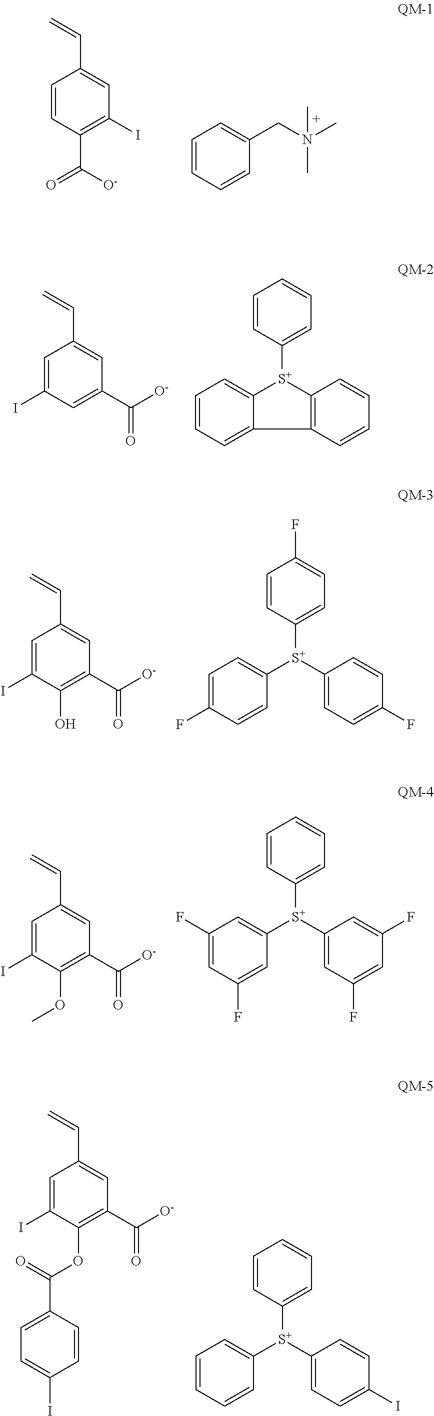

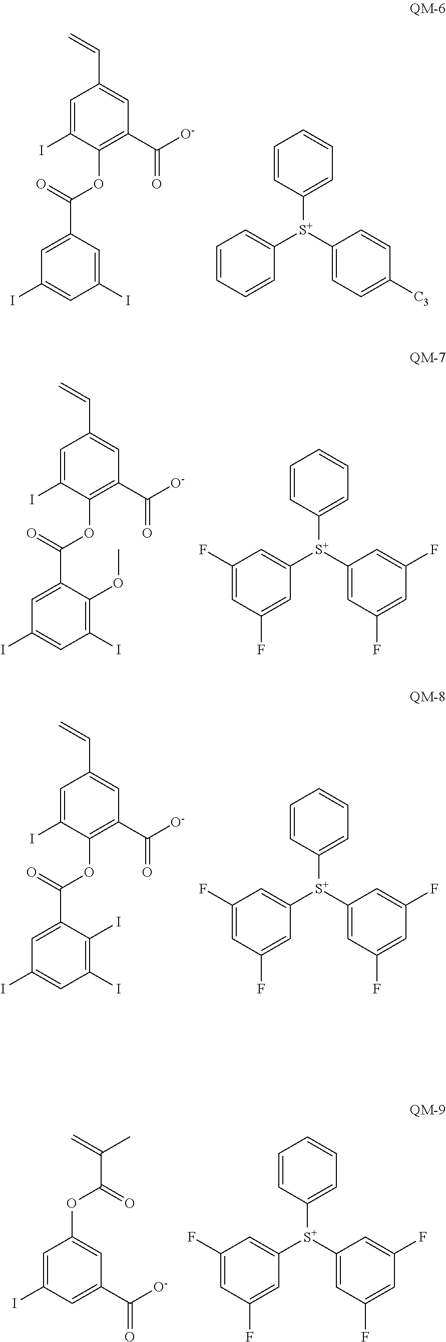

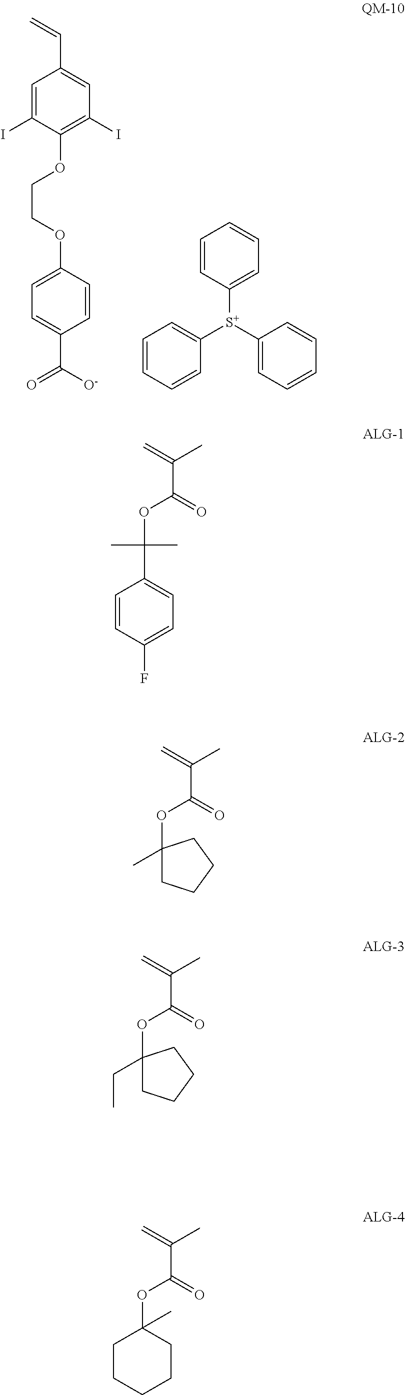 [SMILES: C=Cc1cc(I)c(OCCOc2ccc(C(=O)[O-])cc2)c(I)c1 ; c1ccc([S+](c2ccccc2)c2ccccc2)cc1 ; C=C(C)C(=O)OC(C)(C)c1ccc(F)cc1 ; C=C(C)C(=O)OC1(C)CCCC1 ; C=C(C)C(=O)OC1(CC)CCCC1 ; C=C(C)C(=O)OC1(C)CCCCC1]

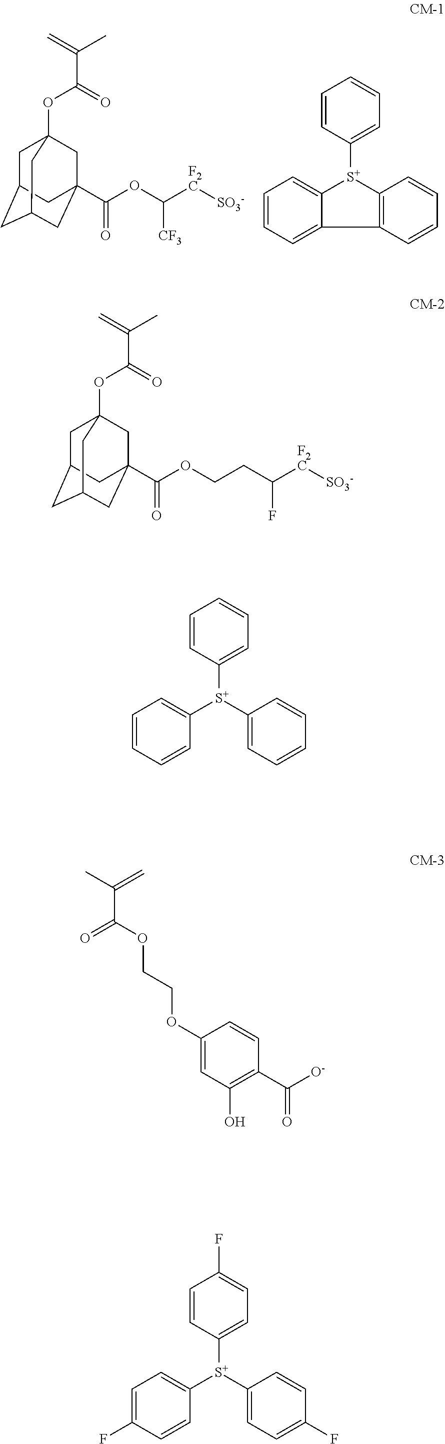

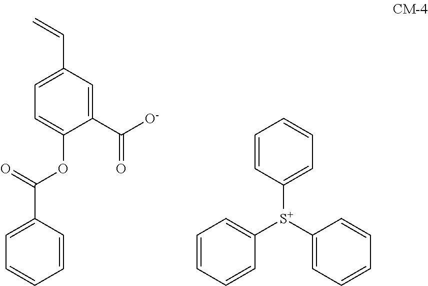 [SMILES: C=Cc1ccc(OC(=O)c2ccccc2)c(C(=O)[O-])c1 ; c1ccc([S+](c2ccccc2)c2ccccc2)cc1]

### Synthesis Example 1

### Synthesis of Polymer P-1

A 2-L flask was charged with 1.4 g of Monomer QM-1, 7.6 g of Monomer ALG-1, 3.2 g of 3-methyl-4-hydroxystyrene, 7.1 g of Monomer PM-4, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of azobisisobutyronitrile (AIBN) as polymerization initiator was added. The reactor was heated at 60° C. and held at the temperature for 15 hours for reaction. The reaction solution was poured into 1 L of isopropyl alcohol (IPA) for precipitation. The resulting white solid was collected by filtration and dried in vacuum at 60° C., obtaining Polymer P-1. The polymer was analyzed by ¹³C- and ¹H-NMR spectroscopy and GPC.

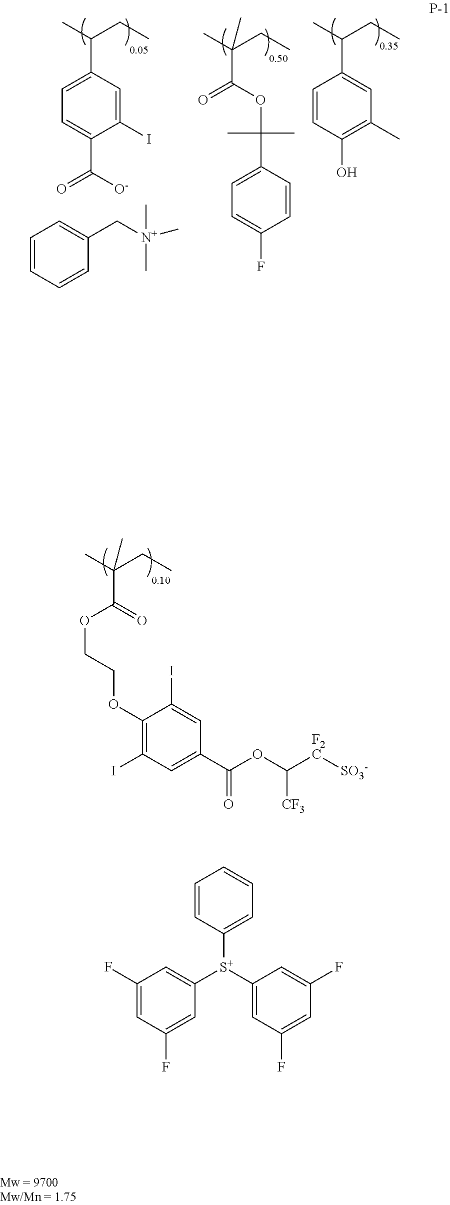

### Synthesis Example 2

### Synthesis of Polymer P-2

A 2-L flask was charged with 1.8 g of Monomer QM-2, 7.6 g of Monomer ALG-1, 3.2 g of 3-methyl-4-hydroxystyrene, 7.1 g of Monomer PM-4, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-2. The polymer was analyzed by NMR spectroscopy and GPC.

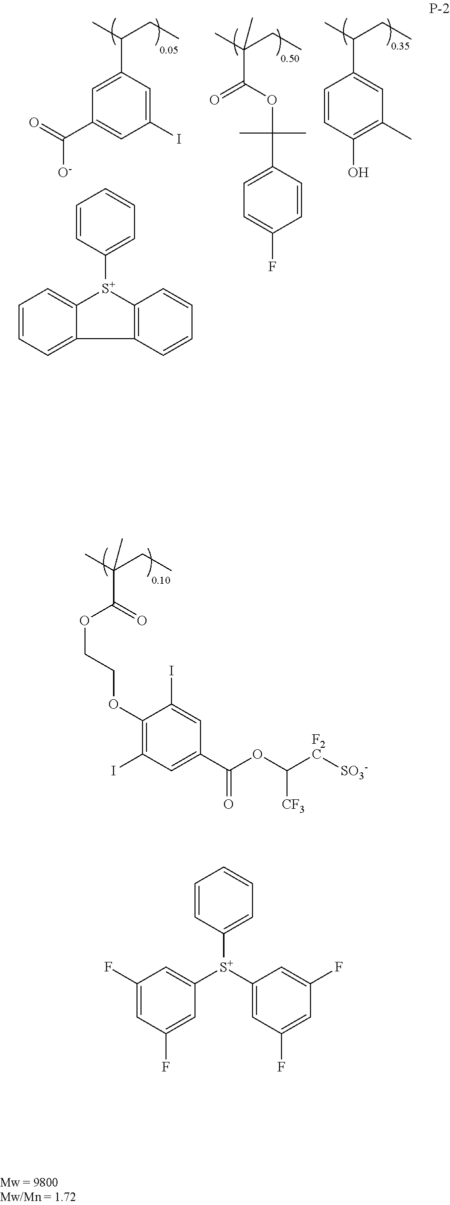

### Synthesis Example 3

### Synthesis of Polymer P-3

A 2-L flask was charged with 2.1 g of Monomer QM-3, 7.6 g of Monomer ALG-1, 3.2 g of 3-methyl-4-hydroxystyrene, 7.1 g of Monomer PM-4, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-3. The polymer was analyzed by NMR spectroscopy and GPC.

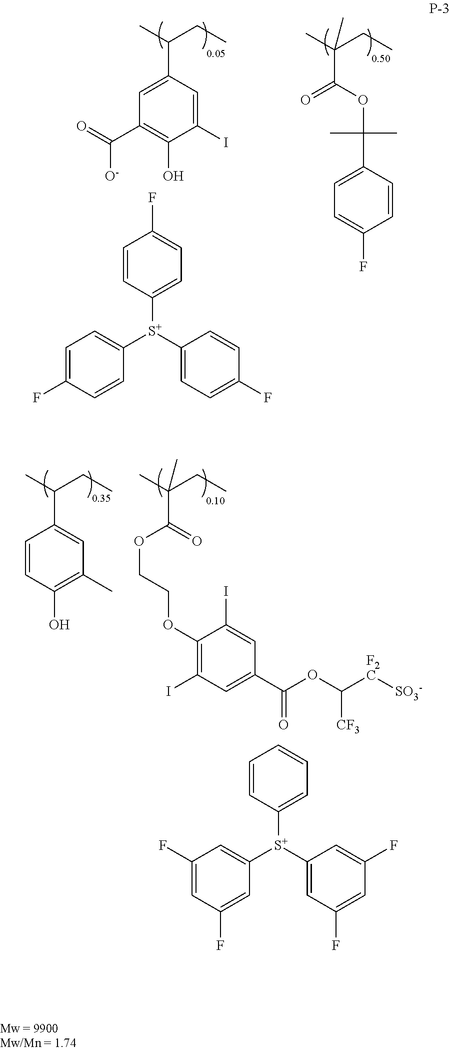

### Synthesis Example 4

### Synthesis of Polymer P-4

A 2-L flask was charged with 2.2 g of Monomer QM-4, 7.6 g of Monomer ALG-1, 2.9 g of 3-hydroxystyrene, 5.8 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-4. The polymer was analyzed by NMR spectroscopy and GPC.

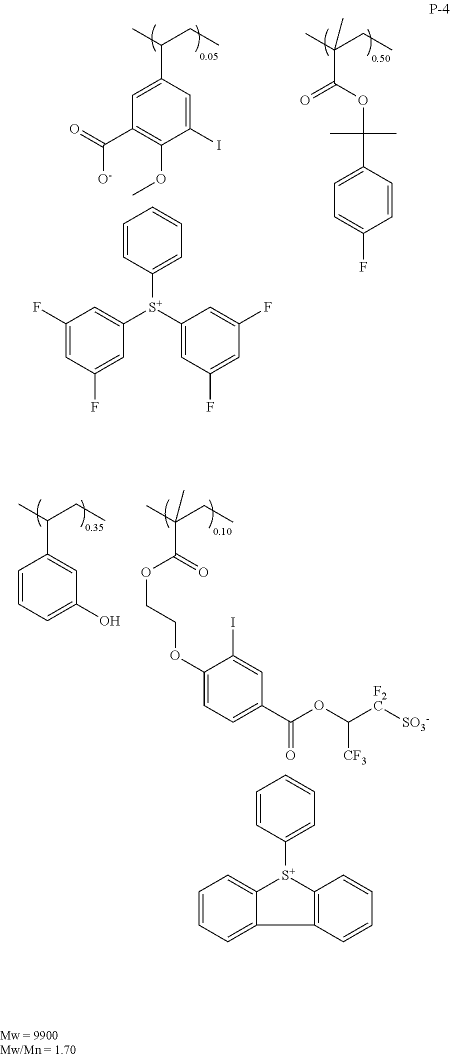

### Synthesis Example 5

### Synthesis of Polymer P-5

A 2-L flask was charged with 3.1 g of Monomer QM-5, 6.2 g of Monomer ALG-3, 2.9 g of 3-hydroxystyrene, 5.8 g of Monomer PM-3, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-5. The polymer was analyzed by NMR spectroscopy and GPC.

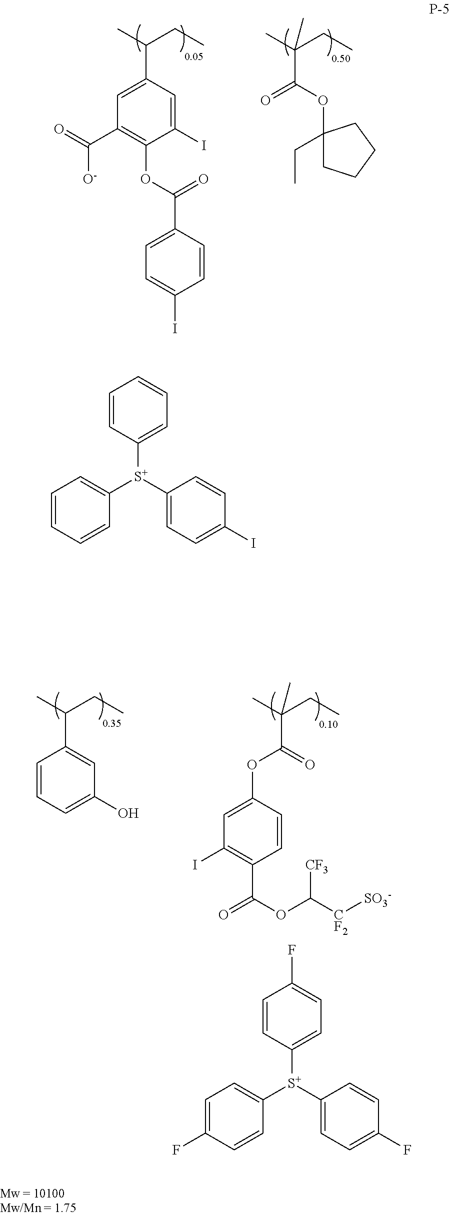

### Synthesis Example 6

### Synthesis of Polymer P-6

A 2-L flask was charged with 3.3 g of Monomer QM-6, 6.2 g of Monomer ALG-4, 2.9 g of 3-hydroxystyrene, 5.8 g of Monomer PM-3, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-6. The polymer was analyzed by NMR spectroscopy and GPC.

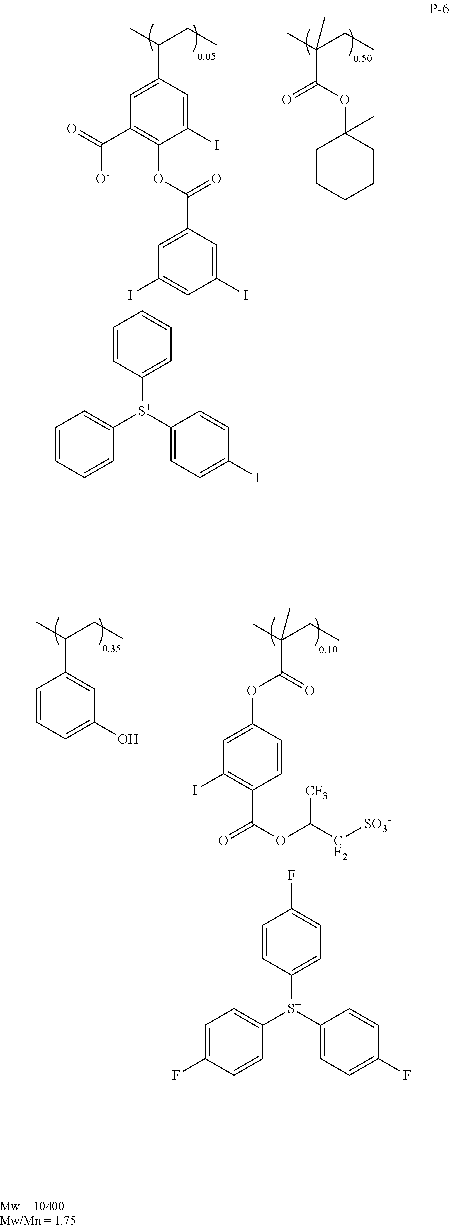

### Synthesis Example 7

### Synthesis of Polymer P-7

A 2-L flask was charged with 3.4 g of Monomer QM-7, 5.7 g of Monomer ALG-2, 2.9 g of 3-hydroxystyrene, 6.0 g of Monomer PM-1, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-7. The polymer was analyzed by NMR spectroscopy and GPC.

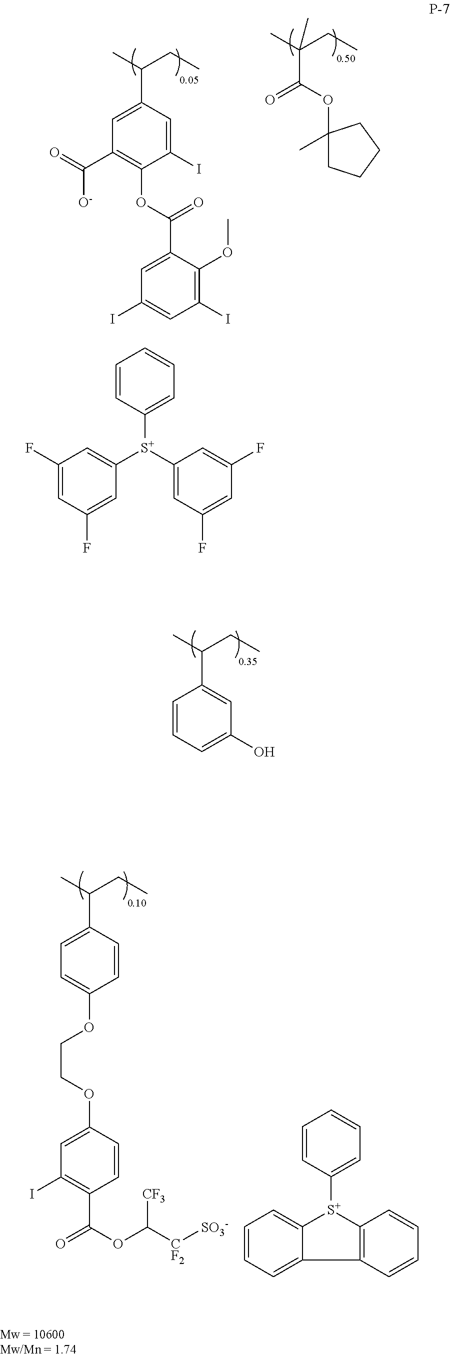

### Synthesis Example 8

### Synthesis of Polymer P-8

A 2-L flask was charged with 3.8 g of Monomer QM-8, 5.7 g of Monomer ALG-2, 2.9 g of 3-hydroxystyrene, 6.0 g of Monomer PM-1, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-8. The polymer was analyzed by NMR spectroscopy and GPC.

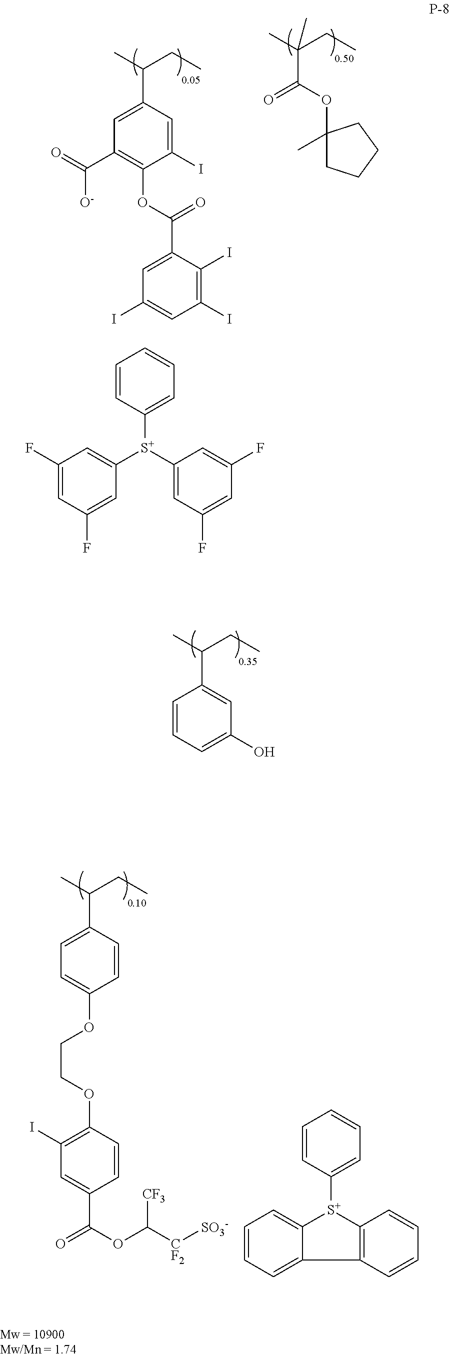

### Synthesis Example 9

### Synthesis of Polymer P-9

A 2-L flask was charged with 2.3 g of Monomer QM-9, 5.7 g of Monomer ALG-2, 2.9 g of 3-hydroxystyrene, 5.8 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-9. The polymer was analyzed by NMR spectroscopy and GPC.

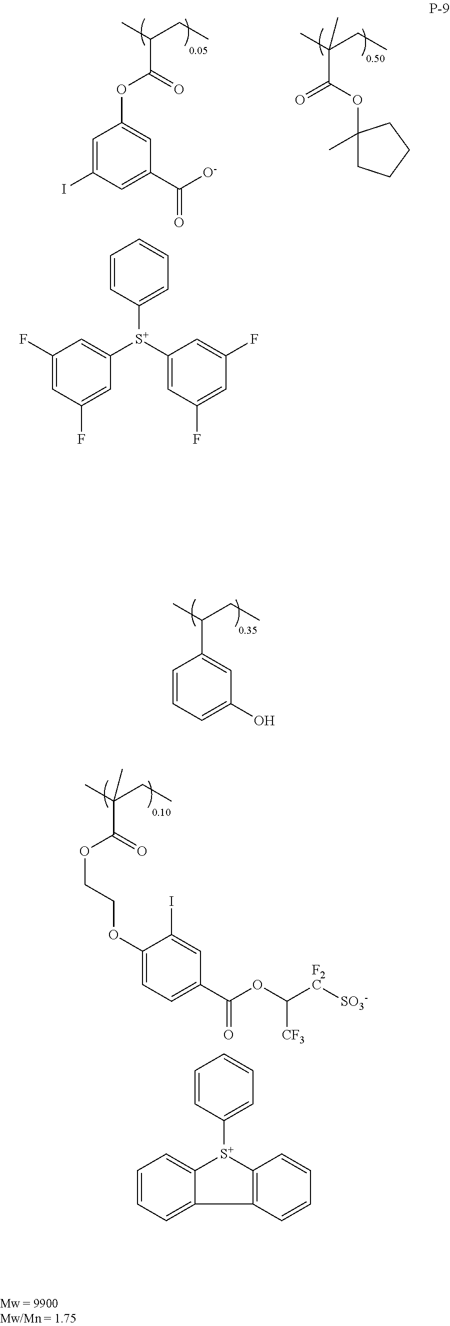

### Synthesis Example 10

### Synthesis of Polymer P-10

A 2-L flask was charged with 2.7 g of Monomer QM-10, 6.2 g of Monomer ALG-3, 2.9 g of 3-hydroxystyrene, 5.8 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-10. The polymer was analyzed by NMR spectroscopy and GPC.

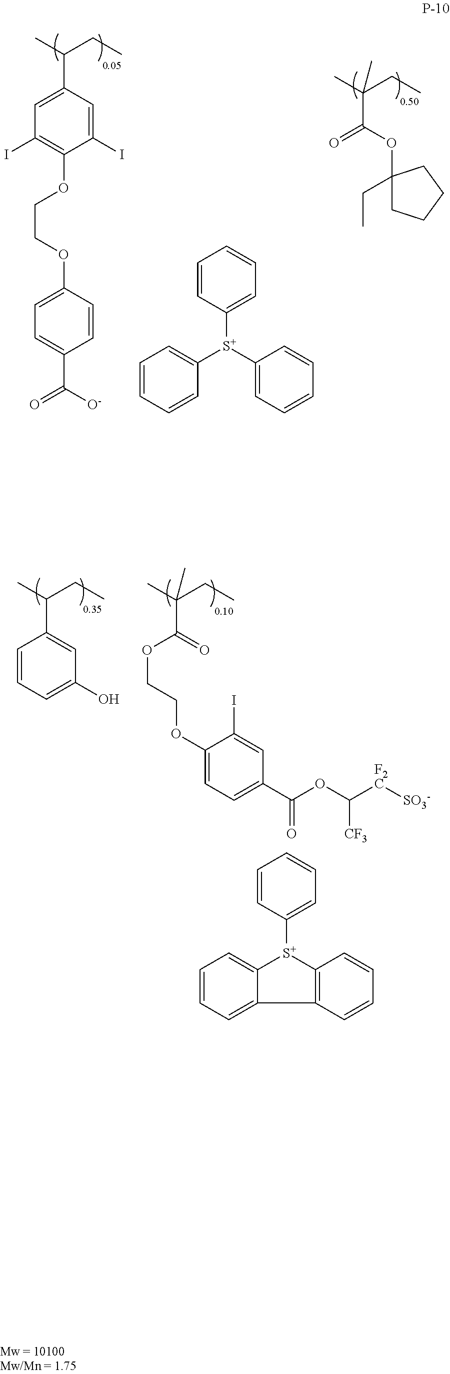

### Synthesis Example 11

### Synthesis of Polymer P-11

A 2-L flask was charged with 1.8 g of Monomer QM-2, 7.3 g of Monomer ALG-1, 2.9 g of 3-hydroxystyrene, 6.9 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-11. The polymer was analyzed by NMR spectroscopy and GPC.

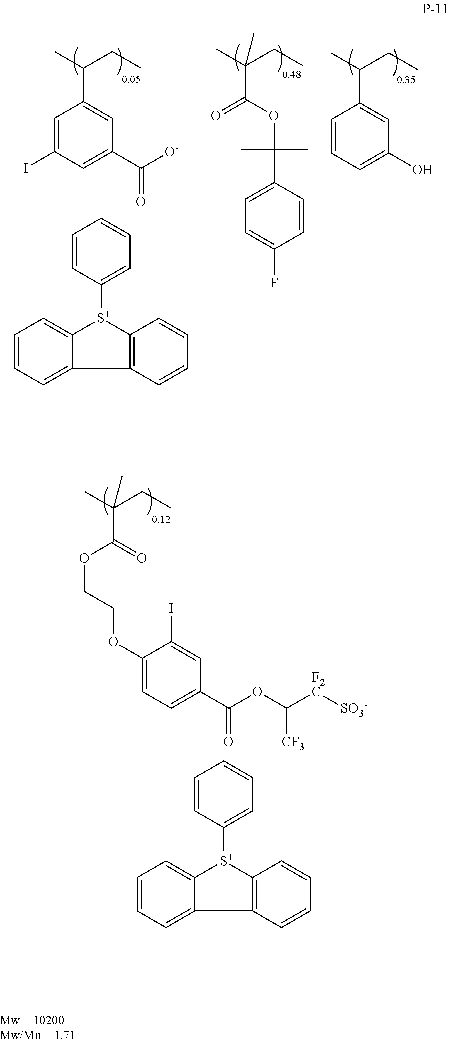

### Synthesis Example 12

### Synthesis of Polymer P-12

A 2-L flask was charged with 2.1 g of Monomer QM-3, 7.3 g of Monomer ALG-1, 2.9 g of 3-hydroxystyrene, 6.9 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-12. The polymer was analyzed by NMR spectroscopy and GPC.

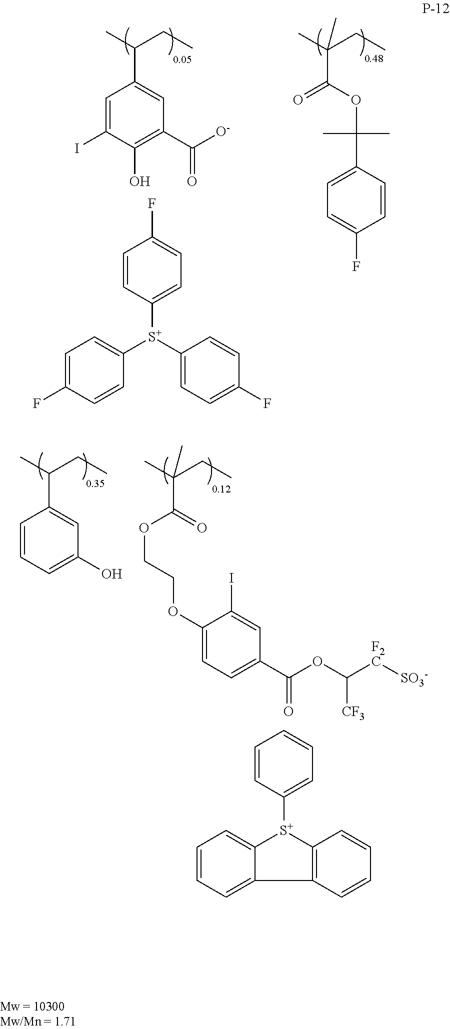

### Synthesis Example 13

### Synthesis of Polymer P-13

A 2-L flask was charged with 2.2 g of Monomer QM-4, 7.3 g of Monomer ALG-1, 2.9 g of 3-hydroxystyrene, 6.9 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-13. The polymer was analyzed by NMR spectroscopy and GPC.

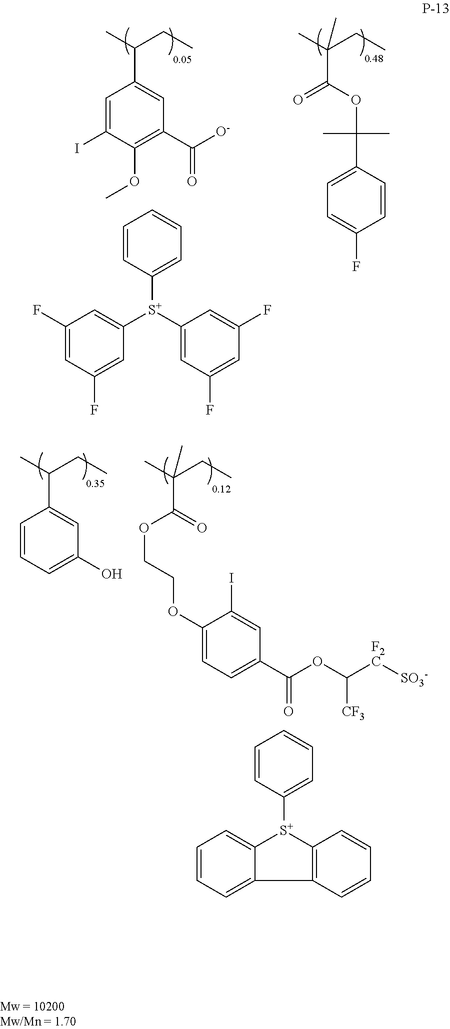

### Synthesis Example 14

### Synthesis of Polymer P-14

A 2-L flask was charged with 3.4 g of Monomer QM-7, 7.3 g of Monomer ALG-1, 2.9 g of 3-hydroxystyrene, 6.9 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-14. The polymer was analyzed by NMR spectroscopy and GPC.

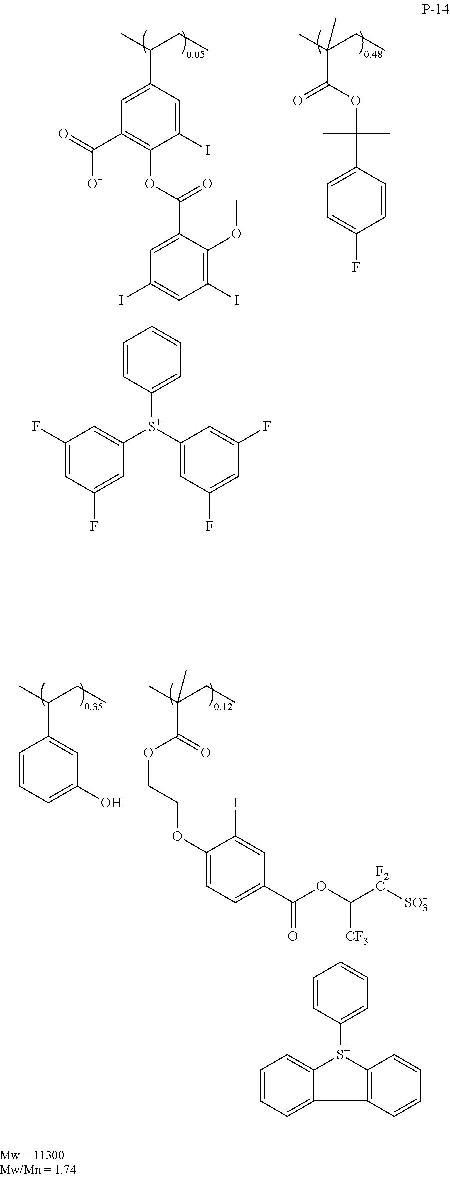

### Synthesis Example 15

### Synthesis of Polymer P-15

A 2-L flask was charged with 4.0 g of Monomer QM-6, 6.2 g of Monomer ALG-4, 2.8 g of 3-hydroxystyrene, 5.8 g of Monomer PM-3, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-15. The polymer was analyzed by NMR spectroscopy and GPC.

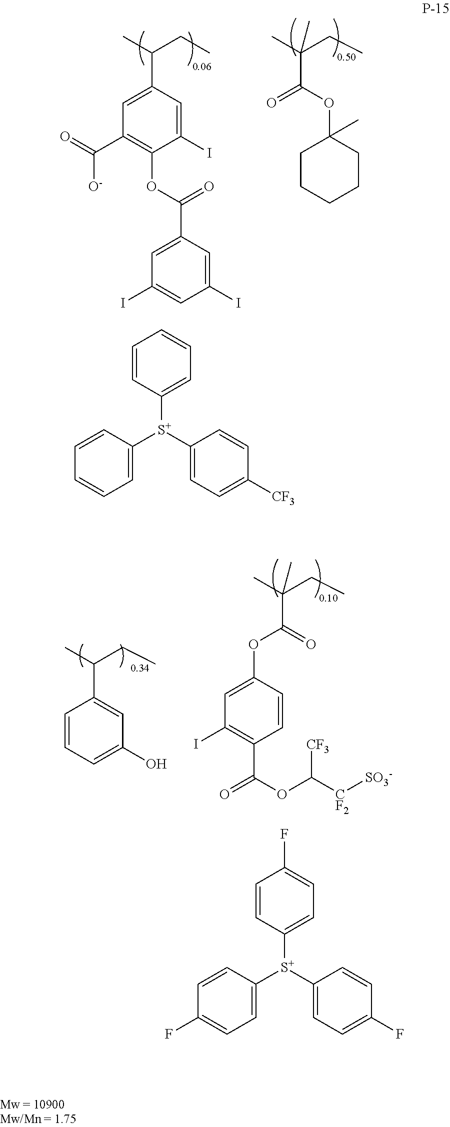

### Synthesis Example 16

### Synthesis of Polymer P-16

A 2-L flask was charged with 1.8 g of Monomer QM-2, 5.7 g of Monomer ALG-2, 2.9 g of 3-hydroxystyrene, 6.8 g of Monomer PM-5, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-16. The polymer was analyzed by NMR spectroscopy and GPC.

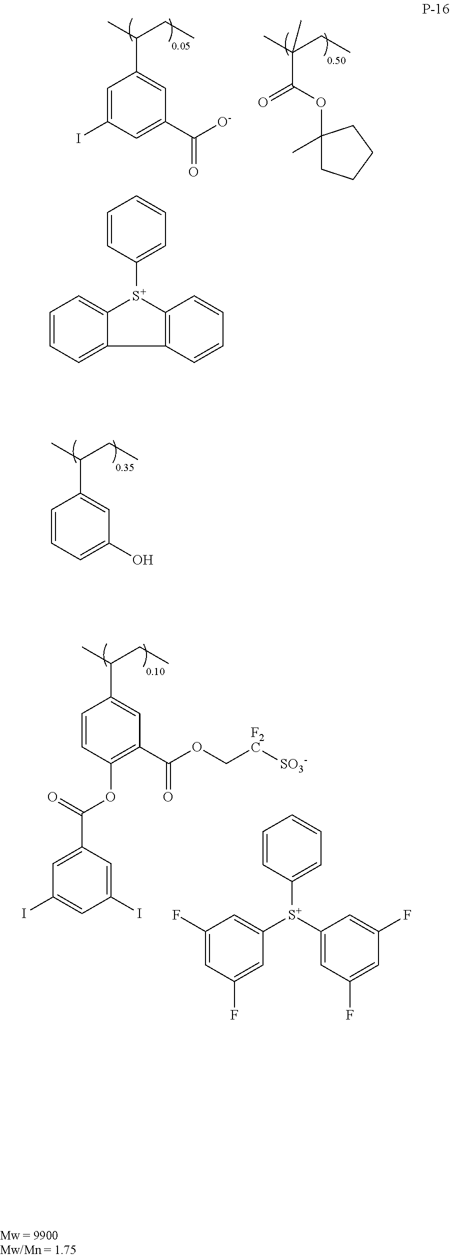

### Comparative Synthesis Example 1

### Synthesis of Comparative Polymer CP-1

Comparative Polymer CP-1 was synthesized by the same procedure as in Synthesis Example 2 aside from omitting Monomer QM-2. The polymer was analyzed by NMR spectroscopy and GPC.

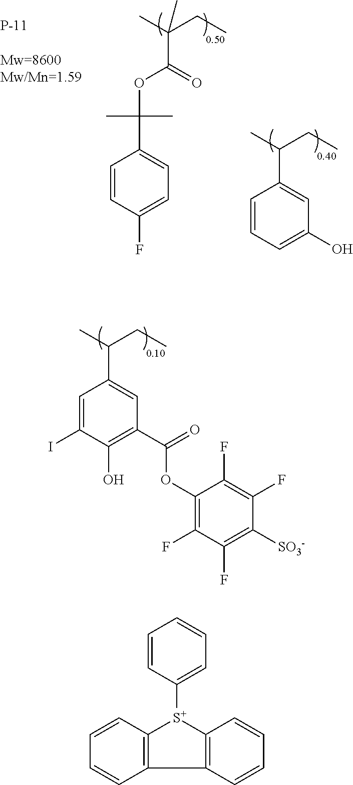

### Comparative Synthesis Example 2

### Synthesis of Comparative Polymer CP-2

A 2-L flask was charged with 3.1 g of Monomer QM-5, 5.7 g of Monomer ALG-2, 2.9 g of 3-hydroxystyrene, 5.0 g of Comparative Monomer CM-1, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Comparative Polymer CP-2. The polymer was analyzed by NMR spectroscopy and GPC.

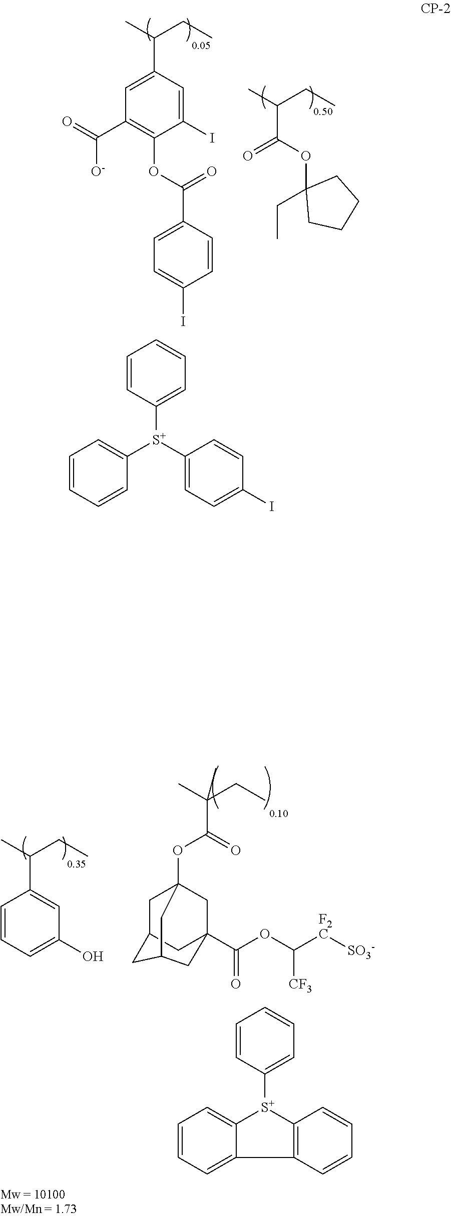

### Comparative Synthesis Example 3

### Synthesis of Comparative Polymer CP-3

A 2-L flask was charged with 3.1 g of Monomer QM-5, 5.7 g of Monomer ALG-2, 2.9 g of 3-hydroxystyrene, 4.9 g of Comparative Monomer CM-2, and 40 g of THE solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Comparative Polymer CP-3. The polymer was analyzed by NMR spectroscopy and GPC.

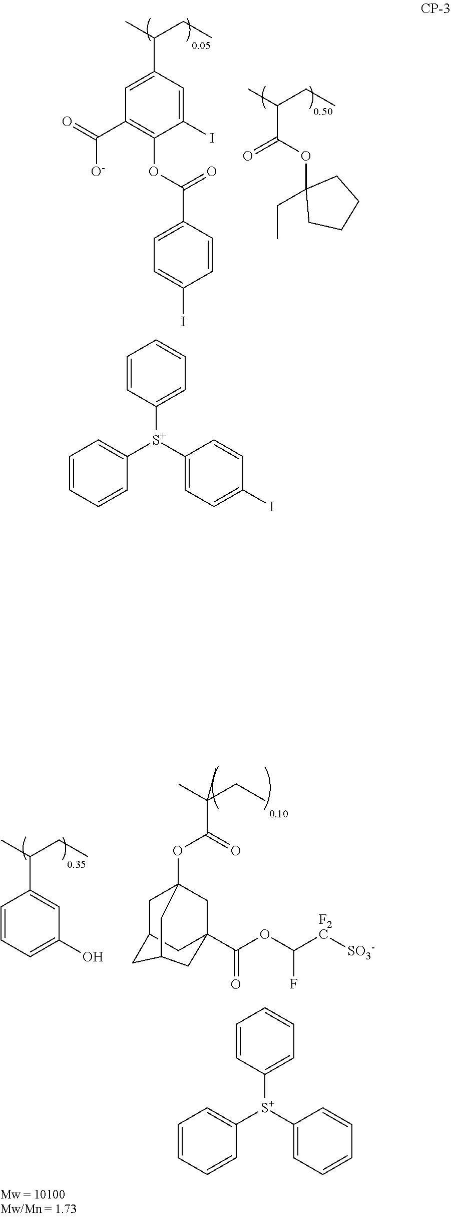

### Comparative Synthesis Example 4

### Synthesis of Comparative Polymer CP-4

A 2-L flask was charged with 2.0 g of Comparative Monomer CM-3, 5.7 g of Monomer ALG-2, 2.9 g of 3-hydroxystyrene, 5.8 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Comparative Polymer CP-4. The polymer was analyzed by NMR spectroscopy and GPC.

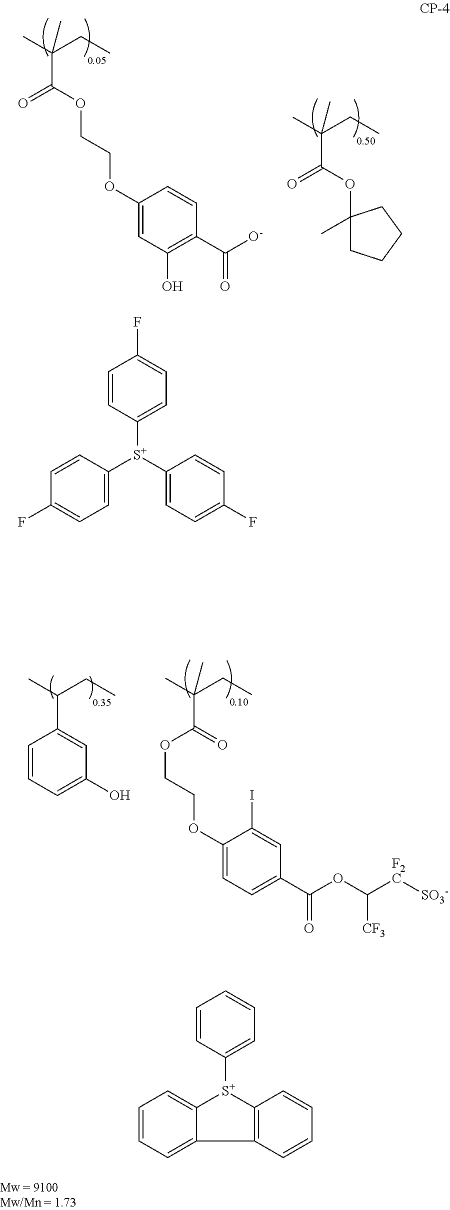

### Comparative Synthesis Example 5

### Synthesis of Comparative Polymer CP-5

A 2-L flask was charged with 1.8 g of Comparative Monomer CM-4, 5.7 g of Monomer ALG-2, 2.9 g of 3-hydroxystyrene, 5.8 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Comparative Polymer CP-5. The polymer was analyzed by NMR spectroscopy and GPC.

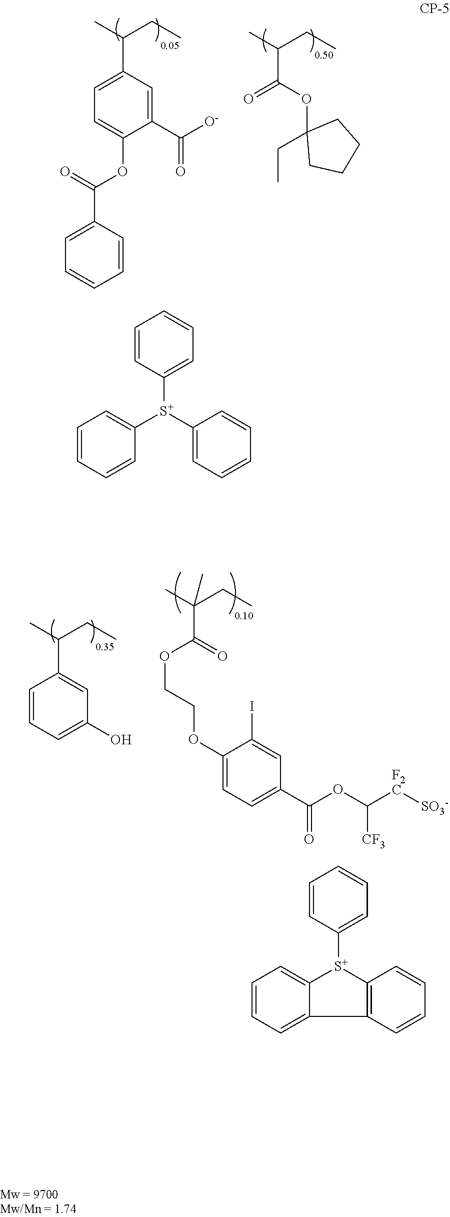

### Comparative Synthesis Example 6

### Synthesis of Comparative Polymer CP-6

Comparative Polymer CP-6 was synthesized by the same procedure as in Synthesis Example 7 aside from omitting Monomers PM-1 and QM-7. The polymer was analyzed by NMR spectroscopy and GPC.

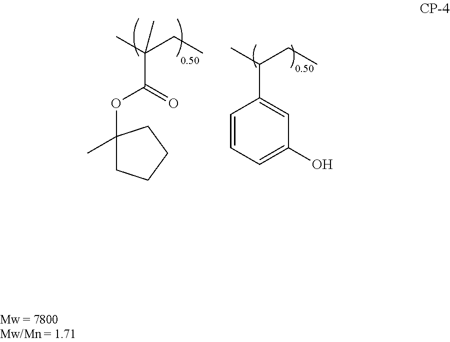

### Examples 1 to 24 and Comparative Examples 1 to 6

### Preparation and Evaluation of Resist Compositions

### (1) Preparation of Resist Compositions

Resist compositions were prepared by dissolving the selected components in a solvent in accordance with the recipe shown in Tables 1 to 3, and filtering through a filter having a pore size of 0.2 μm. The solvent contained 50 ppm of surfactant PolyFox PF-636 (Omnova Solutions Inc.).

The components in Tables 1 to 3 are as identified below.

### Organic Solvents:

PGMEA (propylene glycol monomethyl ether acetate)
DAA (diacetone alcohol)
EL (ethyl lactate)
Acid generator: PAG-1
Quenchers: Q-1 to Q-3

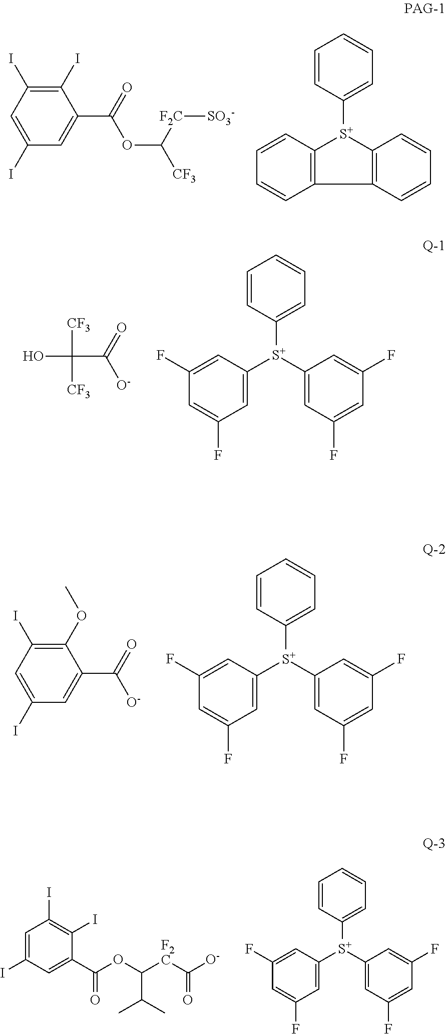

### (2) EUV Lithography Test

Each of the resist compositions in Tables 1 to 3 was spin coated on a silicon substrate having a 20-nm coating of silicon-containing spin-on hard mask SHB-A940 (Shin-Etsu Chemical Co., Ltd., silicon content 43 wt %) and prebaked on a hotplate at 105° C. for 60 seconds to form a resist film of 40 nm thick. Using an EUV scanner NXE3400 (ASML, NA 0.33, σ 0.9/0.6, dipole illumination), the resist film was exposed to EUV through a mask bearing a line- and -space (LS) pattern having a pitch (on-wafer size) of 36 nm. The resist film was baked (PEB) on a hotplate at the temperature shown in Tables 1 to 3 for 60 seconds and developed in a 2.38 wt % TMAH aqueous solution for 30 seconds to form a LS pattern having a size of 18 nm.

The resist pattern was observed under CD-SEM (CG-6300, Hitachi High-Technologies Corp.).

### [Sensitivity]

The optimum dose Eop (mJ/cm²) which provided a LS pattern with a line width of 18 nm and a pitch of 36 nm was determined as an index of sensitivity. A smaller value indicates a higher sensitivity.

### [LWR]

For the LS pattern formed by exposure at the optimum dose Eop, the line width was measured at 10 longitudinally spaced apart points, from which a 3-fold value (3σ) of the standard deviation (σ) was determined and reported as LWR. A smaller value of 30 indicates a pattern having small roughness and uniform line width.

The resist composition is shown in Tables 1 to 3 together with the sensitivity and LWR of EUV lithography.

TABLE 1

| | | Polymer | Acid generator | Quencher | Organic solvent | PEB temp. | Sensitivity | LWR |
|---|---|---|---|---|---|---|---|---|
| | | (pbw) | (pbw) | (pbw) | (pbw) | (° C.) | (mJ/cm²) | (nm) |
| Example | 1 | P-1 | — | — | PGMEA (2000) | 95 | 34.7 | 3.75 |
| | | (80) | | | DAA (500) | | | |
| | | | | | EL (2500) | | | |
| | 2 | P-2 | — | — | PGMEA (2000) | 95 | 34.4 | 3.65 |
| | | (80) | | | DAA (500) | | | |
| | | | | | EL (2500) | | | |
| | 3 | P-3 | — | — | PGMEA (2000) | 95 | 34.1 | 3.60 |
| | | (80) | | | DAA (500) | | | |
| | | | | | EL (2500) | | | |
| | 4 | P-4 | — | — | PGMEA (2000) | 95 | 34.0 | 3.60 |
| | | (80) | | | DAA (500) | | | |
| | | | | | EL (2500) | | | |
| | 5 | P-5 | — | — | PGMEA (2000) | 95 | 34.7 | 3.75 |
| | | (80) | | | DAA (500) | | | |
| | | | | | EL (2500) | | | |
| | 6 | P-6 | — | — | PGMEA (2000) | 95 | 34.9 | 3.75 |
| | | (80) | | | DAA (500) | | | |
| | | | | | EL (2500) | | | |
| | 7 | P-7 | — | — | PGMEA (2000) | 95 | 34.5 | 3.71 |
| | | (80) | | | DAA (500) | | | |
| | | | | | EL (2500) | | | |
| | 8 | P-8 | — | — | PGMEA (2000) | 95 | 34.5 | 3.72 |
| | | (80) | | | DAA (500) | | | |
| | | | | | EL (2500) | | | |
| | 9 | P-9 | — | — | PGMEA (2000) | 95 | 34.7 | 3.75 |
| | | (80) | | | DAA (500) | | | |
| | | | | | EL (2500) | | | |
| | 10 | P-10 | — | — | PGMEA (2000) | 95 | 34.9 | 3.84 |
| | | (80) | | | DAA (500) | | | |
| | | | | | EL (2500) | | | |
| | 11 | P-11 | — | Q-1 | PGMEA (2000) | 95 | 34.3 | 3.58 |
| | | (80) | | (3.7) | DAA (500) | | | |
| | | | | | EL (2500) | | | |
| | 12 | P-12 | — | Q-1 | PGMEA (2000) | 95 | 34.0 | 3.43 |
| | | (80) | | (3.7) | DAA (500) | | | |
| | | | | | EL (2500) | | | |
| | 13 | P-13 | — | Q-1 | PGMEA (2000) | 95 | 33.9 | 3.38 |
| | | (80) | | (3.7) | DAA (500) | | | |
| | | | | | EL (2500) | | | |
| | 14 | P-14 | — | Q-1 | PGMEA (2000) | 95 | 34.3 | 3.55 |
| | | (80) | | (3.7) | DAA (500) | | | |
| | | | | | EL (2500) | | | |
| | 15 | P-11 | — | Q-2 | PGMEA (2000) | 95 | 34.3 | 3.55 |
| | | (80) | | (5.0) | DAA (500) | | | |
| | | | | | EL (2500) | | | |
| | 16 | P-12 | — | Q-2 | PGMEA (2000) | 95 | 34.0 | 3.40 |
| | | (80) | | (5.0) | DAA (500) | | | |
| | | | | | EL (2500) | | | |
| | 17 | P-13 | — | Q-2 | PGMEA (2000) | 95 | 33.9 | 3.35 |
| | | (80) | | (5.0) | DAA (500) | | | |
| | | | | | EL (2500) | | | |
| | 18 | P-14 | — | Q-2 | PGMEA (2000) | 95 | 34.2 | 3.52 |
| | | (80) | | (5.0) | DAA (500) | | | |
| | | | | | EL (2500) | | | |

TABLE 2

| | | Polymer | Acid generator | Quencher | Organic solvent | PEB temp. | Sensitivity | LWR |
|---|---|---|---|---|---|---|---|---|
| | | (pbw) | (pbw) | (pbw) | (pbw) | (° C.) | (mJ/cm²) | (nm) |
| Example | 19 | P-11 | — | Q-3 | PGMEA (2000) | 95 | 34.3 | 3.57 |
| | | (80) | | (6.7) | DAA (500) | | | |
| | | | | | EL (2500) | | | |
| | 20 | P-12 | — | Q-3 | PGMEA (2000) | 95 | 34.0 | 3.42 |
| | | (80) | | (6.7) | DAA (500) | | | |
| | | | | | EL (2500) | | | |
| | 21 | P-13 | — | Q-3 | PGMEA (2000) | 95 | 33.9 | 3.37 |
| | | (80) | | (6.7) | DAA (500) | | | |
| | | | | | EL (2500) | | | |
| | 22 | P-14 | — | Q-3 | PGMEA (2000) | 95 | 34.2 | 3.54 |
| | | (80) | | (6.7) | DAA (500) | | | |
| | | | | | EL (2500) | | | |
| | 23 | P-15 | PAG-1 | — | PGMEA (2000) | 95 | 34.8 | 3.85 |
| | | (80) | (8.0) | | DAA (500) | | | |
| | | | | | EL (2500) | | | |
| | 24 | P-16 | | — | PGMEA (2000) | 95 | 34.8 | 3.66 |
| | | (80) | | | DAA (500) | | | |
| | | | | | EL (2500) | | | |

TABLE 3

| | | Polymer | Acid generator | Quencher | Organic solvent | PEB temp. | Sensitivity | LWR |
|---|---|---|---|---|---|---|---|---|
| | | (pbw) | (pbw) | (pbw) | (pbw) | (° C.) | (mJ/cm²) | (nm) |
| Comparative | 1 | CP-1 | | Q-1 | PGMEA (2000) | 95 | 35.7 | 4.23 |
| Example | | (80) | | (15) | DAA (500) | | | |
| | | | | | EL (2500) | | | |
| | 2 | CP-2 | — | | PGMEA (2000) | 95 | 36.2 | 4.48 |
| | | (80) | | | DAA (500) | | | |
| | | | | | EL (2500) | | | |
| | 3 | CP-3 | — | | PGMEA (2000) | 95 | 36.2 | 4.48 |
| | | (80) | | | DAA (500) | | | |
| | | | | | EL (2500) | | | |
| | 4 | CP-4 | — | | PGMEA (2000) | 95 | 36.0 | 4.38 |
| | | (80) | | | DAA (500) | | | |
| | | | | | EL (2500) | | | |
| | 5 | CP-5 | — | | PGMEA (2000) | 95 | 36.0 | 4.38 |
| | | (80) | | | DAA (500) | | | |
| | | | | | EL (2500) | | | |
| | 6 | CP-6 | PAG-1 | Q-1 | PGMEA (2000) | 95 | 36.8 | 4.78 |
| | | (80) | (20) | (15) | DAA (500) | | | |
| | | | | | EL (2500) | | | |

It is demonstrated in Tables 1 to 3 that resist compositions comprising a base polymer comprising repeat units consisting of an iodized carboxylic acid anion bonded to the backbone and an organic cation and repeat units consisting of an iodized sulfonic acid anion bonded to the backbone and a sulfonium cation have a high sensitivity and form patterns with improved LWR.

Japanese Patent Application No. 2024-103110 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a base polymer comprising repeat units having the formula (a) and repeat units having the formula (b) and an organic solvent, 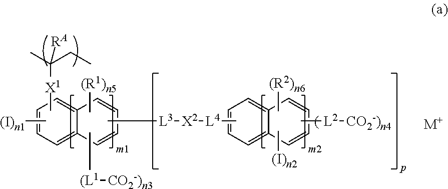
wherein p is 0 or 1, m1 and m2 are each independently 0 or 1,
n1 is 1, 2, 3 or 4 when p=0, n1 and n2 are each independently 0, 1, 2, 3 or 4 and n1+n2≥1 when p=1,
n3 is 1 when p=0, n3 and n4 are each independently 0 or 1 and n3+n4=1 when p=1,
n5 and n6 are each independently 0, 1, 2, 3 or 4,
R^{A} is hydrogen or methyl,
X¹ is a single bond or —C(═O)—O—X¹¹—, X¹¹ is a C₁-C₆ alkanediyl group,
X² is a single bond or C₁-C₆ alkanediyl group,
L¹ is a single bond or a C₁-C₁₂ linking group which contains at least one of ester bond and ether bond and may contain a heteroatom-containing group other than ester bond and ether bond,
L² and L³ are each independently a single bond, ether bond or ester bond,
R¹ and R² are each independently halogen, hydroxy, amino, nitro, a C₁-C₁₂ saturated hydrocarbyloxy group, or an optionally-substituted C₁-C₁₂ organic group which may contain at least one of ester bond and ether bond, a plurality of R¹ may be identical or different when n5 is 2 or more, a plurality of R² may be identical or different when n6 is 2 or more,
M⁺ is a monovalent organic cation, 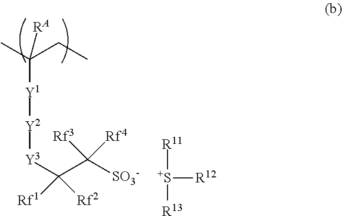
wherein R^{A} is each independently hydrogen or methyl,
Y¹ is a single bond or ester bond,
Y² is —Y²¹—C(═O)—O— or —Y²¹—O—, Y²¹ is a C₁-C₁₂ hydrocarbylene group, phenylene, naphthylene or a C₇-C₁₈ group obtained by combining the foregoing, which contains at least one iodine atom and may contain a carbonyl moiety, ester bond, ether bond, lactone ring, fluorine or bromine,
Y³ is a single bond, methylene group or ethylene group,
Rf¹ to Rf⁴ are each independently hydrogen, fluorine, or trifluoromethyl, at least one of Rf¹ to Rf⁴ being fluorine,
R¹¹, R¹² and R¹³ are each independently halogen or a C₁-C₂₀ hydrocarbyl group which may contain a heteroatom, R¹¹ and R¹² may bond together to form a ring with the sulfur atom to which they are attached.

2. The resist composition of claim 1 wherein L¹ is a single bond.

3. The resist composition of claim 1 wherein X¹ is a single bond.

4. The resist composition of claim 1 wherein M⁺ is a cation having the formula (M-1), (M-2) or (M-3): 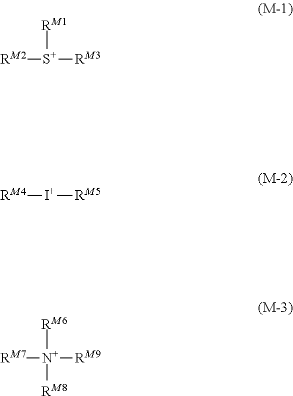
wherein R^{M1} to R^{M9} are each independently halogen or a C₁-C₂₀ hydrocarbyl group which may contain a heteroatom, R^{M1} and R^{M2} may bond together to form a ring with the sulfur atom to which they are attached, any two of R^{M6} to R^{M9} may bond together to form a ring with the nitrogen atom to which they are attached.

5. The resist composition of claim 1 wherein R¹ is hydroxy or a C₁-C₁₂ saturated hydrocarbyloxy group.

6. The resist composition of claim 1 wherein the base polymer further comprises repeat units of at least one type selected from repeat units having the formula (c1) and repeat units having the formula (c2): 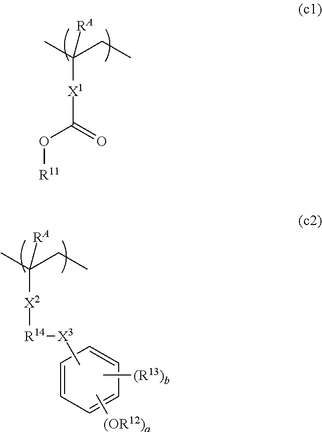
wherein R^{A} is each independently hydrogen or methyl,
Z¹ is a single bond, phenylene group, naphthylene group or a C₁-C₁₂ linking group which contains at least one of ester bond, ether bond and lactone ring,
Z² is a single bond, ester bond or amide bond,
Z³ is a single bond, ether bond or ester bond,
R²¹ and R²² are each independently an acid labile group,
R²³ is fluorine, trifluoromethyl, cyano or a C₁-C₆ saturated hydrocarbyl group,
R²⁴ is a single bond or a C₁-C₆ alkanediyl group in which some —CH₂— may be replaced by an ether bond or ester bond,
a is 1 or 2, and b is 0, 1, 2, 3 or 4.

7. The resist composition of claim 1 wherein the base polymer further comprises repeat units (d) containing an adhesive group selected from hydroxy, carboxy, lactone ring, carbonate bond, thiocarbonate bond, carbonyl group, cyclic acetal group, ether bond, ester bond, sulfonate ester bond, cyano, amide bond, —O—C(═O)—S—, and —O—C(═O)—NH—.

8. The resist composition of claim 1, further comprising at least one additive selected from an acid generator, quencher, and surfactant.

9. The resist composition of claim 8 wherein the additive is a quencher.

10. The resist composition of claim 9 wherein the quencher has the formula (1): 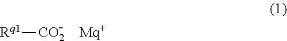
wherein R⁹¹ is a C₁-C₃₀ hydrocarbyl group which may contain a heteroatom, and Mq⁺ is a monovalent organic cation.

11. A pattern forming process comprising the steps of applying the resist composition of claim 1 onto a substrate to form a resist film thereon, exposing the resist film to high-energy radiation, and developing the exposed resist film in a developer.

12. The process of claim 11 wherein the high-energy radiation is i-line, KrF excimer laser, ArF excimer laser, EB or EUV of wavelength 3 to 15 nm.
